(19) United States
(12) Patent Application Publication
(10) Pub. No.: US 2023/0244142 A1
(43) Pub. Date: Aug. 3, 2023

(54) POLYMER, RESIST COMPOSITION, AND PATTERN FORMING METHOD

(71) Applicant: SHIN-ETSU CHEMICAL CO., LTD., Tokyo (JP)

(72) Inventors: Masahiro FUKUSHIMA, Joetsu-shi (JP); Masayoshi SAGEHASHI, Joetsu-shi (JP); Tomohiro KOBAYASHI, Joetsu-shi (JP); Yutaro OTOMO, Joetsu-shi (JP); Koji HASEGAWA, Joetsu-shi (JP)

(73) Assignee: SHIN-ETSU CHEMICAL CO., LTD., Tokyo (JP)

(21) Appl. No.: 18/159,808

(22) Filed: Jan. 26, 2023

(30) Foreign Application Priority Data
Jan. 28, 2022 (JP) 2022-012110

(51) Int. Cl. G03F 7/039; G03F 7/038; C08F 220/18; C08F 220/30; C08F 220/22

(52) U.S. Cl. CPC G03F 7/039; G03F 7/038; C08F 220/1806; C08F 220/301; C08F 220/302; C08F 220/22; C08F 220/1808

(57) ABSTRACT

Provided is a polymer, a resist composition, and a pattern forming method with high sensitivity, high resolution, and high contrast, and that can form a pattern with small variation in pattern width (LWR), and small in-plane uniformity of the pattern (CDU) with high energy ray. A polymer to generate an acid by light exposure and to change in solubility in a developing liquid with an action of the acid, the polymer including: a repeating unit represented by the following formula (A-1); and a repeating unit represented by any one or more of the following formulae (B-1) to (B-4),

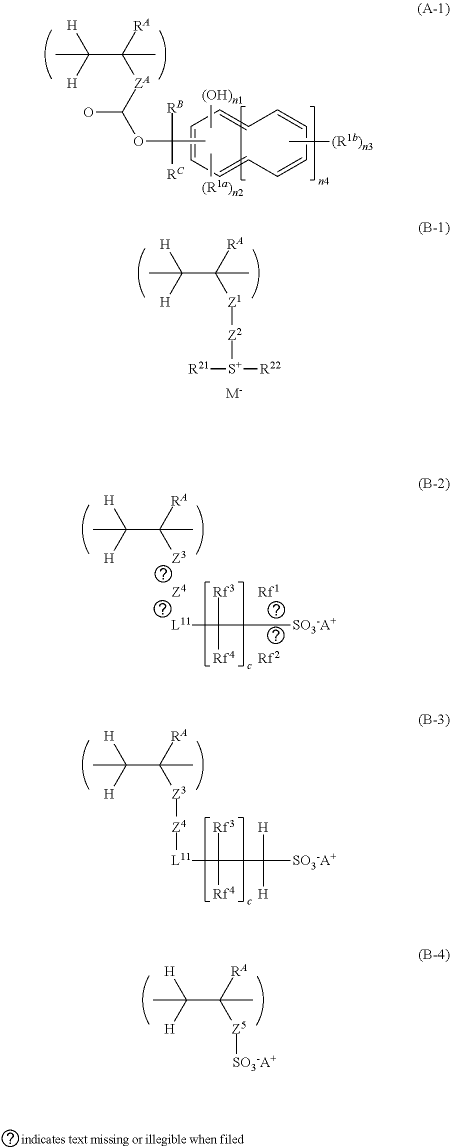

wherein, M⁻ represents a non-nucleophilic counterion, A⁺ represents an onium cation, n1 represents an integer of 1 or 2, n2 represents an integer of 0 to 2, n3 represents an integer of 0 to 5, n4 represents an integer of 0 to 2, and “c” represents an integer of 0 to 3.

### TECHNICAL FIELD

The present invention relates to a polymer, a resist composition, and a pattern forming method using the resist composition.

### BACKGROUND ART

In recent years, fine pattern formation have been required as higher integration of integrated circuits. In processing a pattern with 0.2 μm or smaller, a chemically amplified resist, which uses an acid as a catalyst, is generally used. In this case, high-energy ray such as ultraviolet ray, far ultraviolet ray, and electron beam (EB) is used as an exposure light source. In particular, electron beam lithography, which is used as an ultrafine processing technology, has been essential also as a method for processing a photomask blank used in producing a photomask for semiconductor manufacturing.

Although polymers having many aromatic skeletons having an acidic side chain, for example polyhydroxystyrene, have been suitably used as a resist material for KrF excimer laser, such polymers absorb light having a wavelength of near 200 nm, and thereby have not been used as the resist material for ArF excimer laser. However, such a polymer is an important material as a resist composition for EB lithography and a resist composition for extreme ultraviolet (EUV) lithography, which are useful technologies for forming a pattern smaller than the process limit of the ArF excimer laser, in terms of achievement of high etching resistance.

Mainly used as a base polymer of a positive resist composition for EB lithography or resist composition for EUV lithography is a material in which an acid generated from a photoacid generator by irradiating high-energy ray catalyzes deprotection of an acid-decomposable protective group masking an acidic functional group in a phenol side chain contained in the base polymer to allow the base polymer to be dissolved in an alkaline developing liquid. As the acid-decomposable protective group, a tertiary alkyl group, a tert-butoxycarbonyl group, an acetal group, etc. have been used. Use of a protective group having a relatively low activation energy required for the deprotection, such as an acetal group, has an advantage of availability of a highly sensitive resist film. However, if inhibition of diffusion of the generated acid is insufficient, the deprotection reaction also proceeds in an unexposed part in the resist film, leading to a problem of deterioration of line edge roughness (LER), and decrease in in-plane uniformity (CDU) of the pattern.

Regulations of the resist sensitivity and pattern profile have been variously improved by selection and combination of the materials used for the resist composition, the process condition, etc. One of the improvement involves the acid diffusion problem that considerably affects resolution of the chemically amplified resist composition. Since this acid diffusion problem considerably affects the sensitivity and the resolution, many investigations have been made.

In addition, to improve the sensitivity, it has been attempted to introduce a multiple bond or an aromatic ring into the acid-labile group of the base polymer in the resist composition. The introduction of these substituents improves performance to a certain degree, but a sufficient result still has not been obtained. Since an ally cation and benzyl cation, which are generated after the acid elimination reaction, are more stable than a typical carbocation, a base polymer designed to generate a primary or secondary benzyl cation after the acid elimination reaction is investigated. However, such a base polymer has insufficient reactivity to the acid, and thereby the performance has not been sufficiently improved. Conversely, a tertiary allyl cation and tertiary benzyl cation, which are generated after the acid elimination reaction, have high reactivity to the acid, and in a part thereof, it is observed that a thermal elimination reaction proceeds during polymerization of the base polymer. Thus, such a base polymer still remains a problem in a polymer production process (Patent Documents 1 to 12).

### CITATION LIST

### Patent Literature

Patent Document 1: JP 2013-53196 A
Patent Document 2: JP 2018-92159 A
Patent Document 3: JP 2008-268741 A
Patent Document 4: JP 2019-120759 A
Patent Document 5: JP 2020-085917 A
Patent Document 6: JP 6782569 B
Patent Document 7: JP 2019-214554 A
Patent Document 8: JP 2002-156761 A
Patent Document 9: JP 2006-030232 A
Patent Document 10: JP 2019-008287 A
Patent Document 11: JP 2019-038998 A
Patent Document 12: JP 2019-074733 A

### SUMMARY OF INVENTION

### Technical Problem

The present invention has been made in view of the above-described circumstances. An object of the present invention is to provide a polymer, a resist composition, and a pattern forming method using the composition that can form a pattern with high sensitivity, high resolution, and high contrast, and with small variation of a pattern width (LWR) and in-plane uniformity (CDU) of the pattern particularly by using high-energy ray.

### Solution to Problem

To solve the above problems, the present invention provides a polymer to generate an acid by light exposure and to change in solubility in a developing liquid with an action of the acid, the polymer comprising:

a repeating unit represented by the following formula (A-1); and

a repeating unit represented by any one or more of the following formulae (B-1) to (B-4),

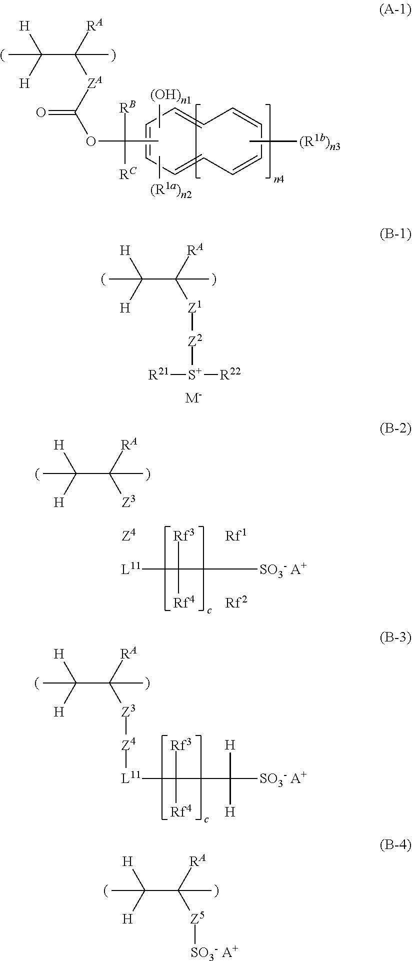

wherein R^{A} represents a hydrogen atom, a fluorine atom, a methyl group, or a trifluoromethyl group; Z^{A} represents a single bond, (main chain)-C(═O)—O—Z^{A1}—, or a phenylene group or a naphthylene group each of which may have an alkoxy group having 1 to 10 carbon atoms and optionally having a fluorine atom, or a halogen atom; Z^{A1} represents a linear, branched, or cyclic alkanediyl group having 1 to 20 carbon atoms, phenylene group, or naphthylene group optionally having a heteroatom, an alkoxy group having 1 to 10 carbon atoms and optionally having a fluorine atom, a hydroxy group, an ether bond, an ester bond, or a lactone ring; R^{B} and R^{C} each independently represents a linear, branched, or cyclic hydrocarbyl group having 1 to 10 carbon atoms and optionally having a heteroatom, R^{B} and R^{C} are optionally bonded to each other to form a cyclic structure; R^{1a} each independently represents any one of a halogen atom, a cyano group, an acyl group having 1 to 5 carbon atoms, an alkoxy group having 1 to 5 carbon atoms, a fluorine-containing alkyl group having 1 to 5 carbon atoms, or a fluorine-containing alkoxy group having 1 to 5 carbon atoms; R^{1b} each independently represents a linear, branched, or cyclic hydrocarbyl group having 1 to 10 carbon atoms and optionally having a heteroatom; n1 represents an integer of 1 or 2; n2 represents an integer of 0 to 2; n3 represents an integer of 0 to 5; and n4 represents an integer of 0 to 2;

Z¹ represents a single bond or a phenylene group;

Z² represents a single bond, —C(═O)—O—Z²¹—, —C(═O)—NH—Z²¹—, or —O—Z²¹—; Z²¹ represents an aliphatic hydrocarbylene group having 1 to 6 carbon atoms, a phenylene group, or a divalent group obtained by combining these groups, and Z²¹ optionally has a carbonyl group, an ester bond, an ether bond, or a hydroxy group;

Z³ represents a single bond, a phenylene group, a naphthylene group, or (main chain)-C(═O)—O—Z³¹—; Z³¹ represents an aliphatic hydrocarbylene group having 1 to 10 carbon atoms, or a phenylene group or a naphthylene group optionally having a hydroxy group, an ether bond, an ester bond, or a lactone ring;

Z⁴ represents a single bond, a methylene group, or —Z⁴¹—C(═O)—O—; Z⁴¹ represents a hydrocarbylene group having 1 to 20 carbon atoms and optionally having a heteroatom, an ether bond, or an ester bond;

Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—; Z⁵¹ represents an aliphatic hydrocarbylene group having 1 to 6 carbon atoms, a phenylene group, a fluorinated phenylene group, or a phenylene group substituted with a trifluoromethyl group, and Z⁵¹ optionally has a carbonyl group, an ester bond, an ether bond, or a hydroxy group;

R²¹ and R²² each independently represents a hydrocarbyl group having 1 to 20 carbon atoms and optionally having a heteroatom, and R²¹ and R²² are optionally bonded to each other to form a ring together with a sulfur atom to which R²¹ and R²² are bonded;

L¹¹ represents a single bond, an ether bond, an ester bond, a carbonyl group, a sulfonic acid ester bond, a carbonate bond, or a carbamate bond;

Rf¹ and Rf² each independently represents a fluorine atom or a fluorinated alkyl group having 1 to 6 carbon atoms;

Rf³ and Rf⁴ each independently represents a hydrogen atom, a fluorine atom, or a fluorinated alkyl group having 1 to 6 carbon atoms;

M⁻ represents a non-nucleophilic counterion;

A⁺ represents an onium cation; and

“c” represents an integer of 0 to 3.

In such a polymer, the repeating unit A having the acid-labile group having a phenolic hydroxy group contributes to the change of solubility in a developing liquid. Both of the acid-labile unit and a sensitizer unit to generate a secondary electron can be increased in the base polymer. The repeating unit B, which generates an acid by light exposure, can inhibit excessive acid diffusion, and can inhibit diffusion of secondary electrons generated at the sensitizer portion.

Therefore, such a polymer can simultaneously achieve high sensitivity, high resolution, and high contrast with high-energy ray. The polymer can also provide: a resist material that can form a pattern with low LWR and CDU; and a pattern forming method using this resist material.

The repeating unit represented by the formula (A-1) is preferably a repeating unit represented by the following formula (A-2),

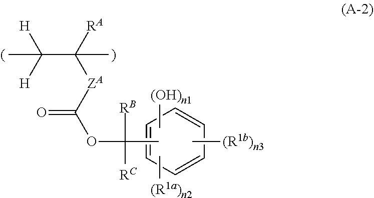

wherein R^{A}, Z^{A}, R^{B}, R^{C}, R^{1a}, R^{1b}, n1, n2, and n3 are same as the above.

Such a polymer can yield a polymer having good solvent solubility.

R^{1a} in the formula (A-1) preferably represents any one of a fluorine atom, a trifluoromethyl group, and a trifluoromethoxy group.

Such a polymer can yield a polymer that is good for lithography with high-energy ray.

A⁺ in the formulae (B-2) to (B-4) preferably represents a cation represented by the following formula (cation-1) or (cation-2),

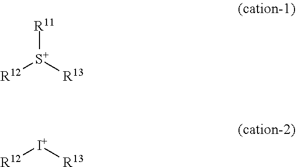

wherein R¹¹, R¹², and R¹³ each independently represents a linear, branched, or cyclic monovalent hydrocarbon group having 1 to 30 carbon atoms and optionally having a heteroatom, and any two of R¹¹, R¹², and R¹³ are optionally bonded to each other to form a ring together with the sulfur atom in the formula; and R¹⁴ and R¹⁵ each independently represents a linear, branched, or cyclic monovalent hydrocarbon group having 1 to 20 carbon atoms and optionally having a heteroatom.

Such a polymer can yield a polymer that is good for lithography with high-energy ray.

The above polymer preferably further comprises a repeating unit represented by the following formula (a-1) or (a-2),

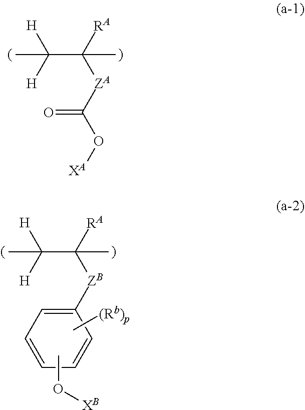

wherein R^{A} and Z^{A} are same as above; Z^{B} represents a single bond, (main chain)-C(═O)—O—, or an alkanediyl group having 1 to 10 carbon atoms and optionally having an ester group, an ether group, or a carbonyl group; R^{b} represents a linear, branched, or cyclic hydrocarbyl group having 1 to 20 carbon atoms and optionally having a heteroatom, a halogen atom, an alkoxy group optionally having a fluorine, or a cyano group; “p” represents an integer of 0 to 4; and X^{A} and X^{B} each independently represents an acid-labile group having no fluorine-containing aromatic ring.

Such a polymer can yield a polymer that is good for lithography with high-energy ray.

The above polymer preferably further comprises a repeating unit represented by the following formula (C-1),

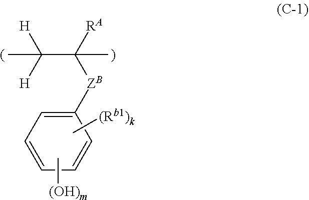

wherein R^{A} is same as above; Z^{B} represents a single bond, (main chain)-C(═O)—O—, or an alkanediyl group having 1 to 10 carbon atoms and optionally having an ester group, an ether group, or a carbonyl group; R^{b1} represents a halogen atom, a cyano group, a hydrocarbyl group having 1 to 20 carbon atoms and optionally having a heteroatom, a hydrocarbyloxy group having 1 to 20 carbon atoms and optionally having a heteroatom, a hydrocarbylcarbonyl group having 2 to 20 carbon atoms and optionally having a heteroatom, a hydrocarbylcarbonyloxy group having 2 to 20 carbon atoms and optionally having a heteroatom, or a hydrocarbyloxycarbonyl group having 2 to 20 carbon atoms and optionally having a heteroatom; “m” represents an integer of 1 to 4; “k” represents an integer of 0 to 3; and “m+k” represents an integer of 4 or less.

Such a polymer can yield a polymer that is good for lithography with high-energy ray.

The above polymer preferably further comprises a repeating unit represented by the following formula (D-1),

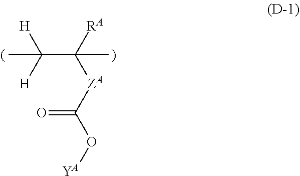

wherein R^{A} and Z^{A} are same as above; and Y^{A} represents a hydrogen atom or a polar group having at least one or more structures selected from a hydroxy group, a cyano group, a carbonyl group, a carboxy group, an ether bond, an ester bond, a sulfonic acid ester bond, a sulfonic acid amide bond, a carbonate bond, a lactone ring, a sultone ring, a sulfur atom, and a carboxylic anhydride.

Such a polymer can yield a polymer that is good for lithography with high-energy ray.

The present invention provides a resist composition comprising the above polymer.

Such a resist composition can provide a resist material having high sensitivity, high resolution, and high contrast with high-energy ray, and that can form a pattern with low LWR and CDU.

The above resist composition preferably further comprises an organic solvent.

Such a resist composition can yield a resist composition that is good for lithography with high-energy ray.

The above resist composition preferably further comprises a photoacid generator other than a photoacid generator bonded to the polymer chain.

Such a resist composition can yield a resist composition that is good for lithography with high-energy ray.

The above resist composition preferably further comprises a quencher.

Such a resist composition can yield a resist composition that is good for lithography with high-energy ray.

The above resist composition preferably further comprises: a surfactant insoluble or hardly soluble in water and soluble in an alkaline developing liquid; and/or a surfactant insoluble or hardly soluble in water and an alkaline developing liquid.

Such a resist composition can yield a resist composition that is good for lithography with high-energy ray.

The present invention provides a pattern forming method, comprising:

(i) a step of forming a resist film on a substrate using the above resist composition;

(ii) a step of exposing the resist film with a high-energy ray; and

(iii) a step of developing the exposed resist film with a developing liquid.

Such a pattern forming method can provide a pattern forming method having high sensitivity, high resolution, and high contrast with high-energy ray, and that can form a pattern with low LWR and CDU.

The high-energy ray in the step (ii) is preferably i-line, KrF excimer laser light, ArF excimer laser light, electron beam, or extreme ultraviolet having a wavelength of 3 to 15 nm.

For the inventive pattern forming method, such high-energy ray can be used.

The developing liquid in the step (iii) can be an alkaline aqueous solution, and an exposed part can be dissolved to obtain a positive pattern with undissolved not-exposure part.

The developing liquid in the step (iii) can be an organic solvent, and a non-exposed part can be dissolved to obtain a negative pattern with undissolved exposure part.

The inventive resist composition can form any of positive type and negative type patterns by selecting the development liquid.

### Advantageous Effects of Invention

As described above, using the inventive polymer, the resist composition and the pattern forming method comprising the polymer, a resist pattern having high sensitivity, low LWR and CDU, high contrast, excellent resolution, and wide process margin can be obtained.

### DESCRIPTION OF EMBODIMENTS

As described above, there have been demands for the developments of an acid-catalyzed chemically amplified resist composition that achieves further higher sensitivity and resolution, and that improves line LWR and hole CDU.

The present inventors have earnestly studied to achieve the above object and consequently found that use of a resist material comprising a polymer having: a repeating unit having a phenolic hydroxy group as an acid-labile group; and a repeating unit to generate an acid by light exposure can form a pattern with high sensitivity, high contrast, excellent resolution, and excellent LWR of a line pattern, excellent CDU of a hole pattern, and wide process margin. This finding has led to the completion of the present invention.

Specifically, the present invention is a polymer to generate an acid by light exposure and to change in solubility in a developing liquid with an action of the acid, the polymer comprising:

a repeating unit represented by the following formula (A-1); and

a repeating unit represented by any one or more of the following formulae (B-1) to (B-4),

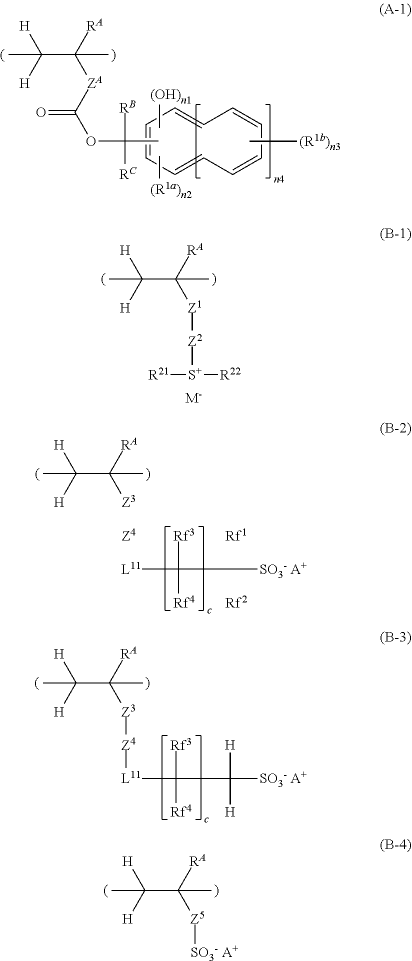

wherein R^{A} represents a hydrogen atom, a fluorine atom, a methyl group, or a trifluoromethyl group; Z^{A} represents a single bond, (main chain)-C(═O)—O—Z^{A1}—, or a phenylene group or a naphthylene group each of which may have an alkoxy group having 1 to 10 carbon atoms and optionally having a fluorine atom, or a halogen atom; Z^{A1} represents a linear, branched, or cyclic alkanediyl group having 1 to 20 carbon atoms, phenylene group, or naphthylene group optionally having a heteroatom, an alkoxy group having 1 to 10 carbon atoms and optionally having a fluorine atom, a hydroxy group, an ether bond, an ester bond, or a lactone ring; R^{B} and R^{C} each independently represents a linear, branched, or cyclic hydrocarbyl group having 1 to 10 carbon atoms and optionally having a heteroatom, R^{B} and R^{C} are optionally bonded to each other to form a cyclic structure; R^{1a} each independently represents any one of a halogen atom, a cyano group, an acyl group having 1 to 5 carbon atoms, an alkoxy group having 1 to 5 carbon atoms, a fluorine-containing alkyl group having 1 to 5 carbon atoms, or a fluorine-containing alkoxy group having 1 to 5 carbon atoms; R^{1b} each independently represents a linear, branched, or cyclic hydrocarbyl group having 1 to 10 carbon atoms and optionally having a heteroatom; n1 represents an integer of 1 or 2; n2 represents an integer of 0 to 2; n3 represents an integer of 0 to 5; and n4 represents an integer of 0 to 2;

Z¹ represents a single bond or a phenylene group;

Z² represents a single bond, —C(═O)—O—Z²¹—, —C(═O)—NH—Z²¹—, or —O—Z²¹—; Z²¹ represents an aliphatic hydrocarbylene group having 1 to 6 carbon atoms, a phenylene group, or a divalent group obtained by combining these groups, and Z²¹ optionally has a carbonyl group, an ester bond, an ether bond, or a hydroxy group;

Z³ represents a single bond, a phenylene group, a naphthylene group, or (main chain)-C(═O)—O—Z³¹—; Z³¹ represents an aliphatic hydrocarbylene group having 1 to 10 carbon atoms, or a phenylene group or a naphthylene group optionally having a hydroxy group, an ether bond, an ester bond, or a lactone ring;

Z⁴ represents a single bond, a methylene group, or —Z⁴¹—C(═O)—O—; Z⁴¹ represents a hydrocarbylene group having 1 to 20 carbon atoms and optionally having a heteroatom, an ether bond, or an ester bond;

Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—; Z⁵¹ represents an aliphatic hydrocarbylene group having 1 to 6 carbon atoms, a phenylene group, a fluorinated phenylene group, or a phenylene group substituted with a trifluoromethyl group, and Z⁵¹ optionally has a carbonyl group, an ester bond, an ether bond, or a hydroxy group;

R²¹ and R²² each independently represents a hydrocarbyl group having 1 to 20 carbon atoms and optionally having a heteroatom, and R²¹ and R²² are optionally bonded to each other to form a ring together with a sulfur atom to which R²¹ and R²² are bonded;

L¹¹ represents a single bond, an ether bond, an ester bond, a carbonyl group, a sulfonic acid ester bond, a carbonate bond, or a carbamate bond;

Rf¹ and Rf² each independently represents a fluorine atom or a fluorinated alkyl group having 1 to 6 carbon atoms;

Rf³ and Rf⁴ each independently represents a hydrogen atom, a fluorine atom, or a fluorinated alkyl group having 1 to 6 carbon atoms;

M⁻ represents a non-nucleophilic counterion;

A⁺ represents an onium cation; and

“c” represents an integer of 0 to 3.

Hereinafter, the present invention will be described in detail, but the present invention is not limited thereto.

### [Polymer (Base Polymer)]

The inventive polymer comprises: a repeating unit having an acid-labile group having a phenolic hydroxy group; and a repeating unit to generate an acid by light exposure.

### [Repeating Unit a Having Acid-Labile Group Having Phenolic Hydroxy Group]

The inventive polymer (base polymer) comprises the repeating unit having an acid-labile group having a phenolic hydroxy group (hereinafter, which may be referred to as the repeating unit A). The repeating unit A is represented by the following formula (A-1).

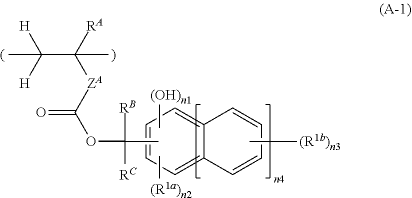

In the formula (A-1), R^{A} each independently represents a hydrogen atom, a fluorine atom, a methyl group, or a trifluoromethyl group.

Z^{A} represents a single bond, (main chain)-C(═O)—O—Z^{A1}—, or a phenylene group or a naphthylene group each of which may have an alkoxy group having 1 to 10 carbon atoms and optionally having a fluorine atom, or a halogen atom. Z^{A1} represents a linear, branched, or cyclic alkanediyl group having 1 to 20 carbon atoms (aliphatic hydrocarbylene group), phenylene group, or naphthylene group optionally having a heteroatom, an alkoxy group having 1 to 10 carbon atoms and optionally having a fluorine atom, a hydroxy group, an ether bond, an ester bond, or a lactone ring.

The alkanediyl group may be a saturated or unsaturated group, and may be any of linear, branched, and cyclic groups. Specific examples thereof include: alkanediyl groups, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-1,1-diyl group, a butane-1,2-diyl group, a butane-1,3-diyl group, a butane-2,3-diyl group, a butane-1,4-diyl group, an 1,1-dimethylethane-1,2-diyl group, a pentane-1,5-diyl group, a 2-methylbutane-1,2-diyl group, a hexane-1,6-diyl group, a heptane-1,7-diyl group, an octane-1,8-diyl group, a nonane-1,9-diyl group, and a decane-1,10-diyl group; cycloalkanediyl groups, such as a cyclopropanediyl group, a cyclobutene-1,1-diyl group, a cyclobutanediyl group, a cyclopentanediyl group, and a cyclohexanediyl group; divalent multicyclic saturated hydrocarbon groups, such as an adamantanediyl group and a norbornanediyl group; and divalent groups obtained by combining these groups.

Examples of the structure with a changed Z^{A} in the formula (A-1) include structures represented by the following formulae, but the structure is not limited thereto. In the following formulae, R^{A} is same as above, and a broken line represents a bond to the carbon atom bonded to R^{B} and R^{C} in the formula (A-1).

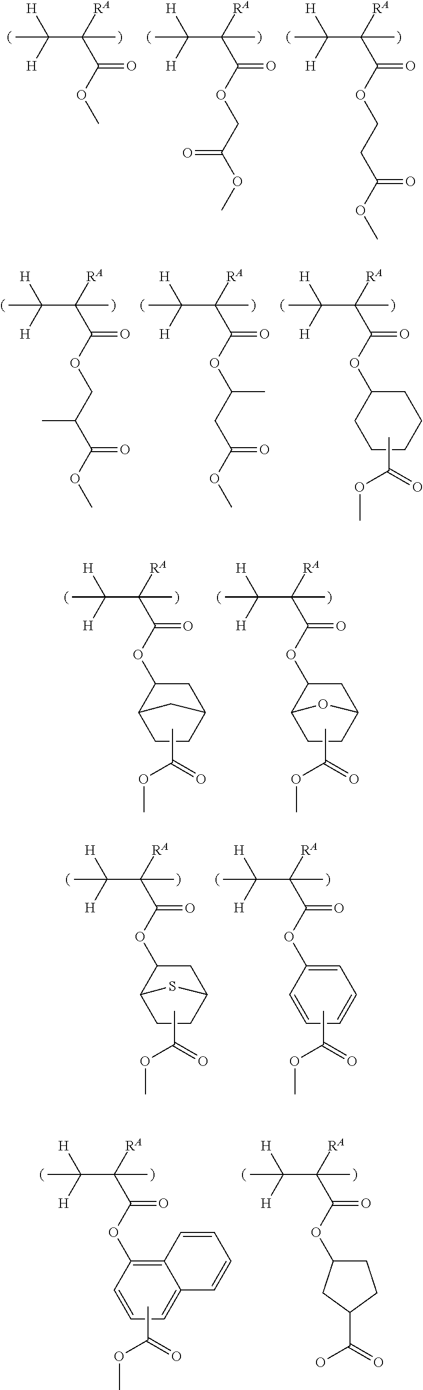

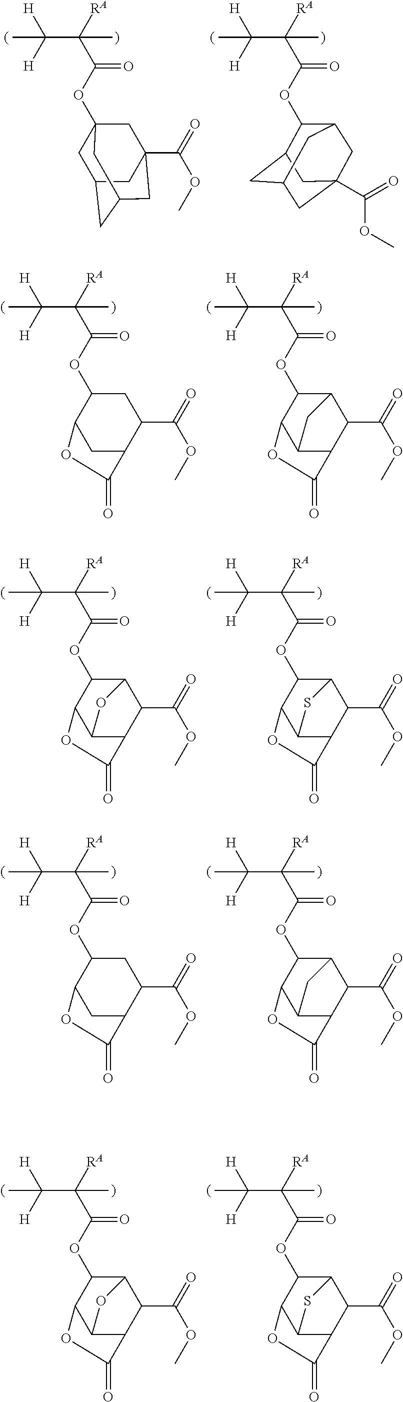

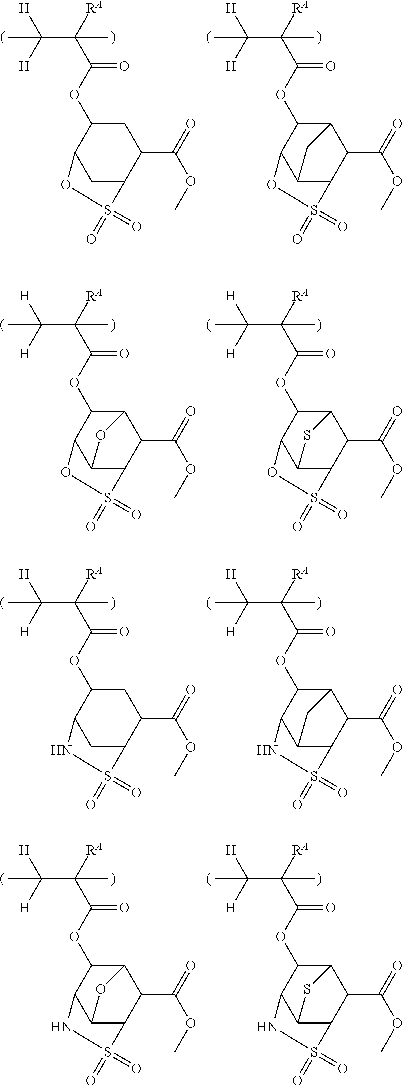

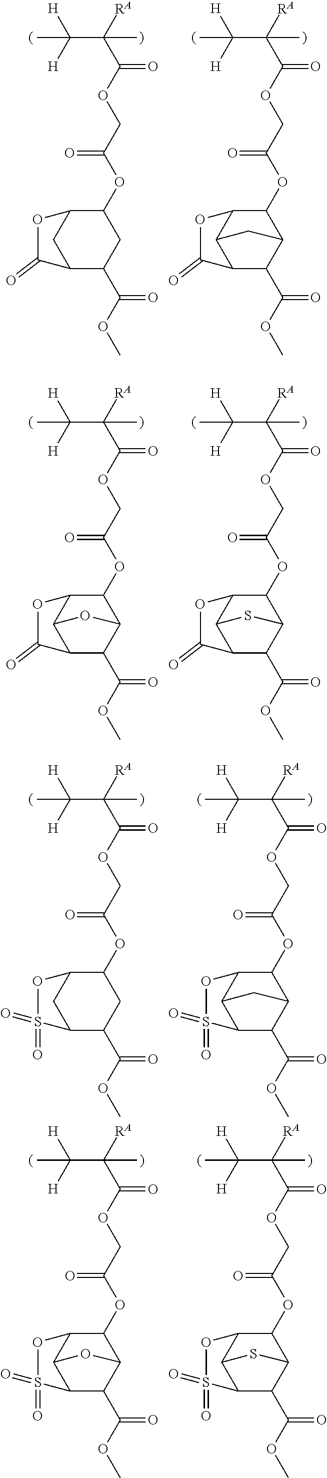

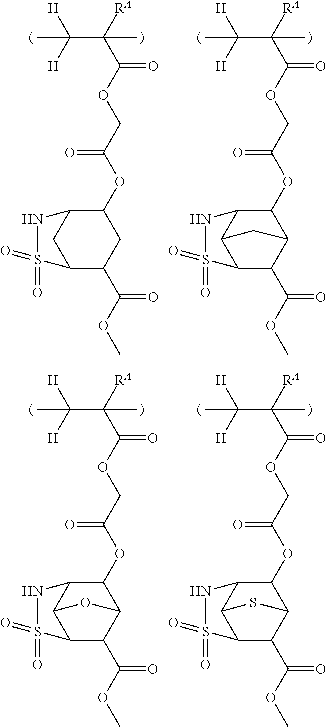

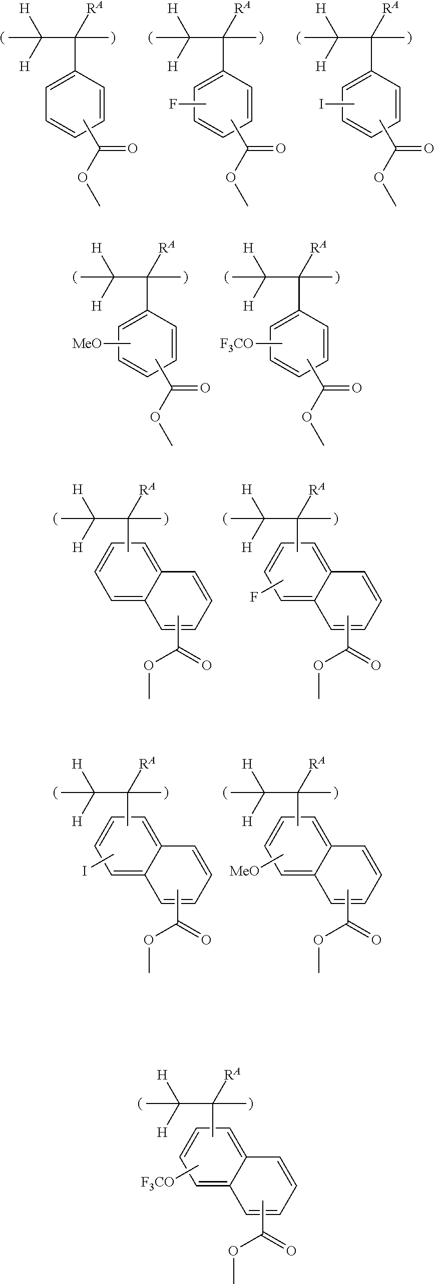

In the formula (A-1), R^{B} and R^{C} each independently represent a linear, branched, or cyclic hydrocarbyl group having 1 to 10 carbon atoms and optionally having a heteroatom. Specific examples thereof include alkyl groups, such as a methyl group, an ethyl group, a propyl group, an isopropyl group, an n-butyl group, a s-butyl group, a t-butyl group, a cyclopentyl group, a cyclohexyl group, a 2-ethylhexyl group, an n-octyl group, a norbornyl group, a tricyclodecanyl group, and an adamantyl group.

In the formula (A-1), R^{B} and R^{C} are optionally bonded each other to form a cyclic structure. Specific examples thereof include a cyclopropane ring, a cyclobutane ring, a cyclopentane ring, and a cyclohexane ring. Among these, a cyclopentane ring and cyclohexane ring are preferable.

In the formula (A-1), “n1” represents an integer of 1 or 2, and is preferably n1=1.

In the formula (A-1), R^{1a} each independently represents any of a halogen atom, a cyano group, an acyl group having 1 to 5 carbon atoms, an alkoxy group having 1 to 5 carbon atoms, a fluorine-containing alkyl group having 1 to 5 carbon atoms, and a fluorine-containing alkoxy group having 1 to 5 carbon atoms. Among these, a fluorine atom or a fluorine-containing alkoxy group having 1 to 5 carbon atoms are preferable, and a fluorine atom, a trifluoromethyl group, and a trifluoromethoxy group are further preferable.

In the formula (A-1), “n2” represents an integer of 0 to 2.

In the formula (A-1), R^{1b} each independently represent a linear, branched, or cyclic hydrocarbyl group having 1 to 10 carbon atoms and optionally having a heteroatom. Specific examples thereof include groups same as R^{B} and R^{C}.

“n3” represents an integer of 0 to 5, and preferably 0 or 1.

“n4” represents an integer of 0 to 2. “n4=0” represents a benzene ring, “n4=1” represents an naphthalene ring, and “n4=2” represents an anthracene ring. From the viewpoint of the solvent solubility, “n4=0” being a benzene ring is preferable.

The repeating unit A represented by the formula (A-1) is more preferably represented by the following formula (A-2),

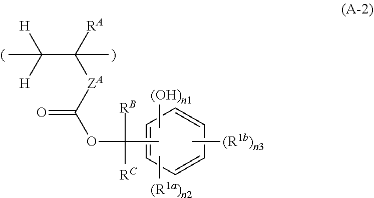

wherein R^{A}, Z^{A}, R^{B}, R^{C}, R^{1a}, R^{1b}, n1, n2, and n3 are same as above.

### [Synthesis of Monomer A Represented by Formula (A-1)]

The repeating unit A represented by the formulae (A-1) and (A-2) can be produced from a monomer A-1 obtained in accordance with the following scheme, for example. Hereinafter, synthesis of a monomer represented by the following formula (Monomer A-1) will be described, but the synthesis method is not limited thereto.

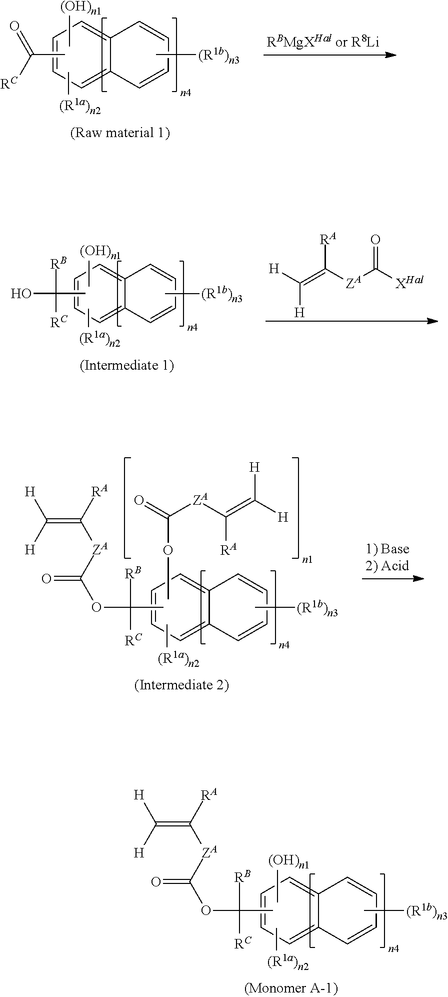

In the formulae, R^{A}, Z^{A}, R^{B}, R^{C}, R^{1a}, R^{1b}, n1, n2, n3, and n4 are same as above. H^{hal} represents a halogen atom except for a fluorine atom.

The first step is a step of reacting a ketone compound (raw material 1) with a Grignard reagent or an organolithium reagent to obtain a tertiary benzyl alcohol (intermediate 1). The ketone compound is a commercially available compound or can be synthesized by a known synthetic method.

The reaction can be proceeded by a known organic synthesis method. Specifically, the ketone compound (raw material 1) diluted with a used solvent is added dropwise to the Grignard reagent or the organolithium reagent, which is a commercially available reagent or prepared by a known procedure. The reaction temperature is from a room temperature to a boiling point of the used solvent. The reaction is desirably monitored by gas chromatography (GC) or silica-gel thin-layer chromatography (TLC) to complete the reaction in terms of yield, and the reaction time is typically approximately 30 minutes to 2 hours. A common aqueous work-up of the reaction mixture can yield the tertiary benzyl alcohol (intermediate 1). The obtained tertiary benzyl alcohol (intermediate 1) can be purified, as necessary, by a common method such as distillation, chromatography, and recrystallization.

The second step is a step of introducing a polymerizable group via an ester bond into the tertiary benzyl alcohol (intermediate 1), obtained in the first step, to obtain the intermediate 2.

The reaction can be proceeded by a known organic synthesis method. Specifically, the tertiary alcohol being the intermediate 1 is dissolved in a solvent, such as toluene, hexane, THF, and acetonitrile, in the presence of an organic base, such as triethylamine and pyridine, and an acid halide such as methacryloyl chloride and acryloyl chloride is added dropwise thereto to proceed the reaction. To increase the reaction rate, 4-dimethylaminopyridine may be added. The reaction temperature is from 5° C. to a boiling point of the used solvent. The reaction is desirably monitored by gas chromatography (GC) or silica-gel thin-layer chromatography (TLC) to complete the reaction in terms of yield, and the reaction time is typically approximately 1 hour to 24 hours. A common aqueous work-up of the reaction mixture can yield the intermediate 2. The obtained intermediate 2 can be purified, as necessary, by common method such as distillation, chromatography, and recrystallization.

The third step is a step of hydrolyzing only the aromatic ester bond of the intermediate 2, obtained in the second step, using a base to obtain a monomer A-1.

The reaction can be proceeded by a known organic synthesis method. Specifically, the intermediate 2 is dissolved in a solvent, such as 1,4-dioxane and THF, and the base is added dropwise thereinto to proceed the reaction. Examples of the used base include an aqueous solution of an inorganic base, such as sodium hydroxide, potassium hydroxide, and potassium carbonate. The reaction temperature is preferably within a range from under ice cooling to 60° C. The reaction is desirably monitored by gas chromatography (GC) or silica-gel thin-layer chromatography (TLC) to complete the reaction in terms of yield, and the reaction time is typically approximately 2 hours to 12 hours. After the reaction is finished, an acid is added to terminate the reaction. Examples of the used acid include an aqueous solution of hydrochloric acid, sulfuric acid, and nitric acid. The reaction is preferably terminated under ice cooling. A common aqueous work-up of the reaction mixture can yield the monomer A-1. The obtained monomer A-1 can be purified, as necessary, by common method such as distillation, chromatography, and recrystallization.

Examples of the specific structure of the repeating unit A represented by the formulae (A-1) and (A-2) include repeating units represented by the following formulae, but the repeating unit A is not limited thereto. In the following formulae, R^{A} is same as above.

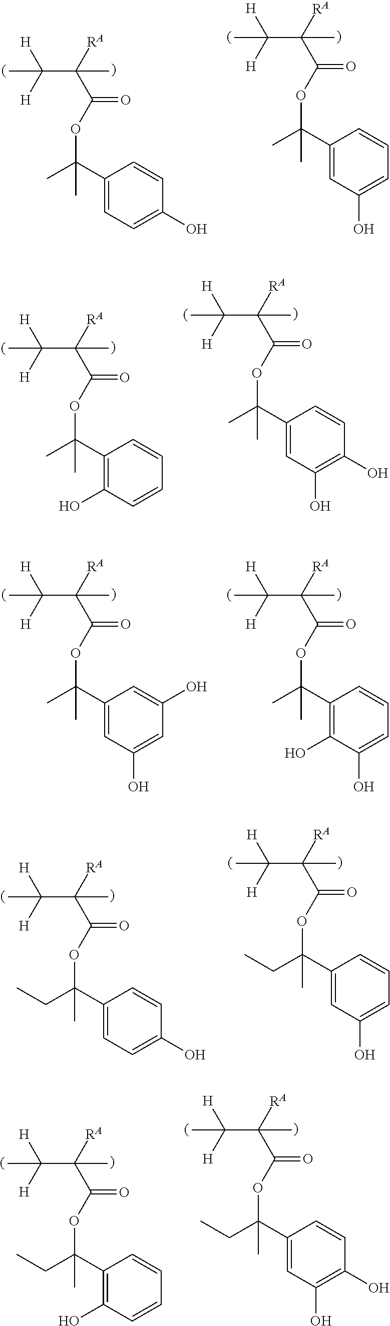

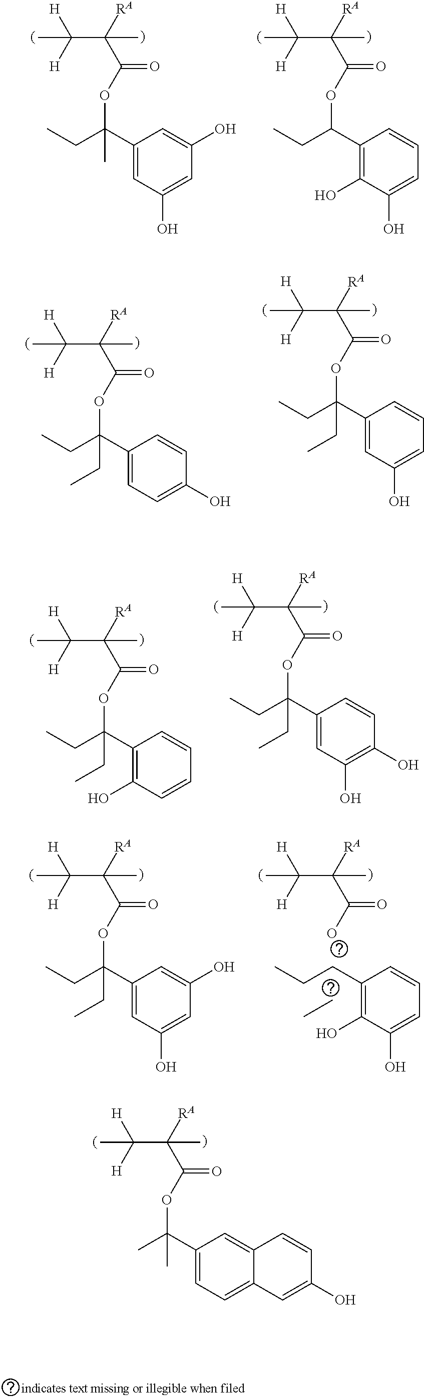

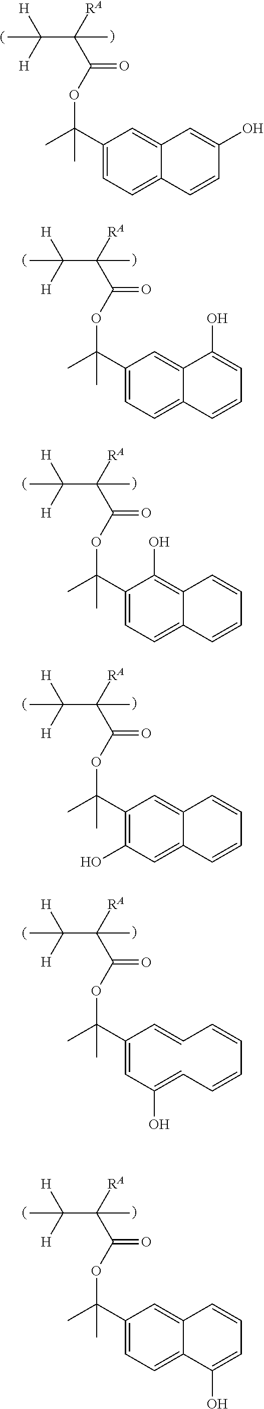

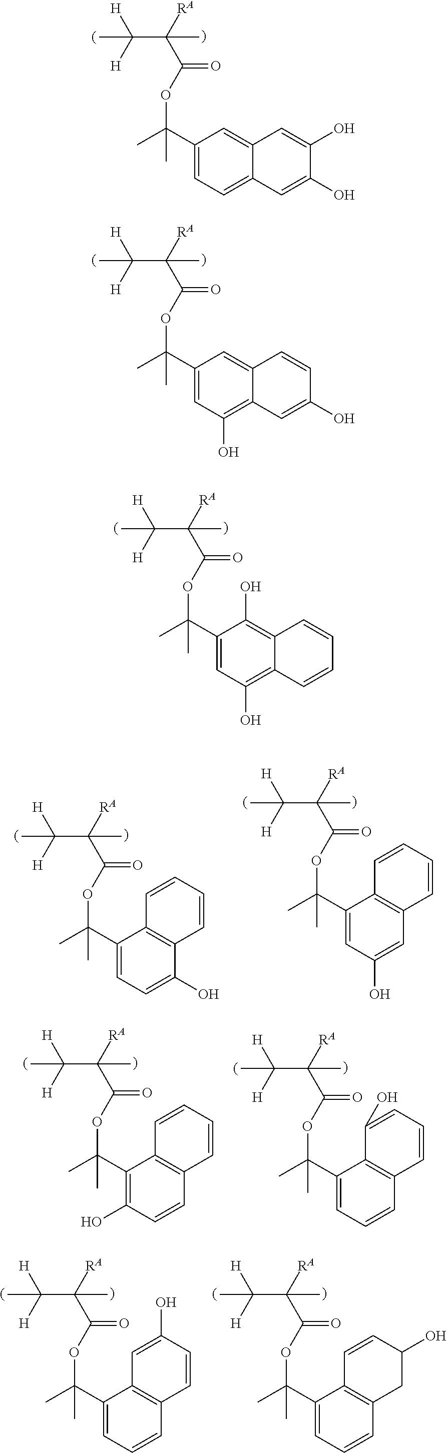

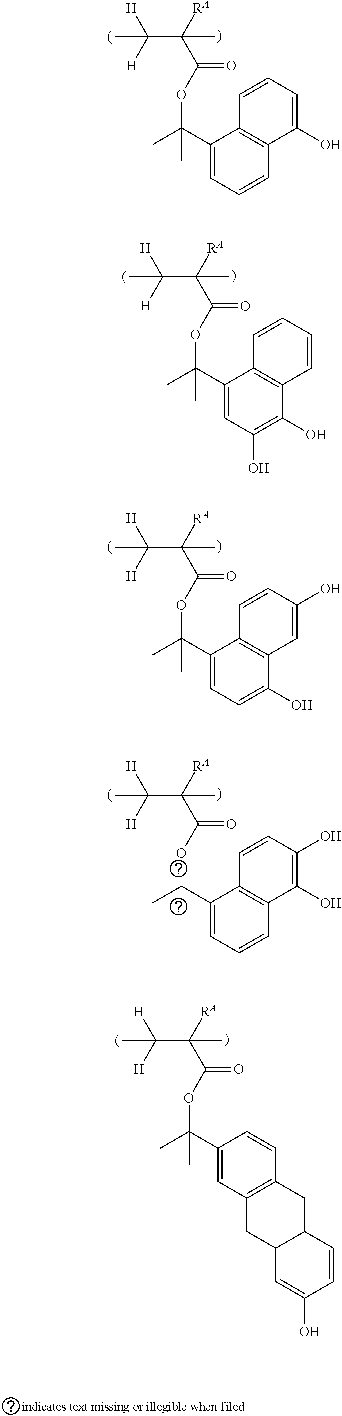

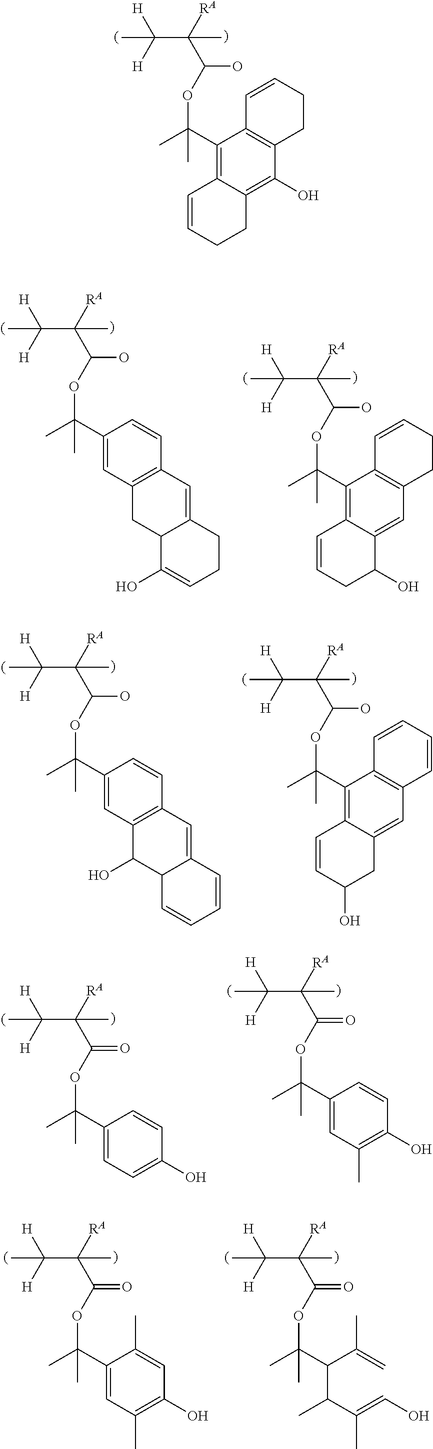

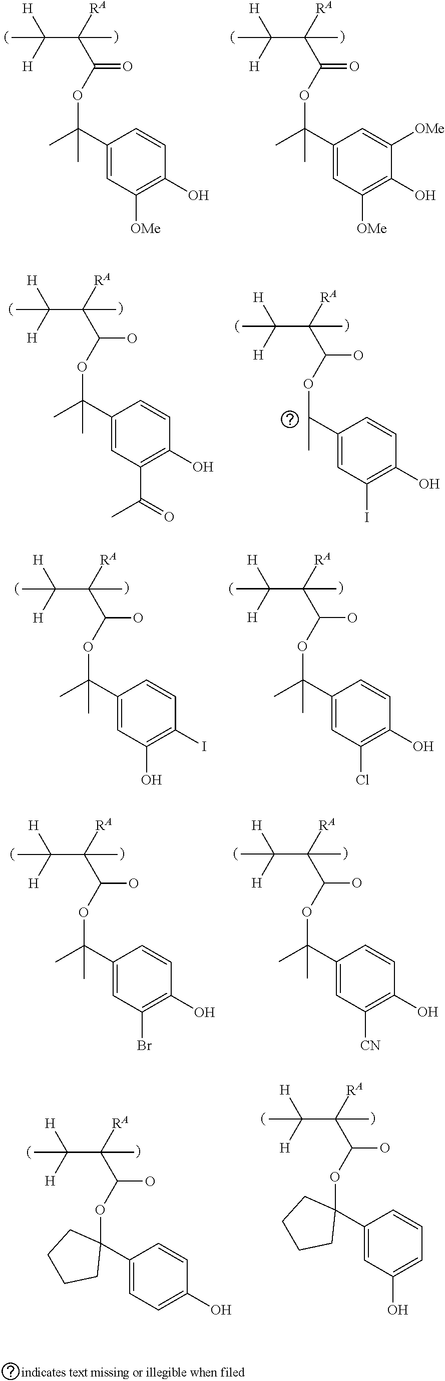

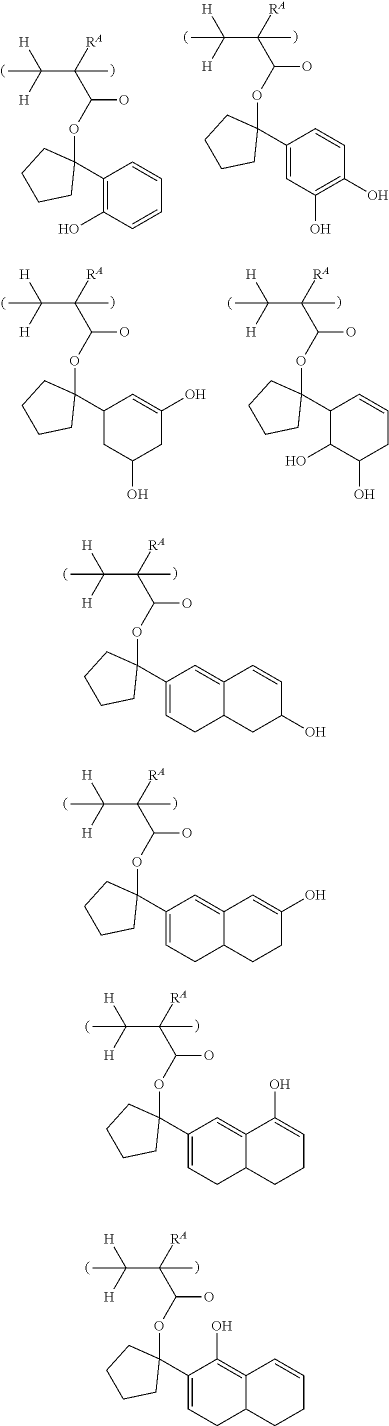

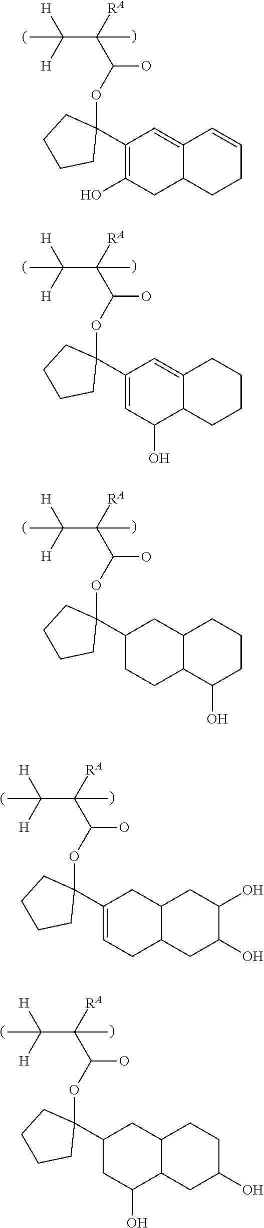

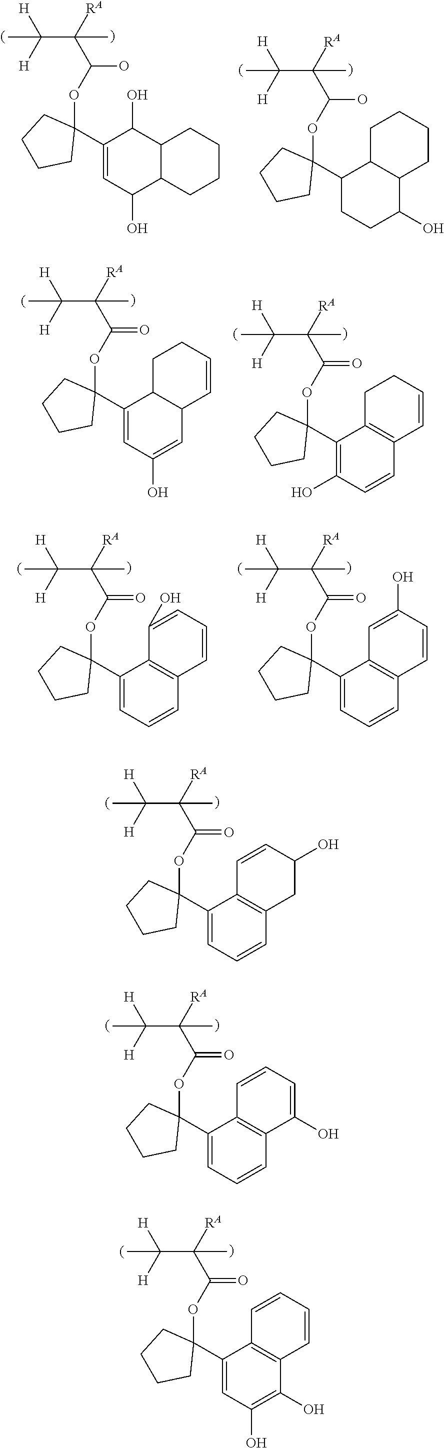

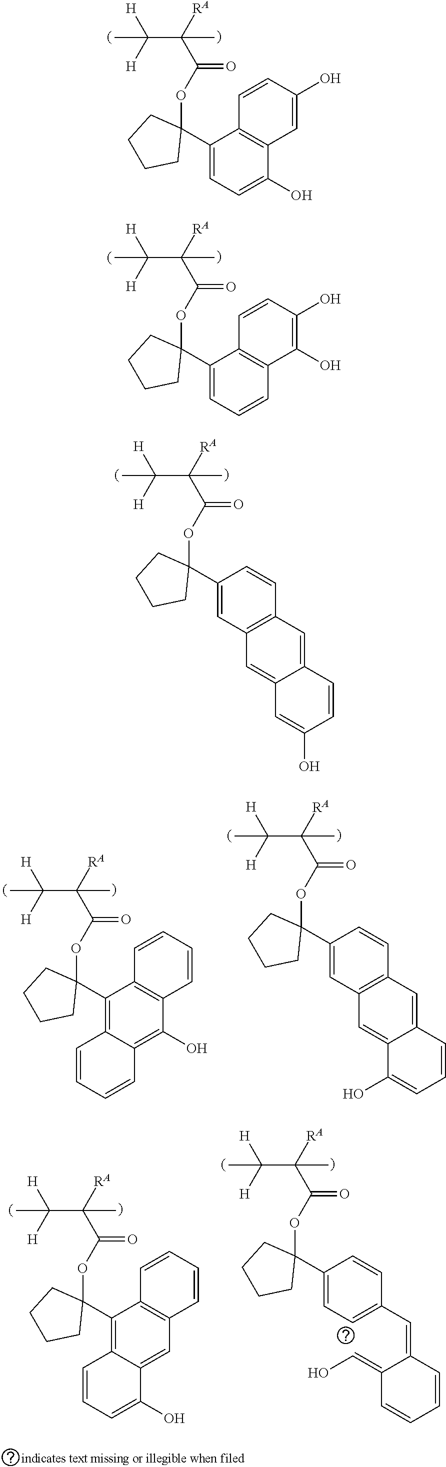

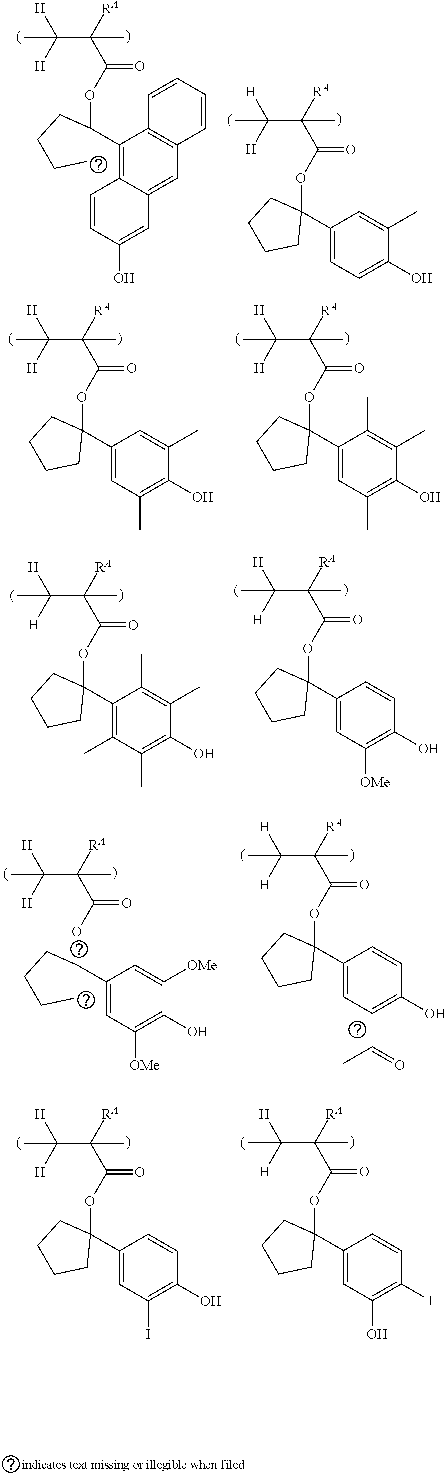

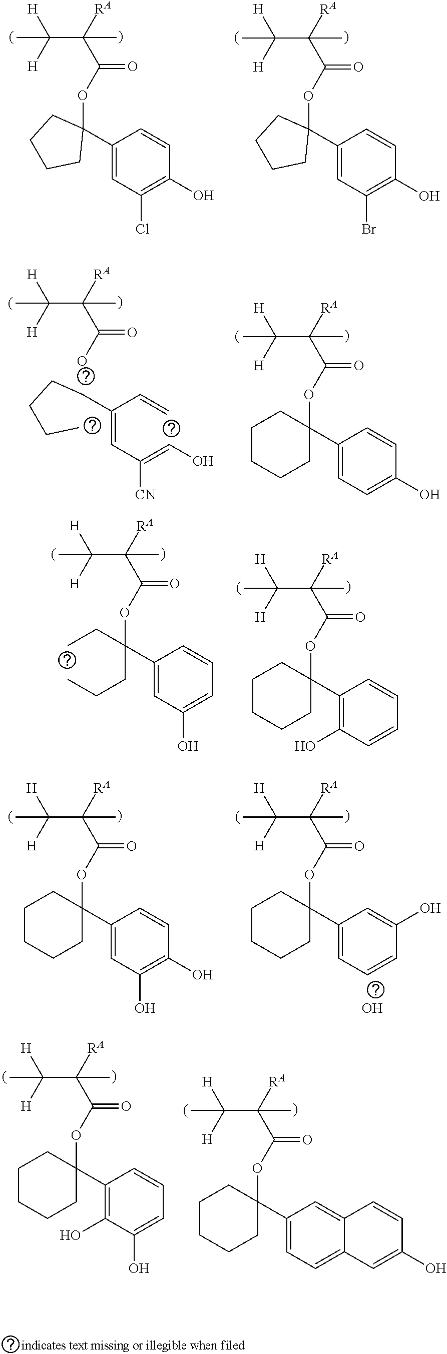

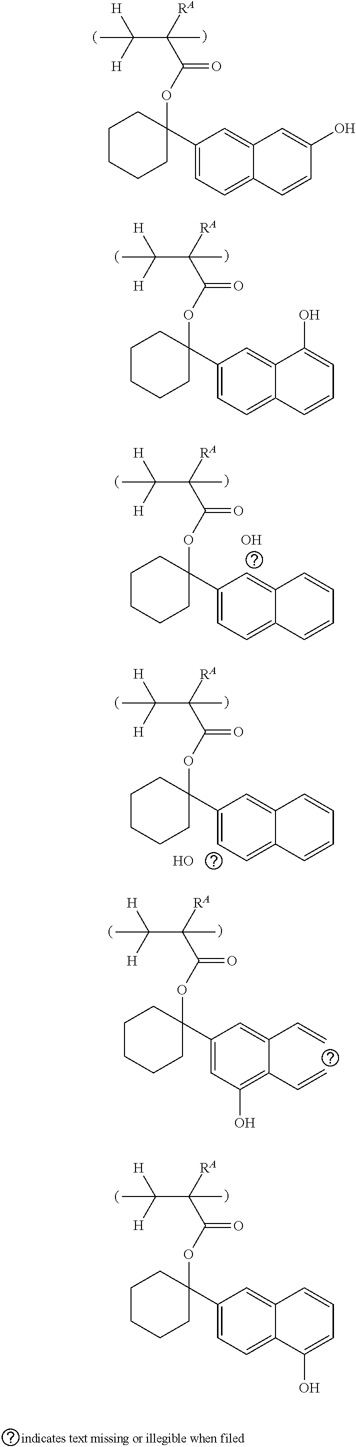

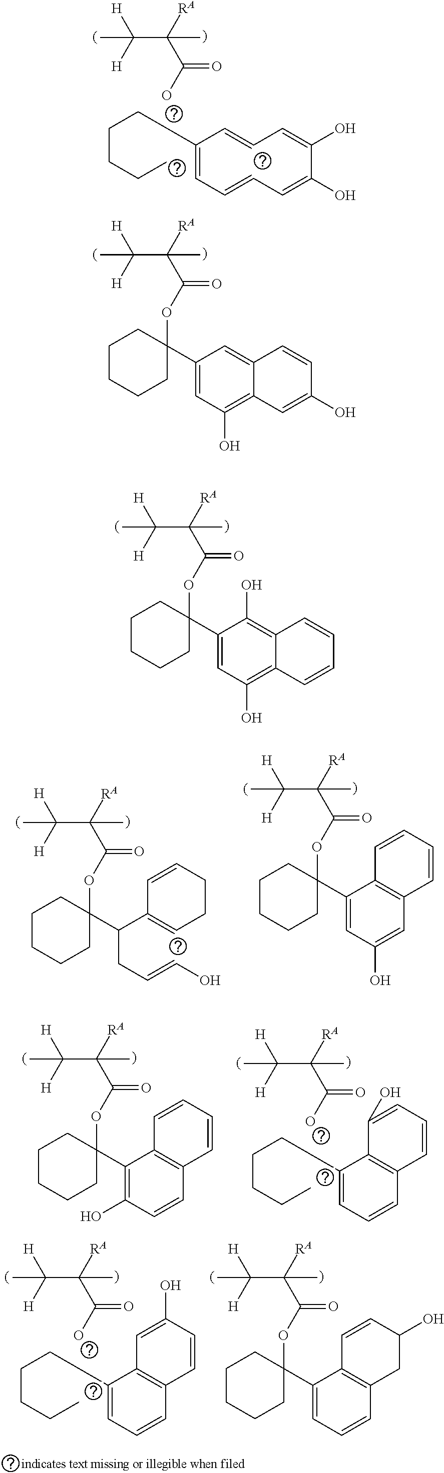

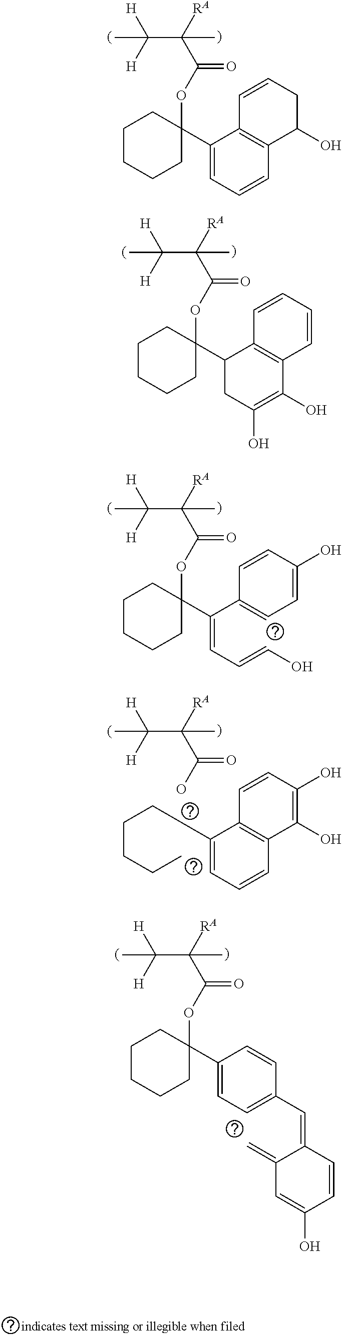

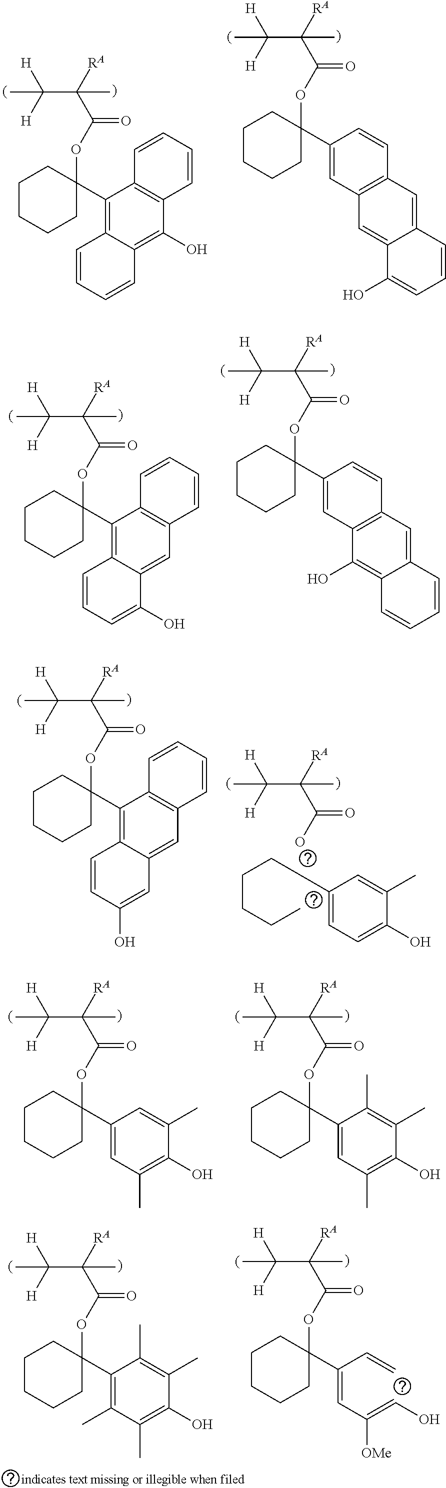

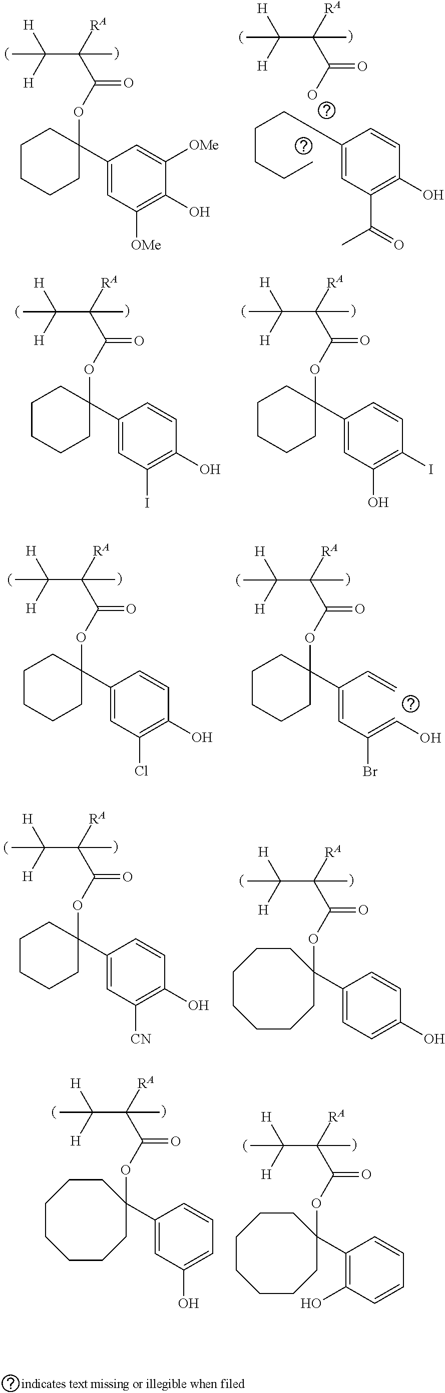

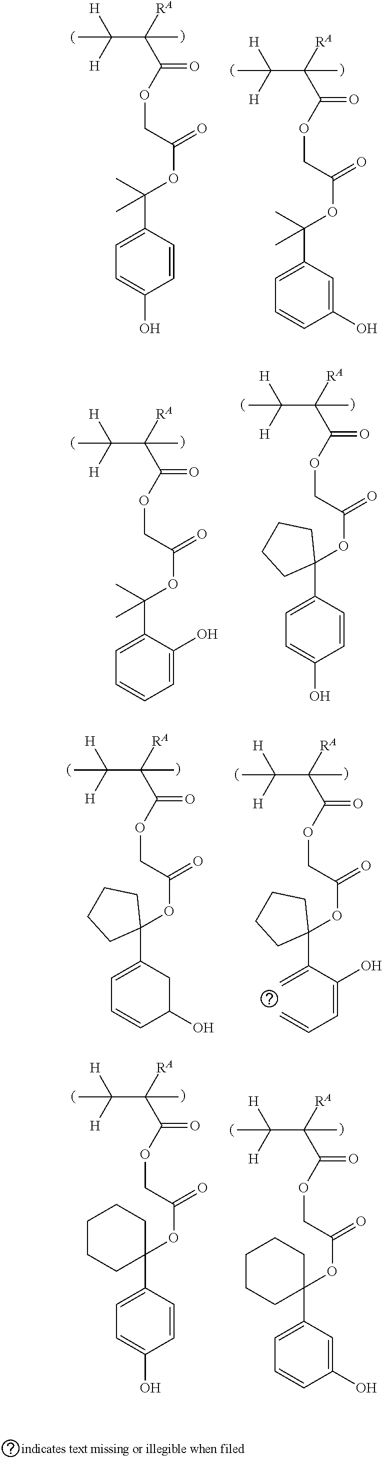

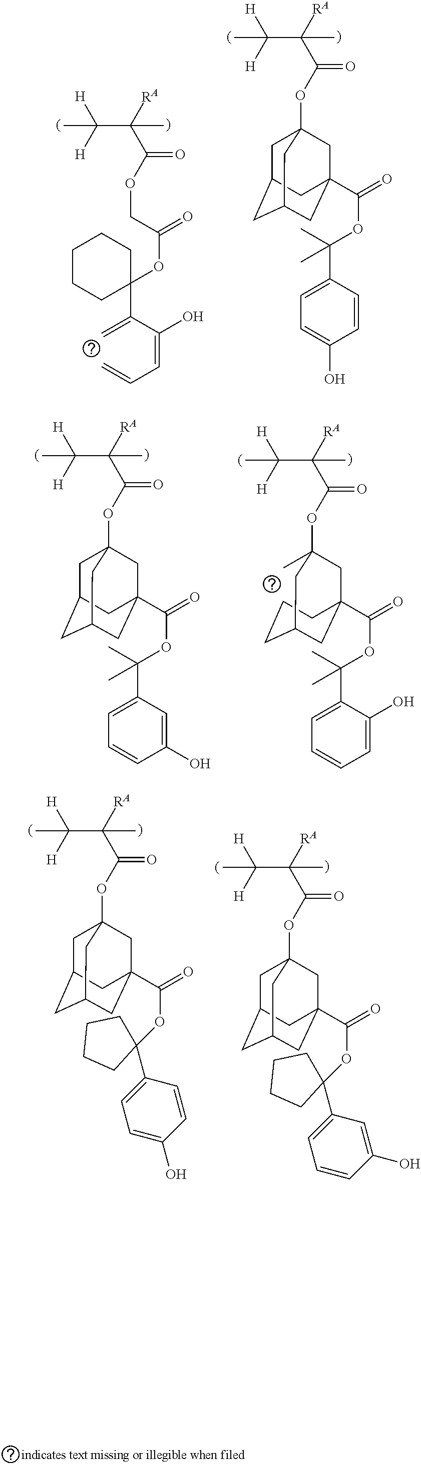

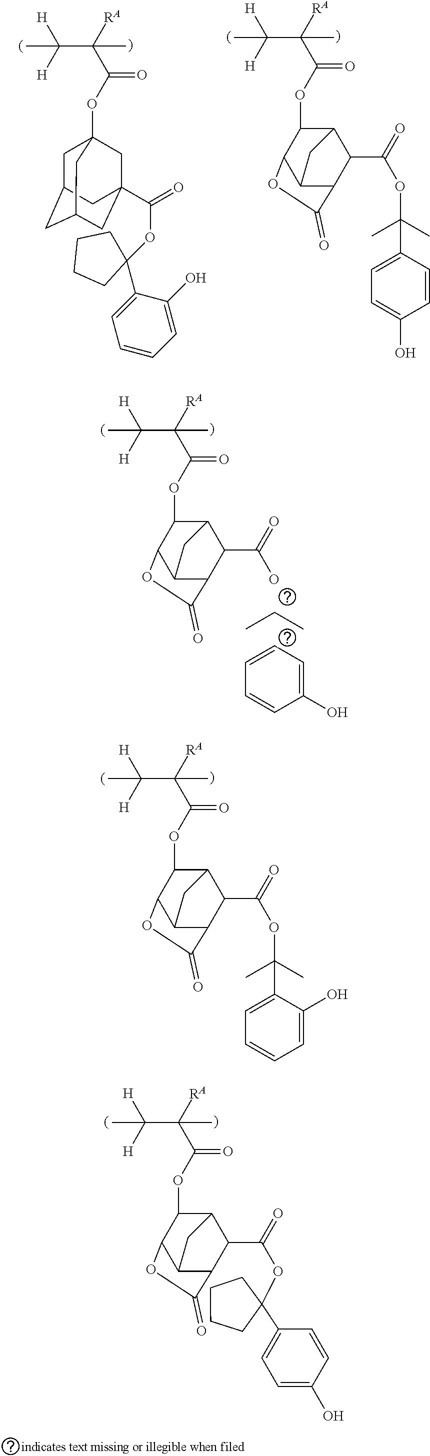

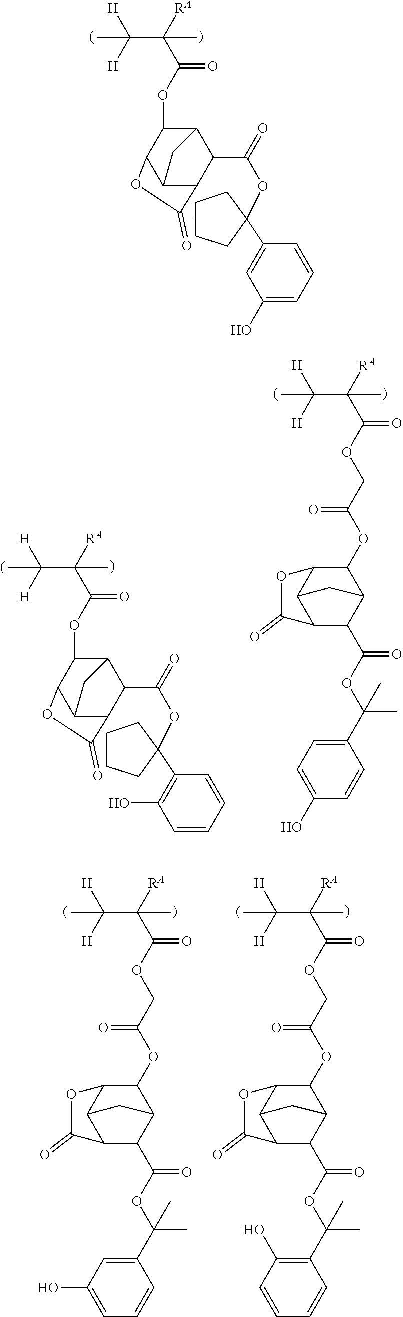

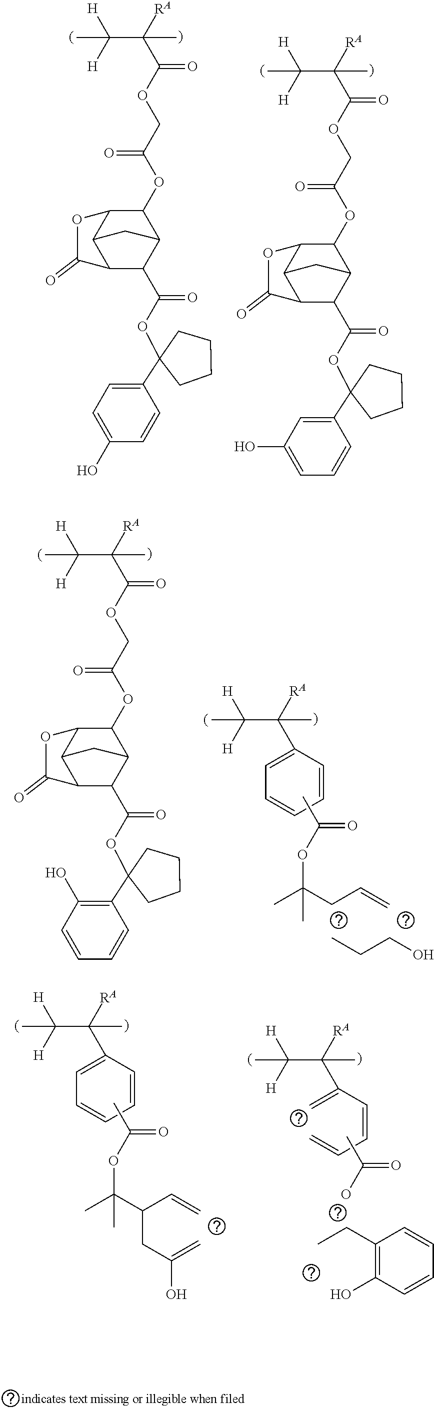

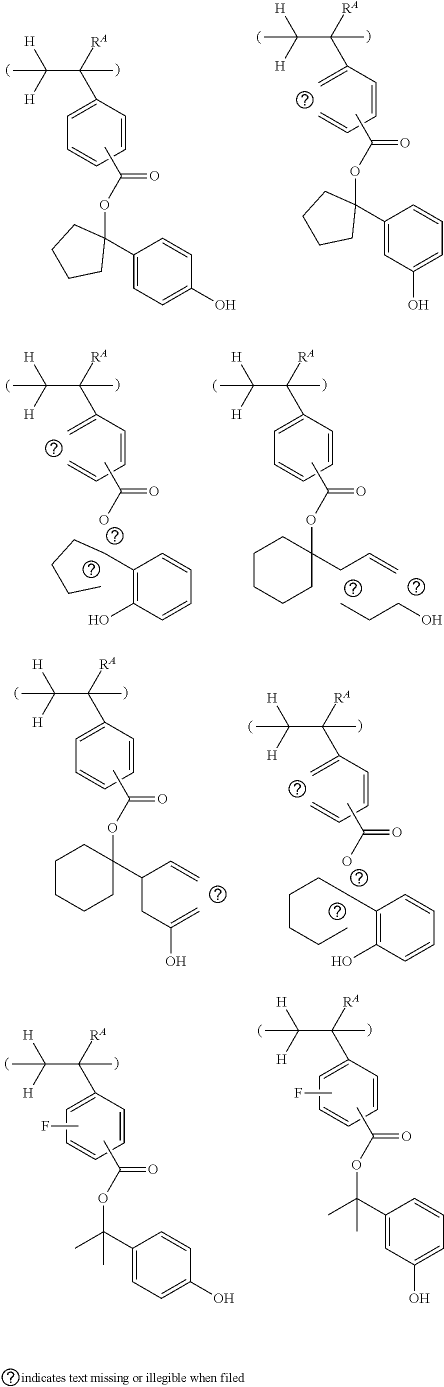

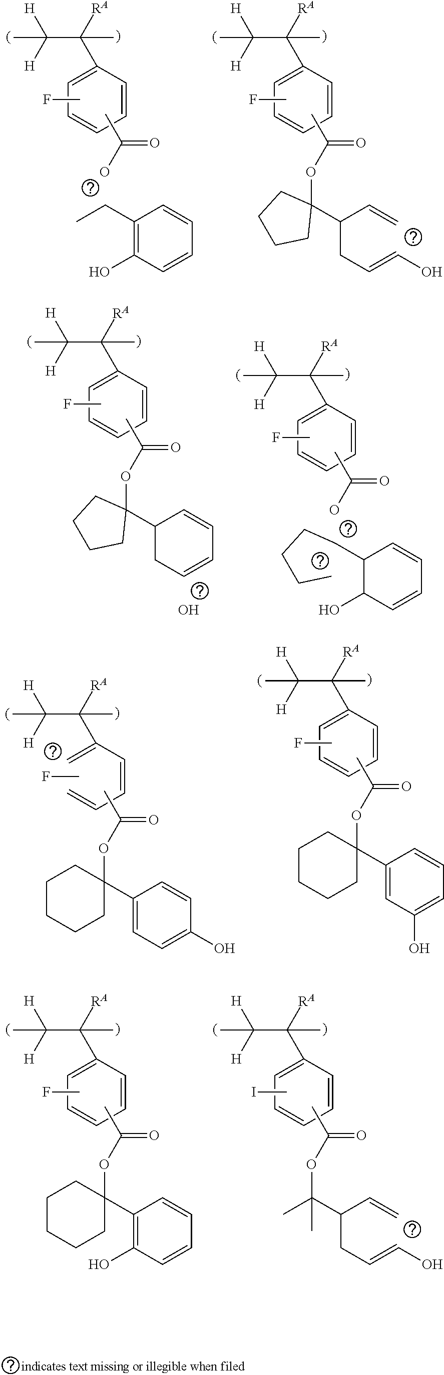

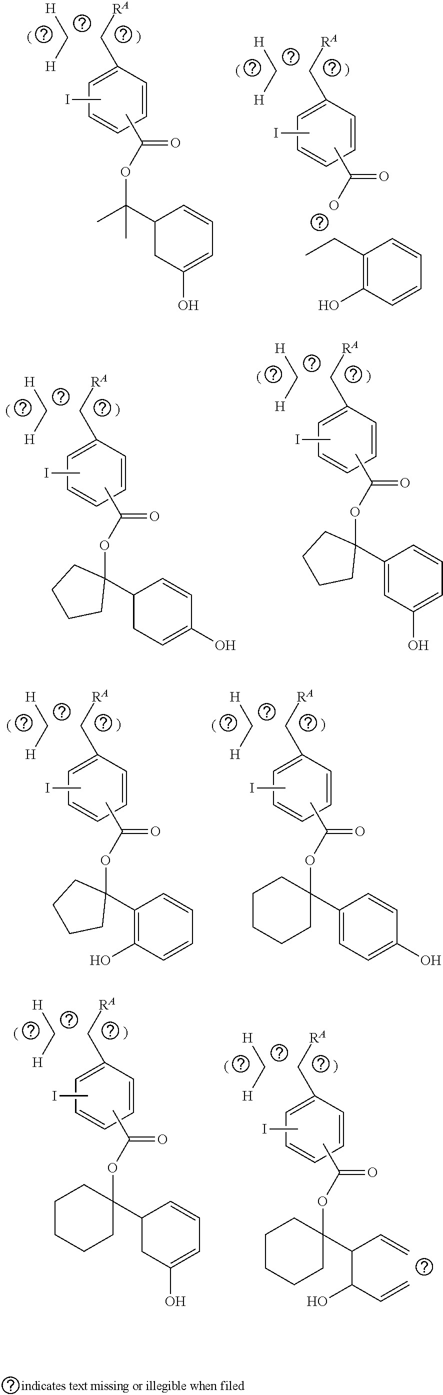

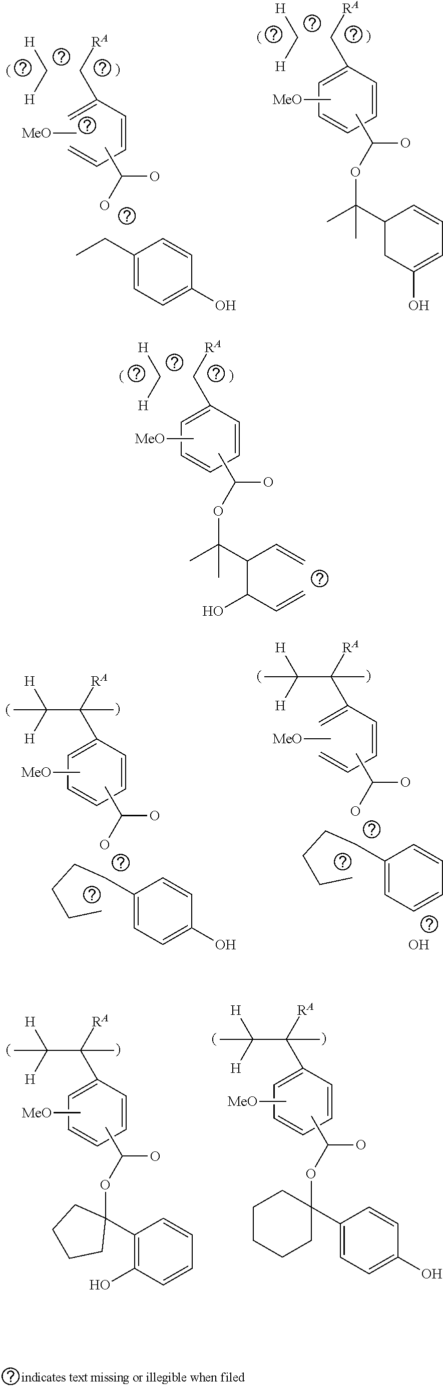

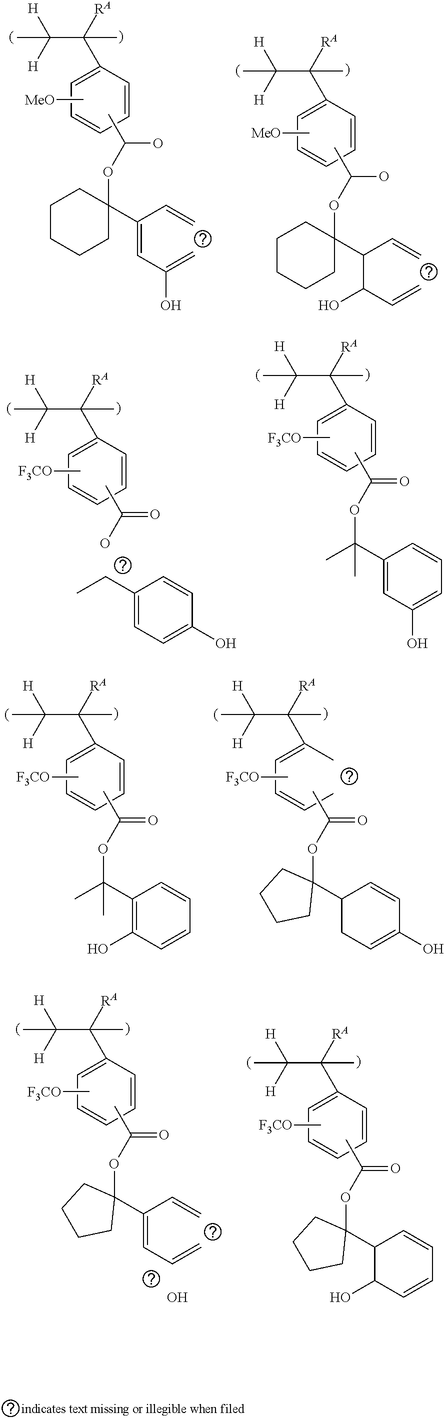

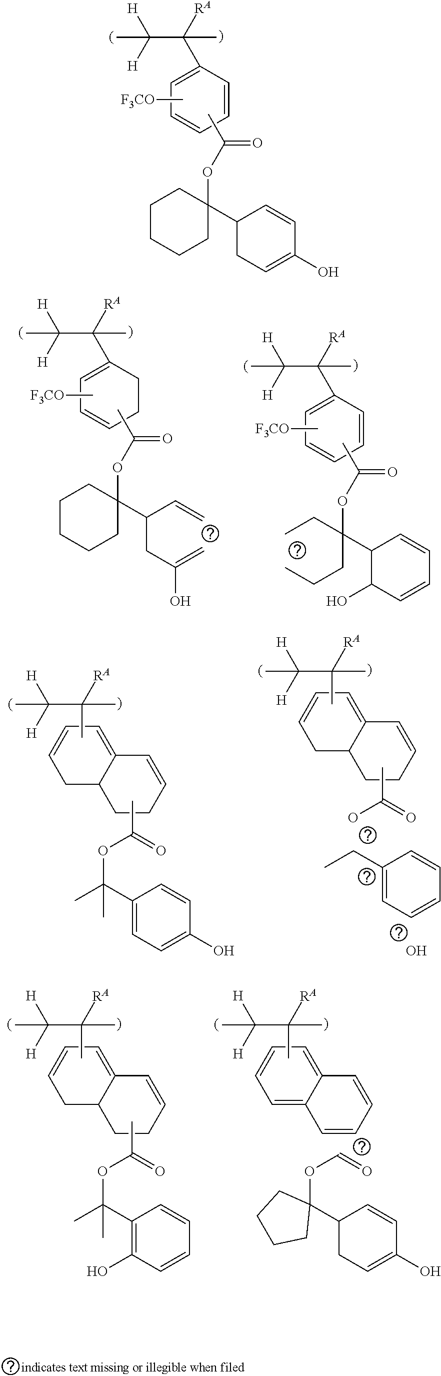

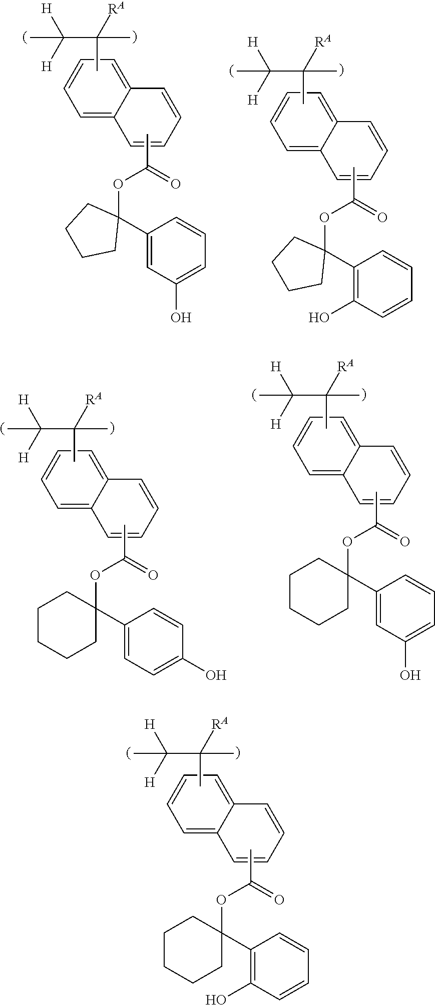

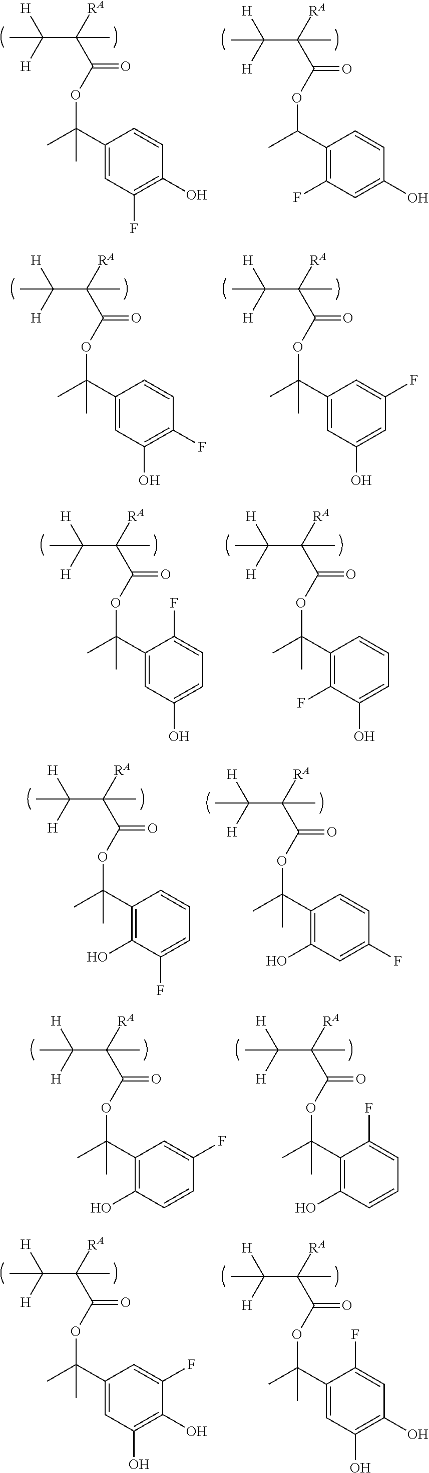

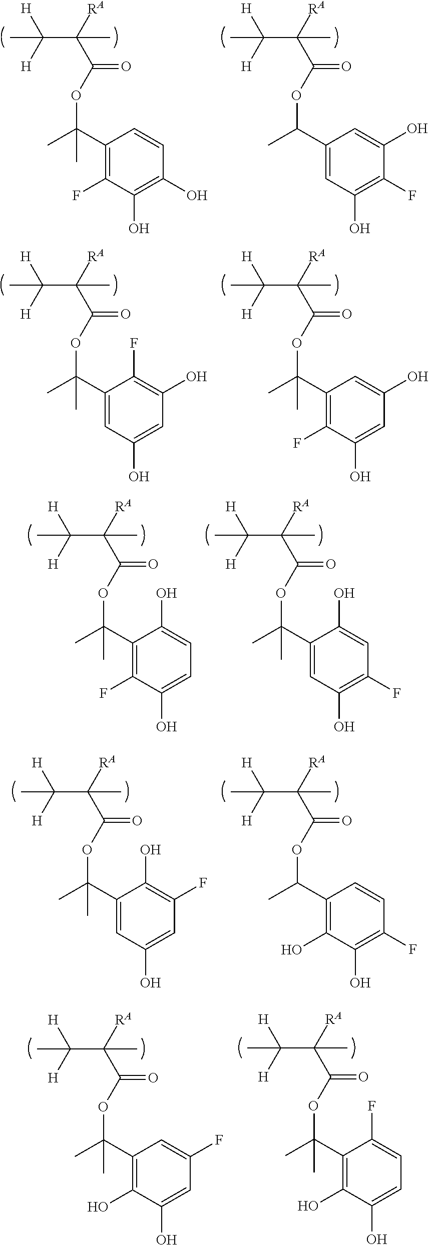

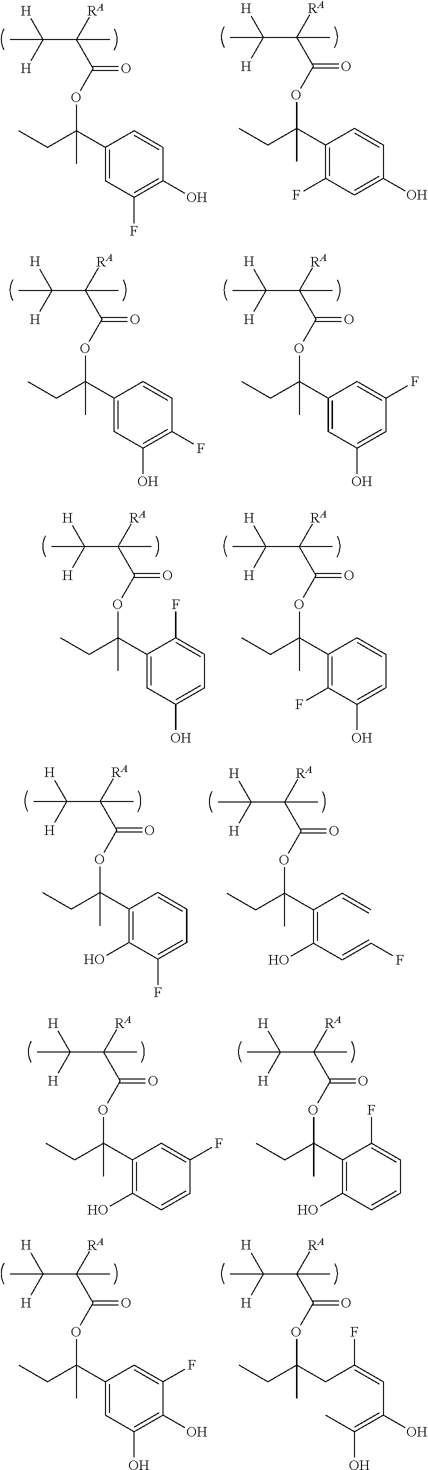

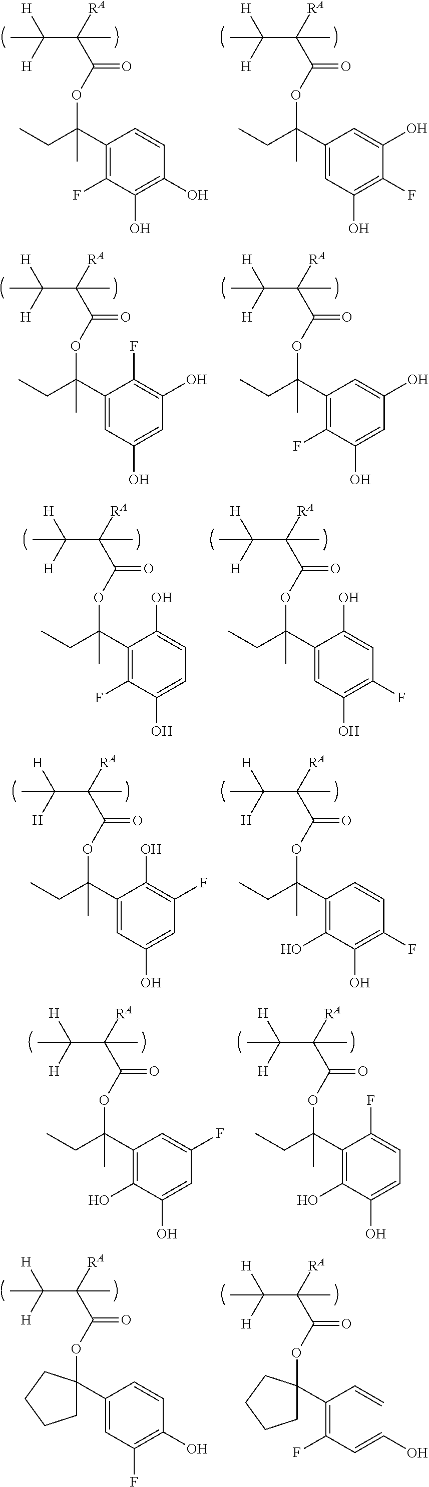

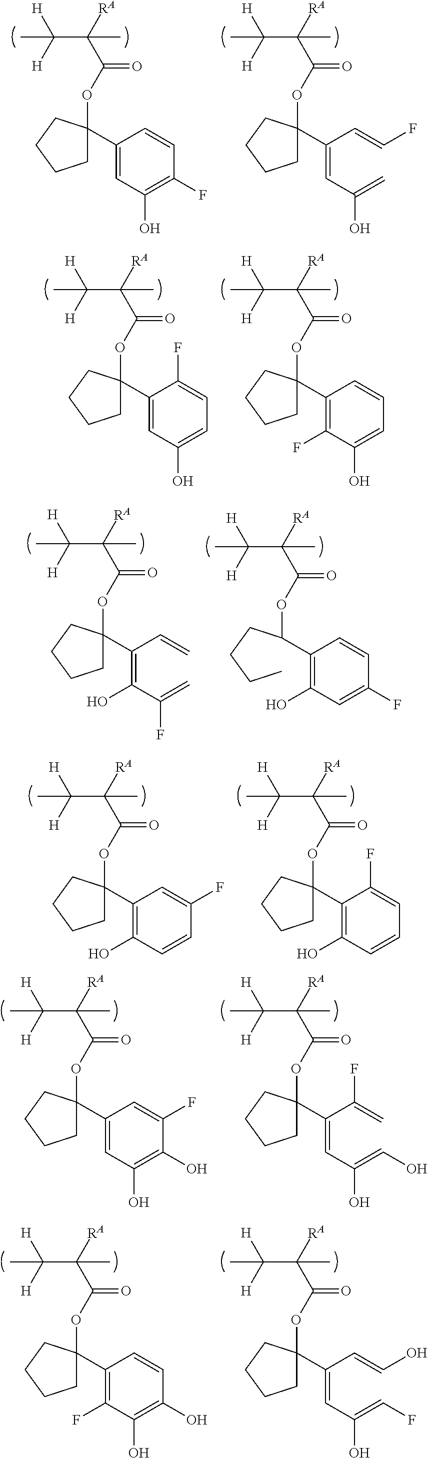

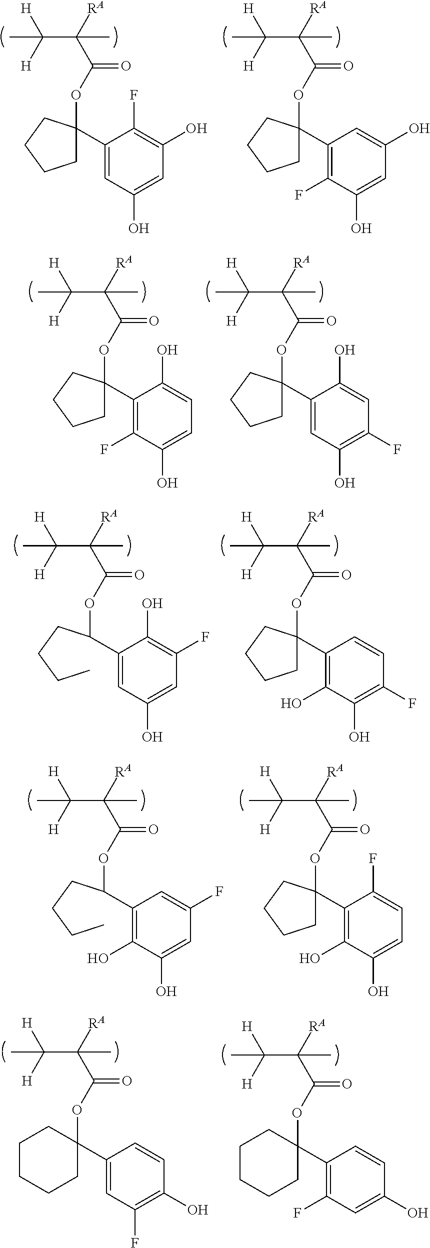

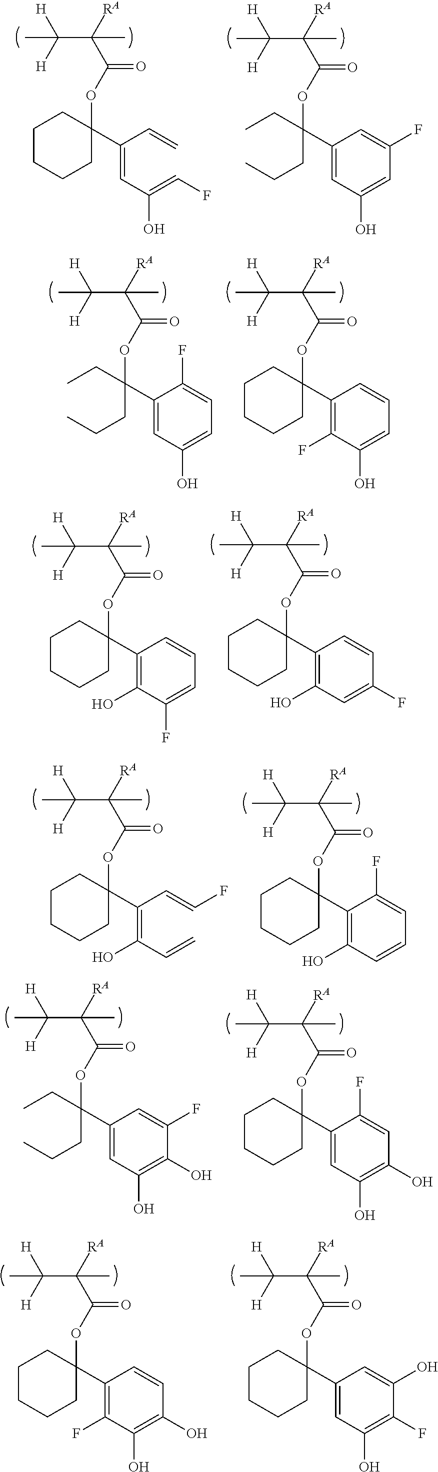

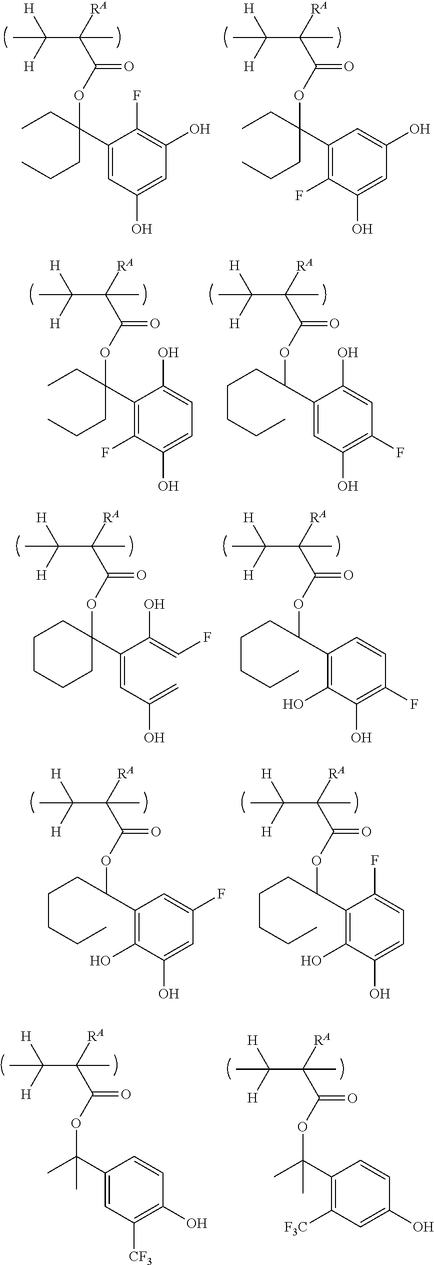

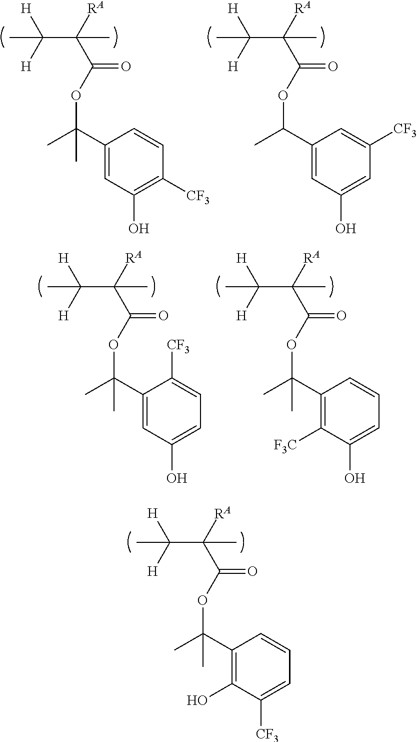

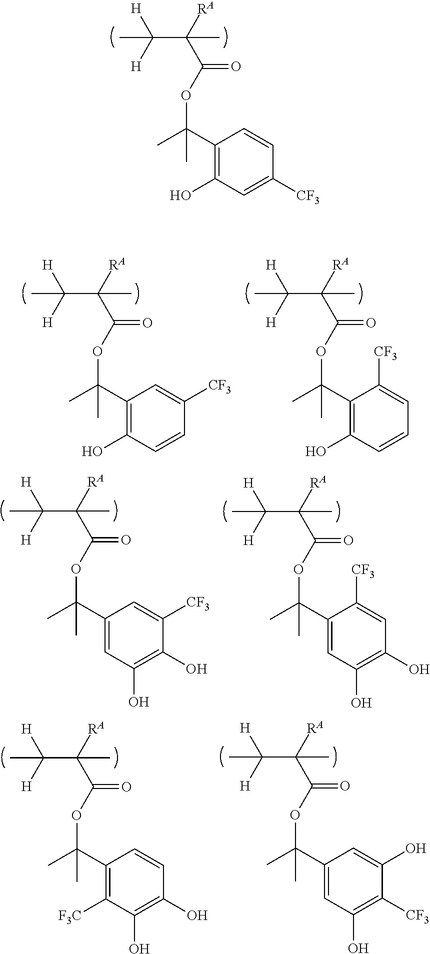

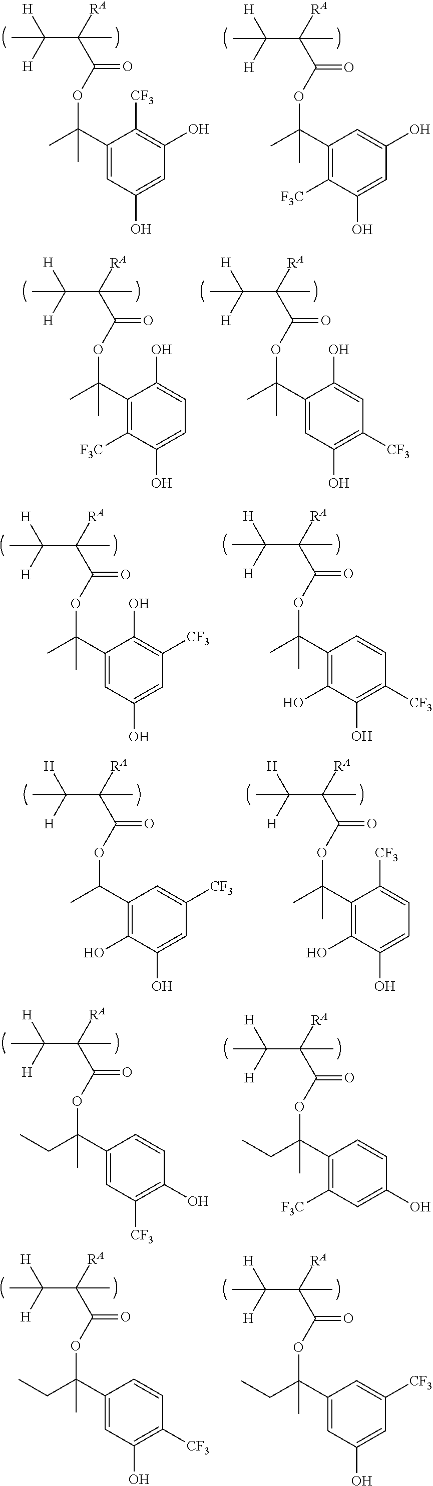

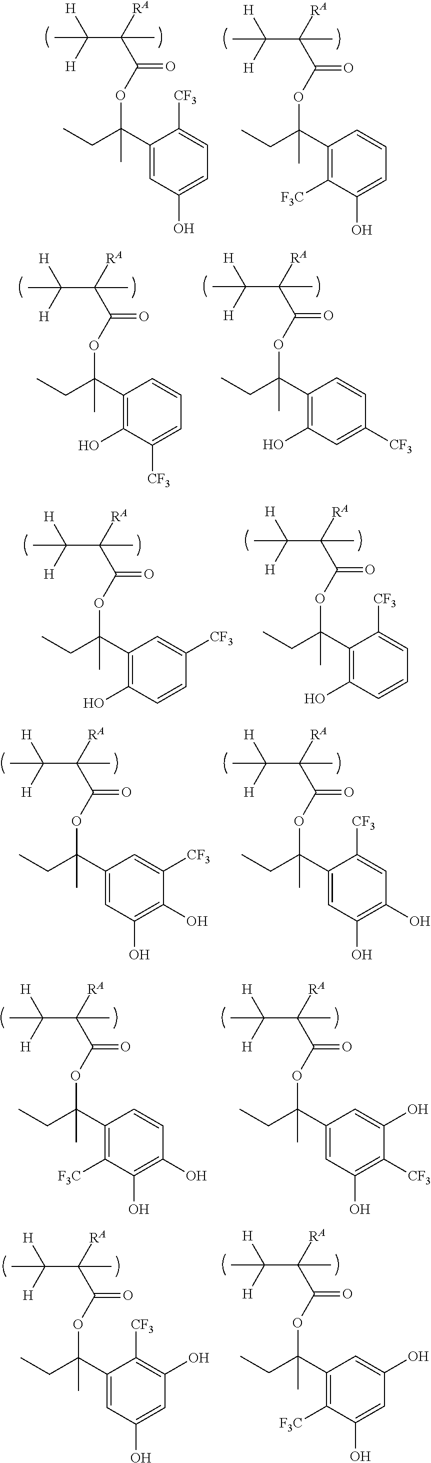

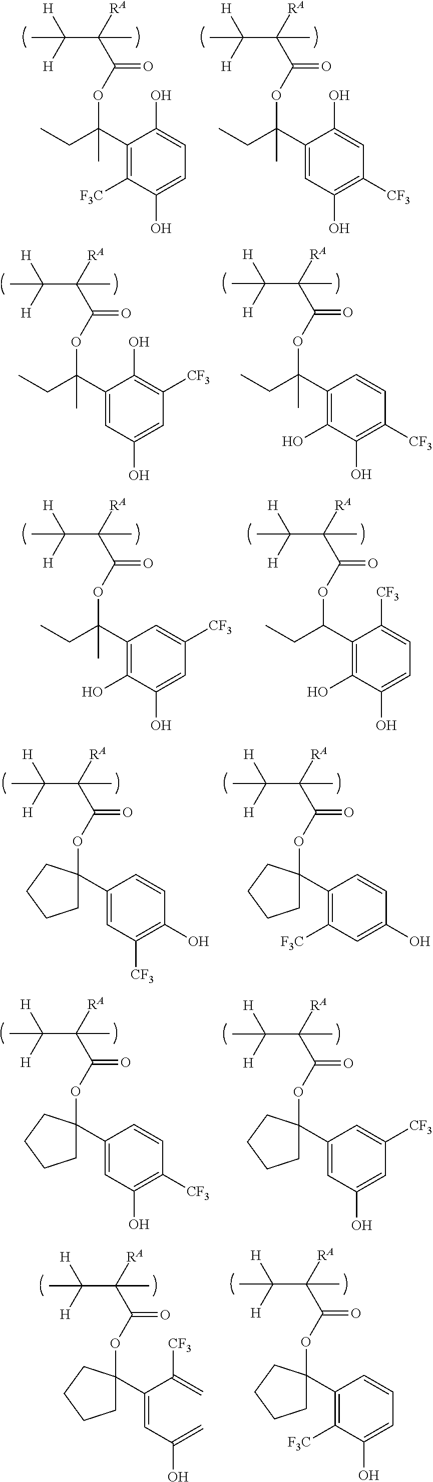

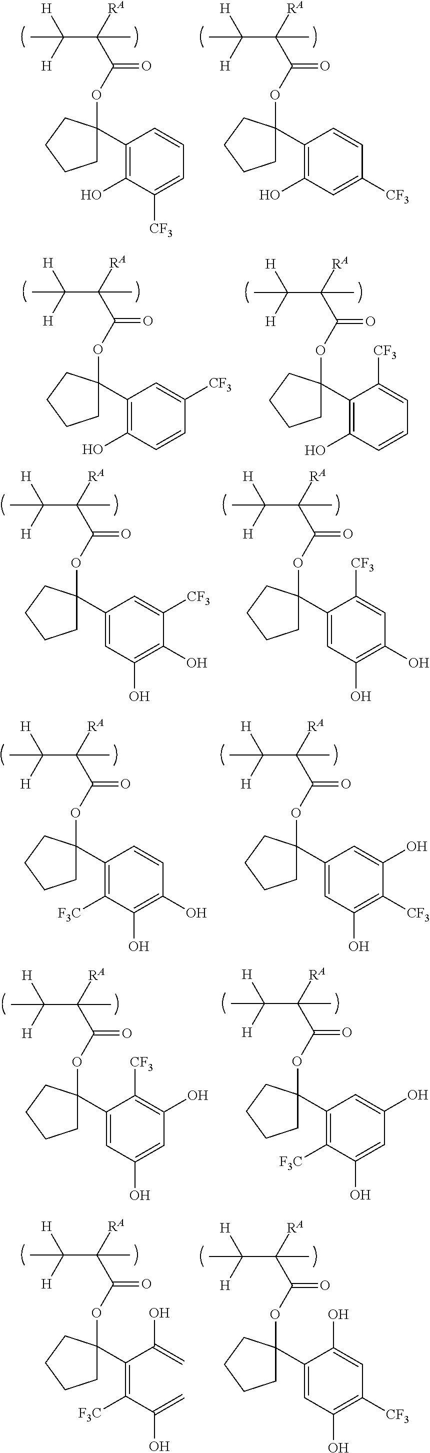

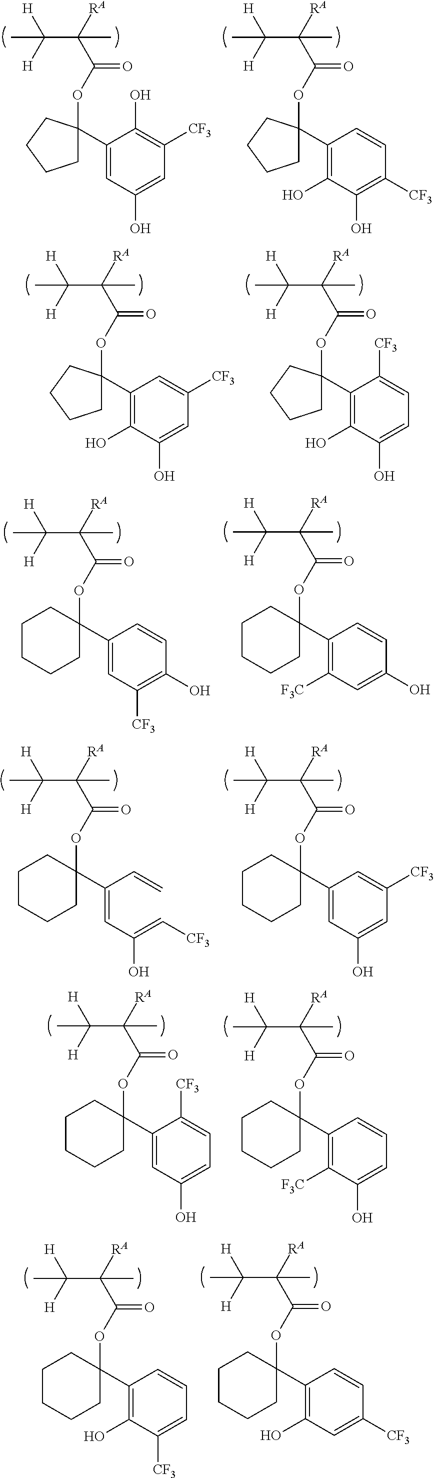

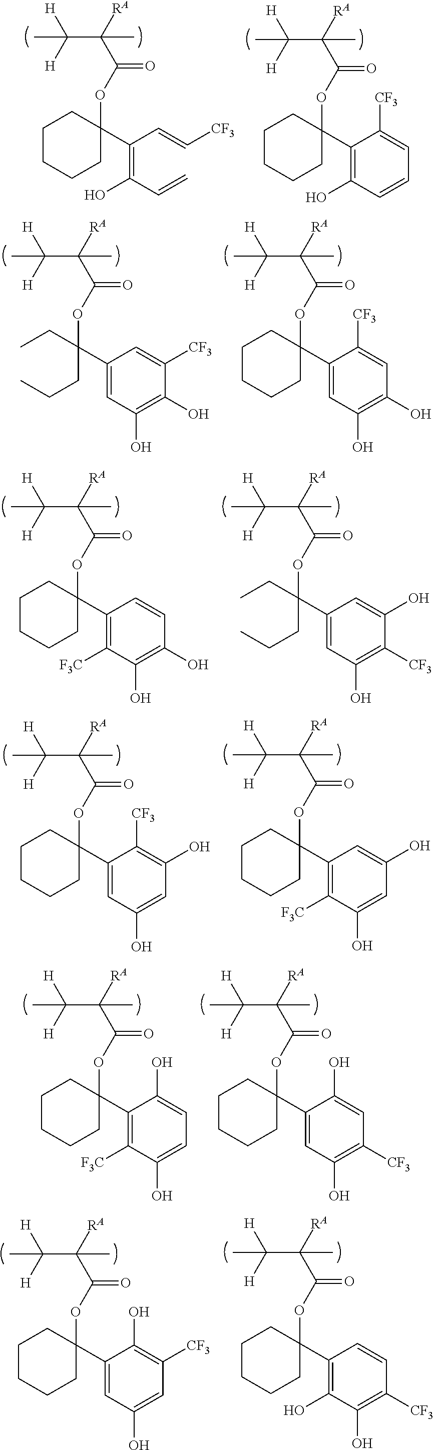

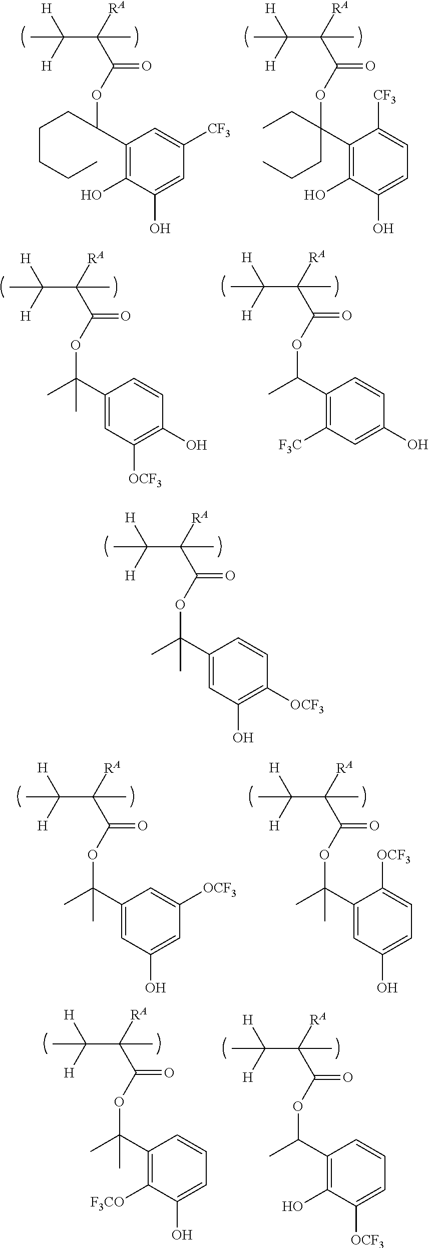

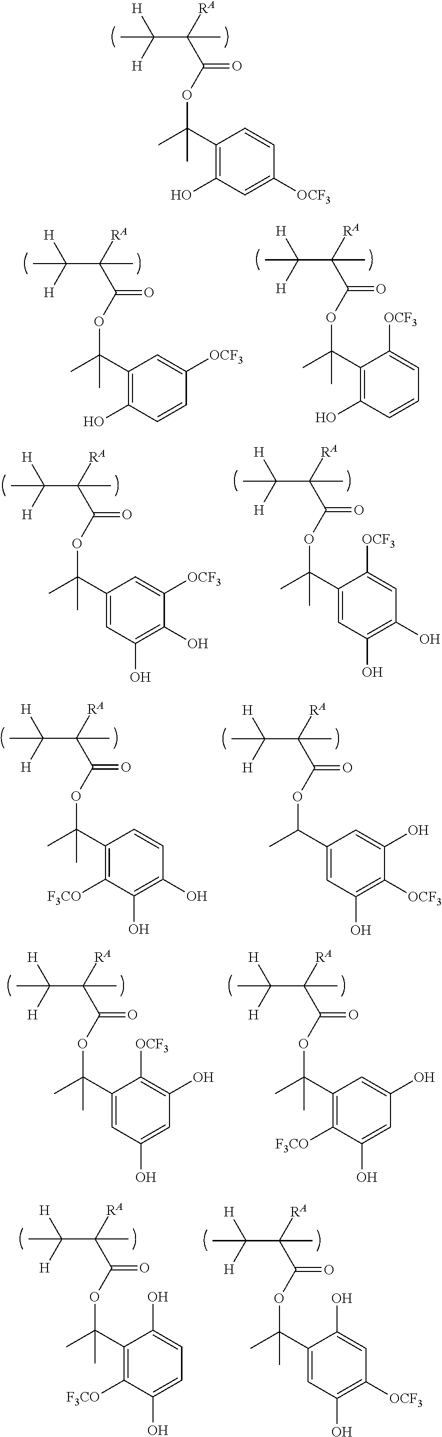

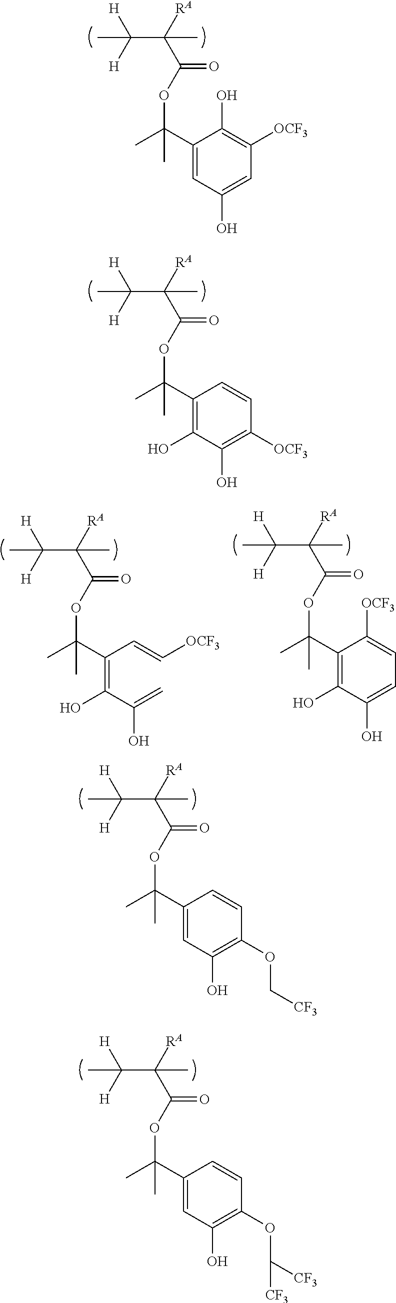

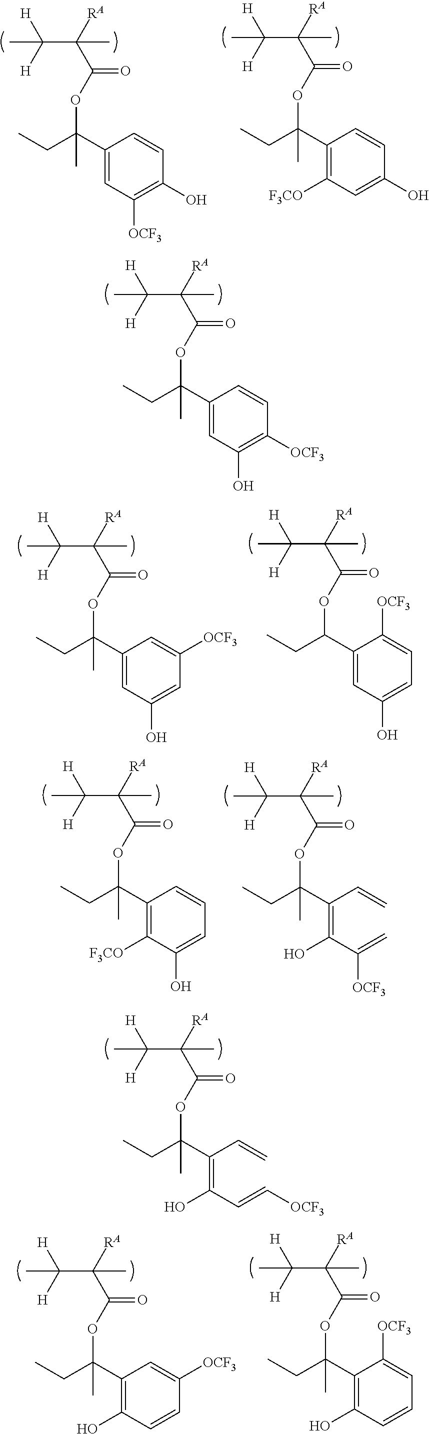

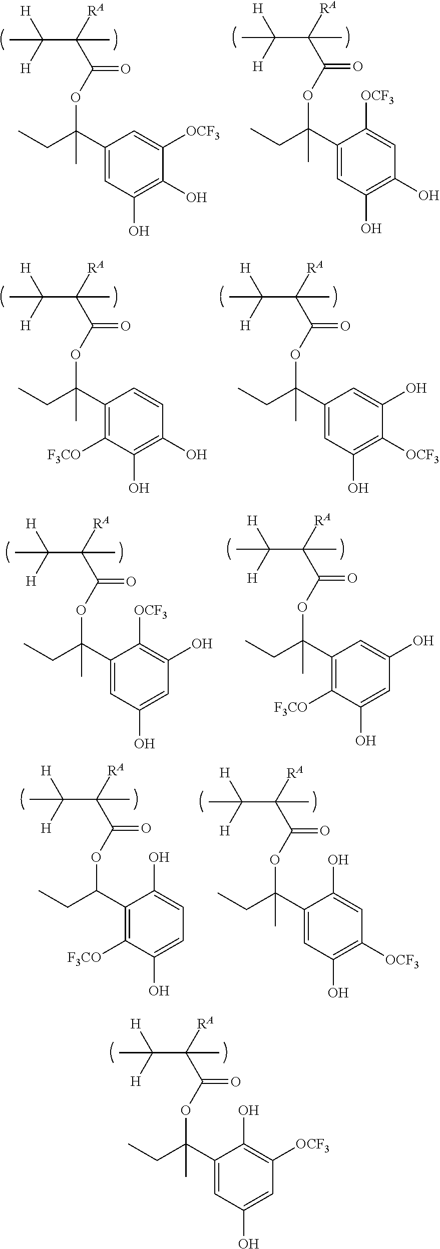

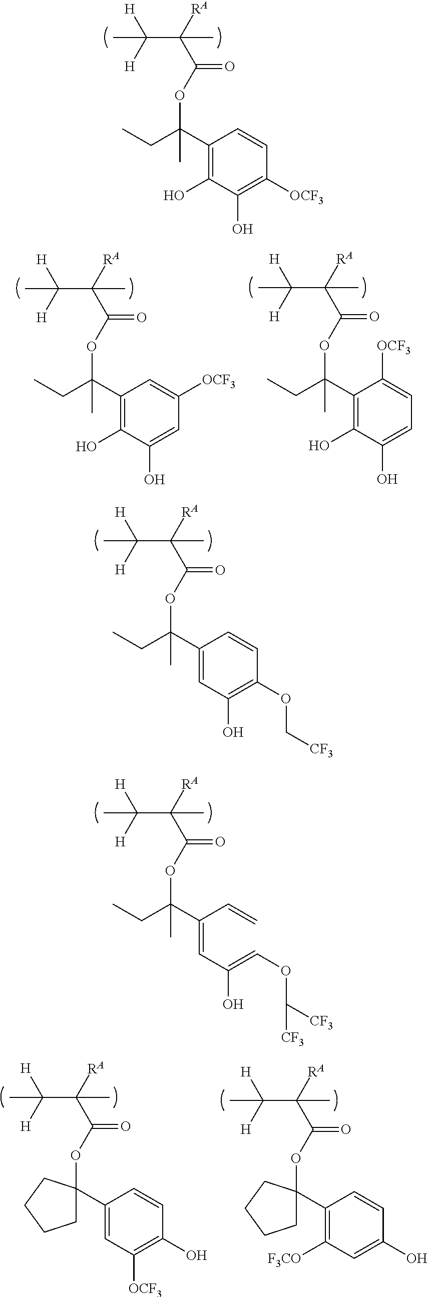

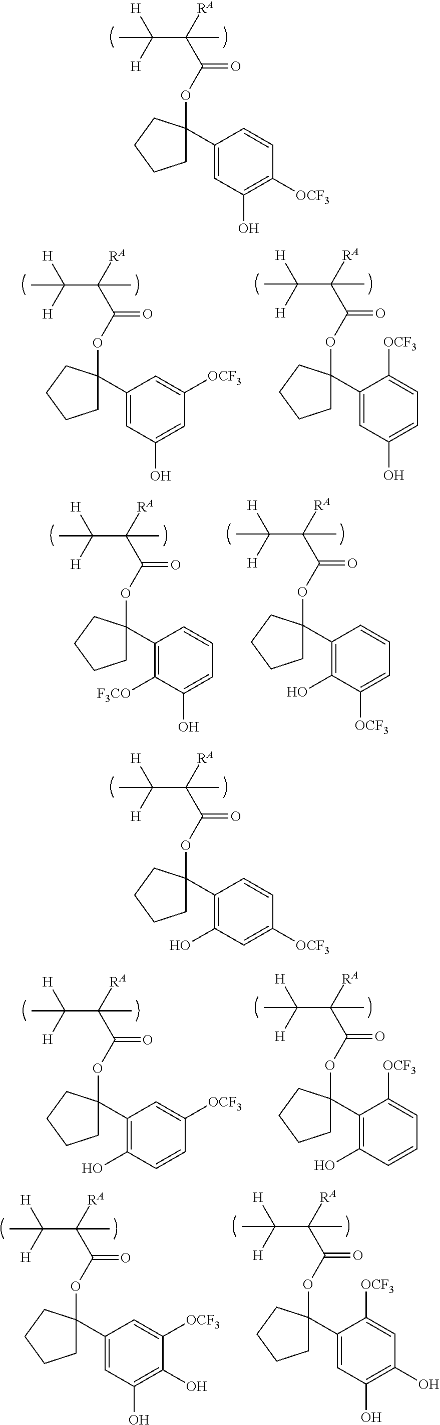

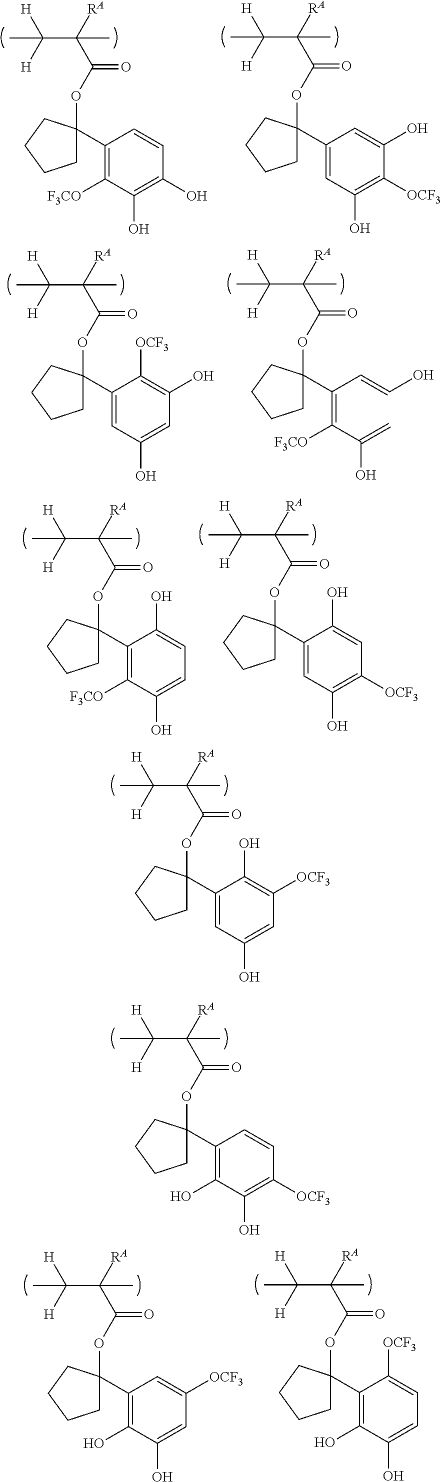

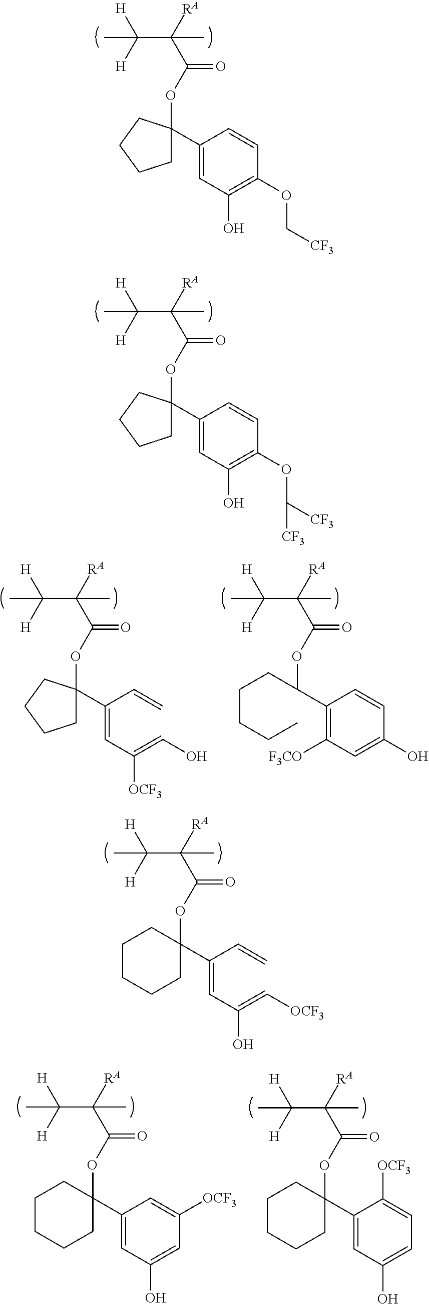

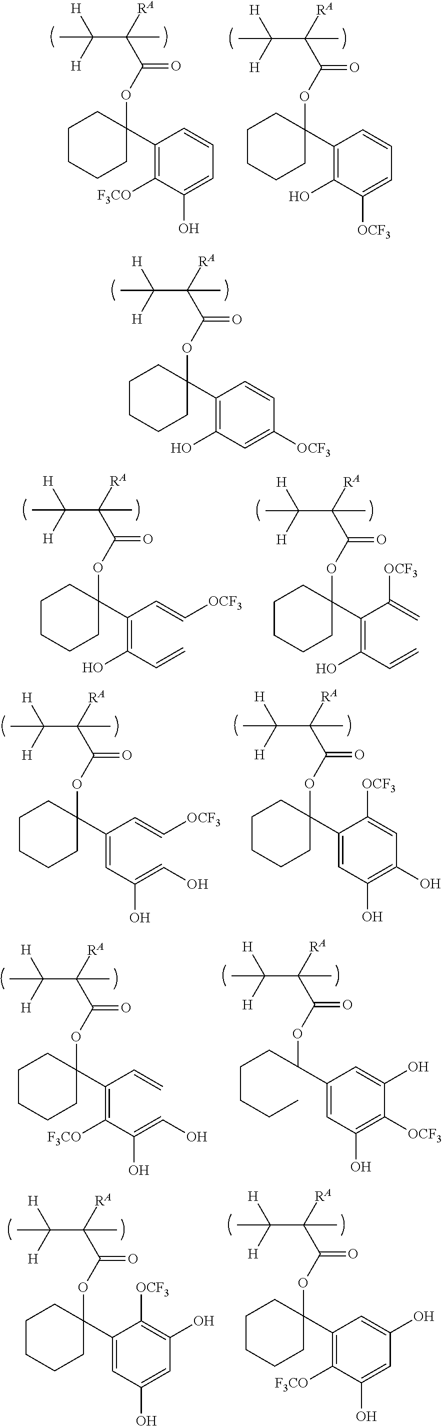

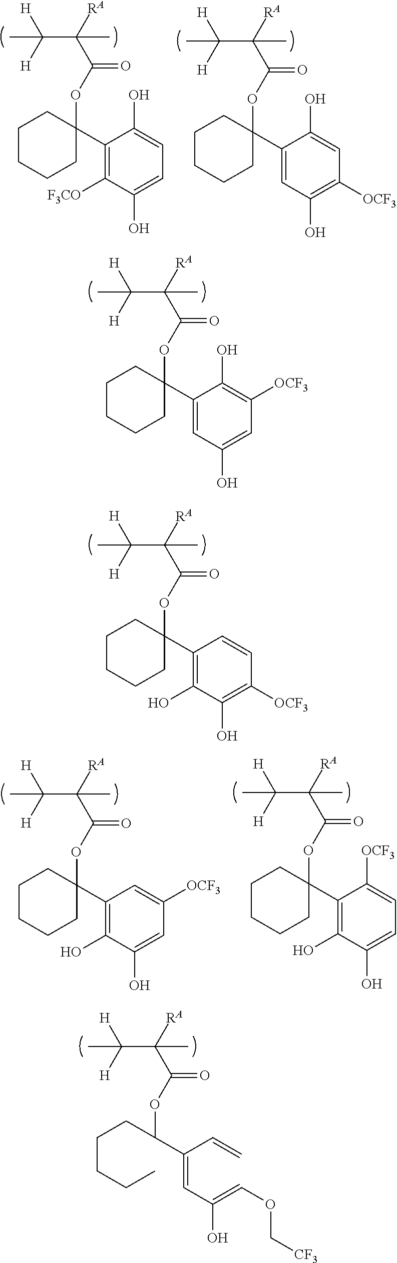

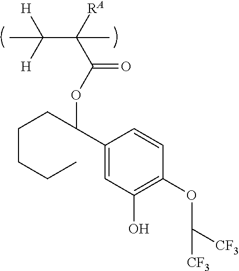

### [Repeating Unit B to Generate Acid by Light Exposure]

The inventive polymer comprises a repeating unit to generate an acid by light exposure (hereinafter, which may be referred to as the repeating unit B). The repeating unit B is any one or more of a repeating unit represented by the following formula (B-1) (hereinafter, which may be referred to as the repeating unit B1), a repeating unit represented by the following formula (B-2) (hereinafter, which may be referred to as the repeating unit B2), a repeating unit represented by the following formula (B-3) (hereinafter, which may be referred to as the repeating unit B3), and a repeating unit represented by the following formula (B-4) (hereinafter, which may be referred to as the repeating unit B4).

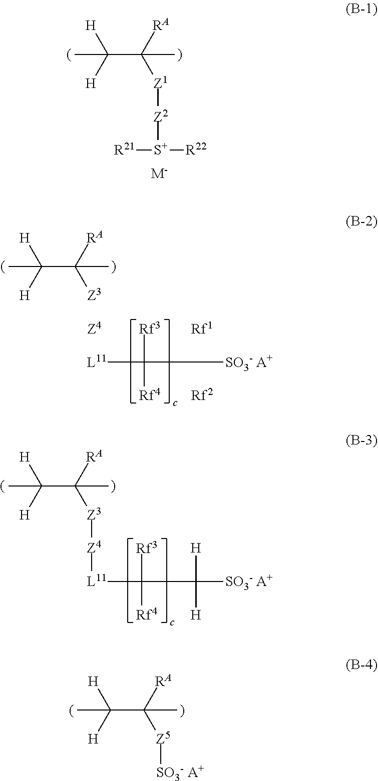

In the formulae (B-1) to (B-4), R^{A} is same as above. Z¹ represents a single bond or a phenylene group. Z² represents a single bond, —C(═O)—O—Z²¹—, —C(═O)—NH—Z²¹—, or —O—Z²¹—. Z²¹ represents an aliphatic hydrocarbylene group having 1 to 6 carbon atoms, a phenylene group, or a divalent group obtained by combining these groups, and Z²¹ optionally has a carbonyl group, an ester bond, an ether bond, or a hydroxy group. Z³ represents a single bond, a phenylene group, a naphthylene group, or (main chain)-C(═O)—O—Z³¹—. Z³¹ represents an aliphatic hydrocarbylene group having 1 to 10 carbon atoms, or a phenylene group or a naphthylene group optionally having a hydroxy group, an ether bond, an ester bond, or a lactone ring. Z⁴ represents a single bond, a methylene group, or —Z⁴¹—C(═O)—O—. Z⁴¹ represents a hydrocarbylene group having 1 to 20 carbon atoms and optionally having a heteroatom, an ether bond, or an ester bond. Z⁵ represents a single bond, a methylene group, an ethylene group, a phenylene group substituted with a trifluoromethyl group, a phenylene group, a fluorinated phenylene group, —C(═O)—O—Z⁵¹—, —C(═O)—NH—Z⁵¹—, or —O—Z⁵¹—. Z⁵¹ represents an aliphatic hydrocarbylene group having 1 to 6 carbon atoms, a phenylene group, a fluorinated phenylene group, or a phenylene group substituted with a trifluoromethyl group, and Z⁵¹ optionally has a carbonyl group, an ester bond, an ether bond, or a hydroxy group.

The aliphatic hydrocarbylene groups represented by Z²¹, Z³¹, and Z⁵¹ may be any of linear, branched, and cyclic groups. Specific examples thereof include groups same as the group exemplified in the description of Z^{A1} in the formula (A-1).

The hydrocarbylene group represented by Z⁴¹ may be a saturated or unsaturated group, and may be any of linear, branched, and cyclic groups. Specific examples thereof include the following groups, but the hydrocarbylene group is not limited thereto.

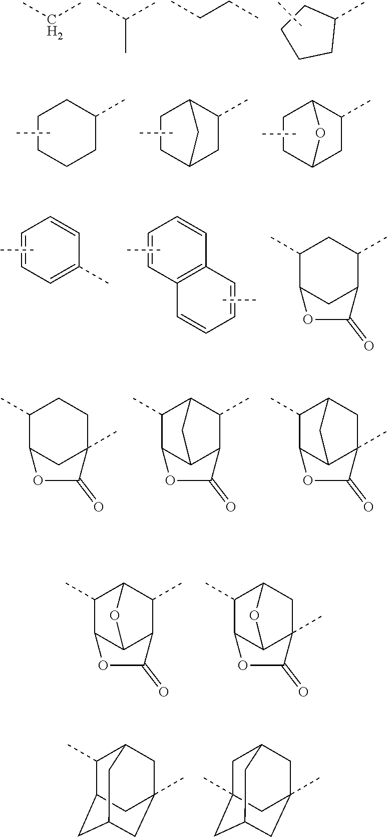

In the formulae, a broken line represents a bond.

In the formula (B-1), R²¹ and R²² each independently represents a hydrocarbyl group having 1 to 20 carbon atoms and optionally having a heteroatom. The hydrocarbyl group represented by R²¹ and R²² may be a saturated or unsaturated group, and may be any of linear, branched, and cyclic groups. Specific examples thereof include: alkyl groups, such as a methyl group, an ethyl group, an n-propyl group, an isopropyl group, an n-butyl group, and a tert-butyl group; cyclic saturated hydrocarbyl groups, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups, such as a vinyl group, an allyl group, a propenyl group, a butenyl group, and a hexenyl group; cyclic unsaturated hydrocarbyl groups, such as a cyclohexenyl group; aryl groups, such as a phenyl group, a naphthyl group, and a thienyl group; aralkyl groups, such as a benzyl group, a 1-phenylethyl group, and a 2-phenylethyl group; and groups obtained by combining these groups. Aryl groups are preferable. A part of hydrogen atoms in the hydrocarbyl group is optionally substituted with a group having a heteroatom, such as an oxygen atom, a sulfur atom, a nitrogen atom, and a halogen atom. Between carbon atoms in these groups, a group having a heteroatom such as an oxygen atom, a sulfur atom, and a nitrogen atom are optionally interposed. As a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, etc. are optionally contained.

R²¹ and R²² are optionally bonded each other to form a ring together with the sulfur atom to which R²¹ and R²² are bonded. Specific examples thereof include the following structures.

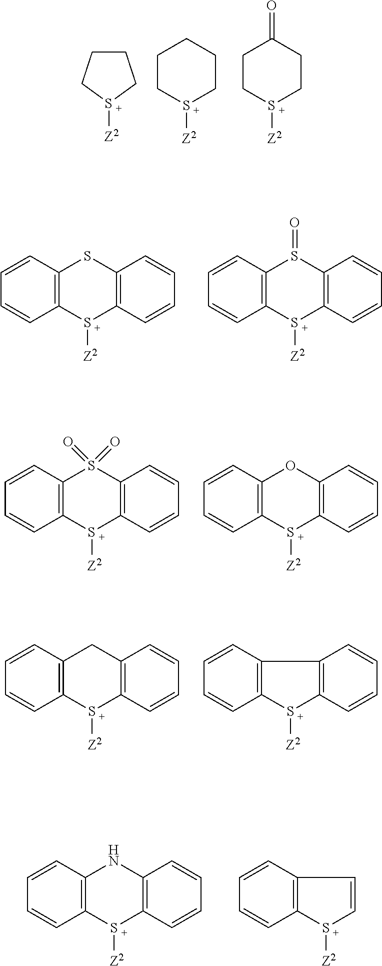

Examples of the cation of the repeating unit B1 include the following cations, but the cation is not limited thereto. In the following formulae, R^{A} is same as above.

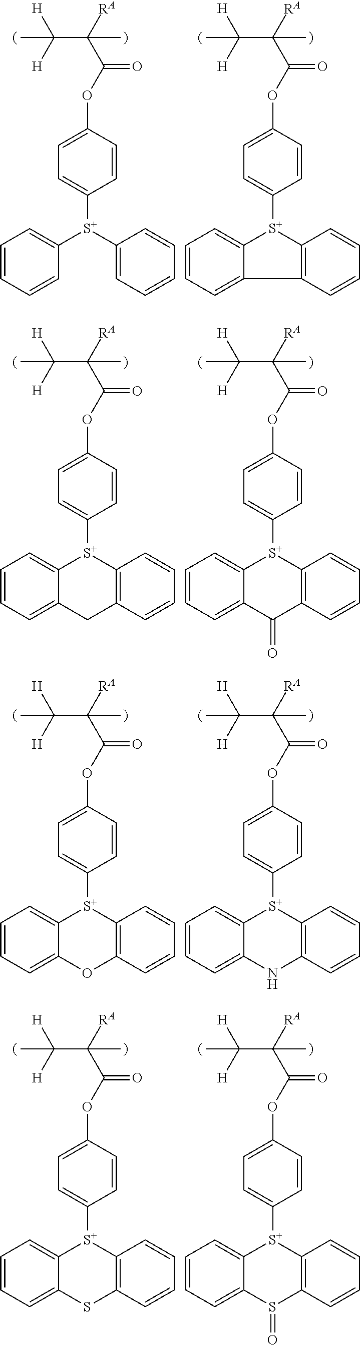

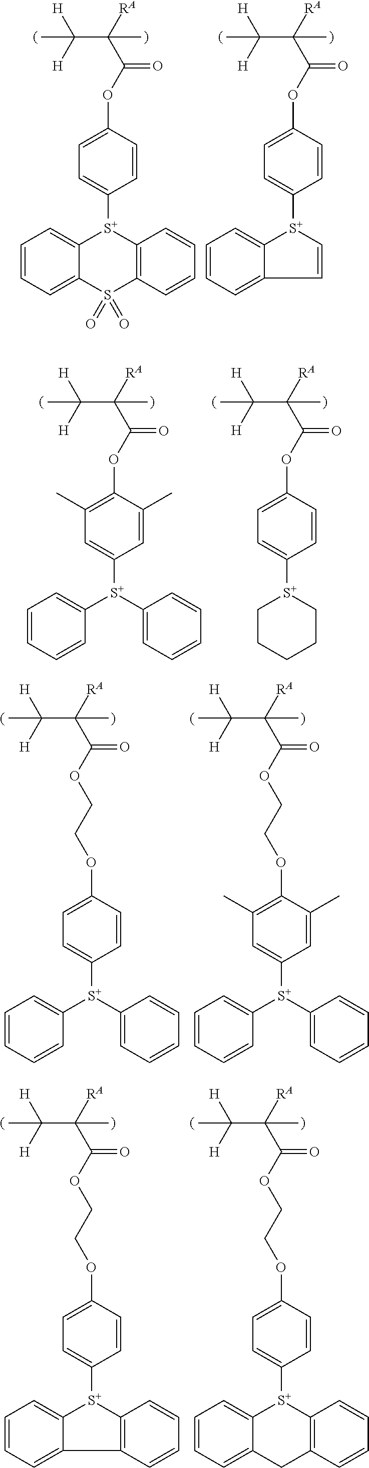

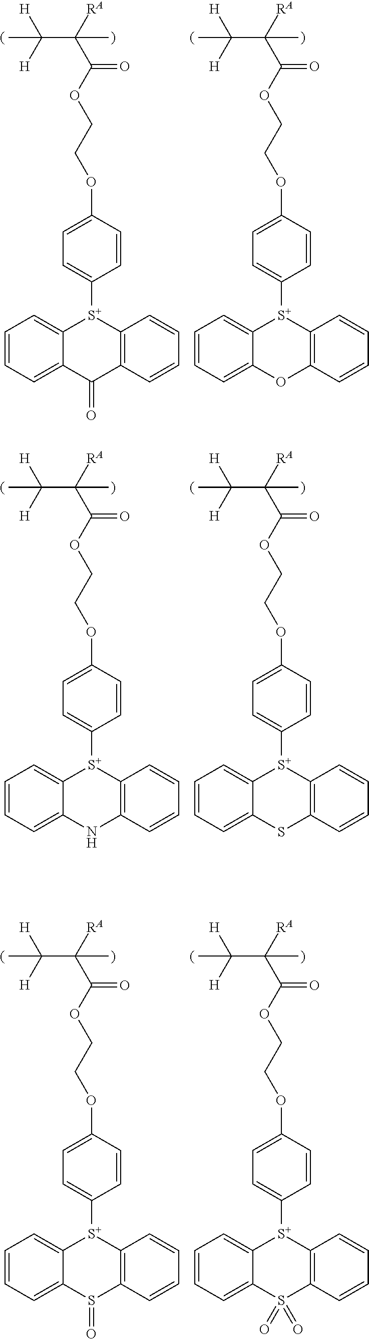

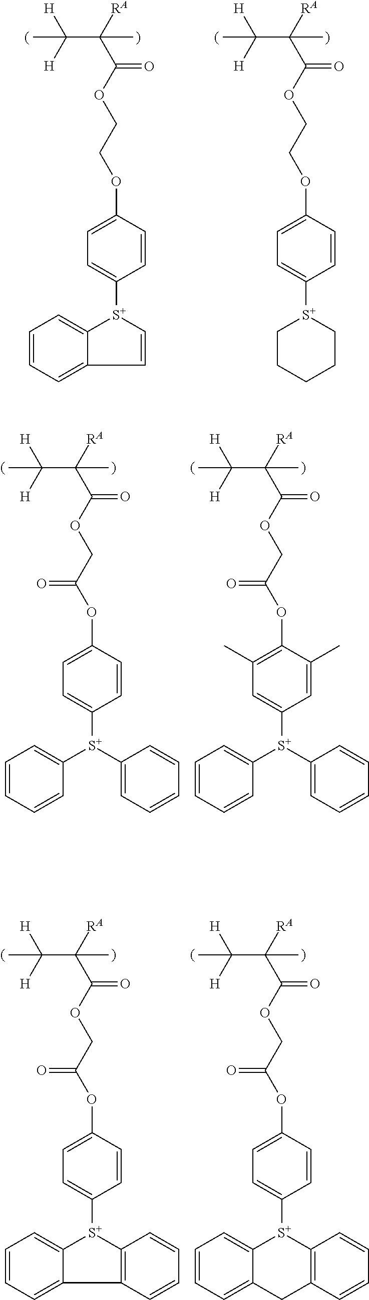

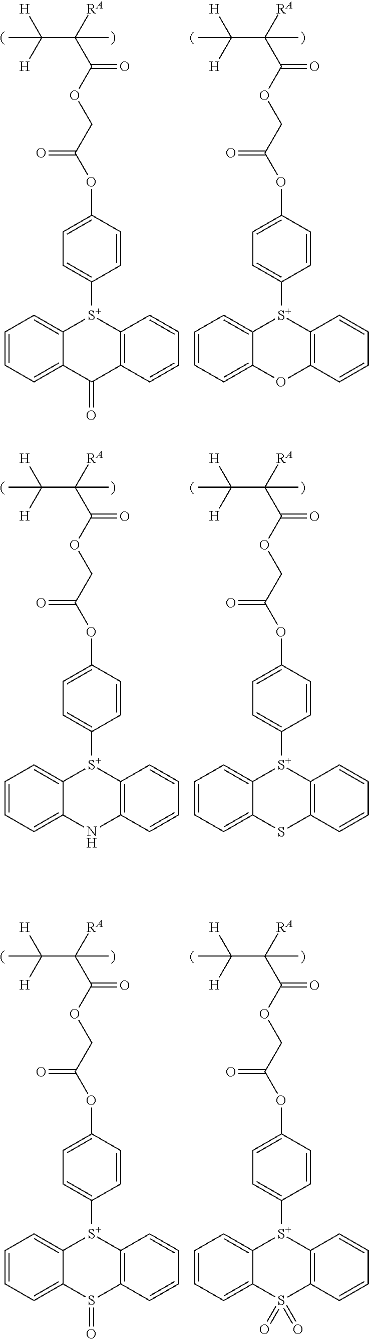

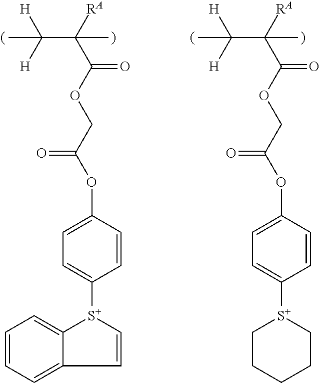

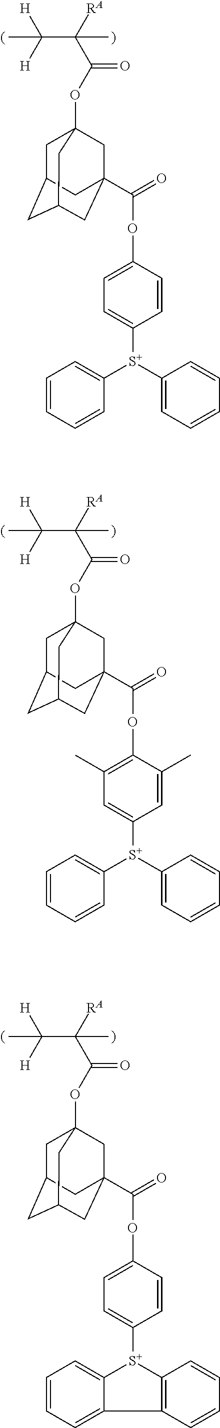

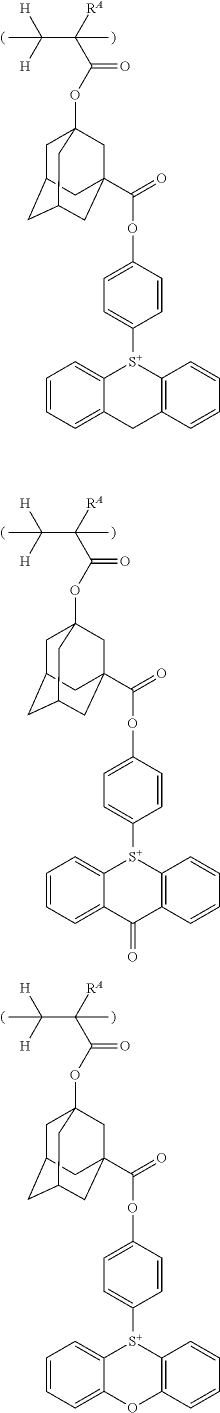

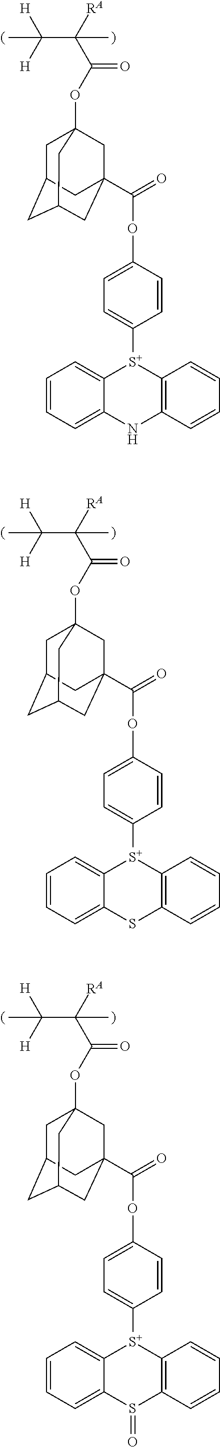

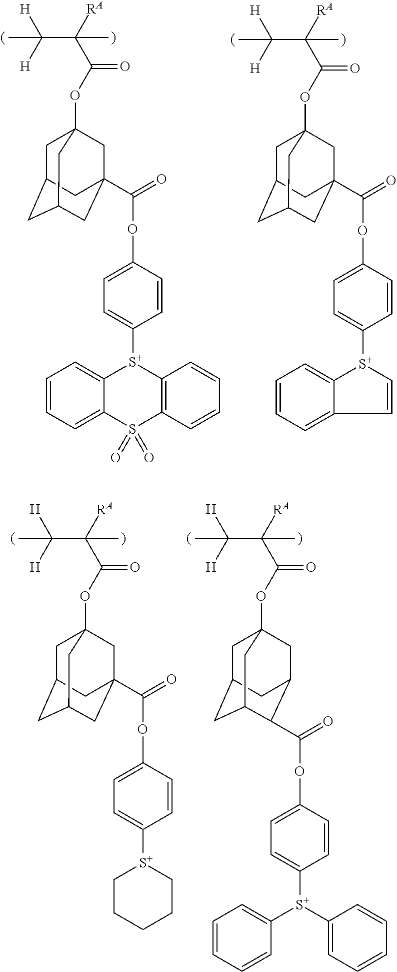

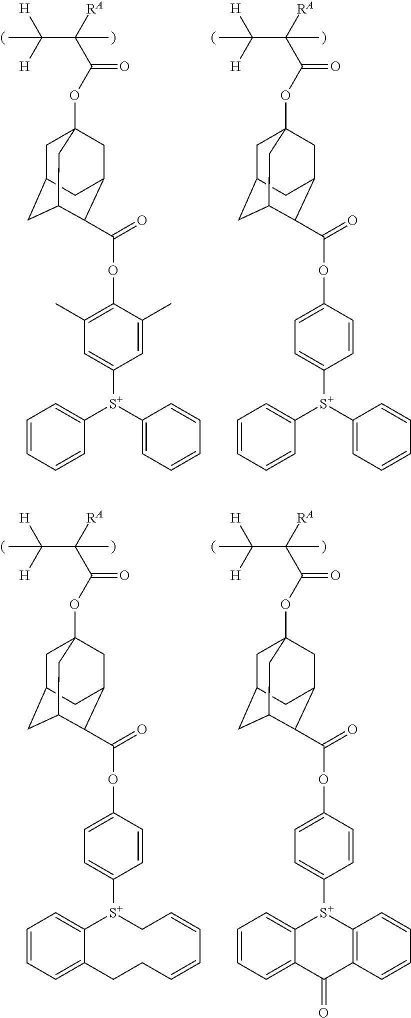

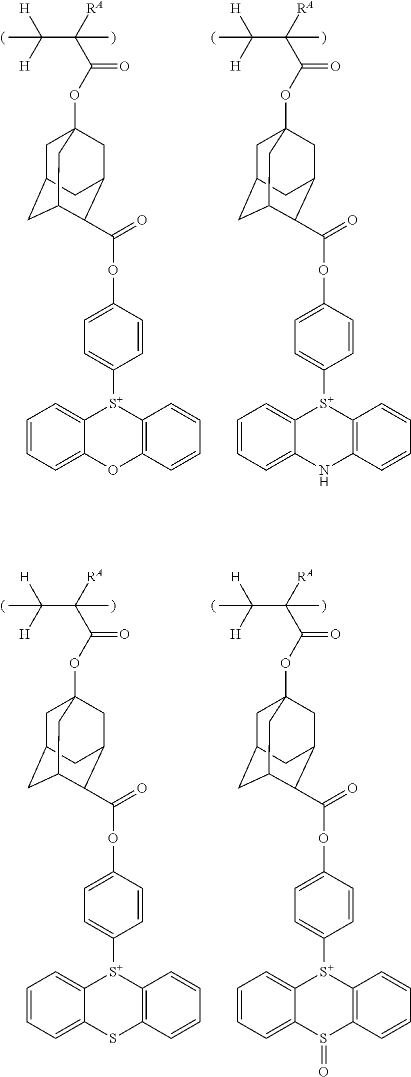

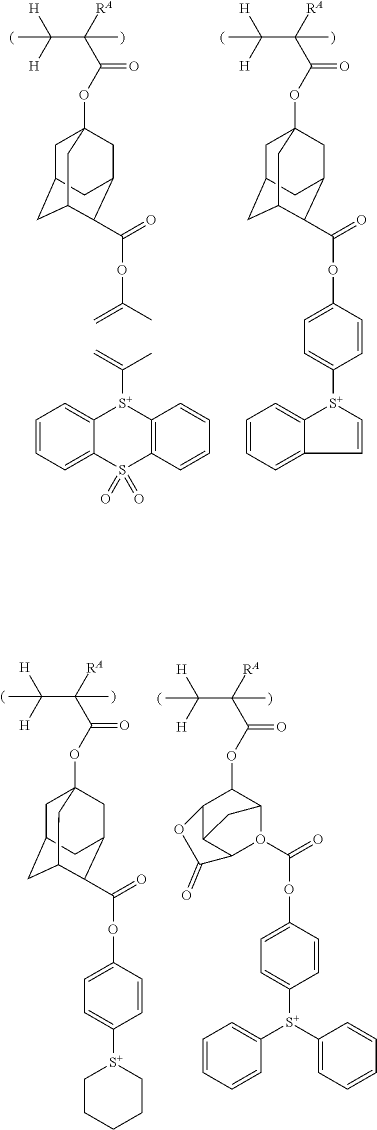

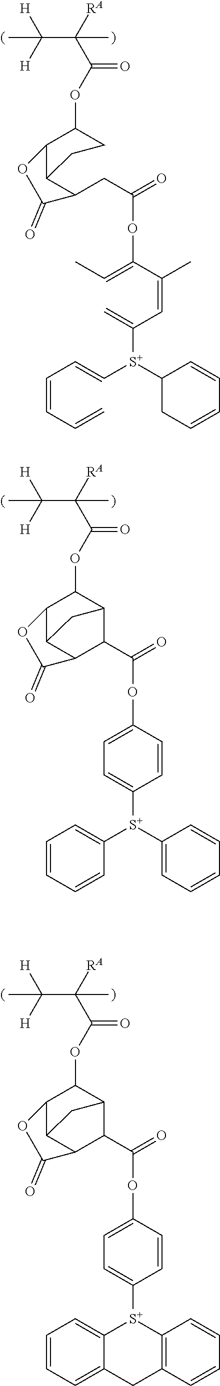

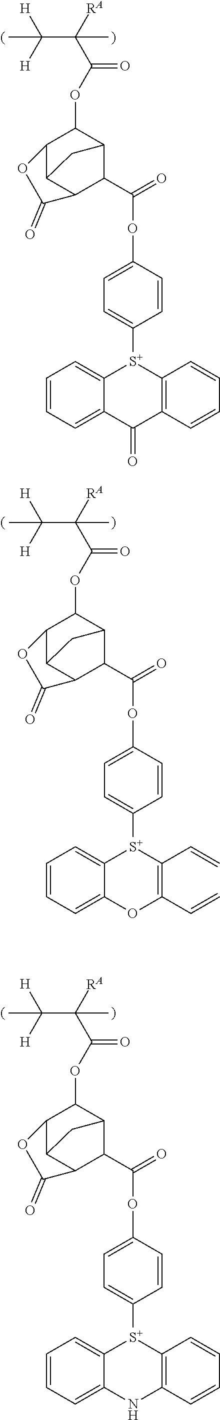

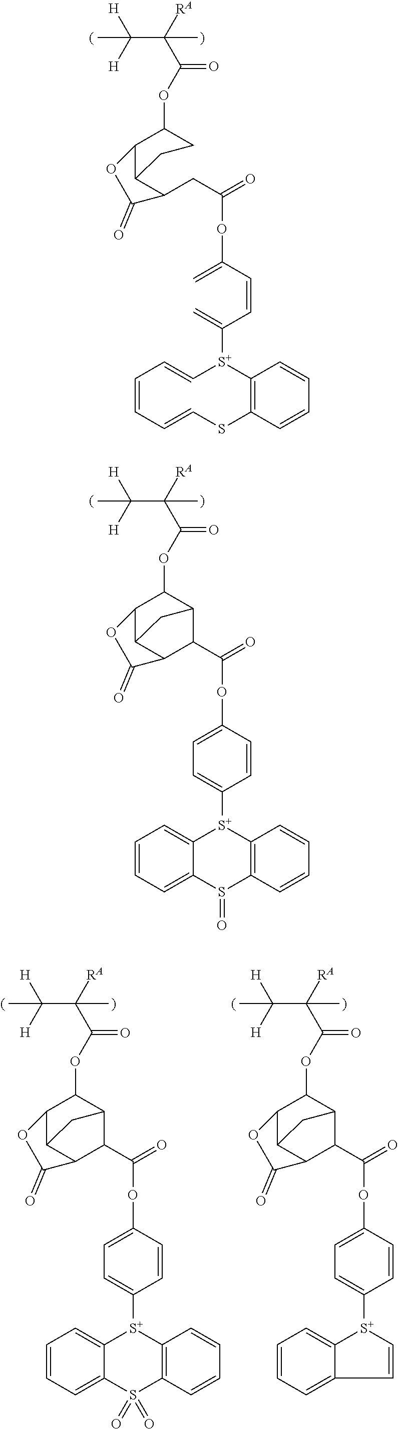

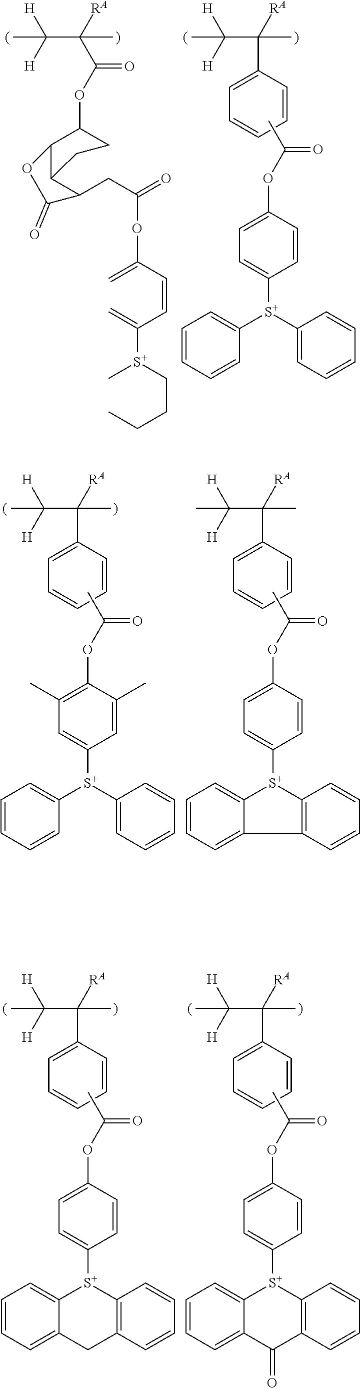

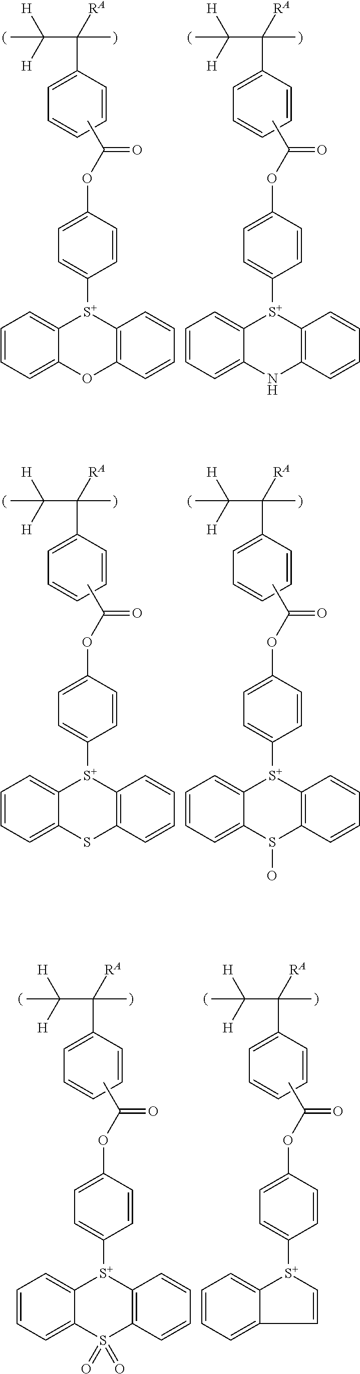

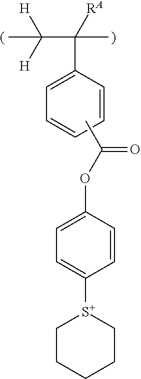

In the formula (B-1), M⁻ represents a non-nucleophilic counterion. Examples of the non-nucleophilic counterion represented by M⁻ include: halide ions, such as a chloride ion and a bromide ion; fluoroalkylsulfonate ions, such as a triflate ion, a 1,1,1-trifluoroethanesulfonate ion, and a nonafluorobutanesulfonate ion; arylsulfonate ions, such as a tosylate ion, a benzenesulfonate ion, a 4-fluorobenzenesulfonate ion, and a 1,2,3,4,5-pentafluorobenzenesulfonate ion; alkylsulfonate ions, such as a mesylate ion and a butanesulfonate ion; imidic acid ions, such as a bis(trifluoromethylsulfonyl)imide ion, a bis(perfluoroethylsulfonyl)imide ion, and a bis(perfluorobutylsulfonyl)imide ion; and methide acid ions, such as a tris(trifluoromethylsulfonyl)methide ion and a tris(perfluoroethylsulfonyl)methide ion.

Examples of the non-nucleophilic counterion further include: sulfonic acid anions represented by the following formula (B-1-1), whose α-position is substituted with a fluorine atom; and sulfonic acid anions represented by the following formula (B-1-2), in which the α-position is substituted with a fluorine atom and the β-position is substituted with a trifluoromethyl group.

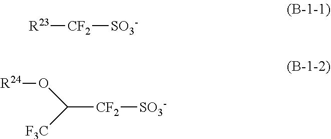

In the formula (B-1-1), R²³ represents a hydrogen atom or a hydrocarbyl group having 1 to 20 carbon atoms and optionally having an ether bond, an ester bond, a carbonyl group, a lactone ring, or a fluorine atom. The hydrocarbyl group may be a saturated or unsaturated group, and may be any of linear, branched, and cyclic groups. Specific examples thereof include groups same as groups that will be described as a hydrocarbyl group represented by R¹⁰⁵ in the formula (3A′).

In the formula (B-1-2), R²⁴ represents a hydrogen atom, a hydrocarbyl group having 1 to 30 carbon atoms, a hydrocarbylcarbonyl group having 2 to 30 carbon atoms, or an aryloxy group having 6 to 20 carbon atoms. These groups optionally have an ether bond, an ester bond, a carbonyl group, or a lactone ring. The hydrocarbyl group and the hydrocarbyl part in the hydrocarbylcarbonyl group may be a saturated or unsaturated group, and may be any of linear, branched, and cyclic groups. Specific examples thereof include groups same as groups that will be described as a hydrocarbyl group represented by R¹⁰⁵ in the formula (3A′).

Specific examples of the sulfonic acid anion represented by the non-nucleophilic counterion include the following anions, but the sulfonic acid anion is not limited thereto. In the following formulae, Q³ represents a hydrogen atom, a fluorine atom, or a fluorinated alkyl group having 1 to 6 carbon atoms. Ac represents an acetyl group.

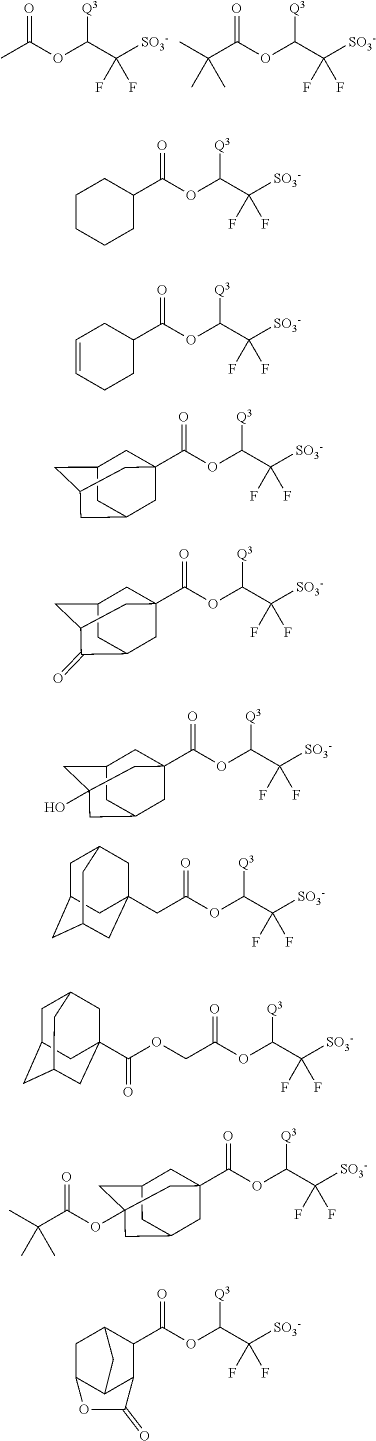

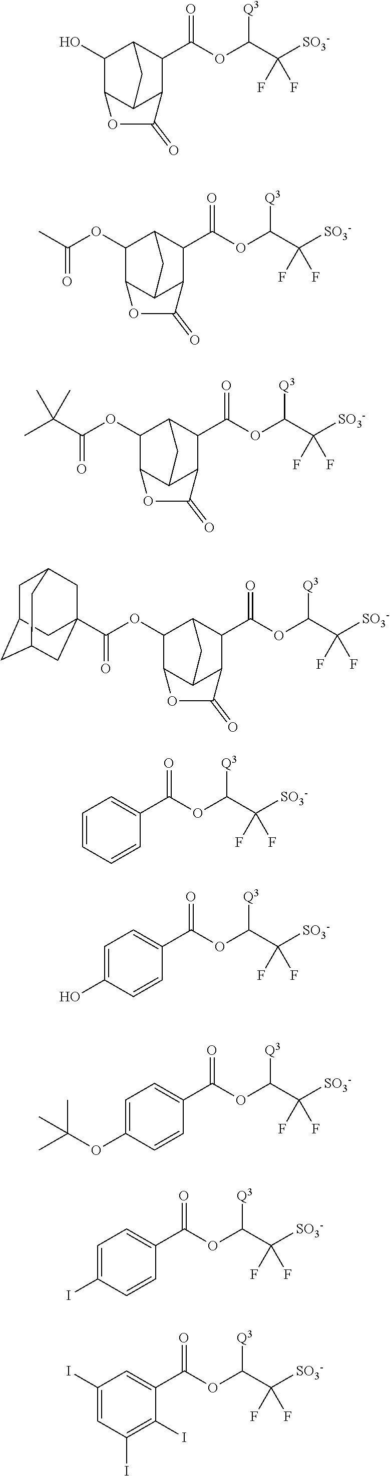

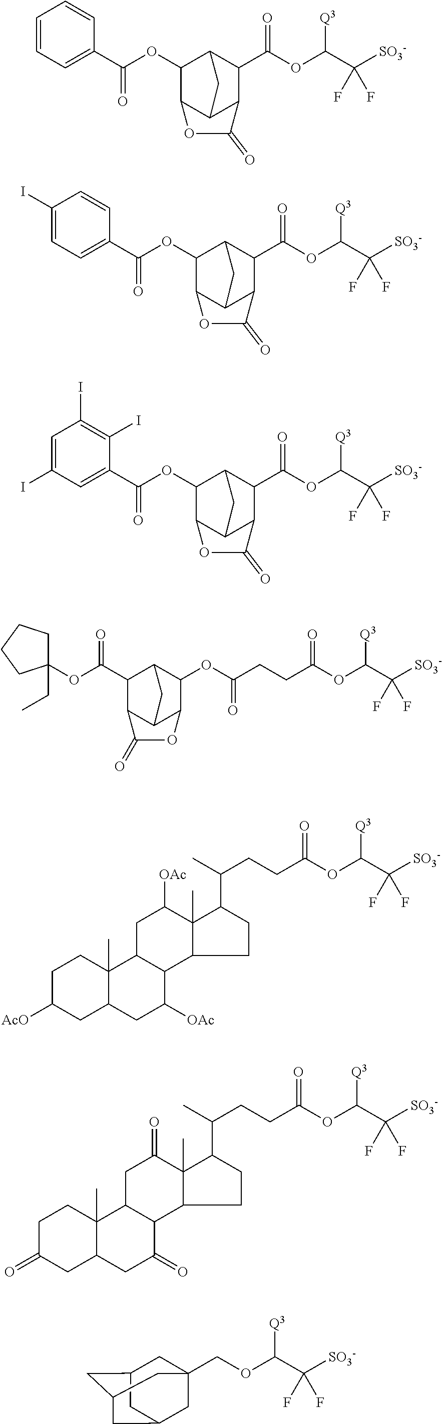

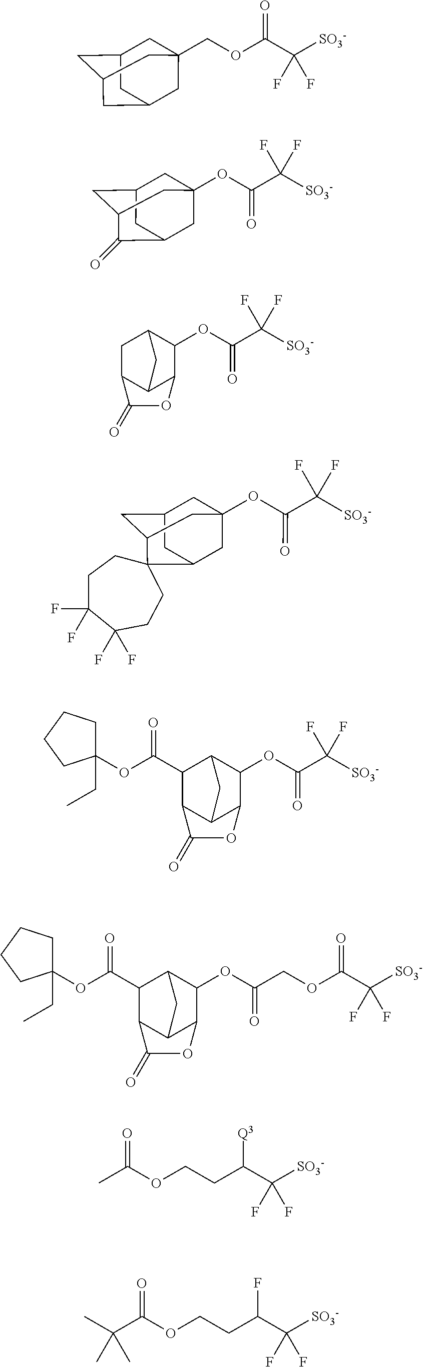

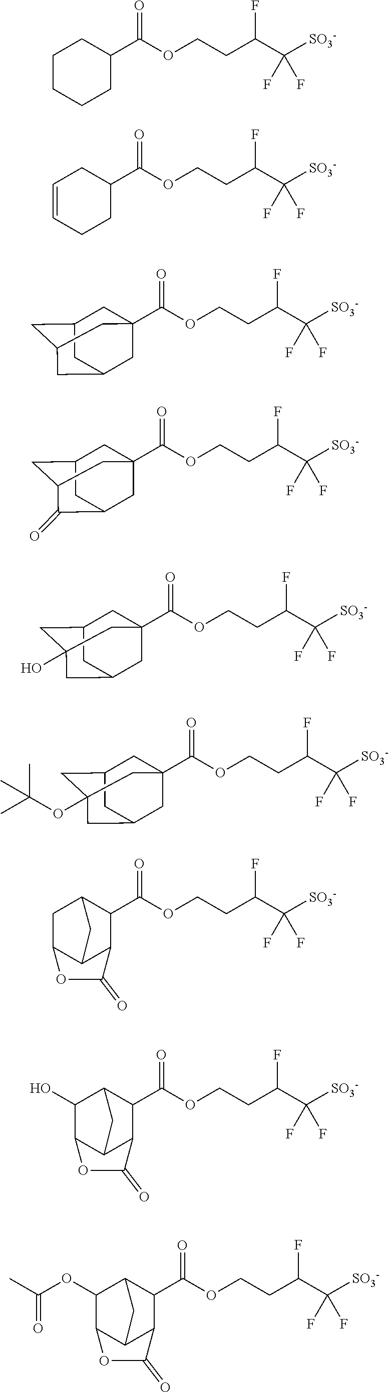

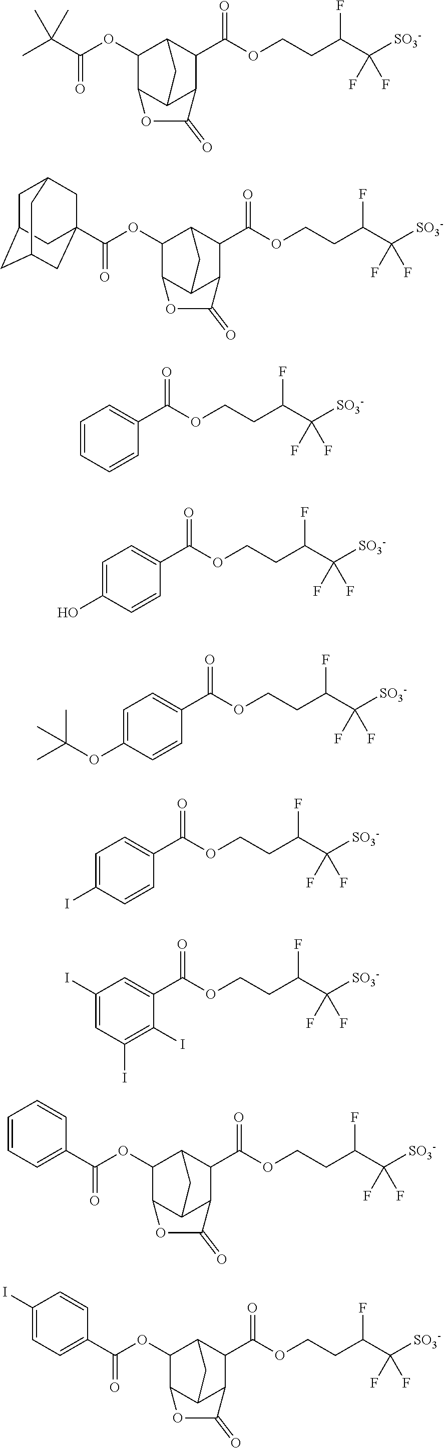

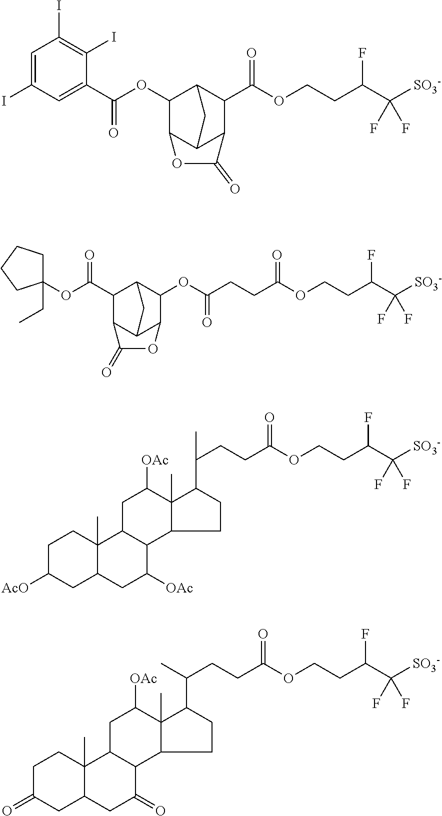

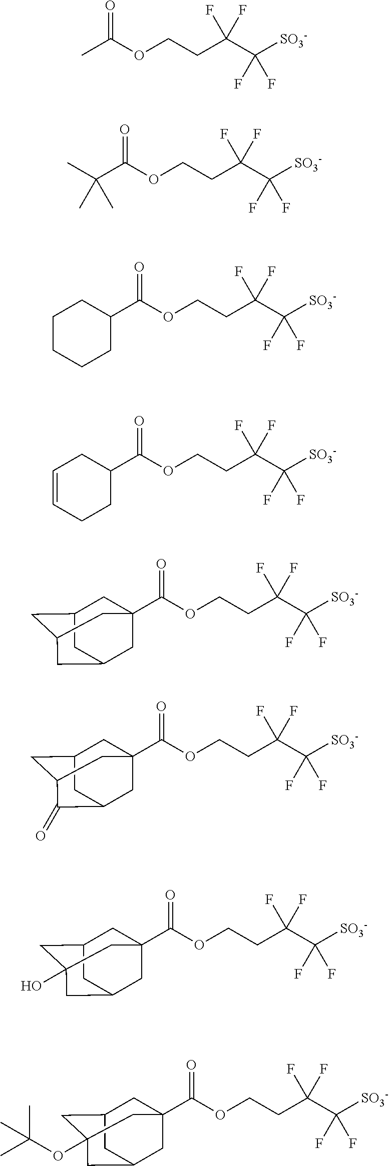

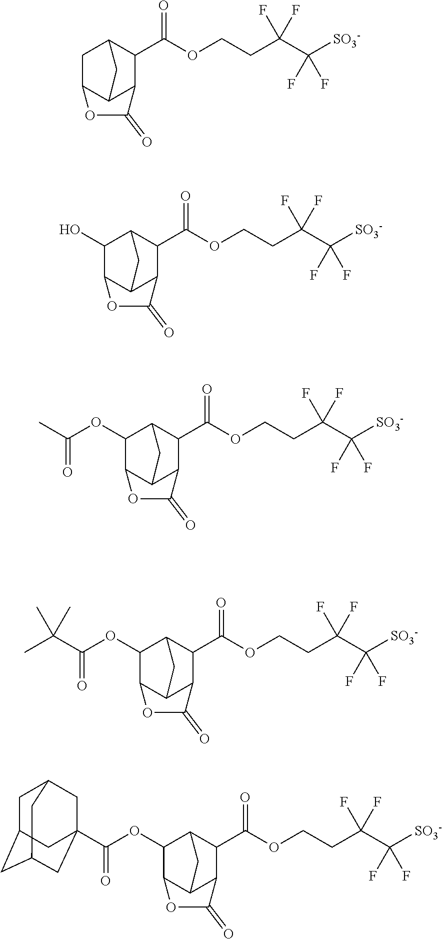

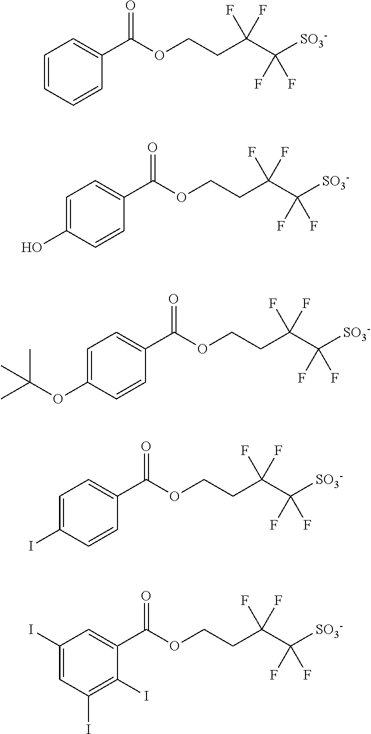

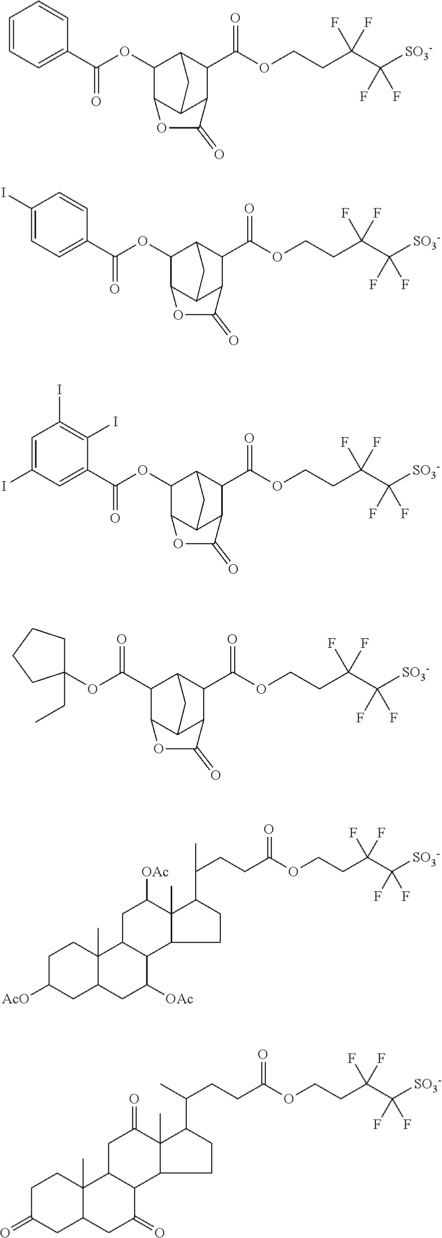

In the formula (B-2), L¹¹ represents a single bond, an ether bond, an ester bond, a carbonyl group, a sulfonic acid ester bond, a carbonate bond, or a carbamate bond. Among these, an ether bond, an ester bond, and a carbonyl group are preferable, and an ester bond and a carbonyl group are further preferable, from the viewpoint of synthesis.

In the formula (B-2), Rf¹ and Rf² each independently represent a fluorine atom or a fluorinated alkyl group having 1 to 6 carbon atoms. Among these, both Rf¹ and Rf² are preferably fluorine atoms in terms of increase in acid strength of the generated acid. Rf³ and Rf⁴ each independently represent a hydrogen atom, a fluorine atom, or a fluorinated alkyl group having 1 to 6 carbon atoms. Among these, at least one of Rf³ and Rf⁴ is preferably a trifluoromethyl group in terms of improvement of the solvent solubility.

In the formula (B-2), “c” represents an integer of 0 to 3, and preferably 1.

Specific examples of the anion of the repeating unit represented by the formula (B-2) include the following anions, but the anion is not limited thereto. In the following formulae, R^{A} is same as above.

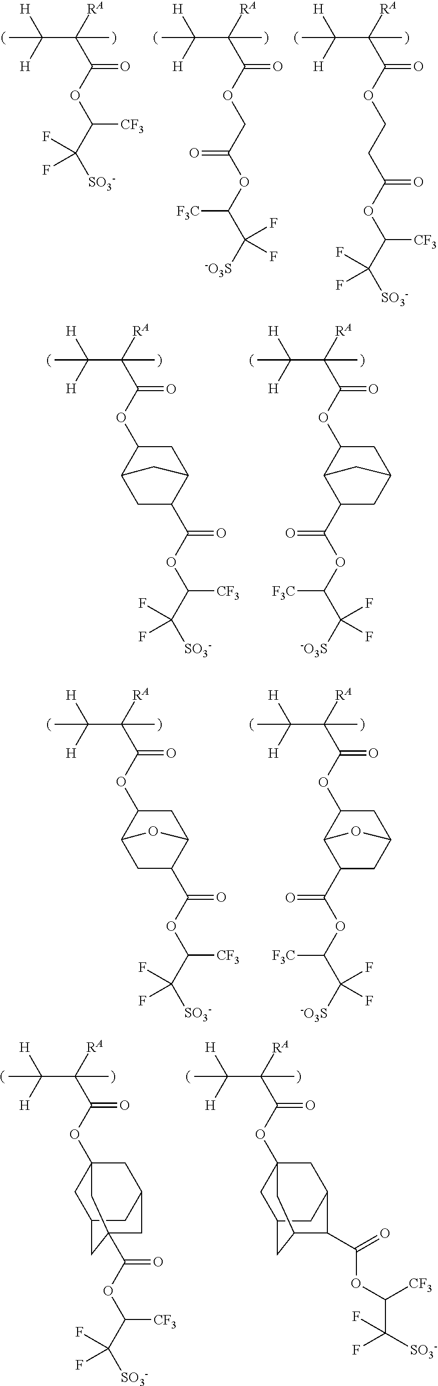

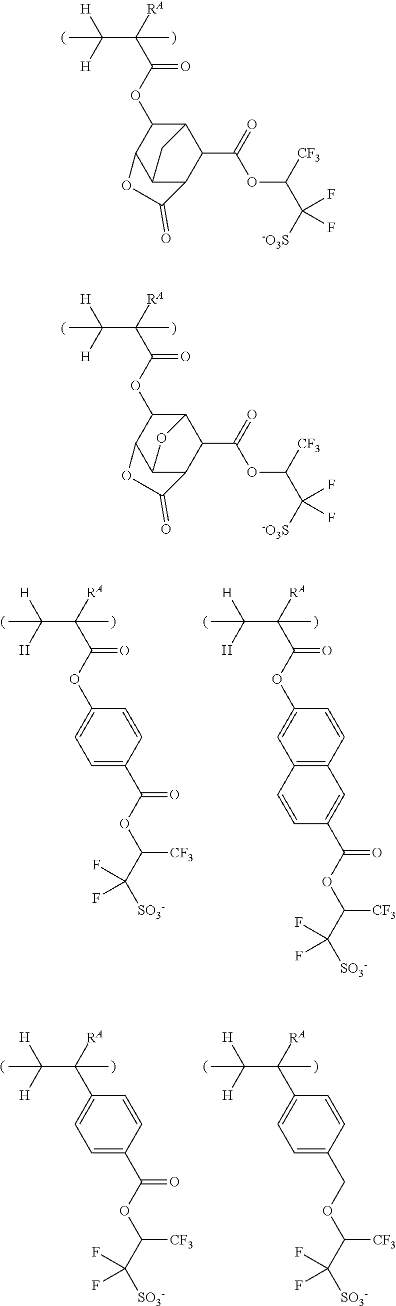

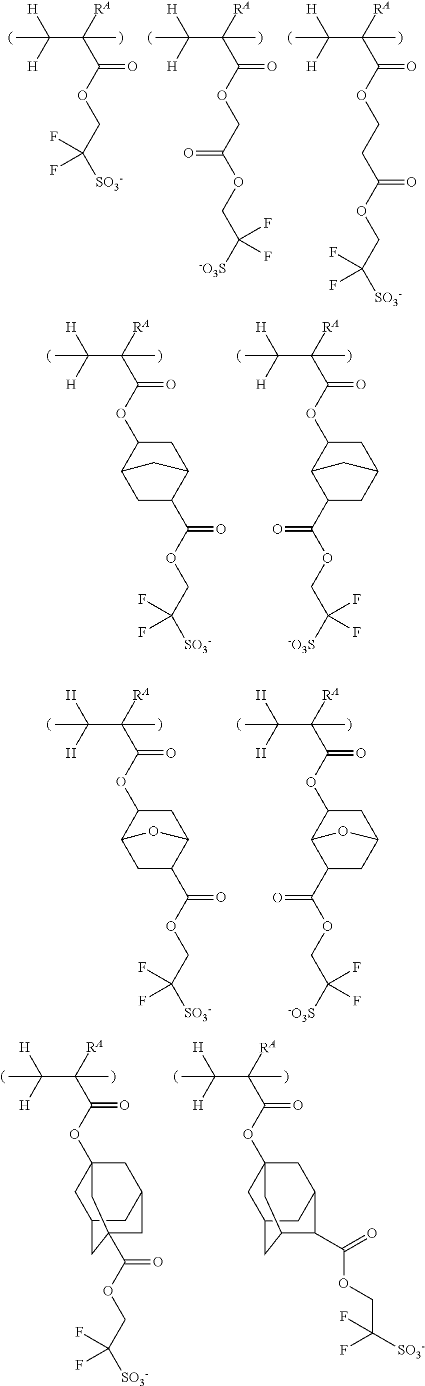

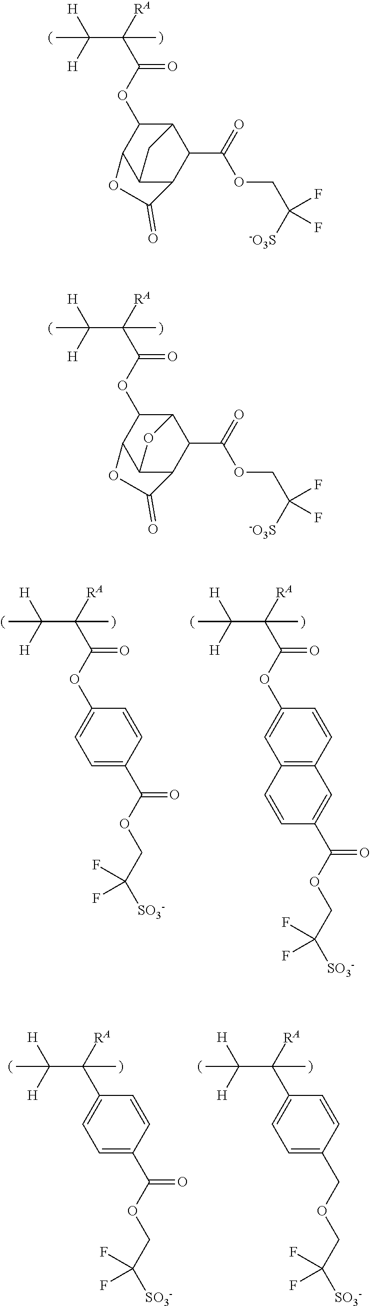

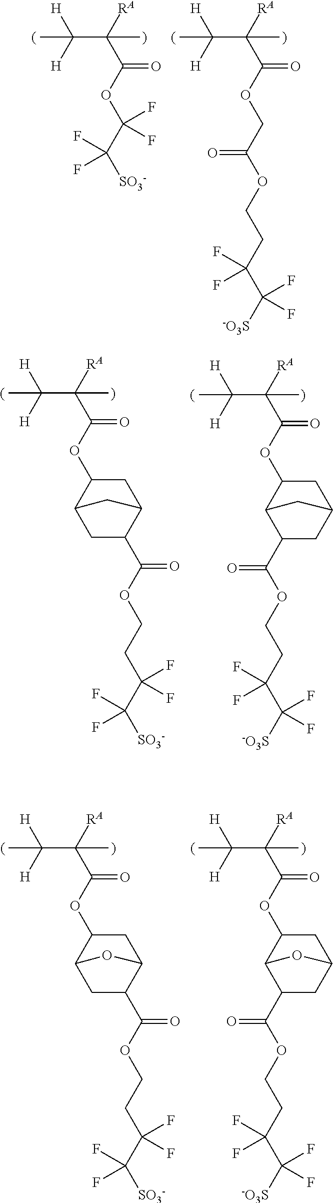

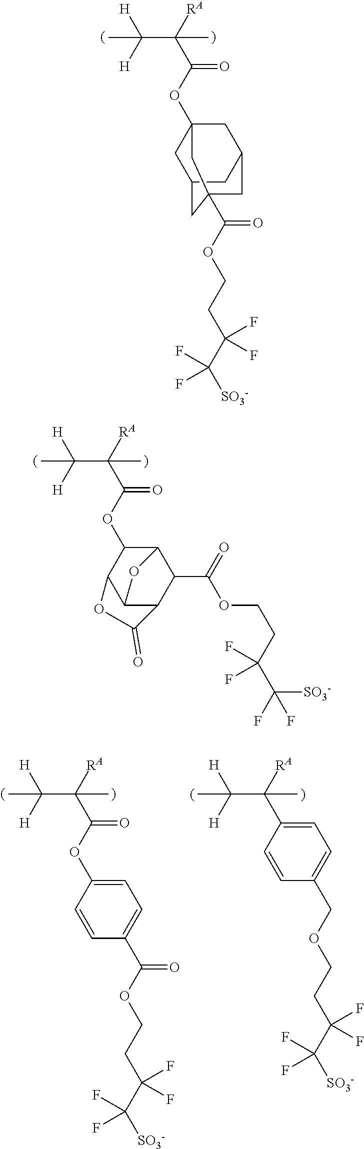

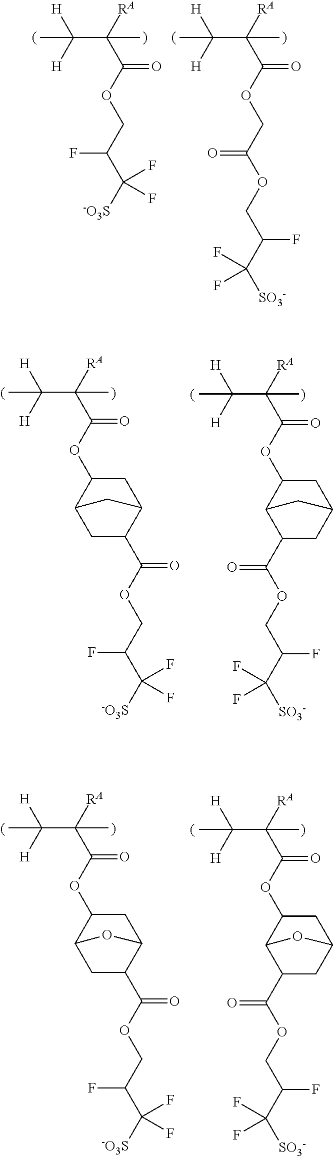

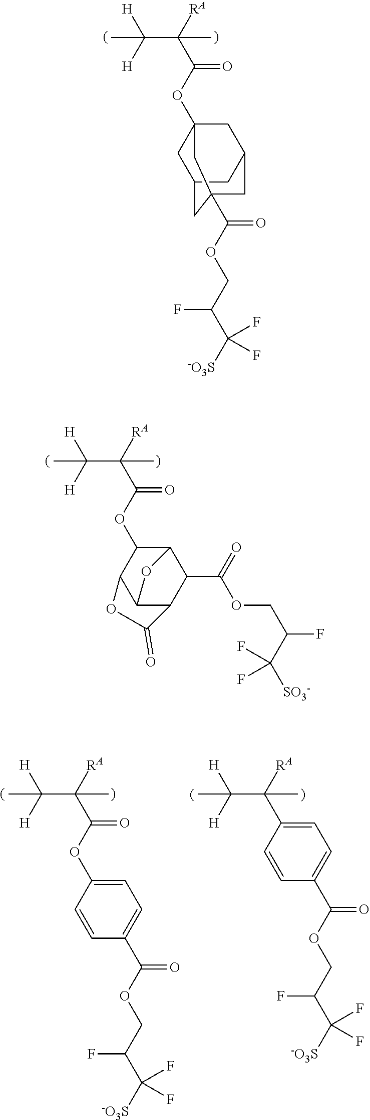

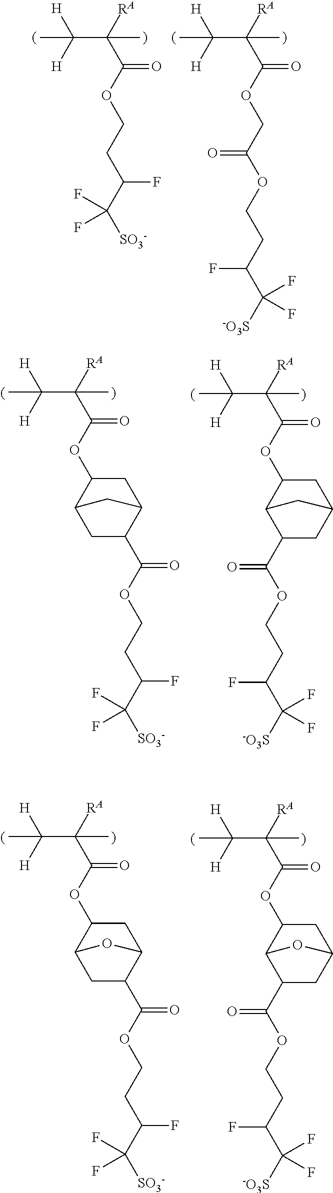

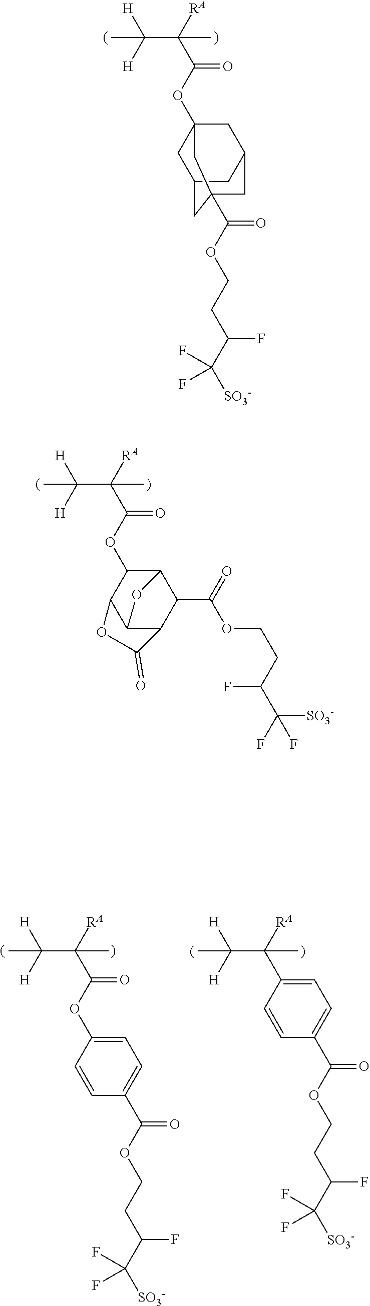

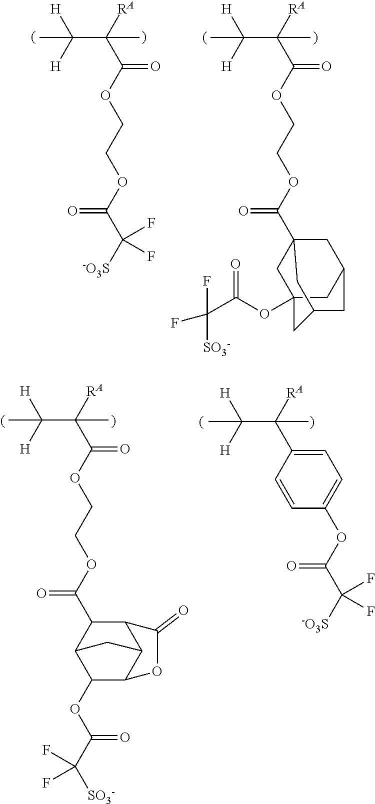

In the formula (B-3), L¹¹ represents a single bond, an ether bond, an ester bond, a carbonyl group, a sulfonic acid ester bond, a carbonate bond, or a carbamate bond. Among these, an ether bond, an ester bond, and a carbonyl group are preferable, and an ester bond and a carbonyl group are further preferable, from the viewpoint of synthesis.

In the formula (B-3), Rf³ and Rf⁴ each independently represent a hydrogen atom, a fluorine atom, or a fluorinated alkyl group having 1 to 6 carbon atoms. Among these, at least one of Rf³ and Rf⁴ is preferably a trifluoromethyl group in terms of improvement of the solvent solubility.

In the formula (B-3), “c” represents an integer of 0 to 3, and preferably 1.

Specific examples of the anion of the repeating unit represented by the formula (B-3) include the following anions, but the anion is not limited thereto. In the following formulae, R^{A} is same as above.

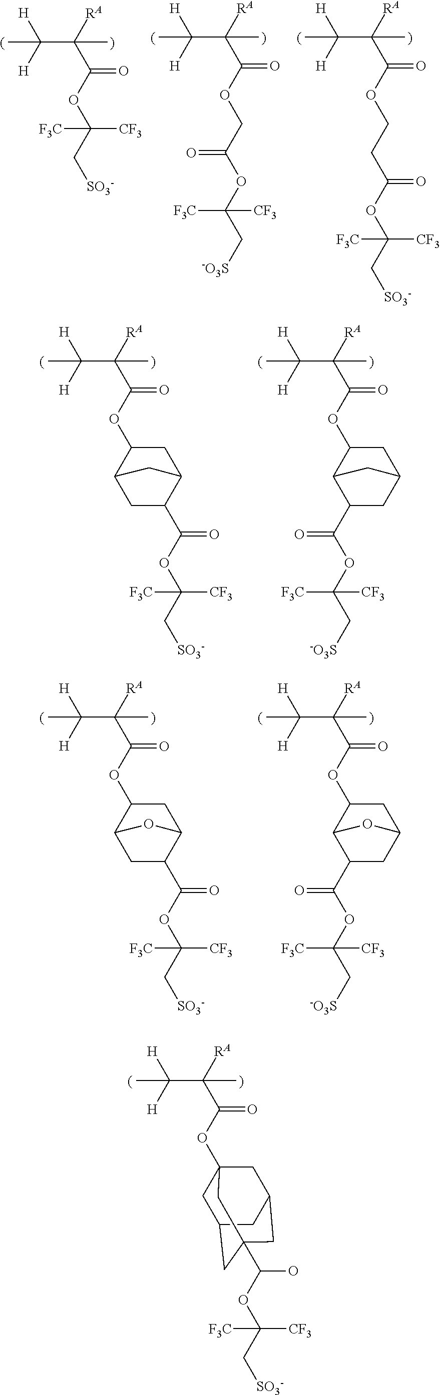

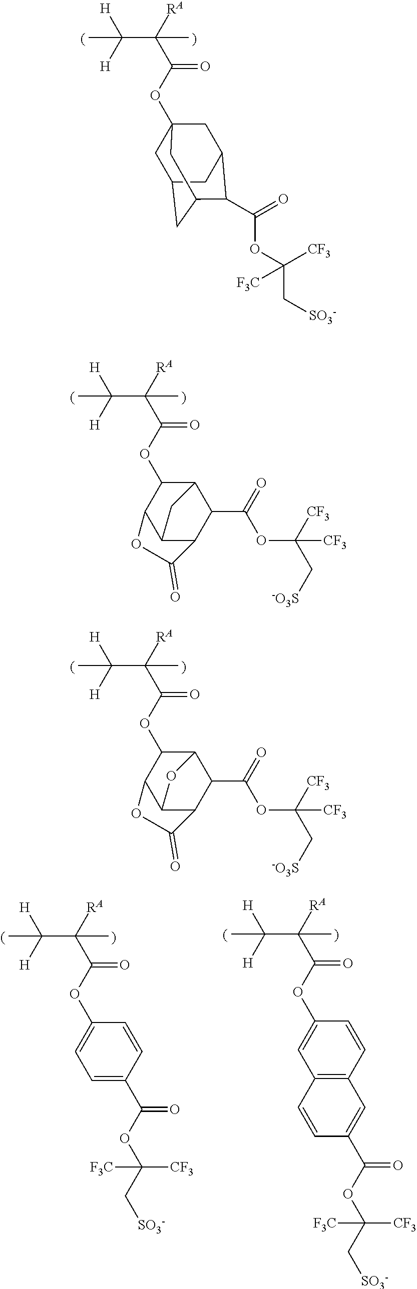

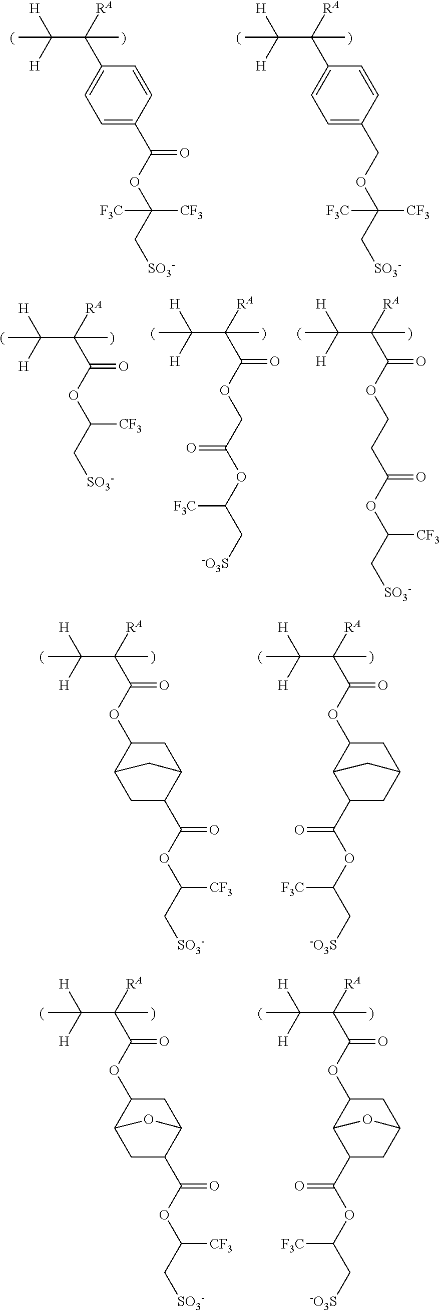

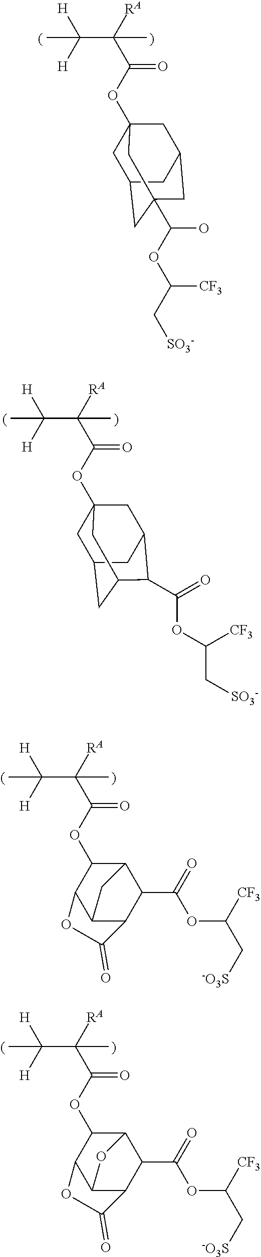

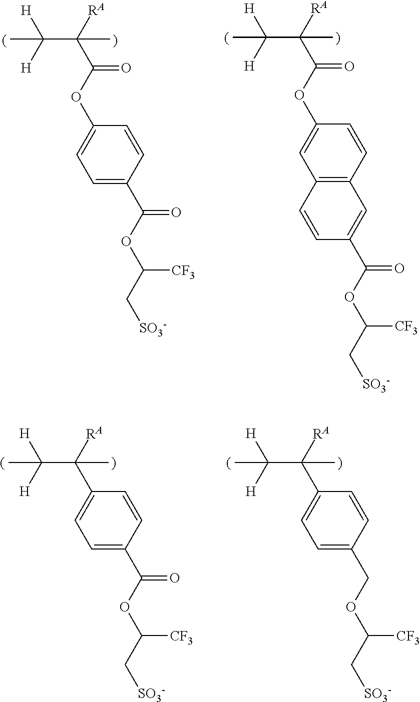

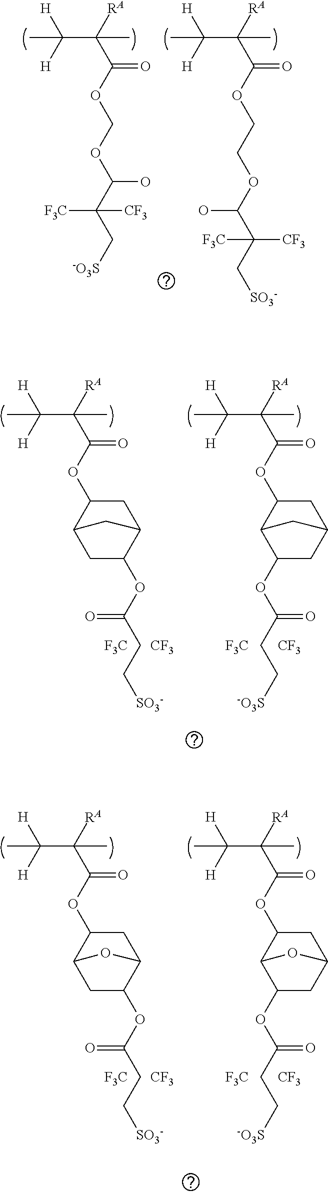

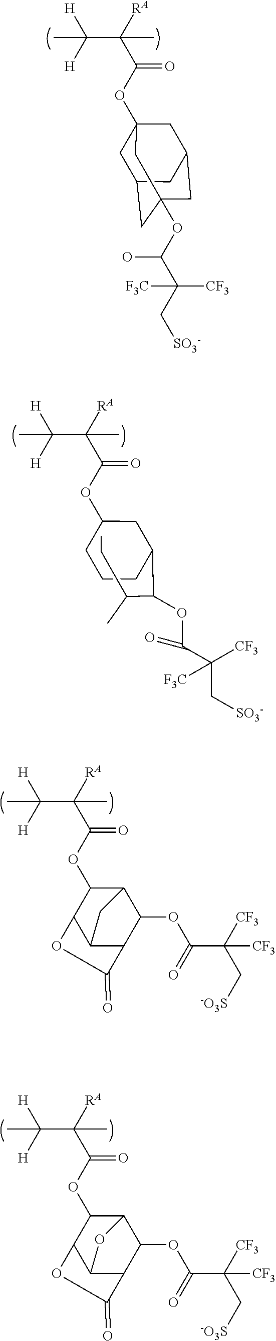

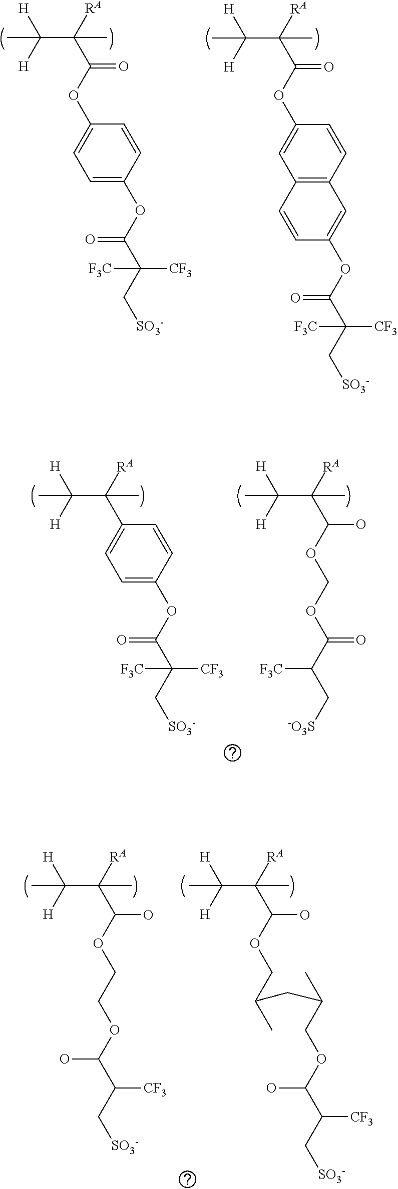

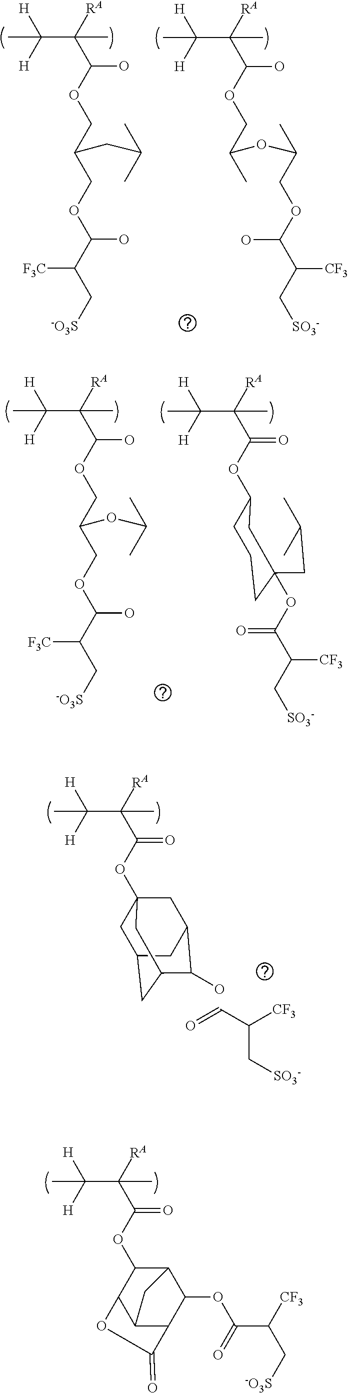

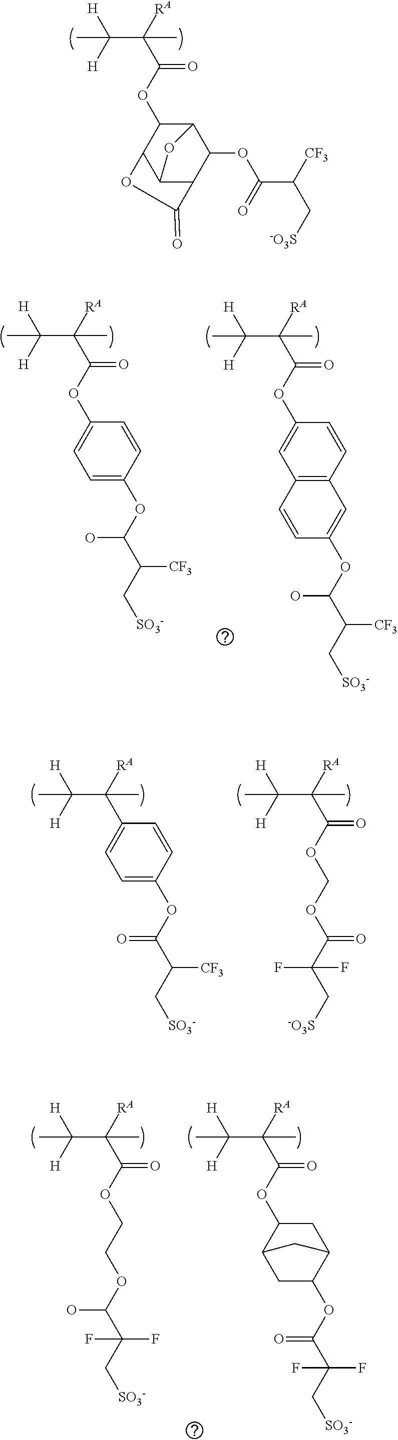

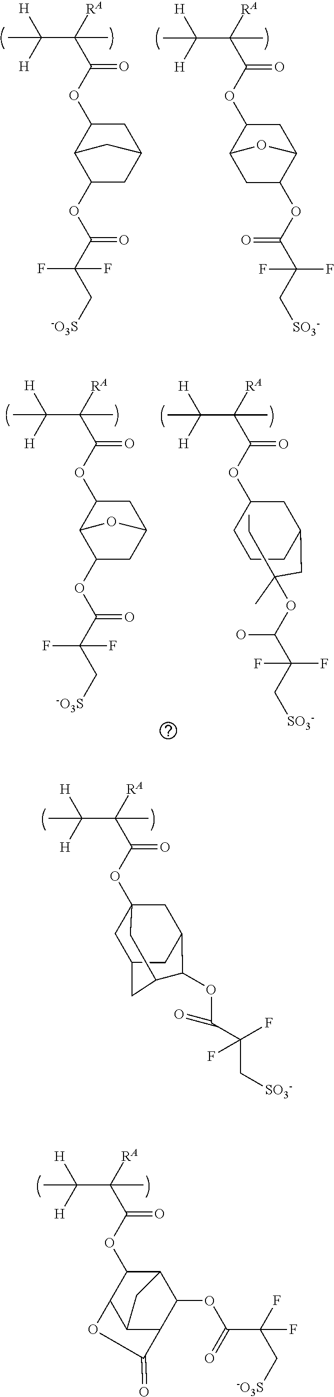

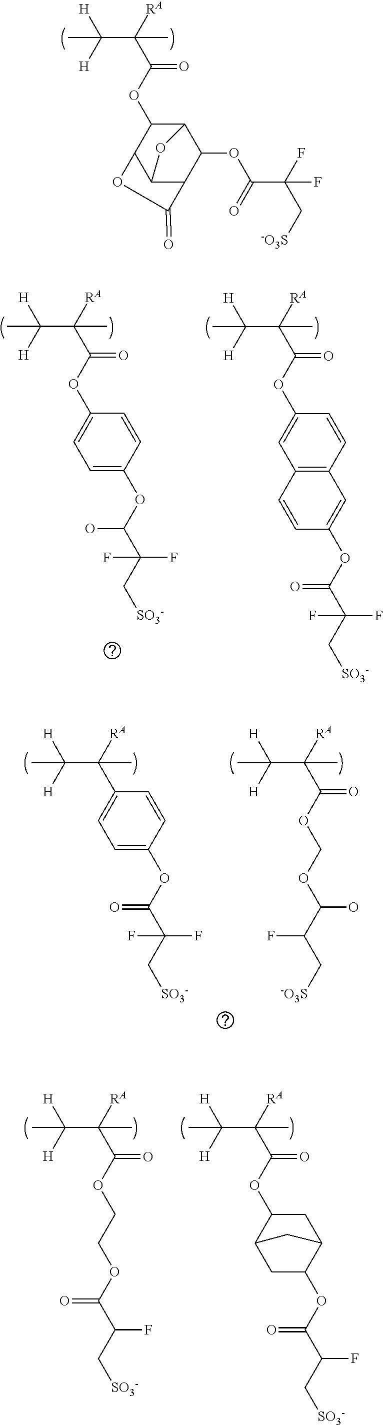

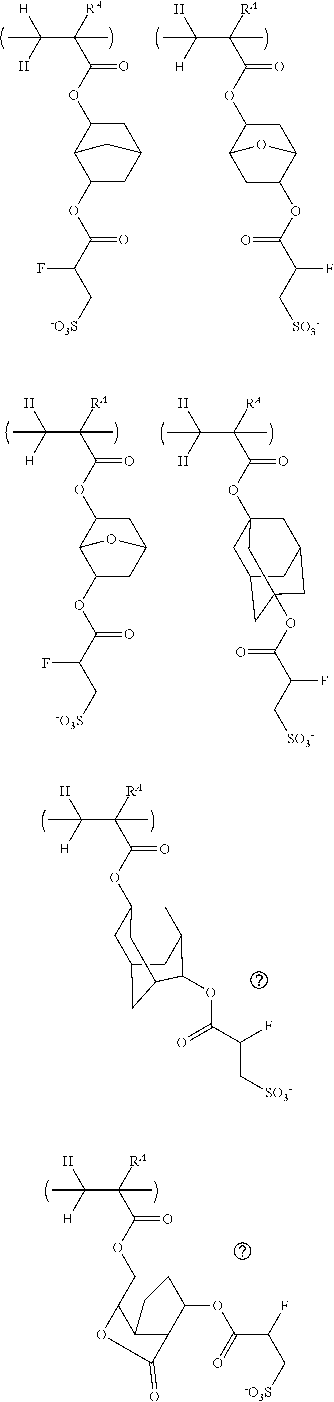

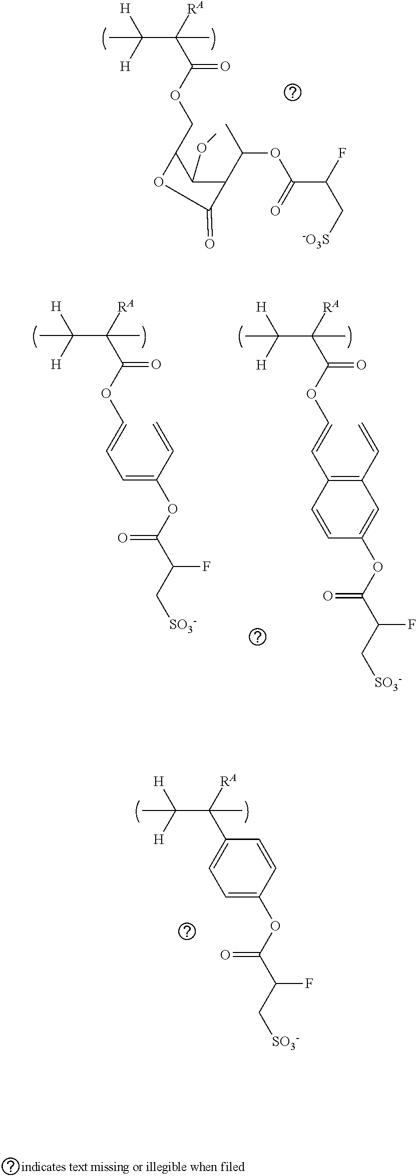

Specific examples of the anion of the repeating unit represented by the formula (B-4) include the following anions, but the anion is not limited thereto. In the following formulae, R^{A} is same as above.

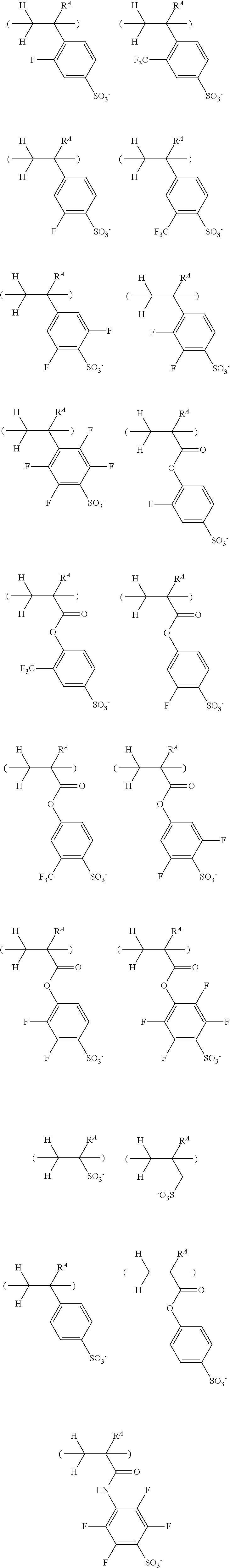

In the formulae (B-2) to (B-4), A⁺ represents an onium cation. Examples of the onium cation include an ammonium cation, a sulfonium cation, and an iodonium cation. A sulfonium cation and an iodonium cation are preferable. A sulfonium cation represented by the following formula (cation-1) and an iodonium cation represented by the following formula (cation-2) are more preferable.

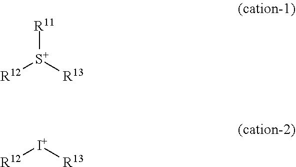

In the formulae (cation-1) and (cation-2), R¹¹ to R¹⁵ each independently represent a hydrocarbyl group having 1 to 30 carbon atoms and optionally having a heteroatom. The hydrocarbyl group may be a saturated or unsaturated group, and may be any of linear, branched, and cyclic groups. Specific examples thereof include: alkyl groups, such as a methyl group, an ethyl group, an n-propyl group, an isopropyl group, an n-butyl group, and a tert-butyl group; cyclic saturated hydrocarbyl groups, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups, such as a vinyl group, an allyl group, a propenyl group, a butenyl group, and a hexenyl group; cyclic unsaturated hydrocarbyl groups, such as a cyclohexenyl group; aryl groups, such as a phenyl group, a naphthyl group, and a thienyl group; aralkyl groups, such as a benzyl group, a 1-phenylethyl group, and a 2-phenylethyl group; and groups obtained by combining these groups. Aryl groups are preferable. A part of hydrogen atoms in the hydrocarbyl group is optionally substituted with a group having a heteroatom, such as an oxygen atom, a sulfur atom, a nitrogen atom, and a halogen atom. Between carbon atoms in these groups, a group having a heteroatom such as an oxygen atom, a sulfur atom, and a nitrogen atom are optionally interposed. As a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, etc. are optionally contained.

R¹¹ and R¹² are optionally bonded each other to form a ring together with the sulfur atom to which R¹¹ and R¹² are bonded. In this time, examples of the sulfonium cation represented by the formula (cation-1) include the following cations.

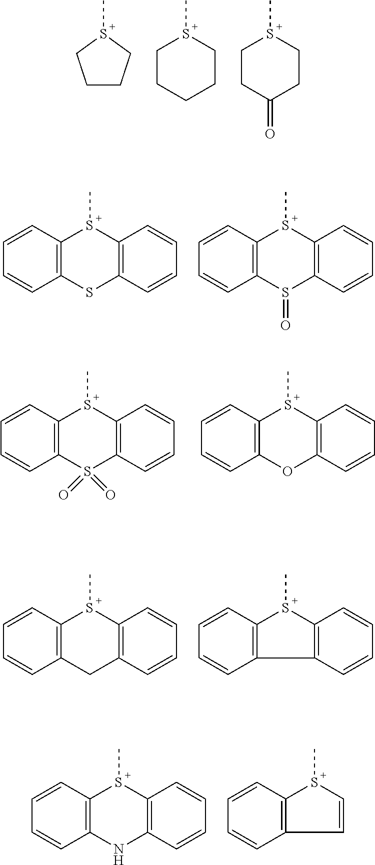

In the formulae, a broken line represents a bond to R¹³.

Examples of the sulfonium cation represented by the formula (cation-1) include the following cations, but the sulfonium cation is not limited thereto.

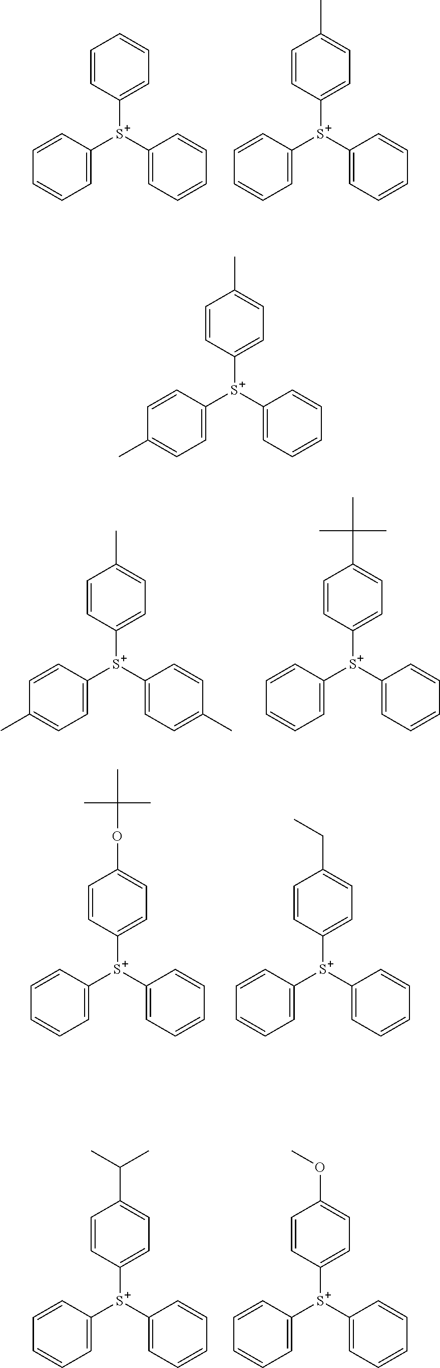

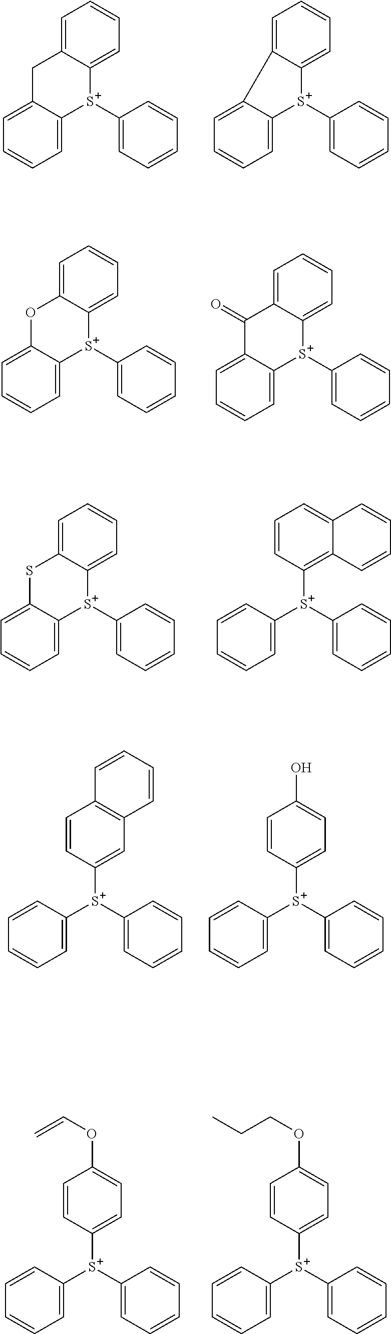

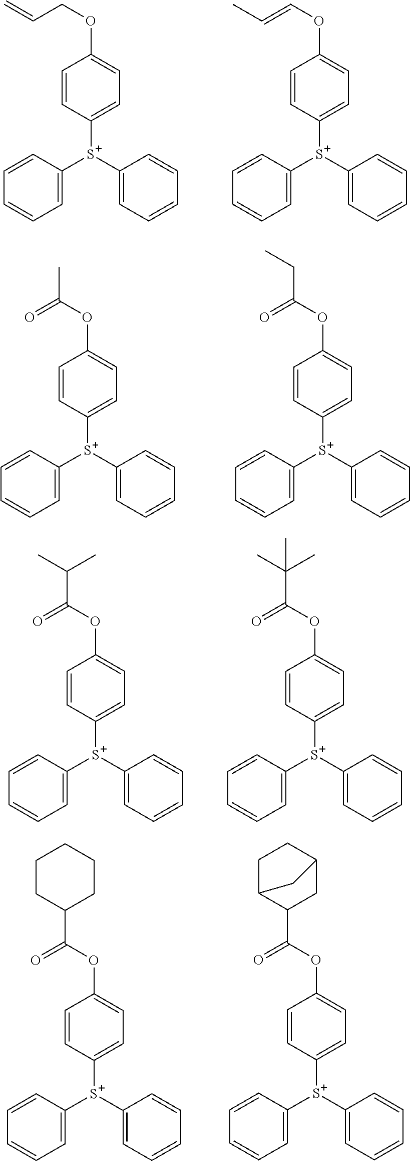

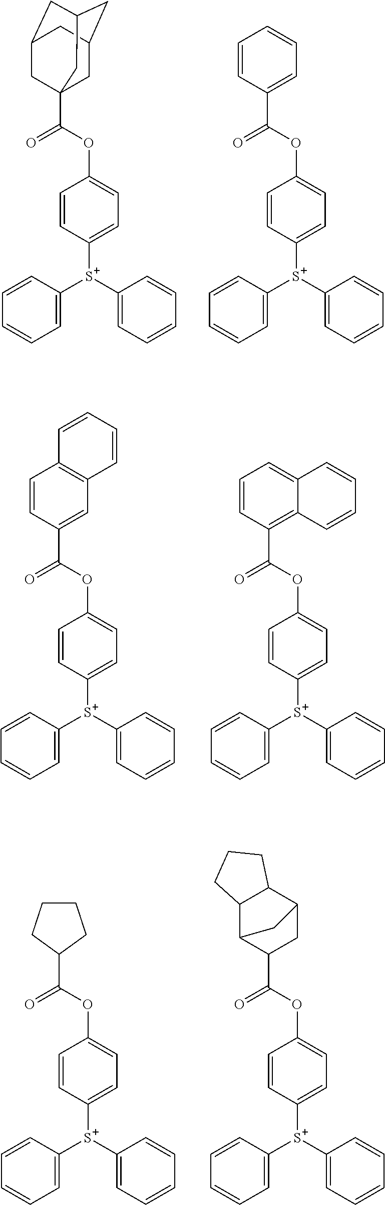 [SMILES: O=C(Oc1ccc([S+](c2ccccc2)c2ccccc2)cc1)C12CC3CC(CC(C3)C1)C2 ; O=C(Oc1ccc([S+](c2ccccc2)c2ccccc2)cc1)c1ccccc1 ; O=C(Oc1ccc([S+](c2ccccc2)c2ccccc2)cc1)c1ccc2ccccc2c1 ; O=C(Oc1ccc([S+](c2ccccc2)c2ccccc2)cc1)c1cccc2ccccc12 ; O=C(Oc1ccc([S+](c2ccccc2)c2ccccc2)cc1)C1CCCC1 ; O=C(Oc1ccc([S+](c2ccccc2)c2ccccc2)cc1)C1CC2CC1C1CCCC21]

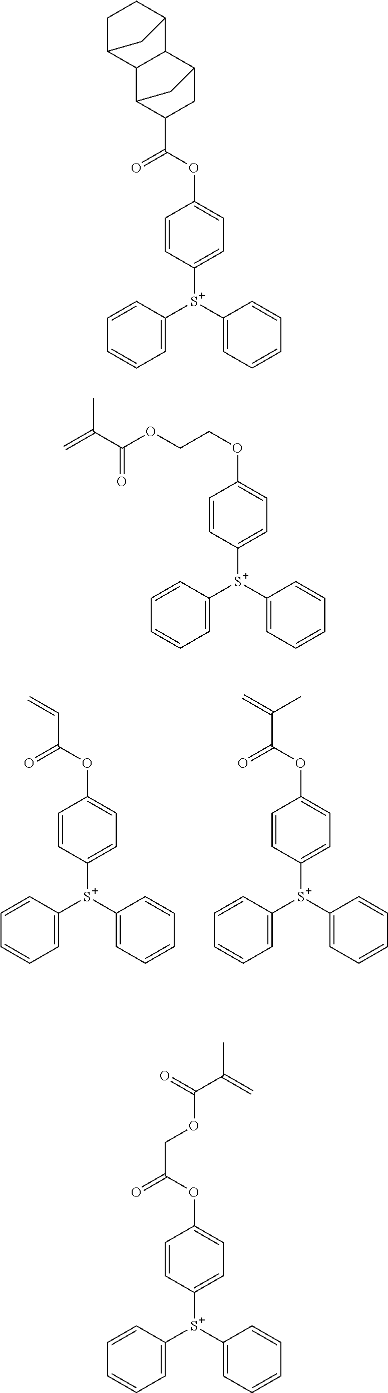 [SMILES: O=C(Oc1ccc([S+](c2ccccc2)c2ccccc2)cc1)C1CC2CC1C1C3CCC(C3)C21 ; C=C(C)C(=O)OCCOc1ccc([S+](c2ccccc2)c2ccccc2)cc1 ; C=CC(=O)Oc1ccc([S+](c2ccccc2)c2ccccc2)cc1 ; C=C(C)C(=O)Oc1ccc([S+](c2ccccc2)c2ccccc2)cc1 ; C=C(C)C(=O)OCC(=O)Oc1ccc([S+](c2ccccc2)c2ccccc2)cc1]

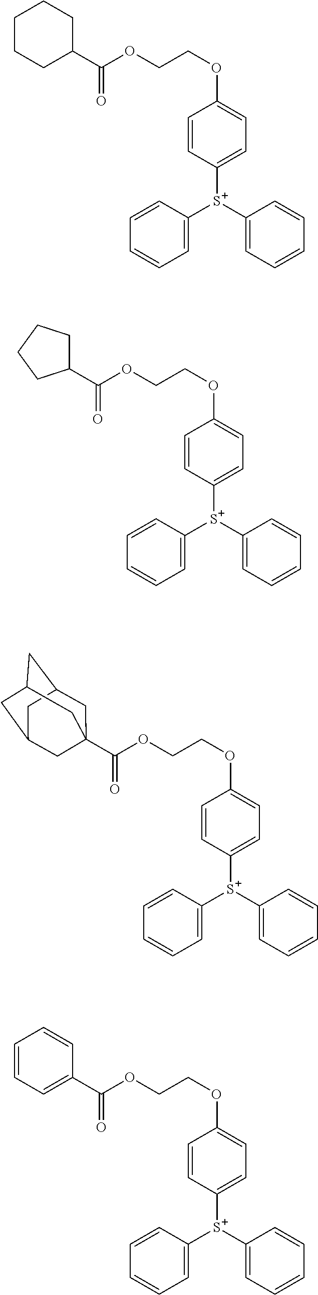 [SMILES: O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2 ; O=C(OCCOc1ccc([S+](c2ccccc2)c2ccccc2)cc1)c1ccccc1]

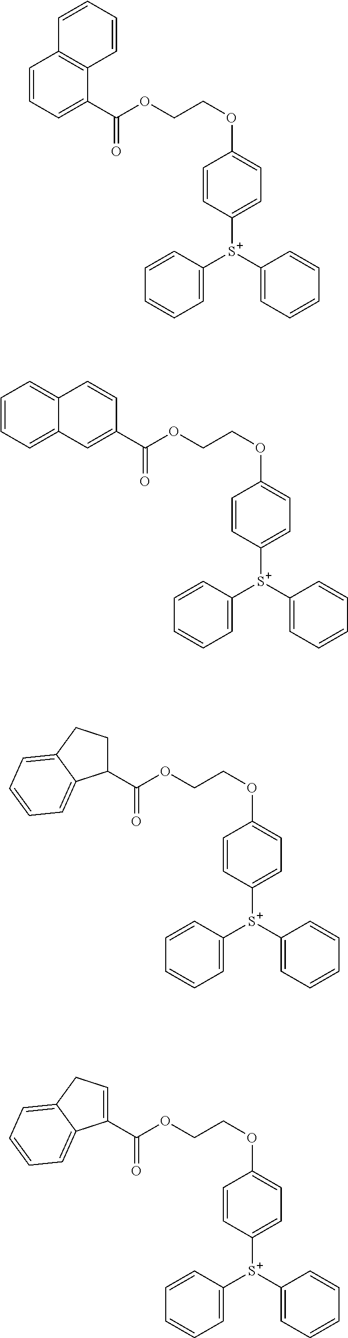 [SMILES: O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21 ; O=C(OCCOc1ccc([S+](c2ccccc2)c2ccccc2)cc1)C1=CCc2ccccc21]

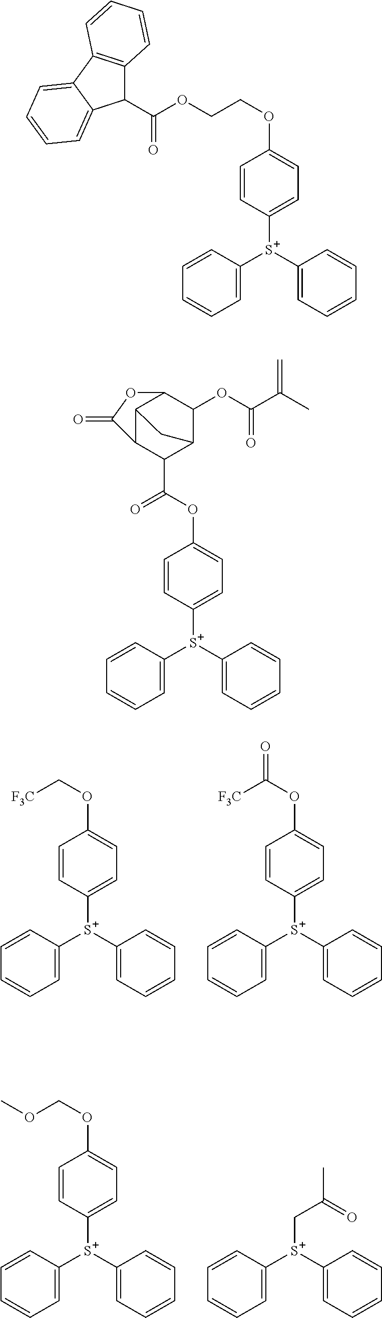 [SMILES: O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F ; COCOc1ccc([S+](c2ccccc2)c2ccccc2)cc1 ; CC(=O)C[S+](c1ccccc1)c1ccccc1]

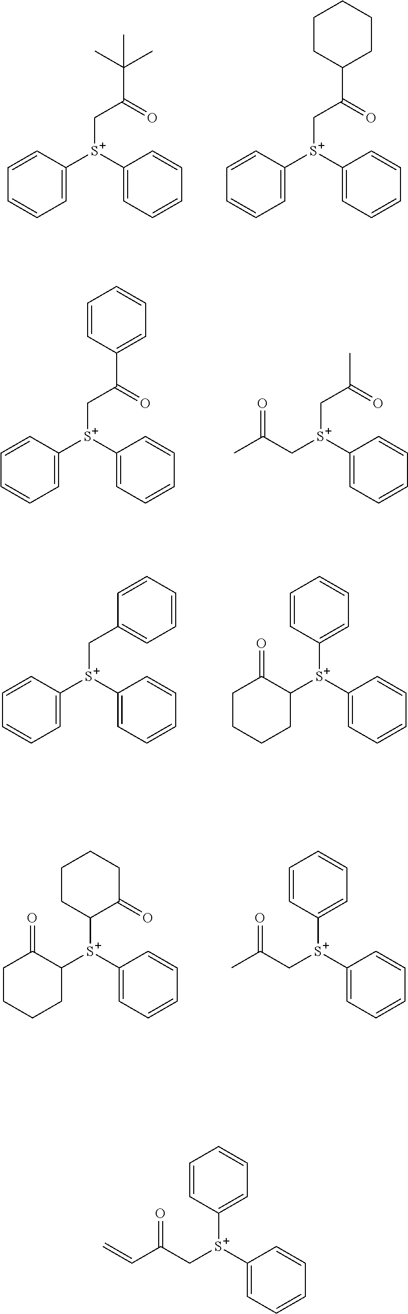

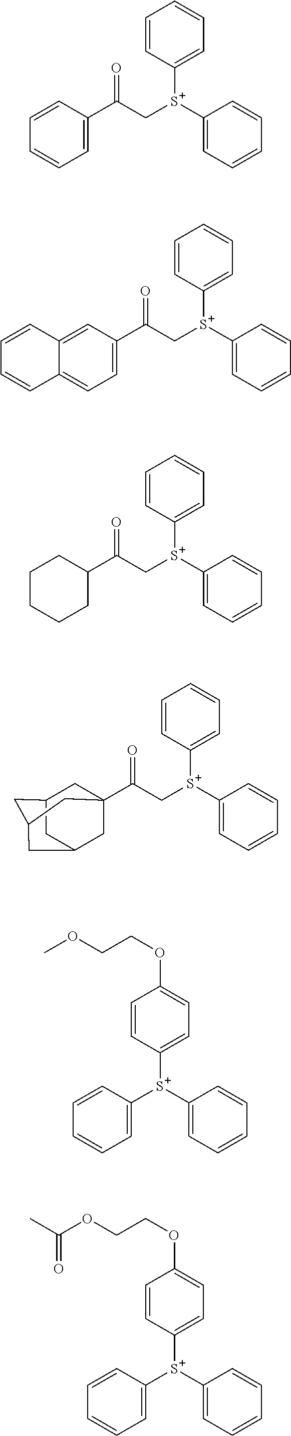 [SMILES: O=C(C[S+](c1ccccc1)c1ccccc1)c1ccccc1 ; O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2 ; COCCOc1ccc([S+](c2ccccc2)c2ccccc2)cc1 ; CC(=O)OCCOc1ccc([S+](c2ccccc2)c2ccccc2)cc1]

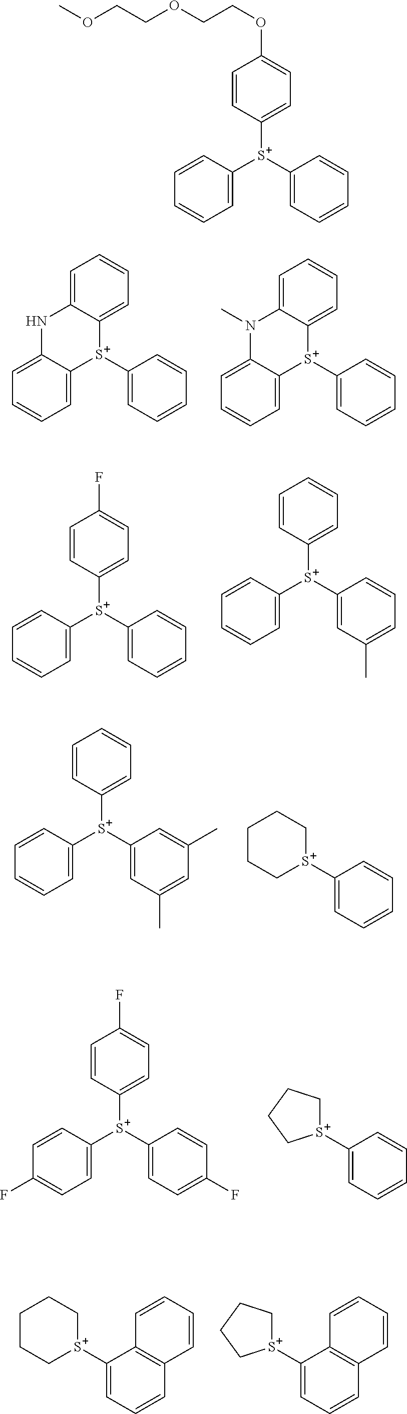

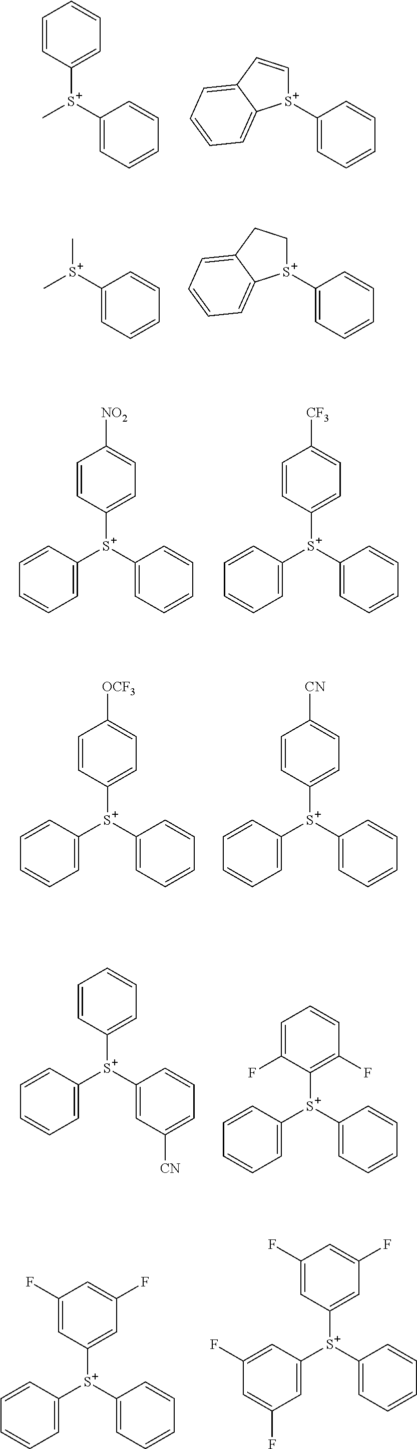

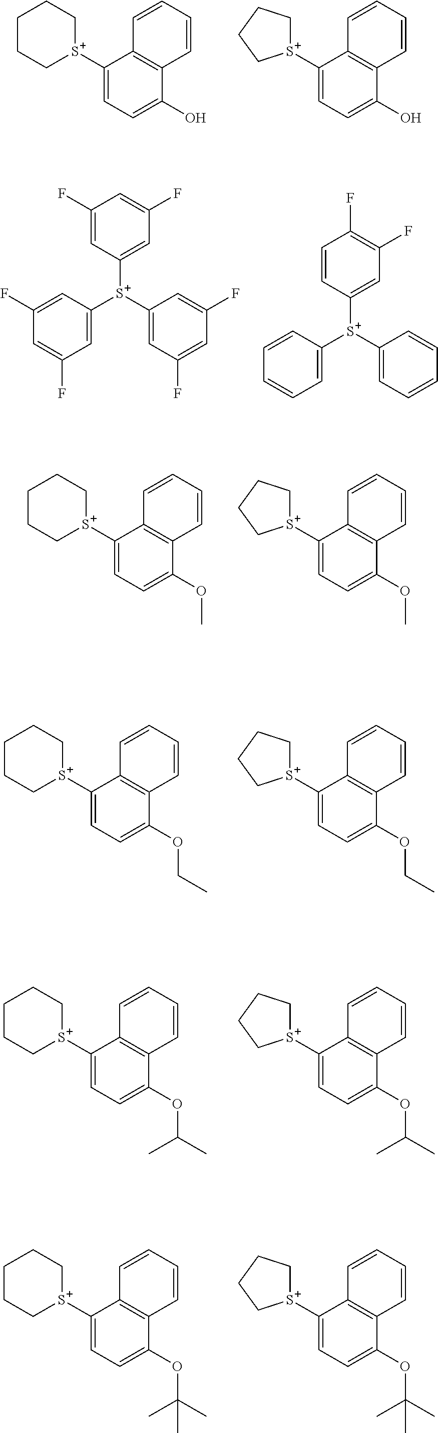

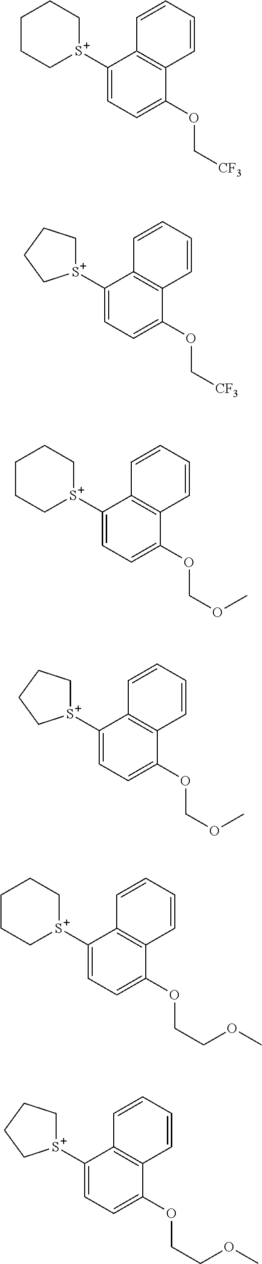 [SMILES: FC(F)(F)COc1ccc([S+]2CCCCC2)c2ccccc12 ; FC(F)(F)COc1ccc([S+]2CCCC2)c2ccccc12 ; COCOc1ccc([S+]2CCCCC2)c2ccccc12 ; COCOc1ccc([S+]2CCCC2)c2ccccc12 ; COCCOc1ccc([S+]2CCCCC2)c2ccccc12 ; COCCOc1ccc([S+]2CCCC2)c2ccccc12]

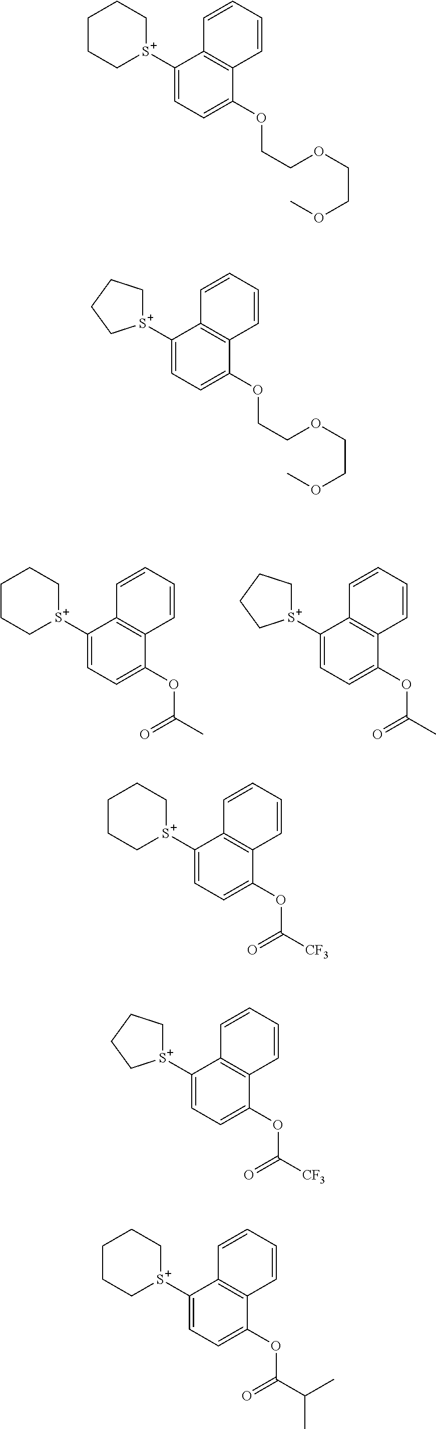

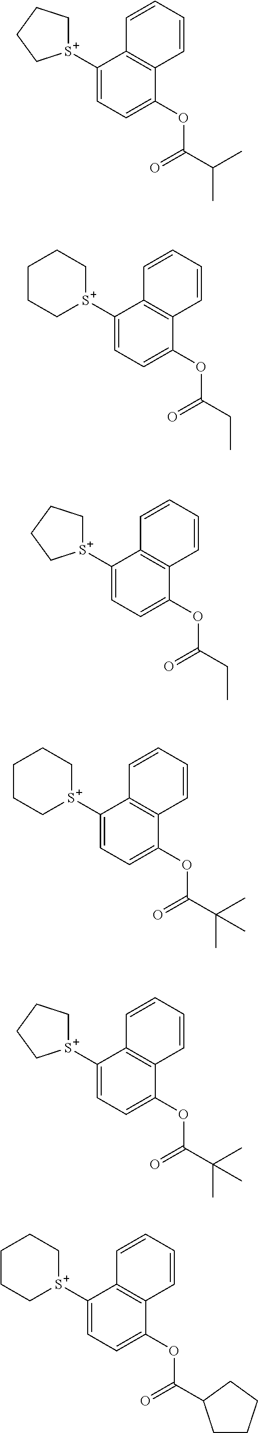 [SMILES: CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12 ; CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1]

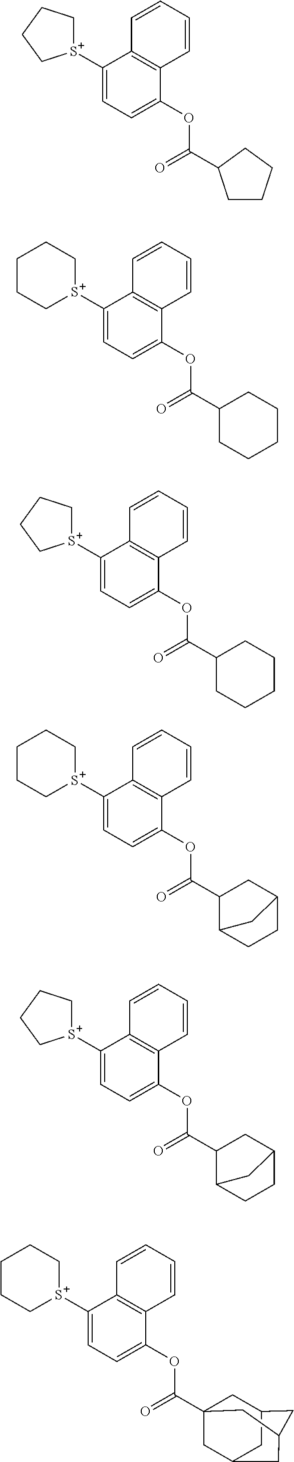 [SMILES: O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1 ; O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2]

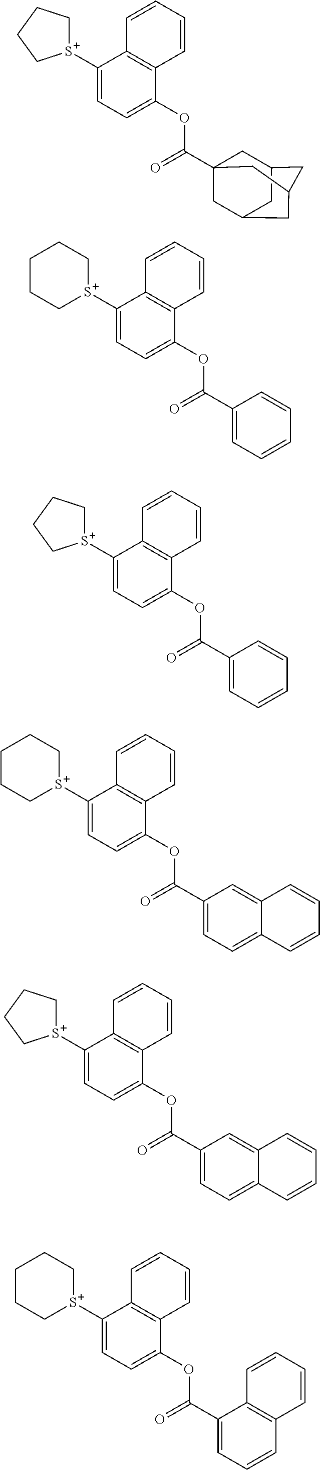 [SMILES: O=C(Oc1ccc([S+]2CCCC2)c2ccccc12)C12CC3CC(CC(C3)C1)C2 ; O=C(Oc1ccc([S+]2CCCCC2)c2ccccc12)c1ccccc1 ; O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12]

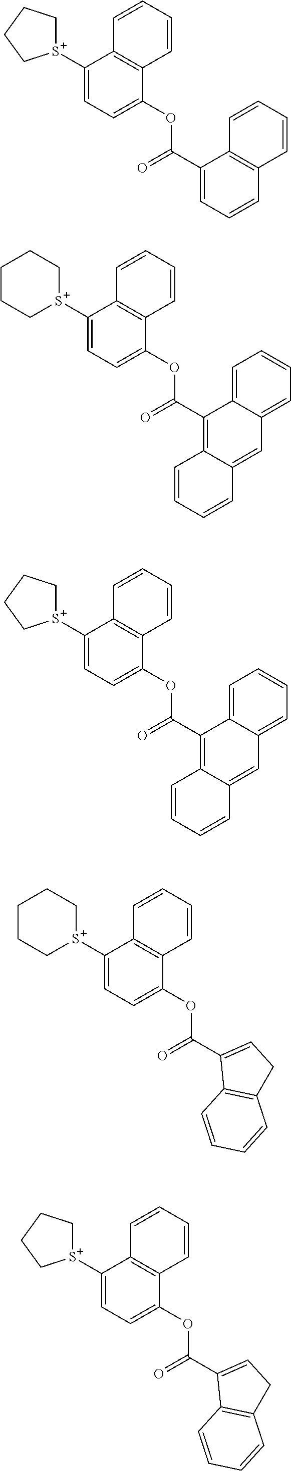 [SMILES: O=C(Oc1ccc([S+]2CCCC2)c2ccccc12)c1cccc2ccccc12 ; O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21]

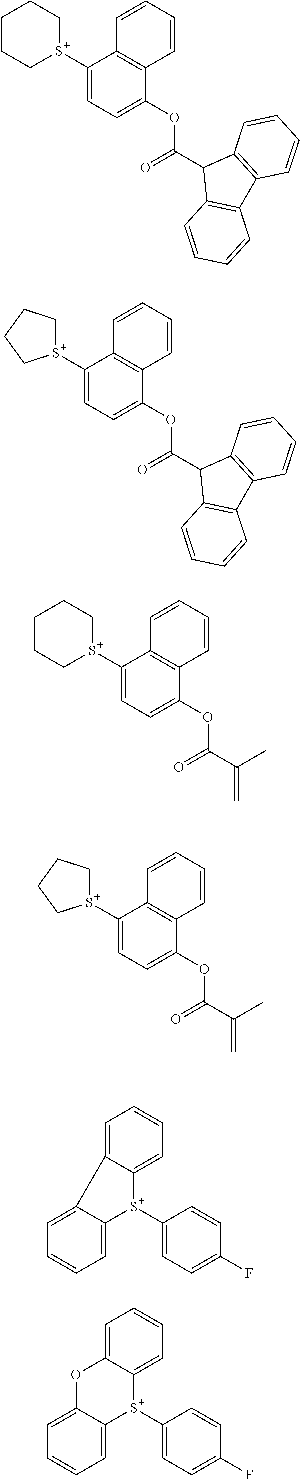 [SMILES: O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21 ; C=C(C)C(=O)Oc1ccc([S+]2CCCCC2)c2ccccc12 ; C=C(C)C(=O)Oc1ccc([S+]2CCCC2)c2ccccc12 ; Fc1ccc(-[s+]2c3ccccc3c3ccccc32)cc1 ; Fc1ccc([S+]2c3ccccc3Oc3ccccc32)cc1]

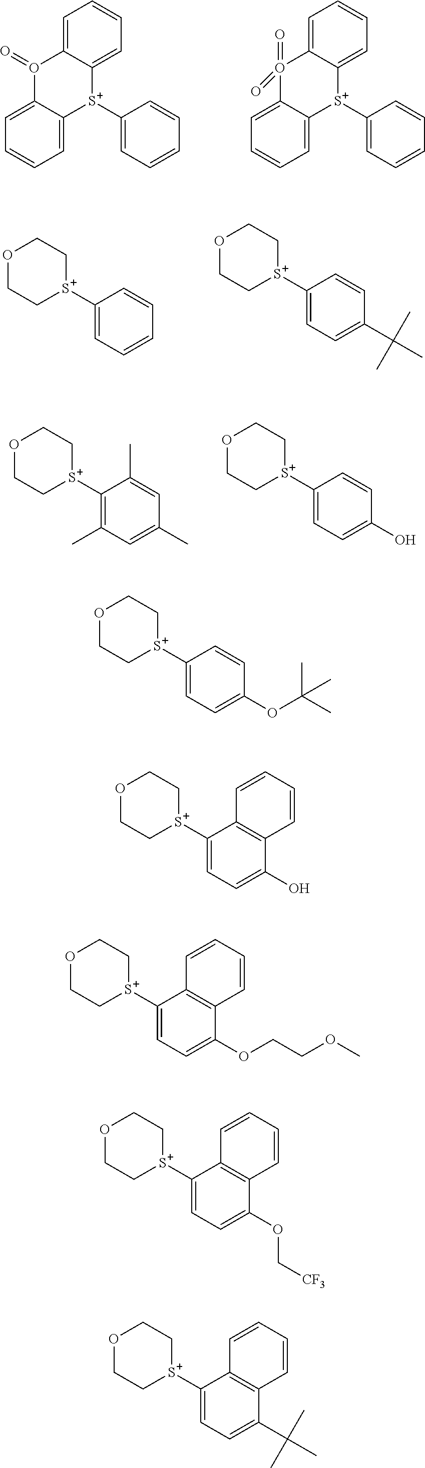

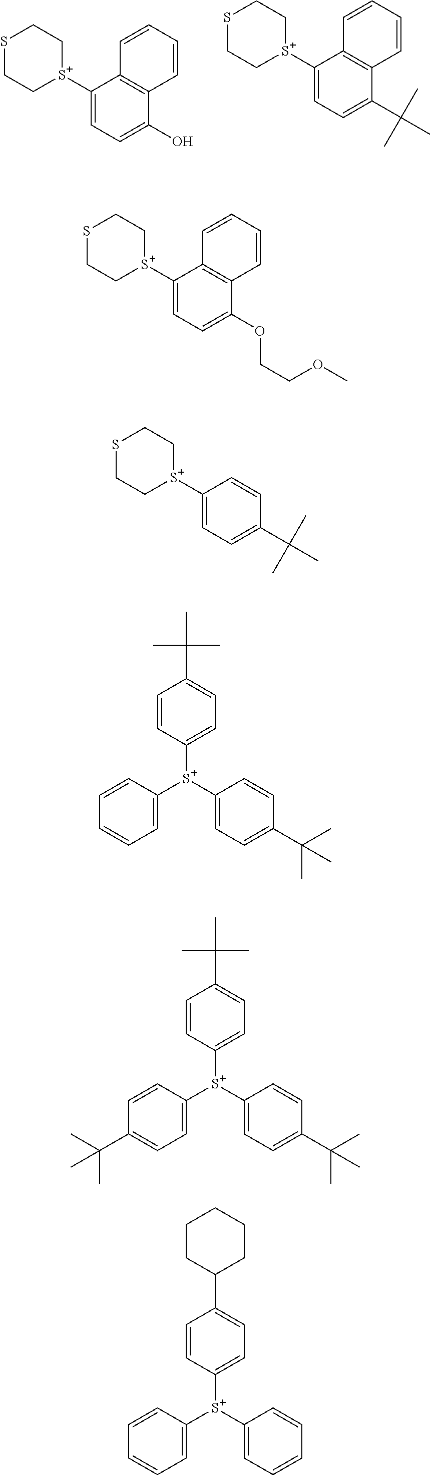

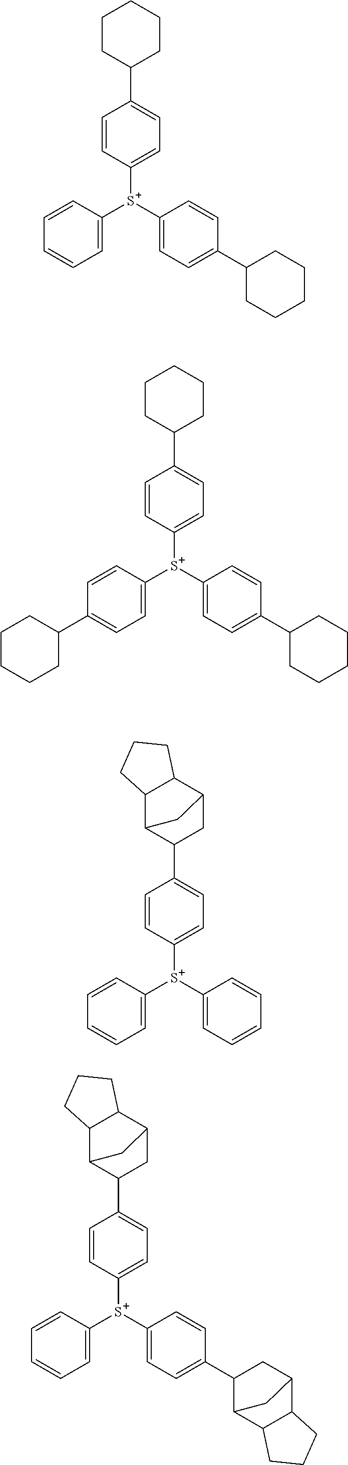 [SMILES: c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1]

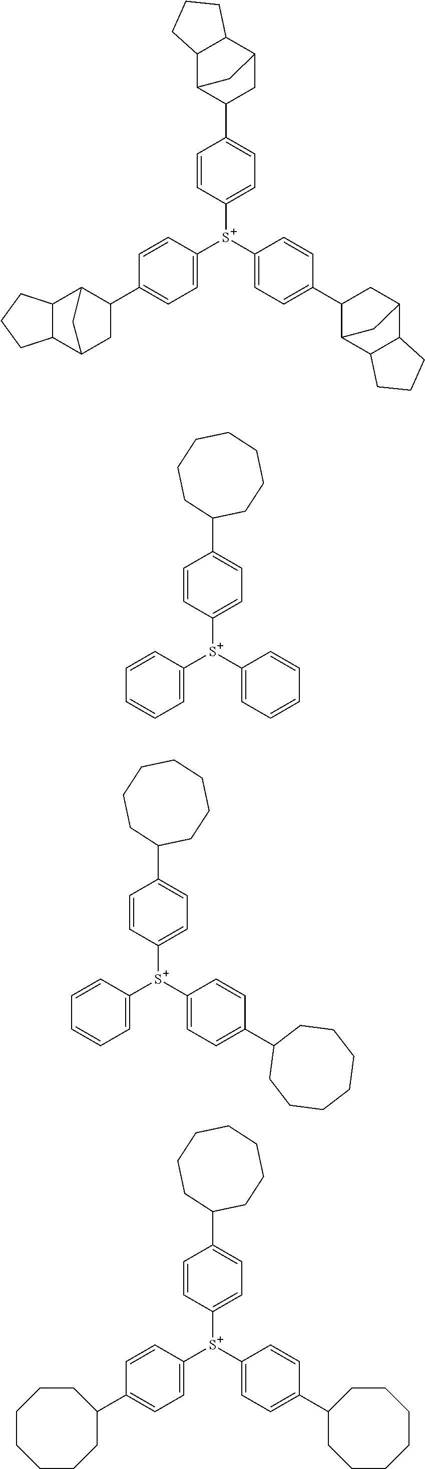 [SMILES: c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

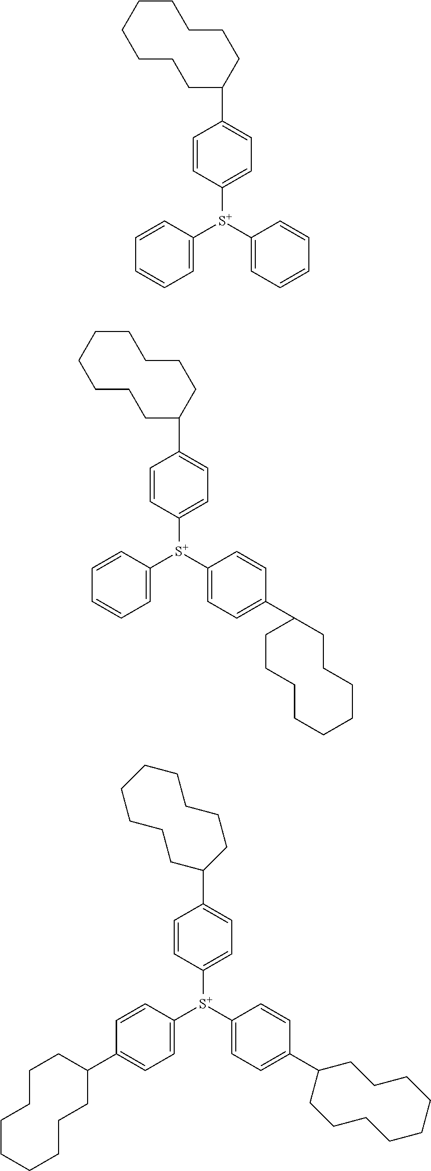 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

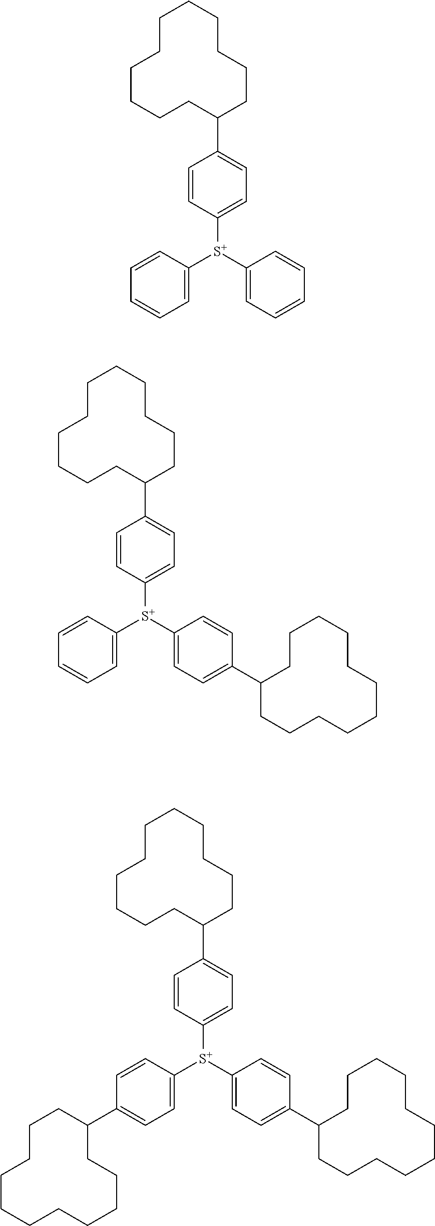 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1]

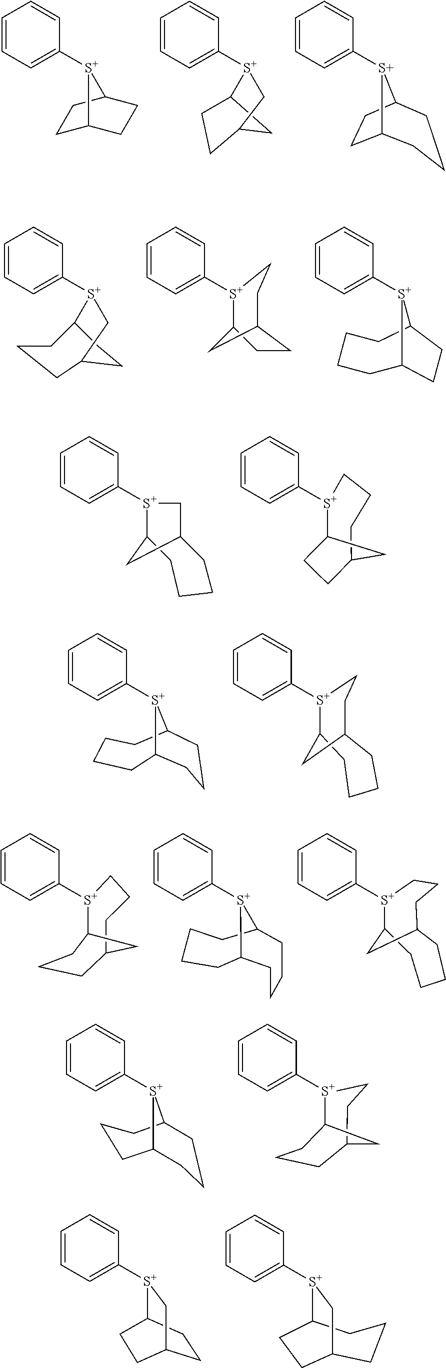

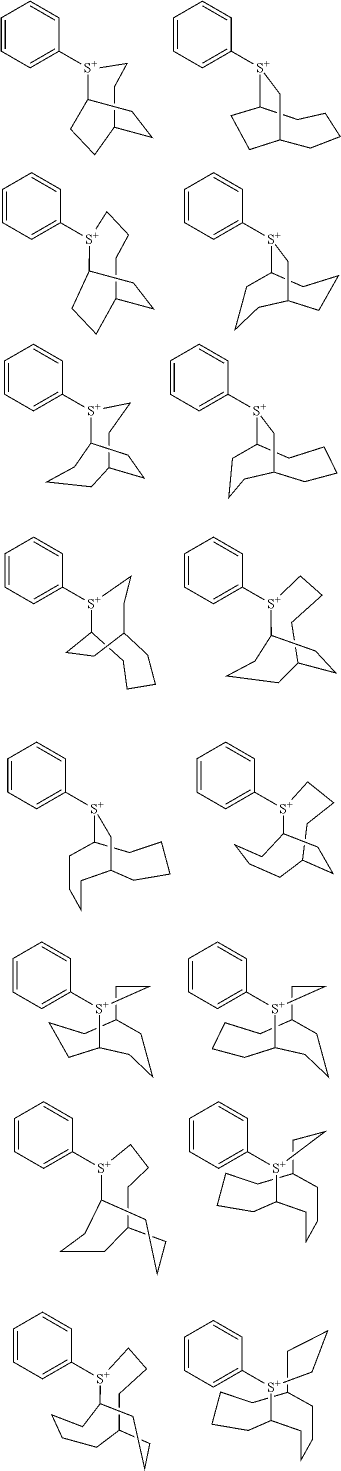

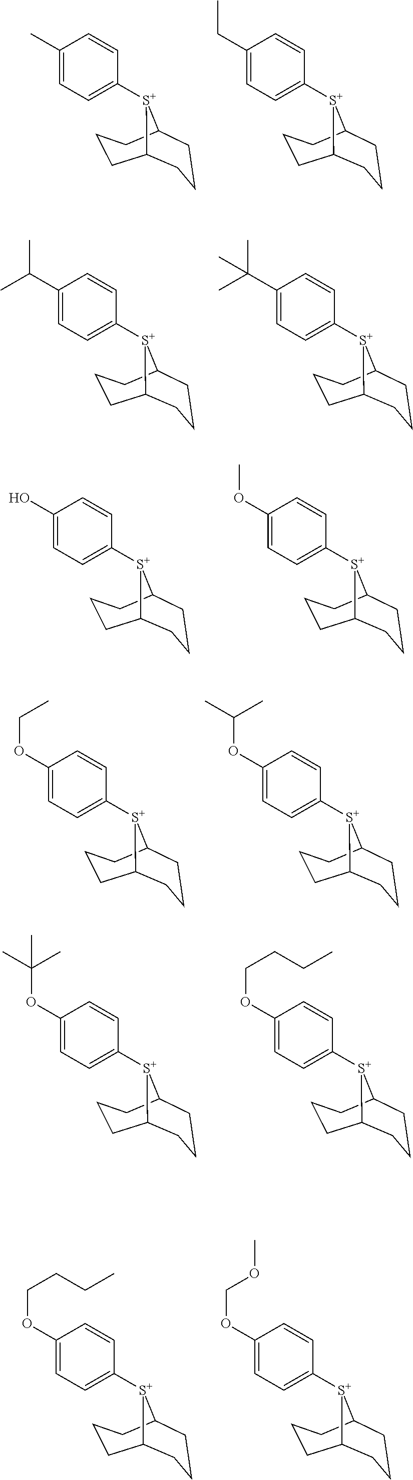

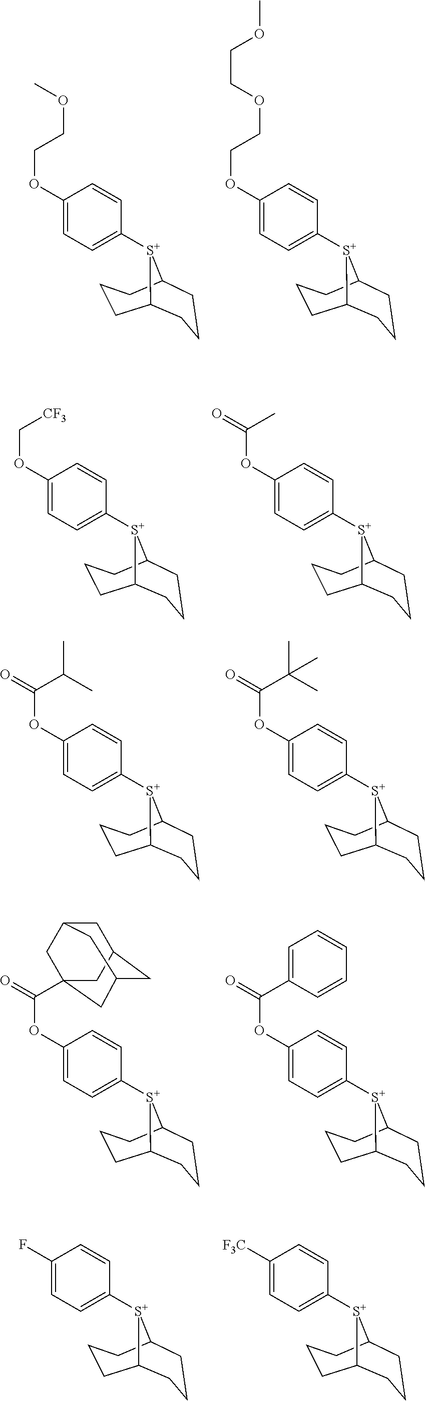

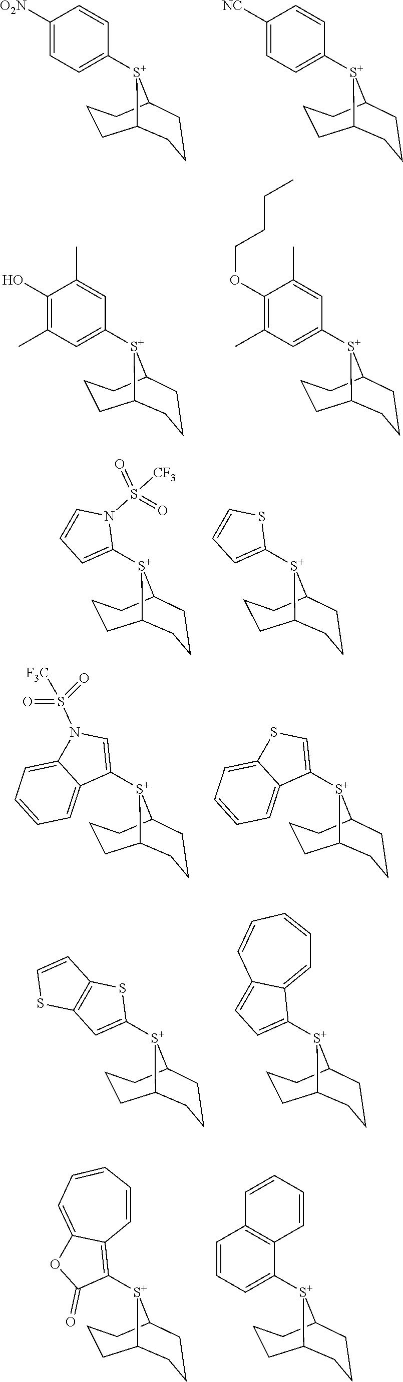

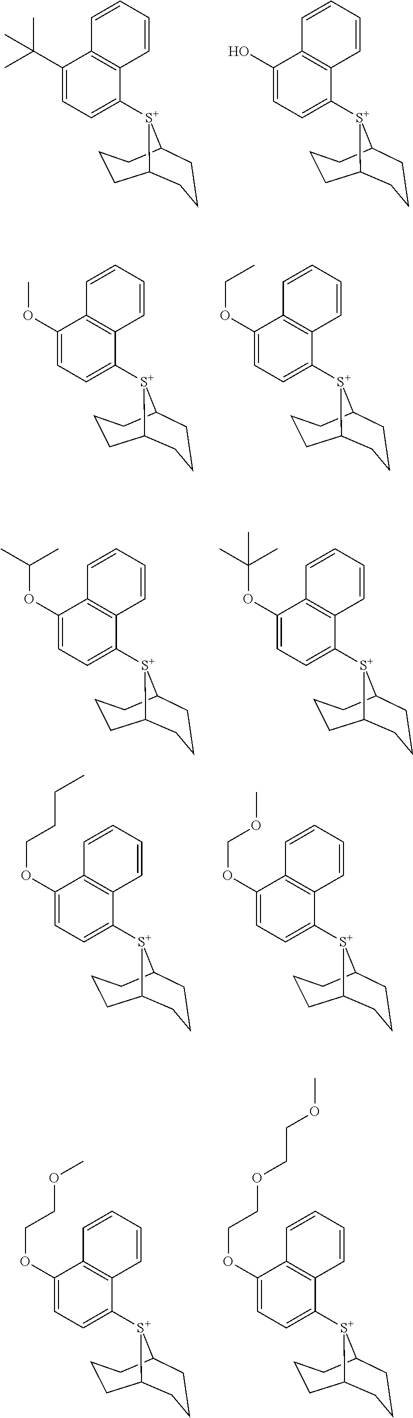

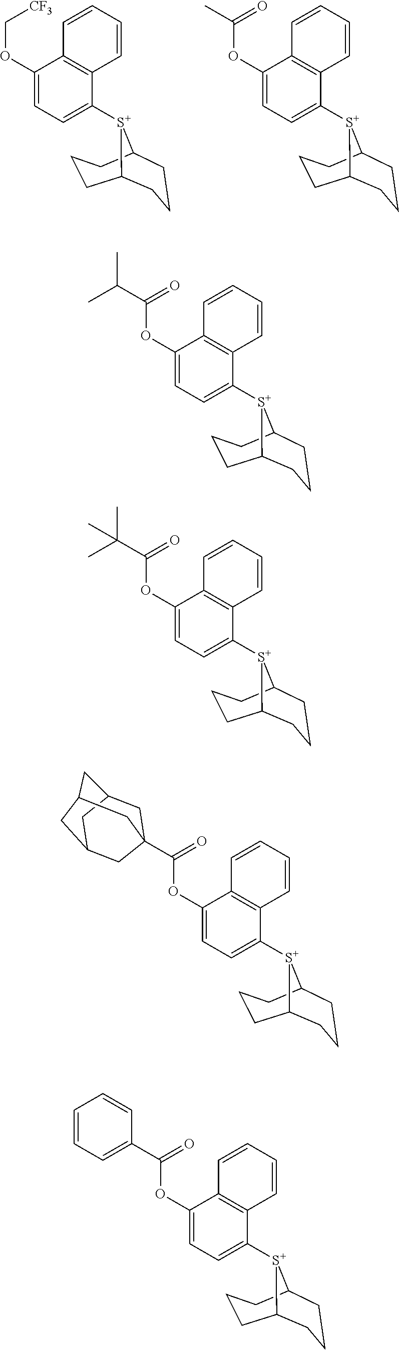 [SMILES: FC(F)(F)COc1ccc([S+]2C3CCCC2CCC3)c2ccccc12 ; CC(=O)Oc1ccc([S+]2C3CCCC2CCC3)c2ccccc12 ; CC(C)C(=O)Oc1ccc([S+]2C3CCCC2CCC3)c2ccccc12 ; CC(C)(C)C(=O)Oc1ccc([S+]2C3CCCC2CCC3)c2ccccc12 ; O=C(Oc1ccc([S+]2C3CCCC2CCC3)c2ccccc12)C12CC3CC(CC(C3)C1)C2 ; O=C(Oc1ccc([S+]2C3CCCC2CCC3)c2ccccc12)c1ccccc1]

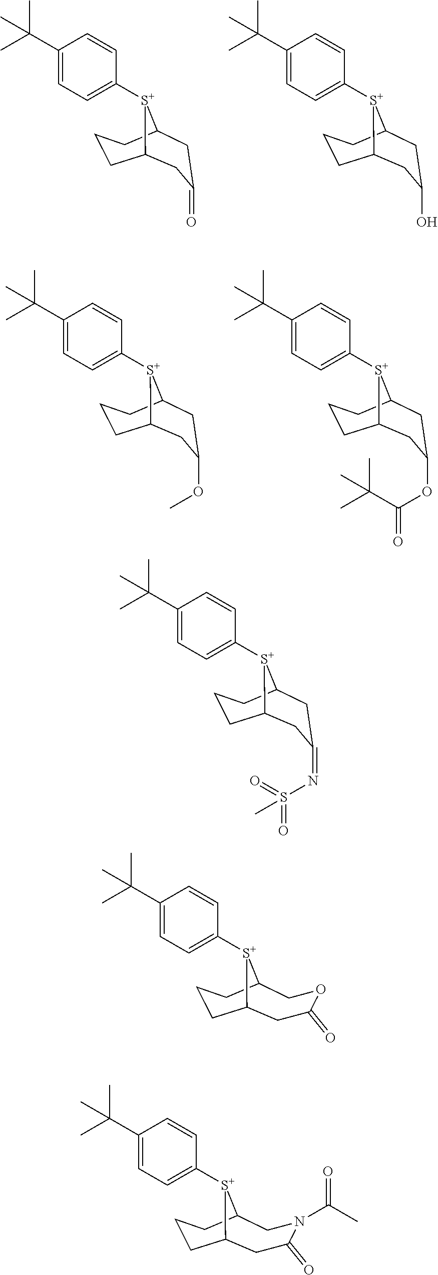

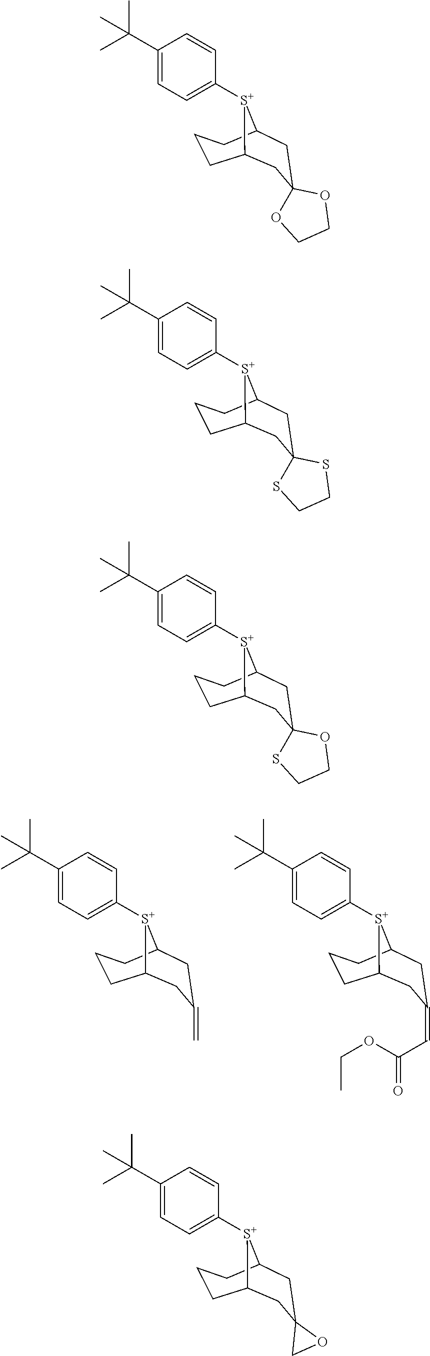 [SMILES: CC(C)(C)c1ccc([S+]2C3CCCC2CC2(C3)OCCO2)cc1 ; CC(C)(C)c1ccc([S+]2C3CCCC2CC2(C3)SCCS2)cc1 ; CC(C)(C)c1ccc([S+]2C3CCCC2CC2(C3)OCCS2)cc1 ; C=C1CC2CCCC(C1)[S+]2c1ccc(C(C)(C)C)cc1 ; CCOC(=O)C=C1CC2CCCC(C1)[S+]2c1ccc(C(C)(C)C)cc1 ; CC(C)(C)c1ccc([S+]2C3CCCC2CC2(CO2)C3)cc1]

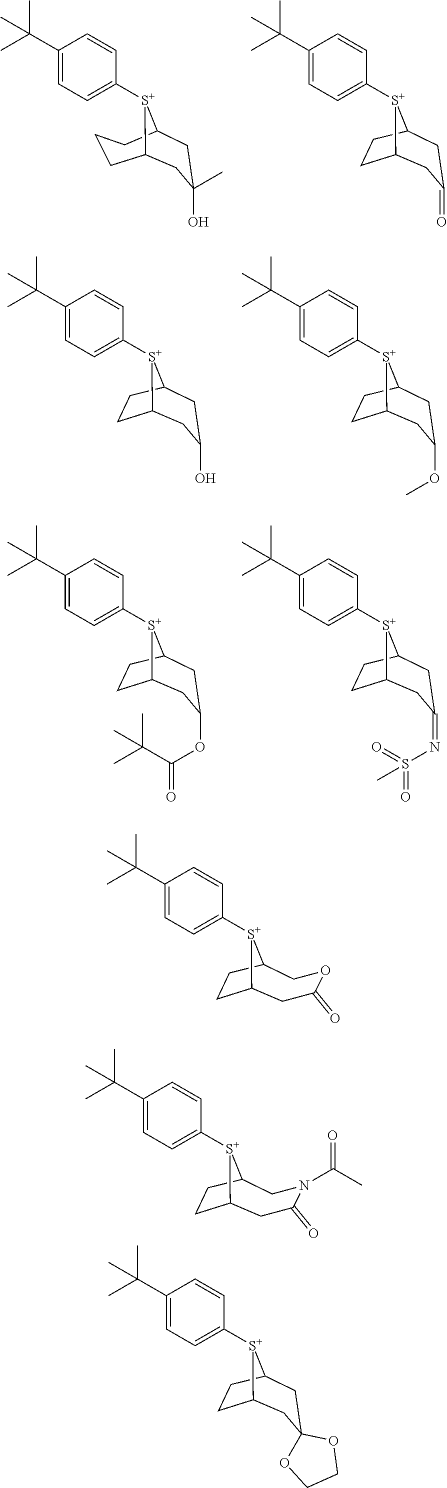

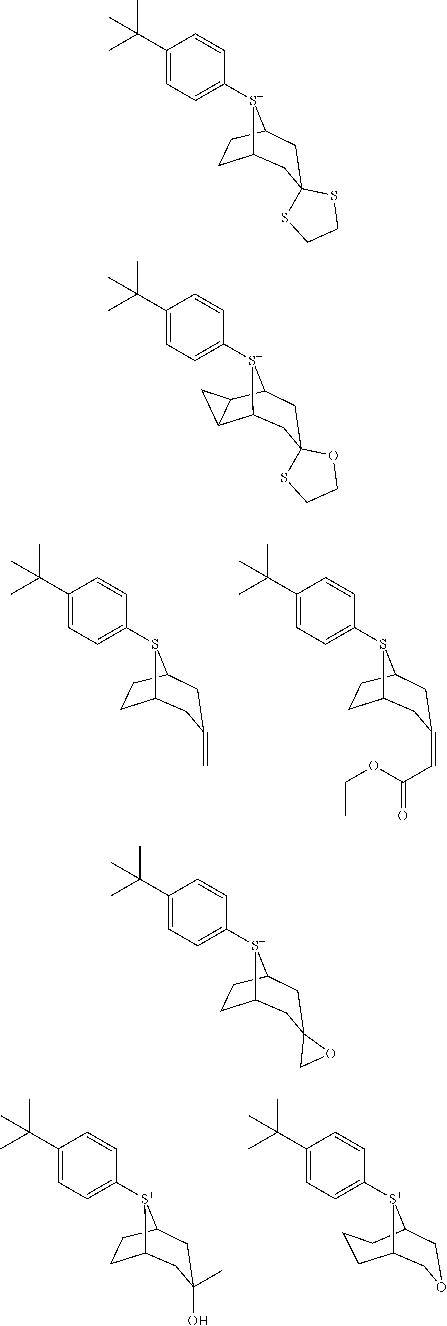

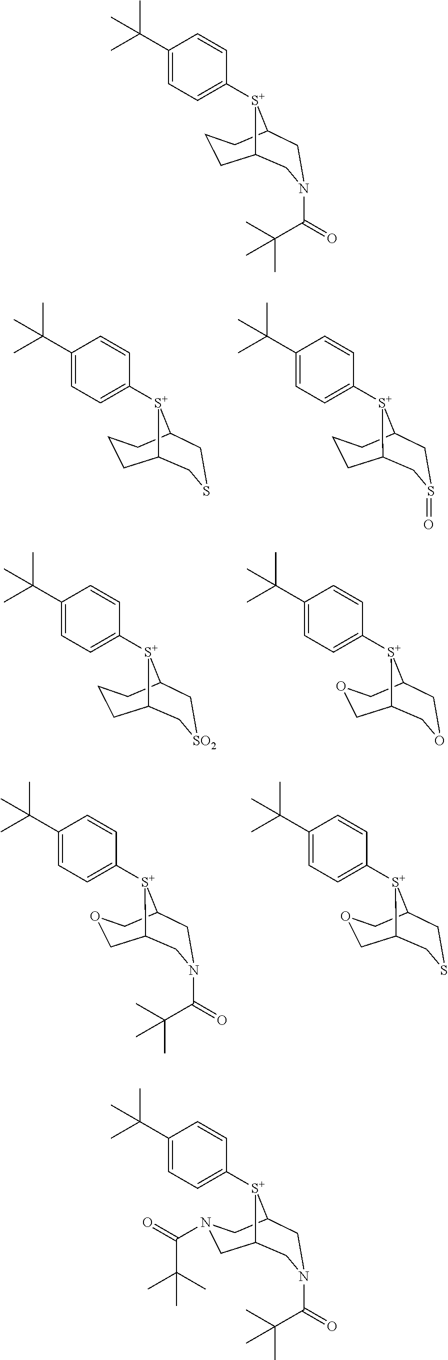

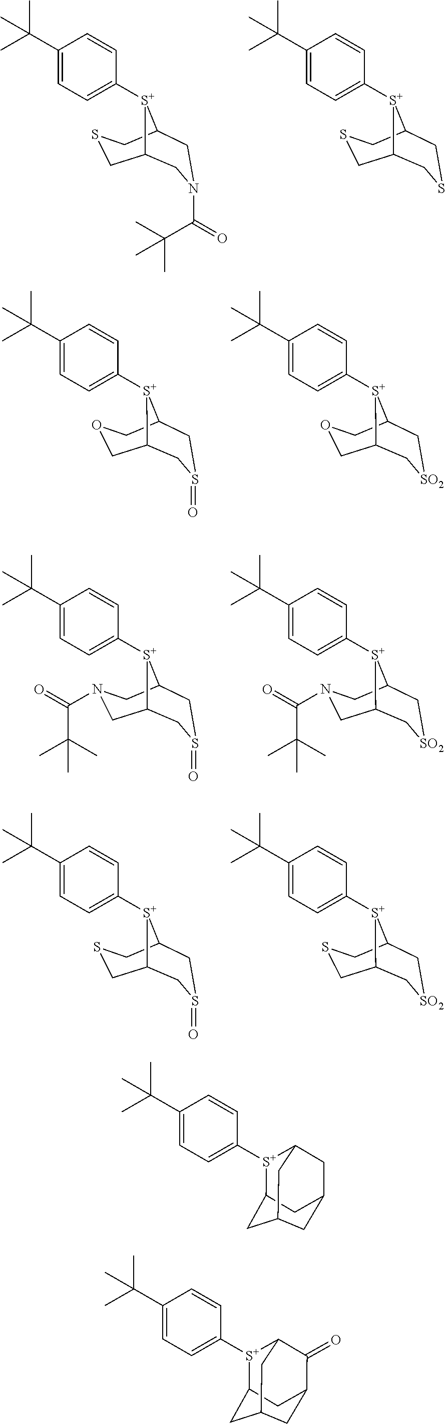

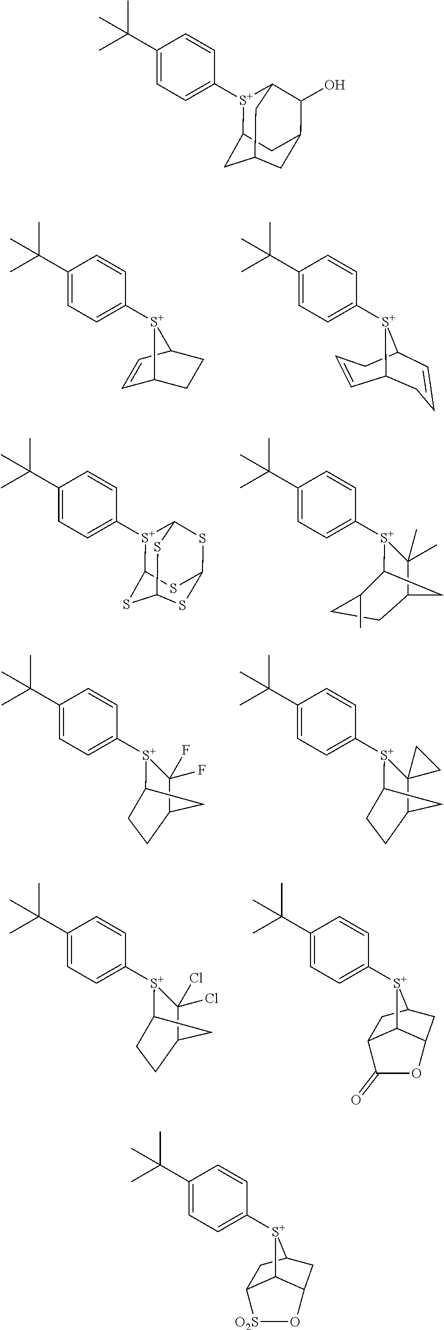

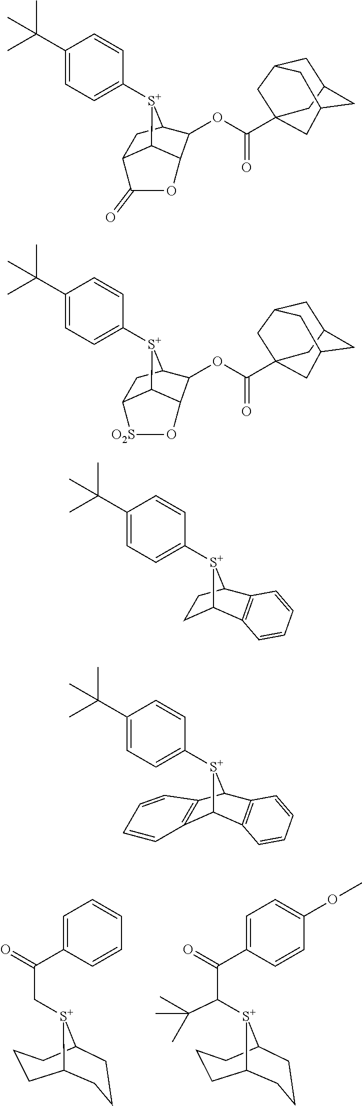 [SMILES: CC(C)(C)c1ccc([S+]2C3CC4C(=O)OC(C3OC(=O)C35CC6CC(CC(C6)C3)C5)C42)cc1 ; CC(C)(C)c1ccc([S+]2C3CC4C2C(OS4(=O)=O)C3OC(=O)C23CC4CC(CC(C4)C2)C3)cc1 ; CC(C)(C)c1ccc([S+]2C3CCC2c2ccccc23)cc1 ; CC(C)(C)c1ccc([S+]2C3c4ccccc4C2c2ccccc23)cc1 ; O=C(C[S+]1C2CCCC1CCC2)c1ccccc1 ; COc1ccc(C(=O)C([S+]2C3CCCC2CCC3)C(C)(C)C)cc1]

Examples of the iodonium cation represented by the formula (cation-2) include the following cations, but the iodonium cation is not limited thereto.

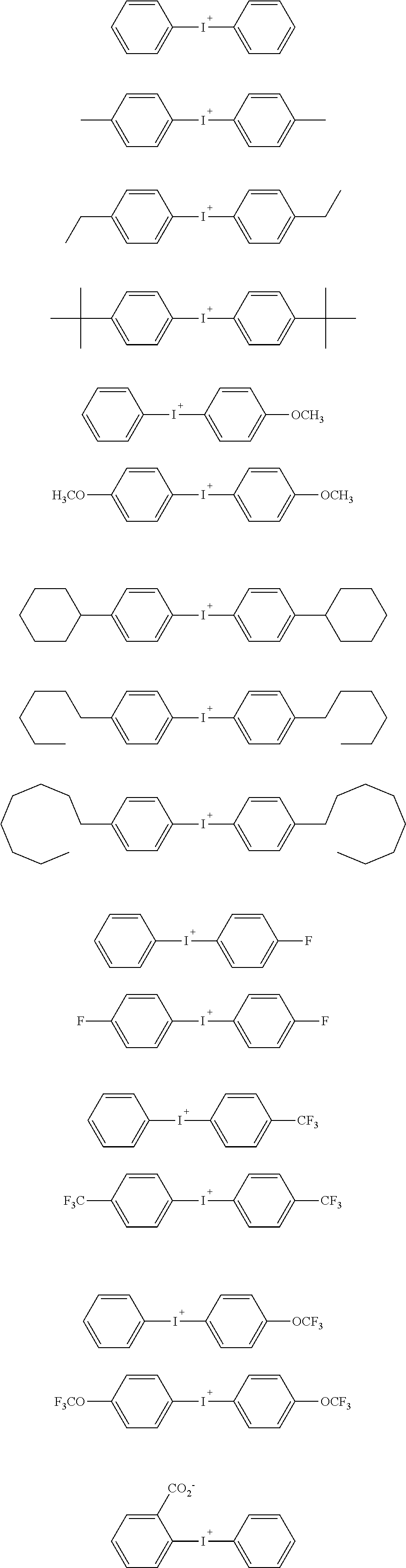

Examples of specific structures of the repeating units represented by the formulae (B-1) to (B-4) include any combination of the above anions and cations.

The repeating unit B is preferably the repeating unit B2, B3, or B4 from the viewpoint of inhibition of the acid diffusion. The repeating units B2 and B4 are further preferable from the viewpoint of the acid strength of the generated acid, and the repeating unit B2 is more preferable from the viewpoint of the solvent solubility.

The characteristic of the inventive polymer is to have: the repeating unit A having an acid-labile group having a phenolic hydroxy group; and the repeating unit B to generate an acid by light exposure. It is considered that the base polymer having the repeating unit to generate an acid by light-exposure can inhibit excessive acid diffusion, particularly when the anion bound type, in which the generated acid after light exposure is bonded to the main chain of the base polymer, is employed, and secondary electrons generated at the sensitizer portion do not diffuse to contribute to the cation decomposition. The repeating unit having an acid-labile group having a phenolic hydroxy group contributes to the change in solubility in the developing liquid in the deprotection reaction after the light exposure, and particularly contributes to the sensitizing effect of generating secondary electrons from EUV light. When the acid-labile unit and the sensitizer unit are each separately introduced in the base polymer, increasing an introduction amount of the acid-labile unit to improve the contrast decreases an introduction amount of the sensitizer unit and decreases a generation amount of the secondary electrons, resulting in lower sensitivity. Conversely, increasing the sensitizer unit increases the generation amount of the secondary electrons, but decreases the introduction amount of the acid-labile unit in the base polymer, resulting in lower dissolution contrast. From such viewpoints, introducing the repeating unit having an acid-labile group having a phenolic hydroxy group can simultaneously increases the acid-labile unit and the sensitizer unit in the base polymer. The synergistic effect thereof can simultaneously achieve the higher sensitivity and the higher contrast, and enables to form a pattern such as a line pattern with low LWR and a hole pattern with low CDU.

[Repeating Unit a1 and a2]

The inventive polymer optionally further comprises at least one selected from: a repeating unit represented by the following formula (a-1) (hereinafter, which may be represented by the repeating unit a1); and a repeating unit represented by the following formula (a-2) (hereinafter, which may be represented by the repeating unit a2).

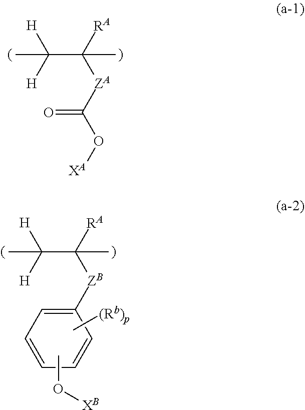

In the formulae (a-1) and (a-2), R^{A}, Z^{A}, Z^{B}, and R^{b} are same as above. “p” represents an integer of 0 to 4. X^{A} and X^{B} each independently represent an acid-labile group having no fluorine-containing aromatic ring.

In the formulae (a-1) and (a-2), examples of the acid-labile group represented by X^{A} and X^{B} include groups described in JP 2013-80033 A and JP 2013-83821 A.

Typical examples of the acid-labile group include groups represented by the following formulae (AL-1) to (AL-3).

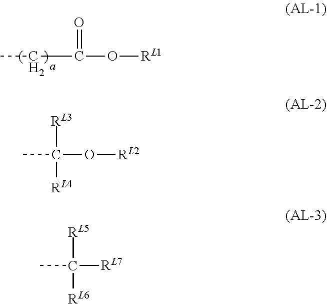

In the formulae, a broken line represents a bond.

In the formulae (AL-1) and (AL-2), R^{L1} and R^{L2} each independently represent a saturated hydrocarbyl group having 1 to 40 carbon atoms and optionally having a heteroatom, such as an oxygen atom, a sulfur atom, a nitrogen atom, and a fluorine atom. The saturated hydrocarbyl group may be any of linear, branched, and cyclic groups. The saturated hydrocarbyl group preferably has 1 to 20 carbon atoms.

In the formula (AL-1), “a” represents an integer of 0 to 10, and preferably an integer of 1 to 5.

In the formula (AL-2), R^{L3} and R^{L4} each independently represent a hydrogen atom or a saturated hydrocarbyl group having 1 to 20 carbon atoms and optionally having a heteroatom, such as an oxygen atom, a sulfur atom, a nitrogen atom, and a fluorine atom. The saturated hydrocarbyl group may be any of linear, branched, and cyclic groups. Any two of R^{L2}, R^{L3}, and R^{L4} are optionally bonded each other to form a ring having 3 to 20 carbon atoms together with the carbon atom or together with the carbon atom and the oxygen atom to which these two groups are bonded. The ring preferably has 4 to 16 carbon atoms, and is particularly preferably an aliphatic ring.

In the formula (AL-3), R^{L5}, R^{L6}, and R^{L7} each independently represent a saturated hydrocarbyl group having 1 to 20 carbon atoms and optionally having a heteroatom, such as an oxygen atom, a sulfur atom, a nitrogen atom, and a fluorine atom. The hydrocarbyl group may be any of linear, branched, and cyclic groups. Any two of R^{L5}, R^{L6}, and R^{L7} are optionally bonded each other to form a ring having 3 to 20 carbon atoms together with the carbon atom to which these two groups are bonded. The ring preferably has 4 to 16 carbon atoms, and is particularly preferably an aliphatic ring.

Examples of the repeating unit a1 include the following repeating units, but the repeating unit a1 is not limited thereto. In the following formulae, R^{A} and X^{A} are same as above.

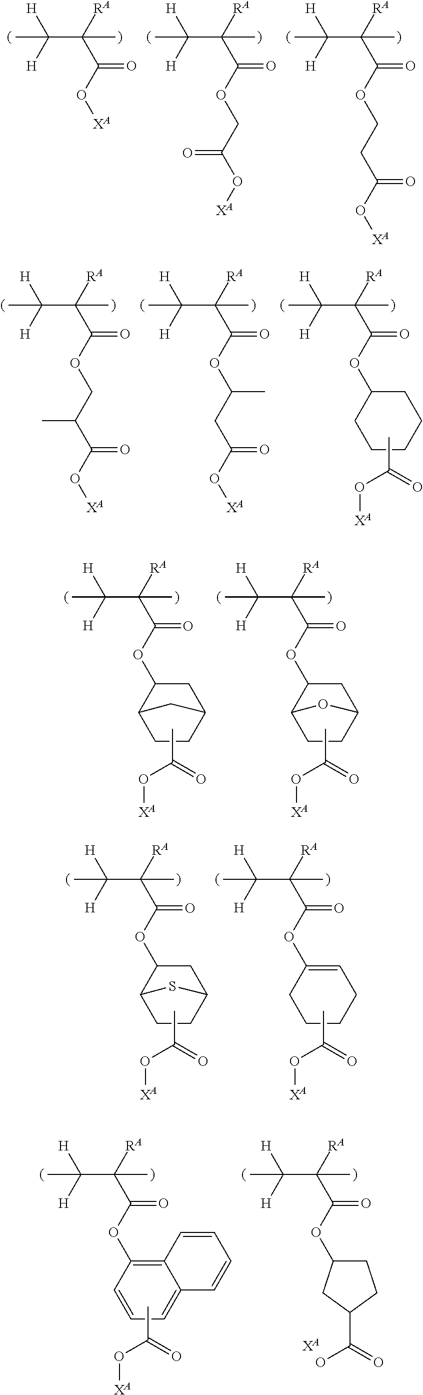

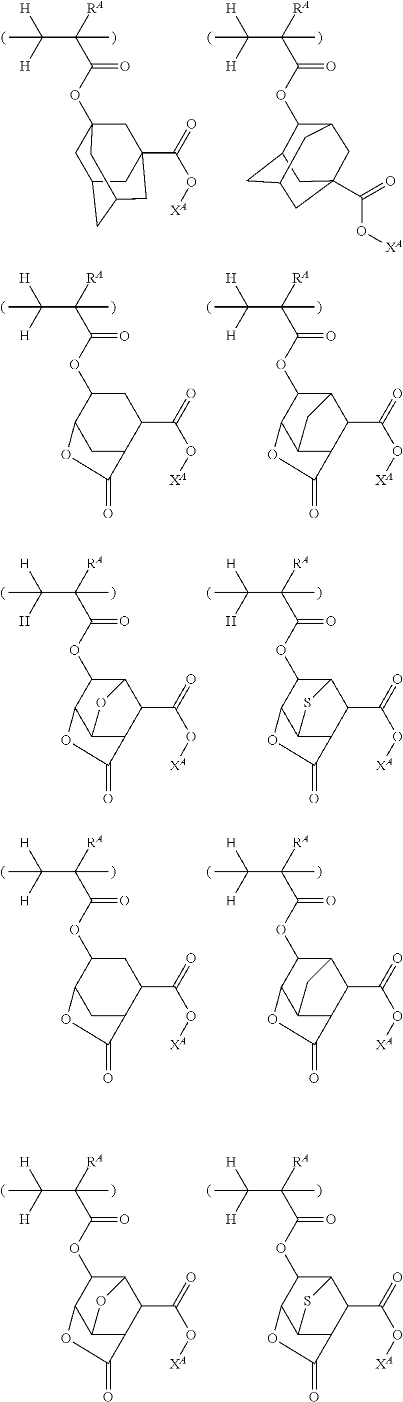

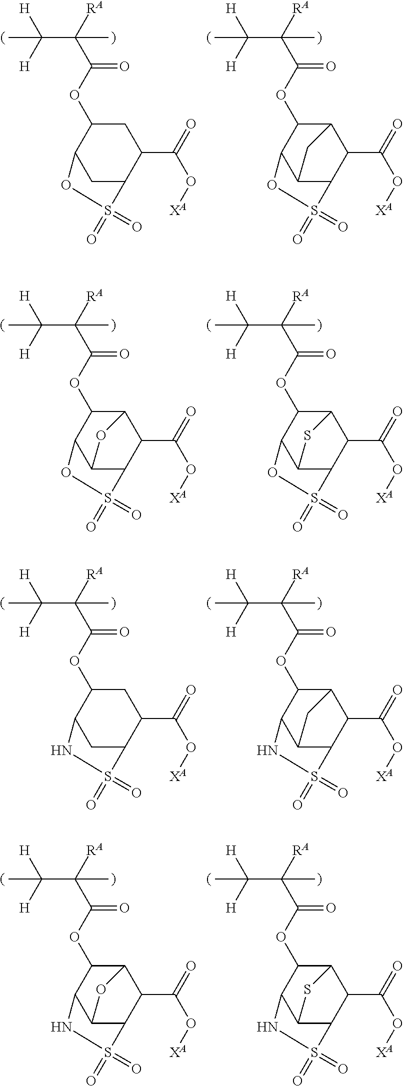

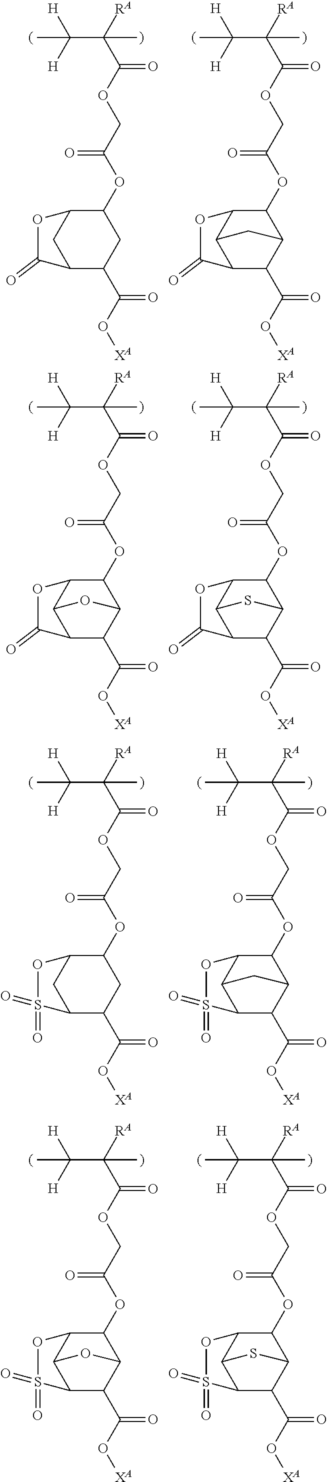

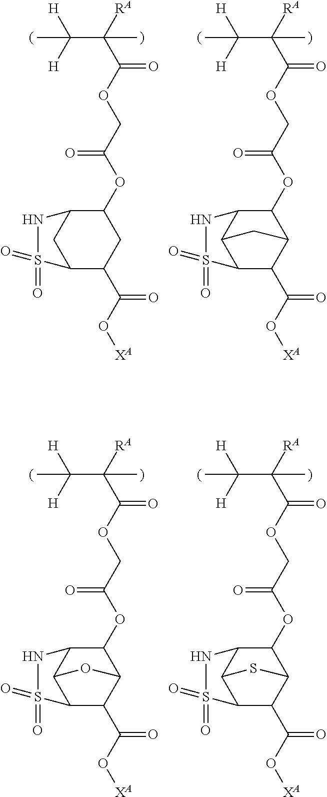

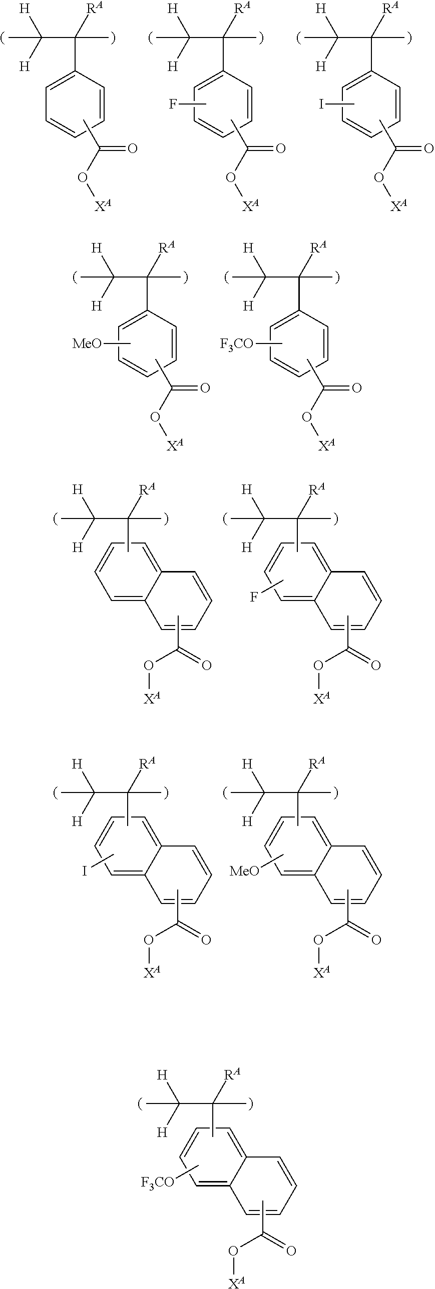

Examples of the repeating unit a2 include the following repeating units, but the repeating unit a2 is not limited thereto. In the following formulae, R^{A} and X^{B} are same as above.

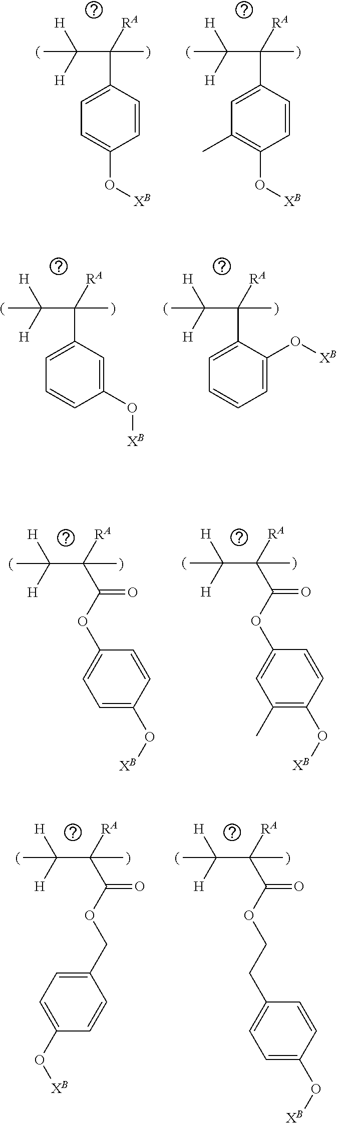

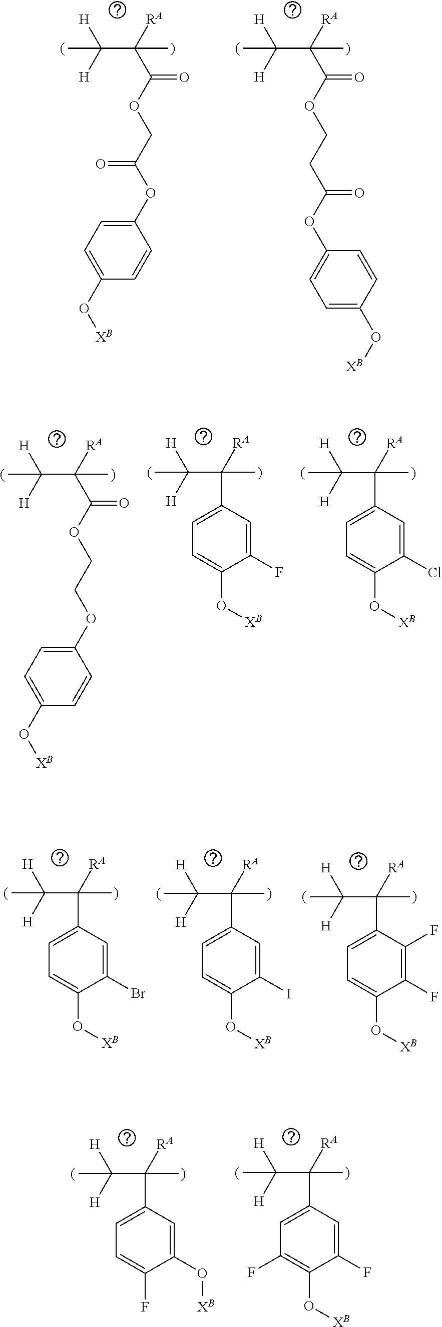

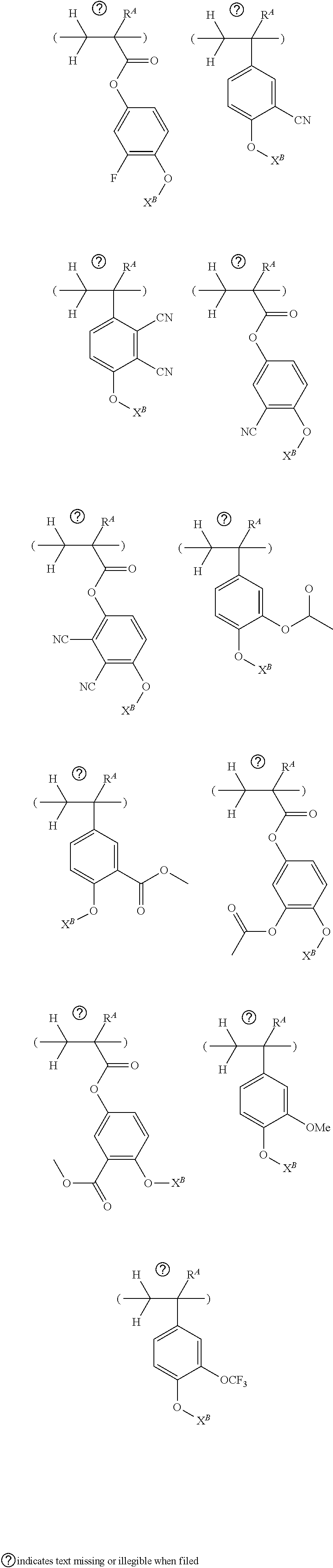

### [Repeating Unit C Having Phenolic Hydroxy Group]

The inventive polymer comprises a repeating unit having a phenolic hydroxy group (hereinafter, which may be also referred to as the repeating unit C). The repeating unit C is preferably a repeating unit represented by the following formula (C-1).

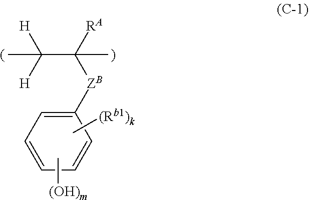

In the formula (C-1), R^{A} is same as above. Z^{B} represents a single bond or (main chain)-C(═O)—O—. R^{b1} represents a halogen atom, a cyano group, a hydrocarbyl group having 1 to 20 carbon atoms and optionally having a heteroatom, a hydrocarbyloxy group having 1 to 20 carbon atoms and optionally having a heteroatom, a hydrocarbylcarbonyl group having 2 to 20 carbon atoms and optionally having a heteroatom, a hydrocarbylcarbonyloxy group having 2 to 20 carbon atoms and optionally having a heteroatom, or a hydrocarbyloxycarbonyl group having 2 to 20 carbon atoms and optionally having a heteroatom. “m” represents an integer of 1 to 4, “k” represents an integer of 0 to 3, and “m+k” represents an integer of 4 or less.

The hydrocarbyl group represented by R^{b1} may be a saturated or unsaturated group, and may be any of linear, branched, and cyclic groups. Specific examples thereof include groups same as the group exemplified in the description of R^{1b} in the formula (A-1). Specific examples of the hydrocarbyl part in the hydrocarbyloxy group and the hydrocarbylcarbonyl group also include groups same as the group exemplified in the description of R^{1b}.

Example of the repeating unit C include the following repeating units, but the repeating unit C is not limited thereto. In the following formula, R^{A} is same as above.

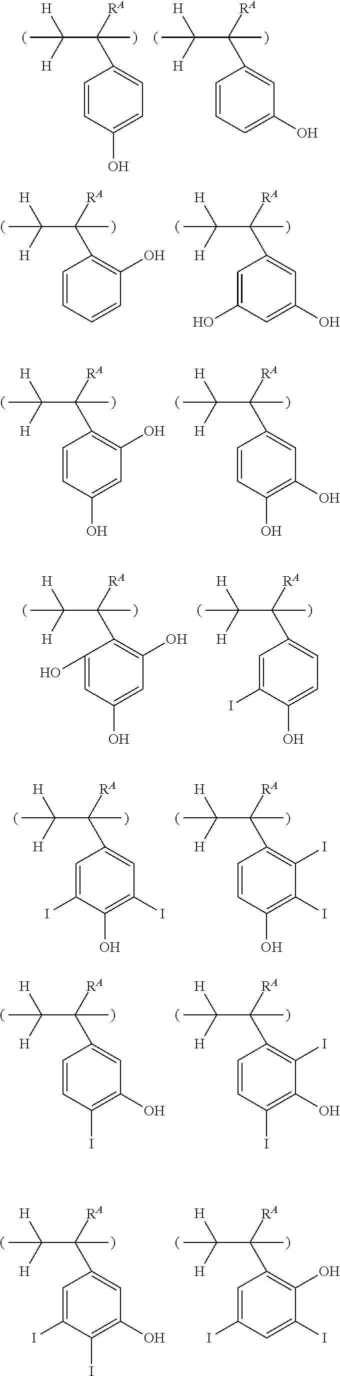

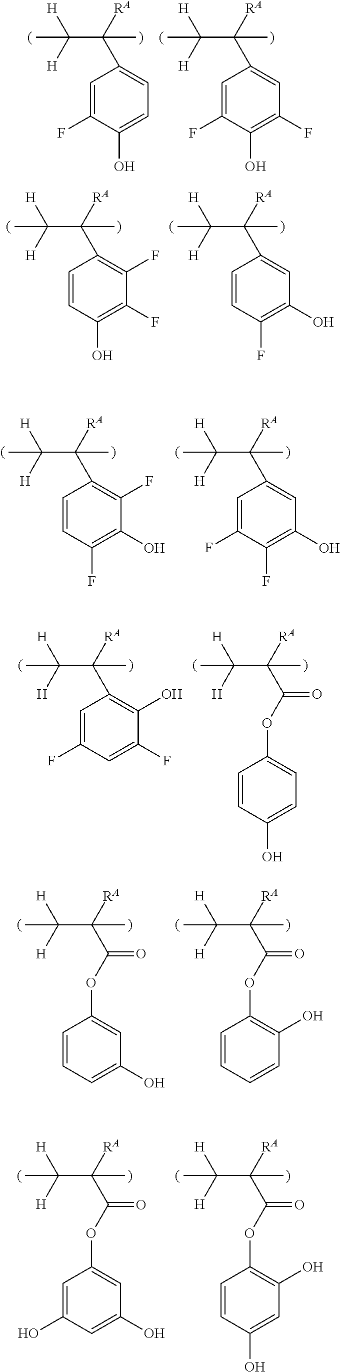

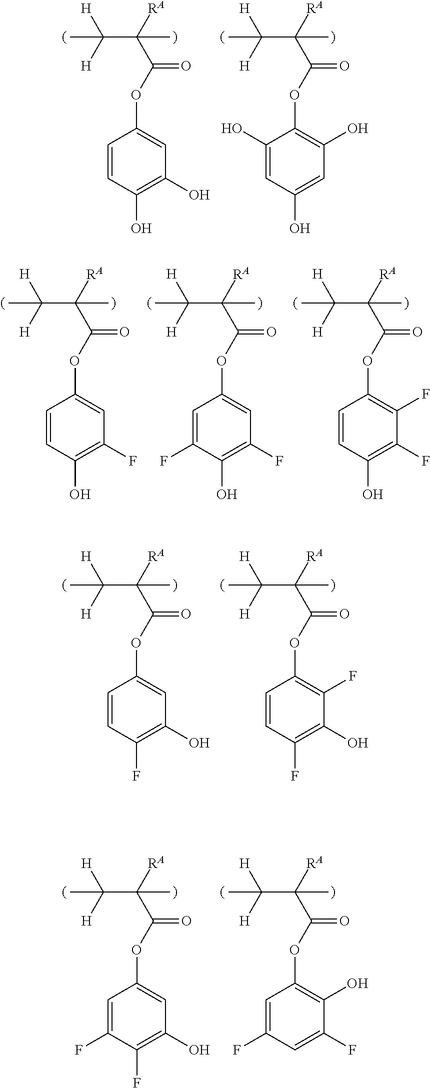

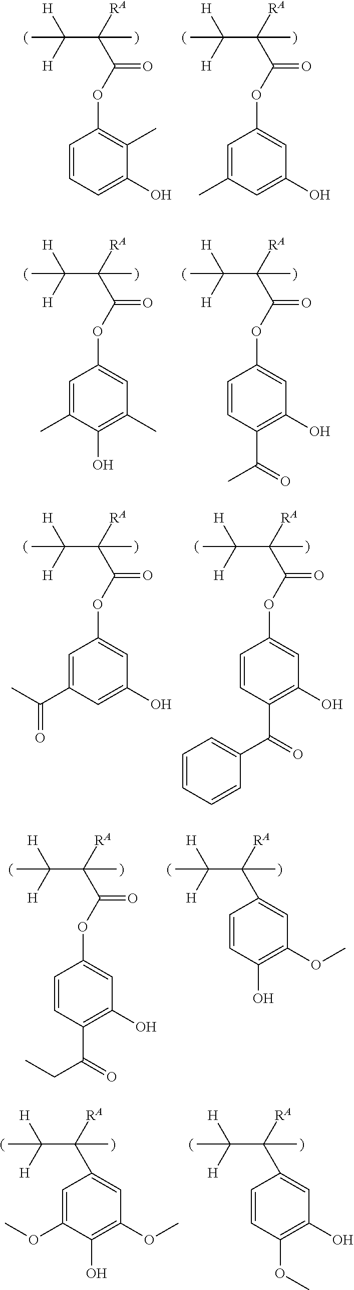

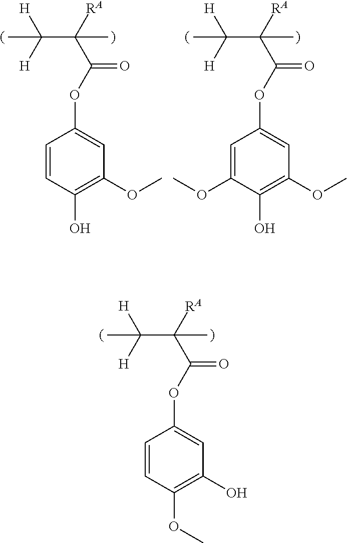

### [Repeating Unit D]

The inventive polymer optionally further comprises a repeating unit represented by the following formula (D-1) (hereinafter, which may be referred to as the repeating unit D).

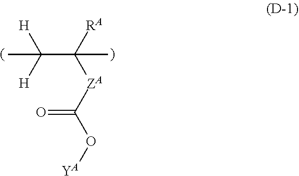

In the formula, R^{A} and Z^{A} is same as above. Y^{A} represents a hydrogen atom or a polar group having at least one or more structures selected from a hydroxy group, a cyano group, a carbonyl group, a carboxy group, an ether bond, an ester bond, a sulfonic acid ester bond, a sulfonic acid amide bond, a carbonate bond, a lactone ring, a sultone ring, a sulfur atom, and a carboxylic anhydride.

The Y^{A} may represent a hydrogen or a polar group having at least one or more structures selected from a hydroxy group other than a phenolic hydroxy group, a cyano group, a carbonyl group, a carboxy group, an ether bond, an ester bond, a sulfonic acid ester bond, a carbonate bond, a lactone ring, a sultone ring, and a carboxylic anhydride.

Examples of the repeating unit D include the following repeating units, but the repeating unit D is not limited thereto. In the formulae, R^{A} is same as above.

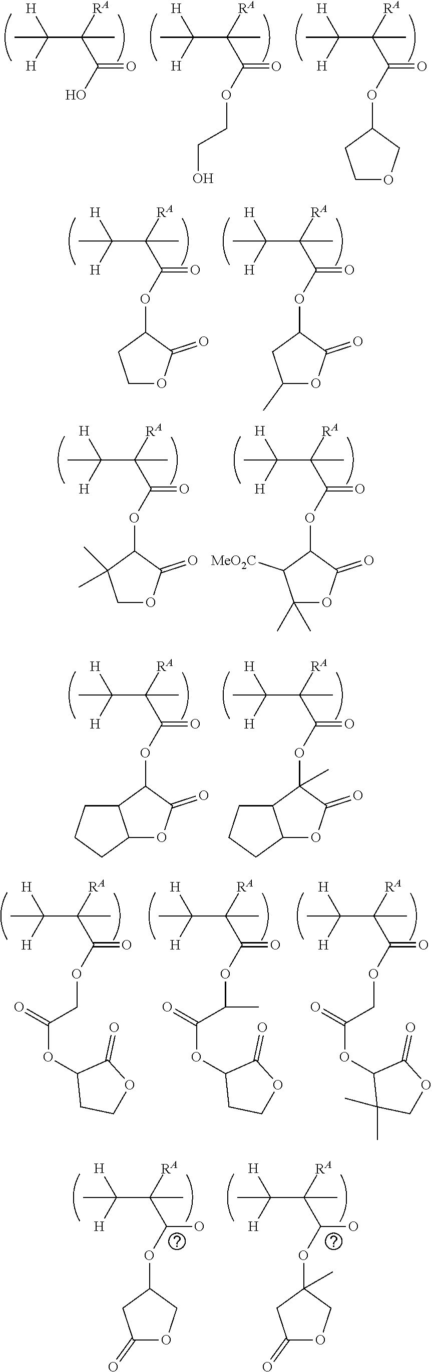

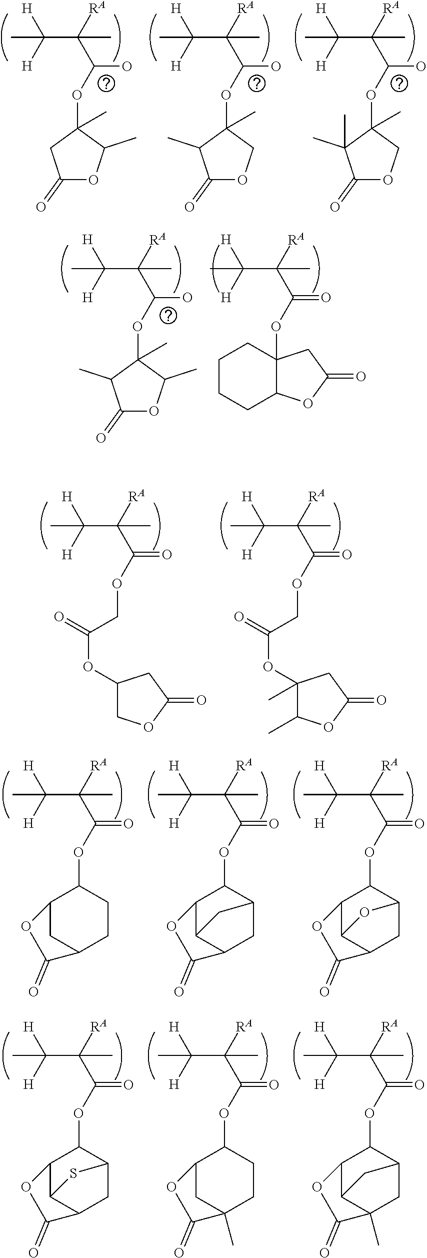

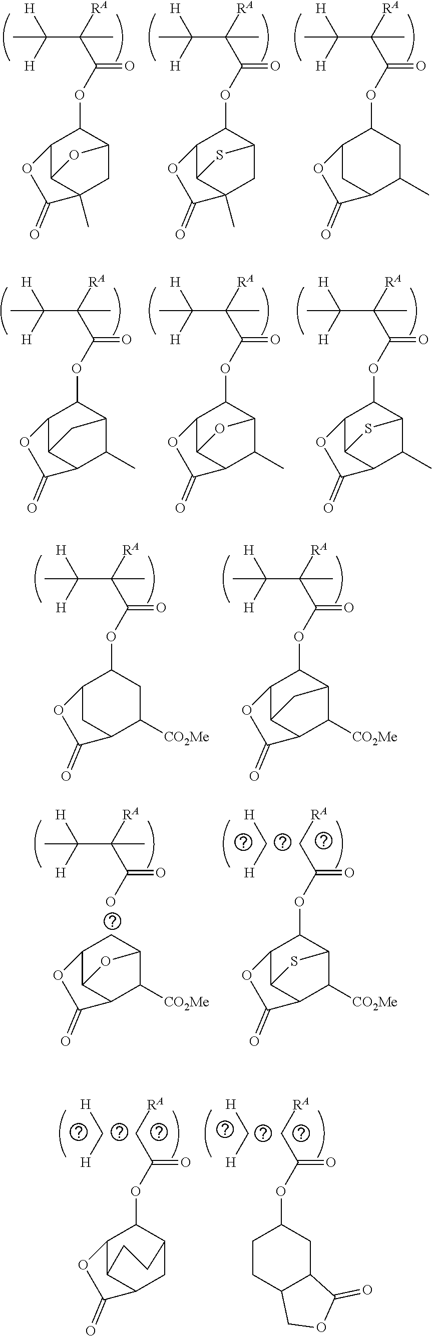

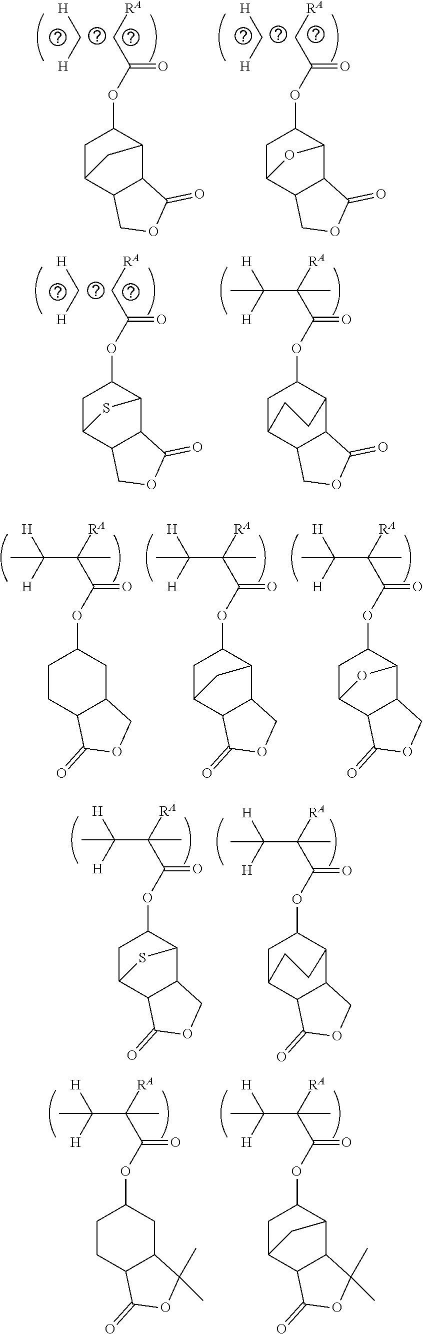

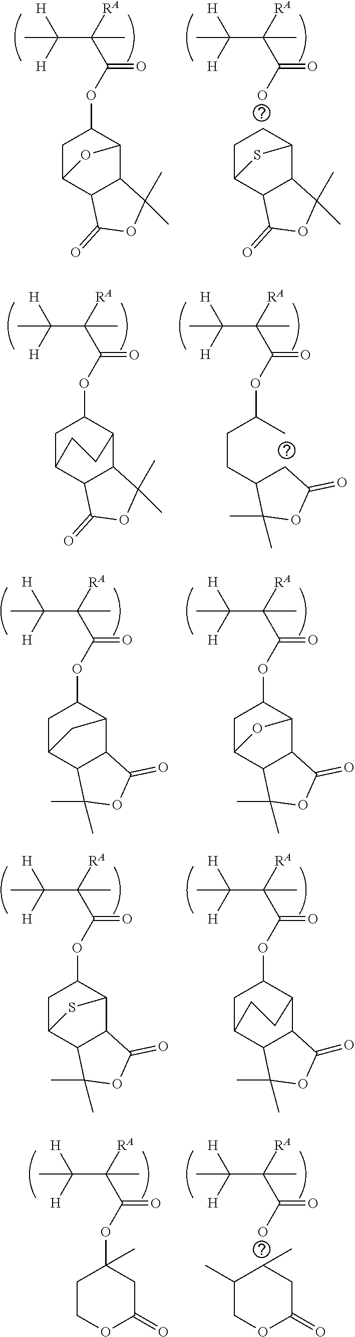

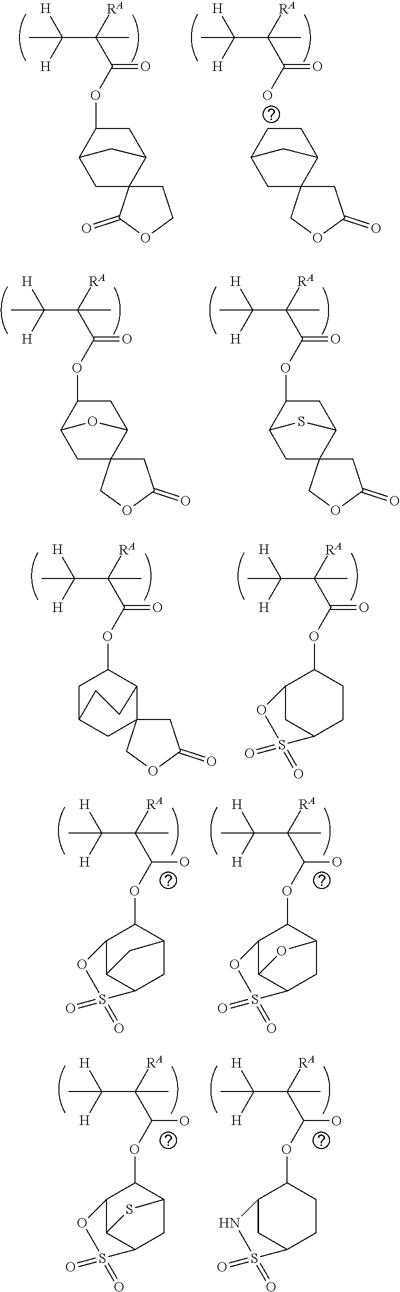

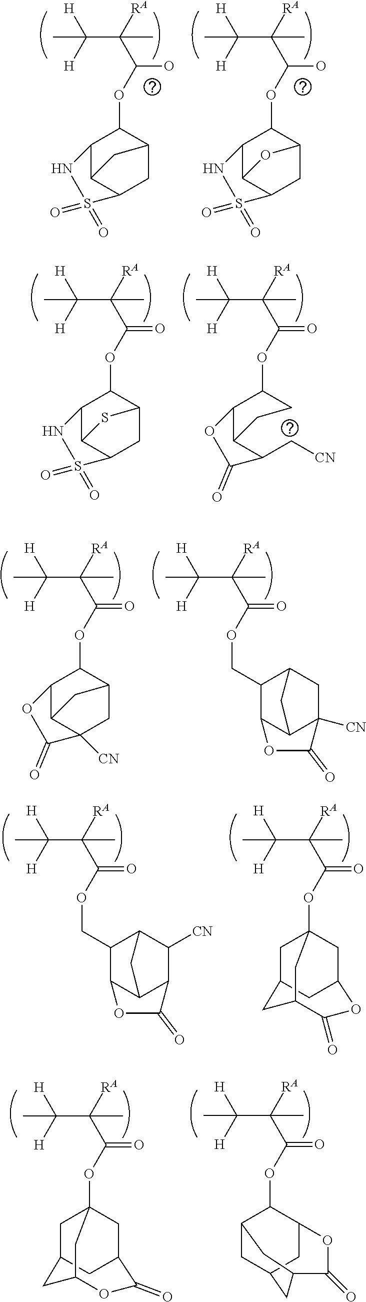

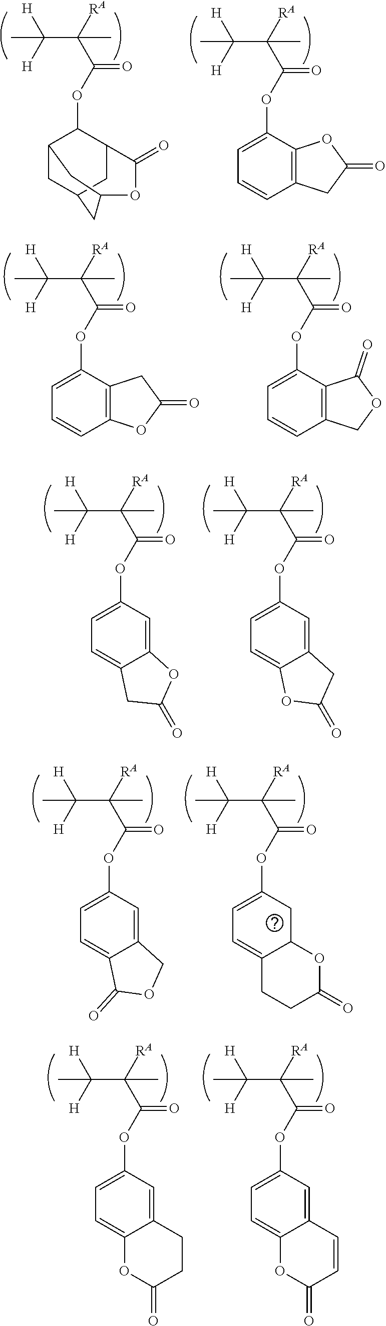

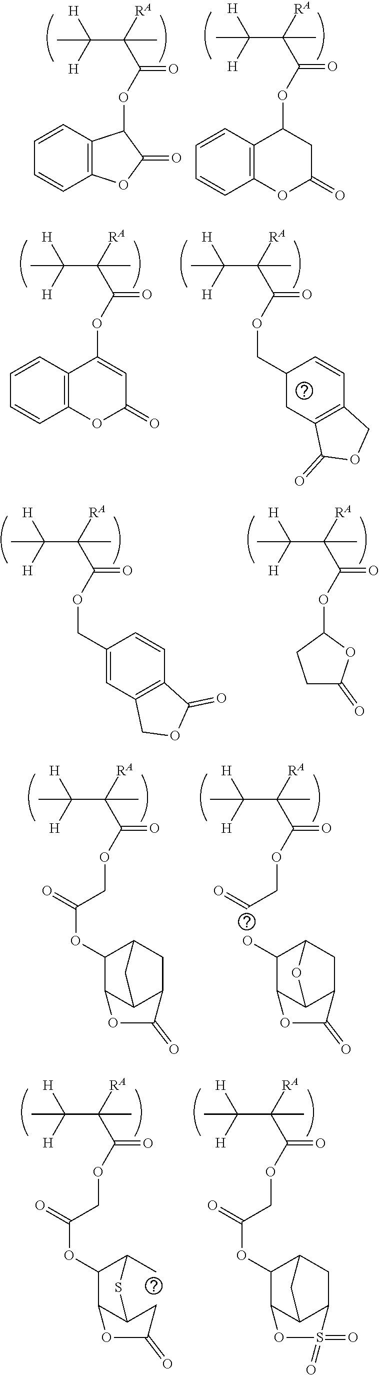

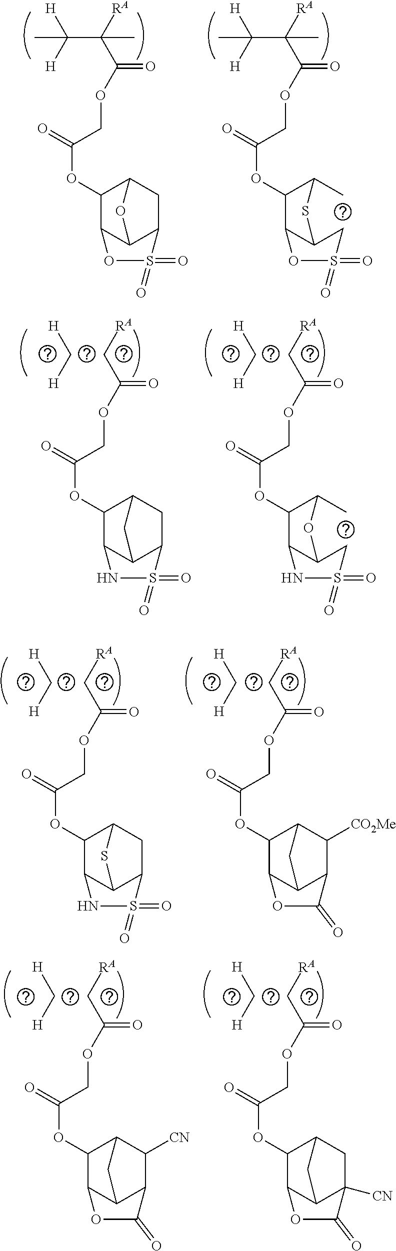

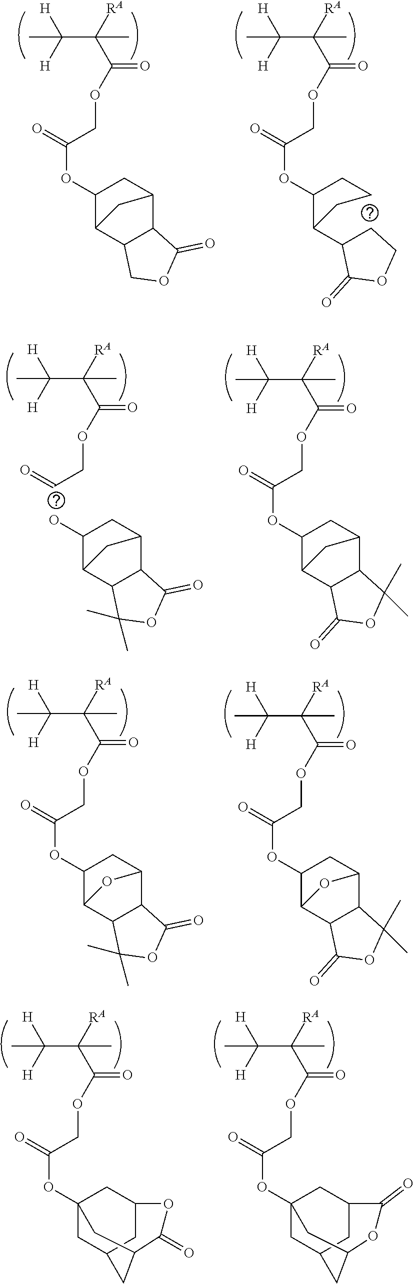

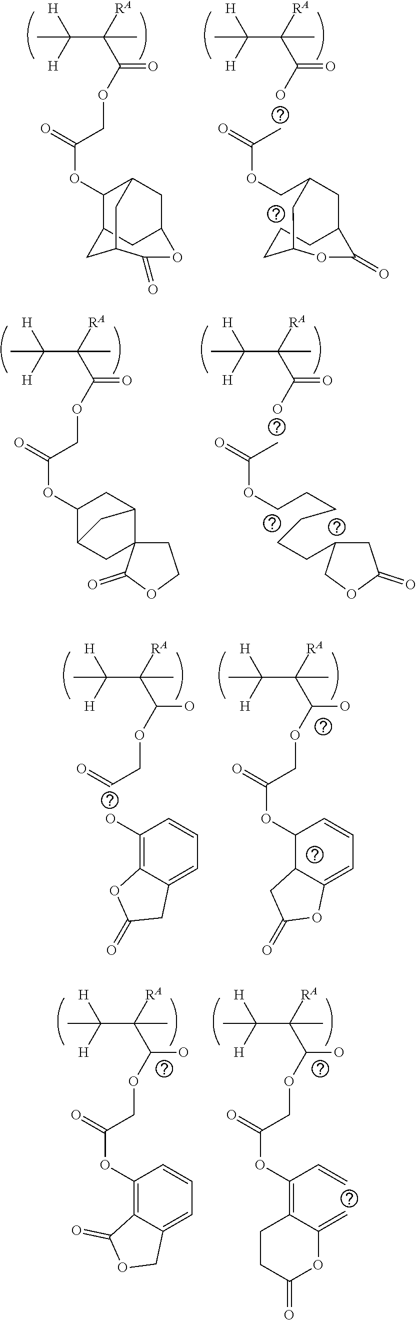

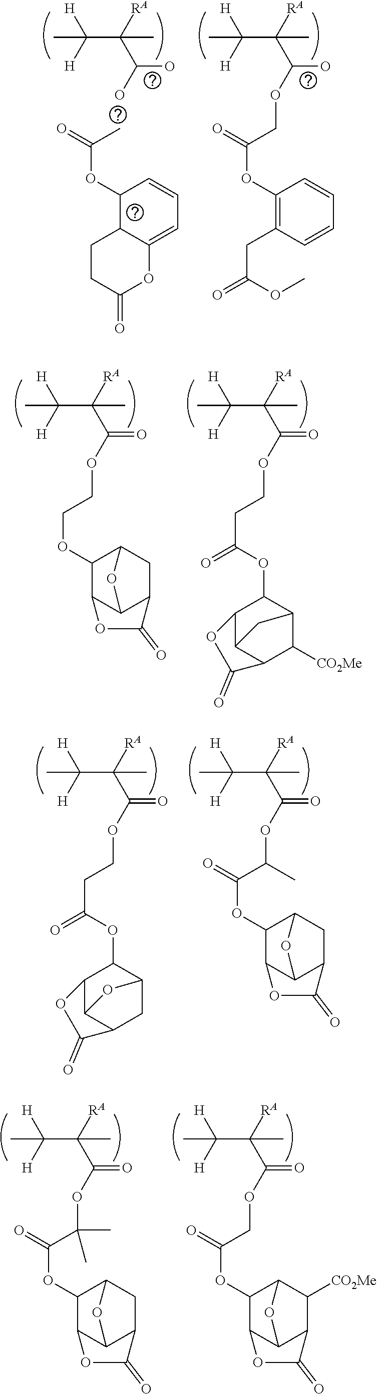

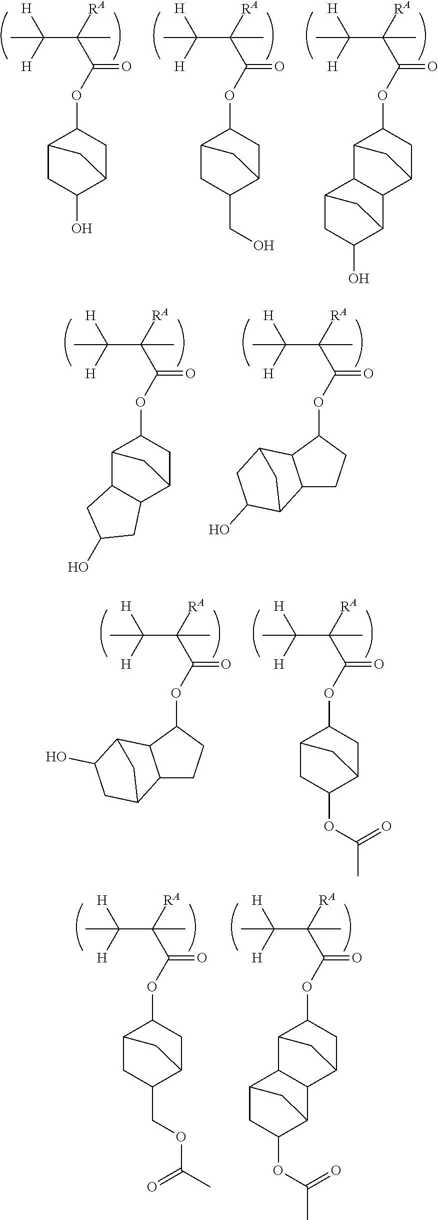

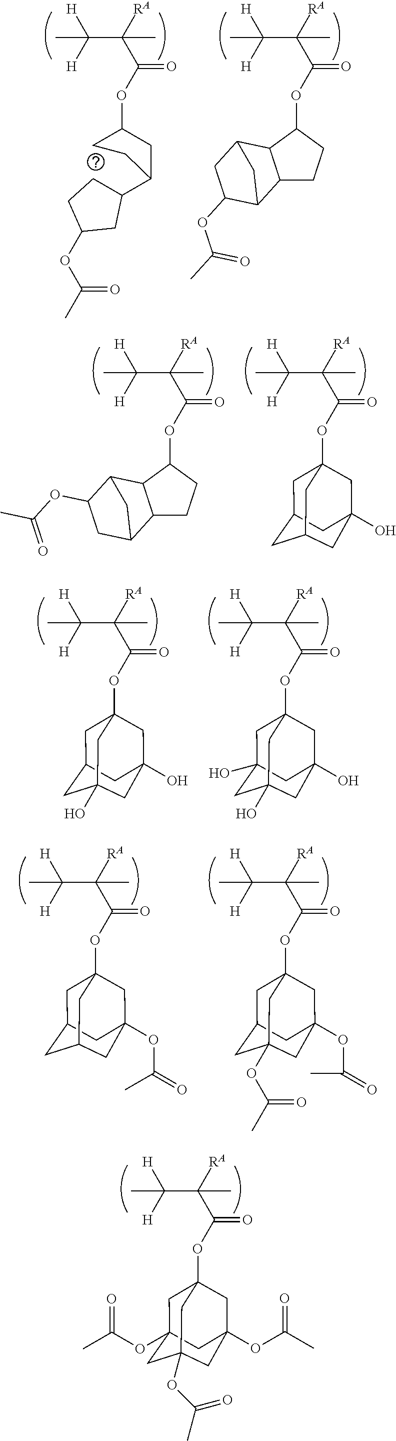

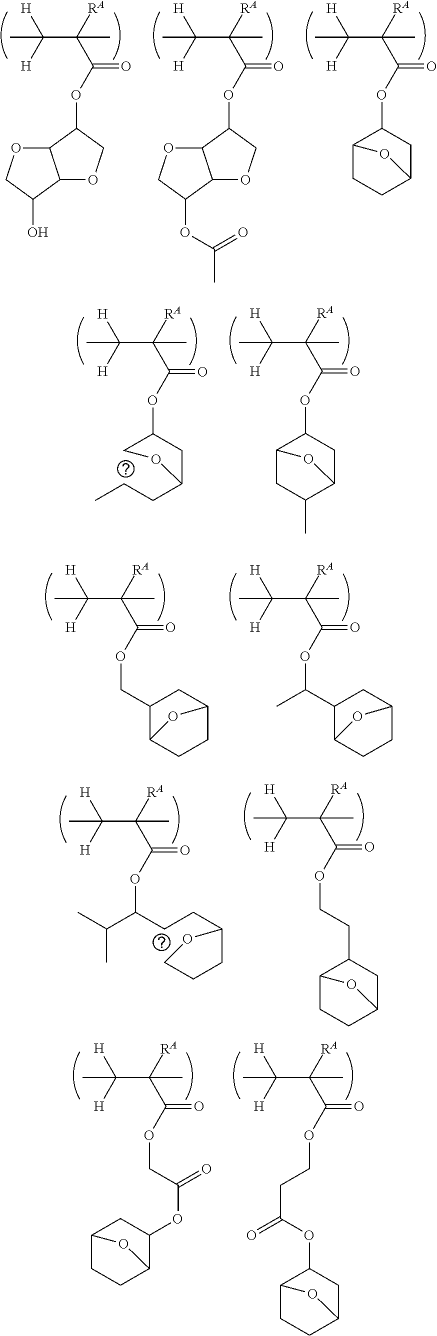

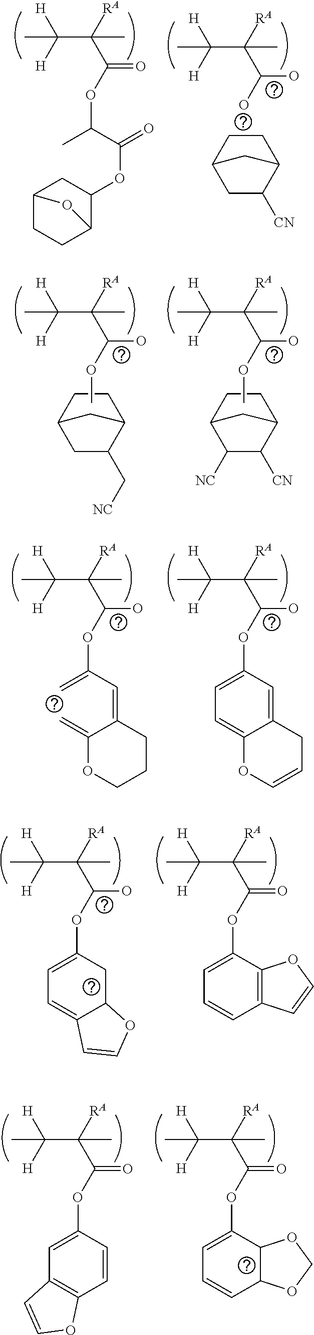

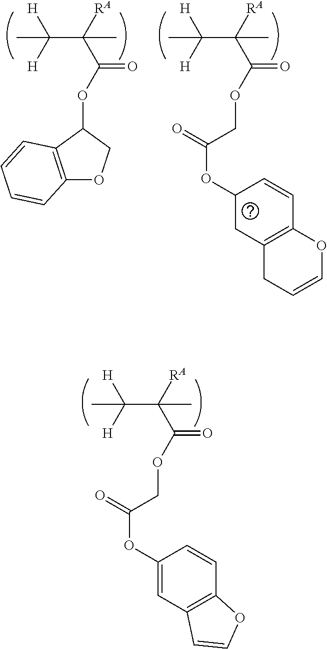

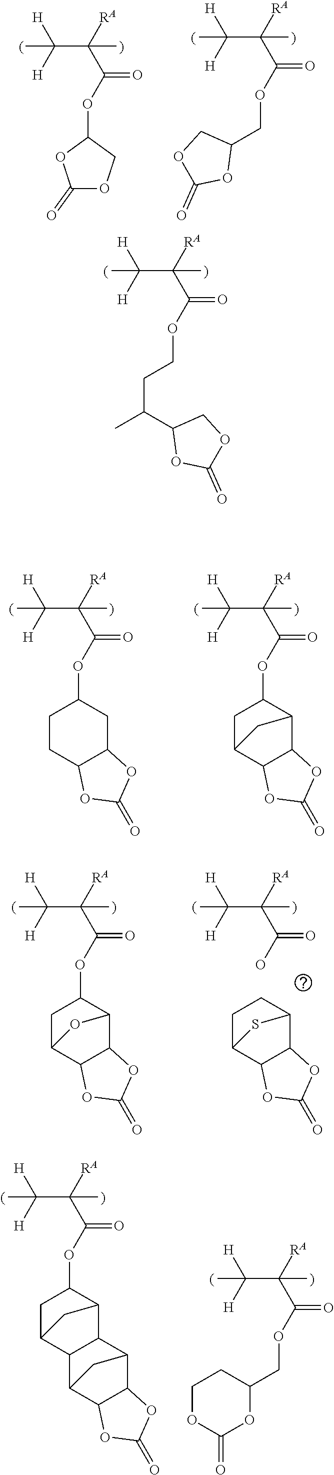

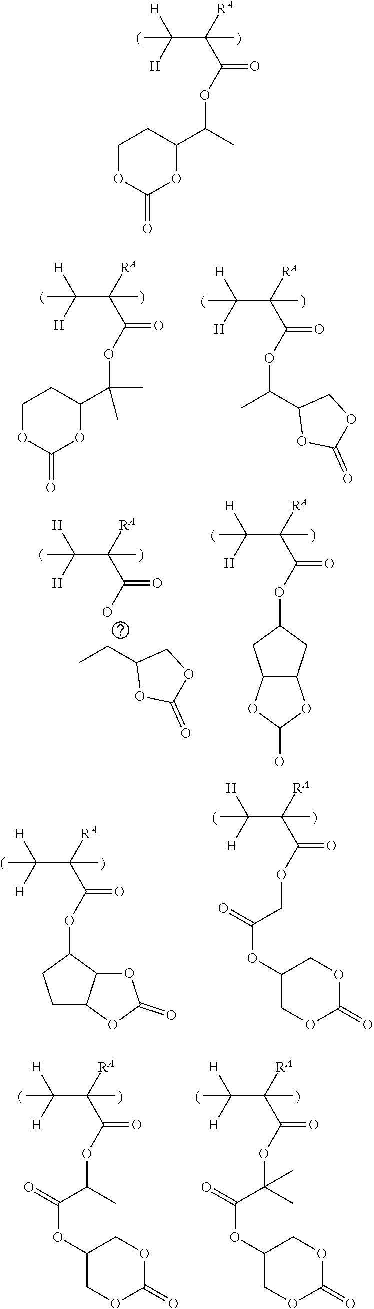

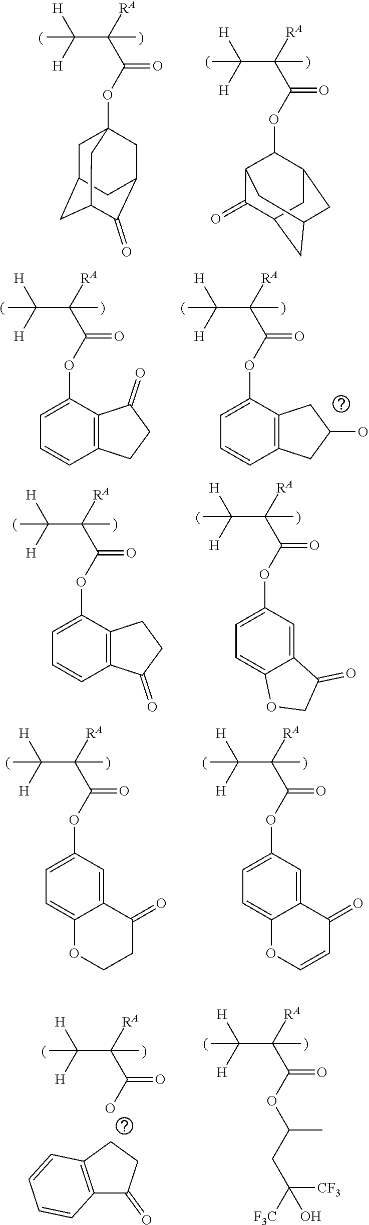

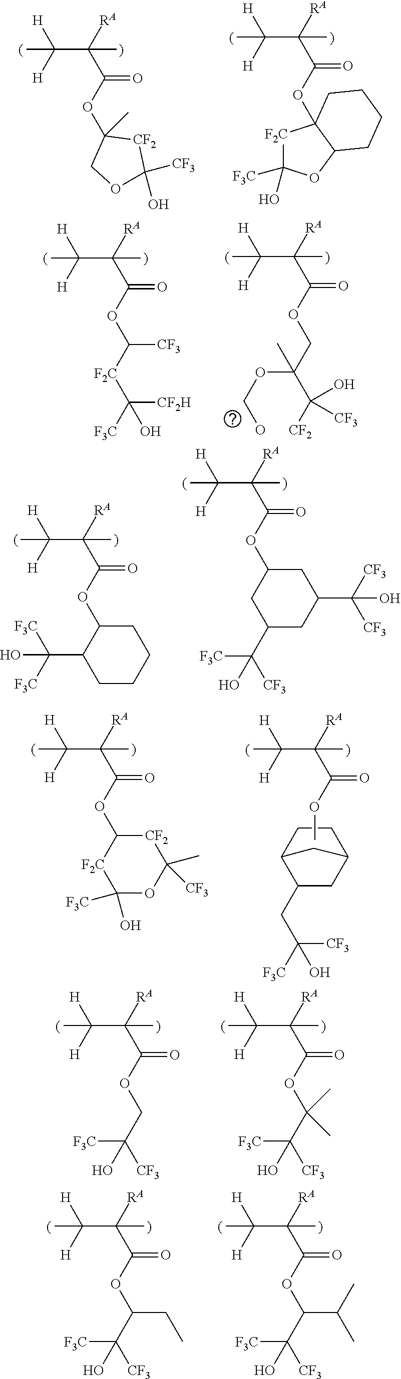

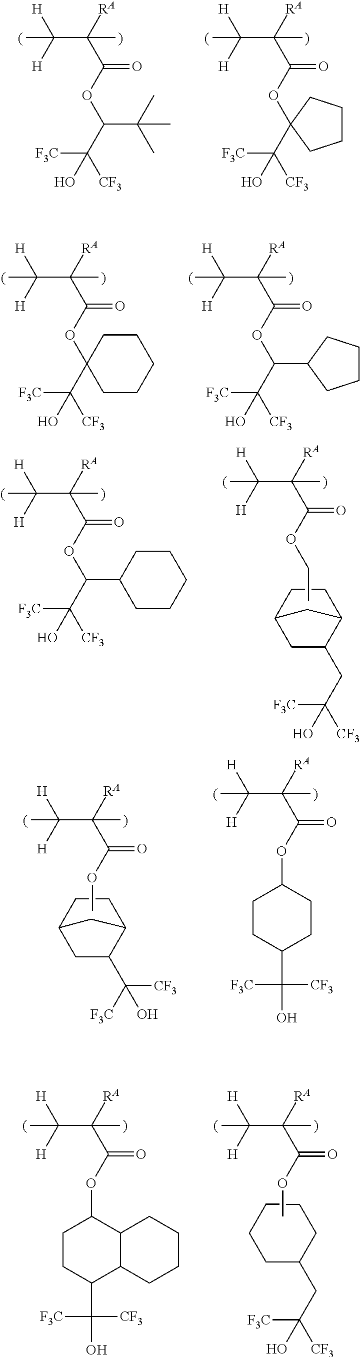

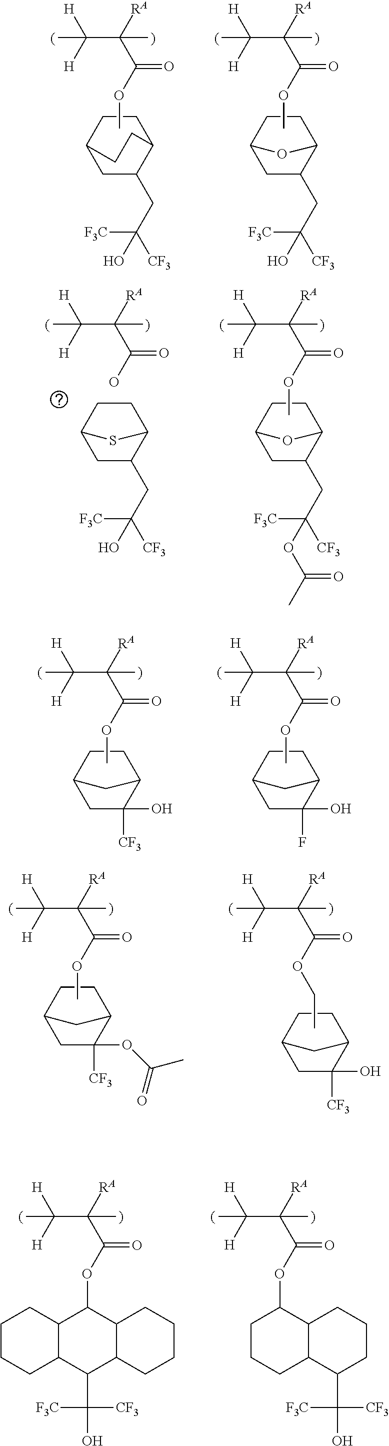

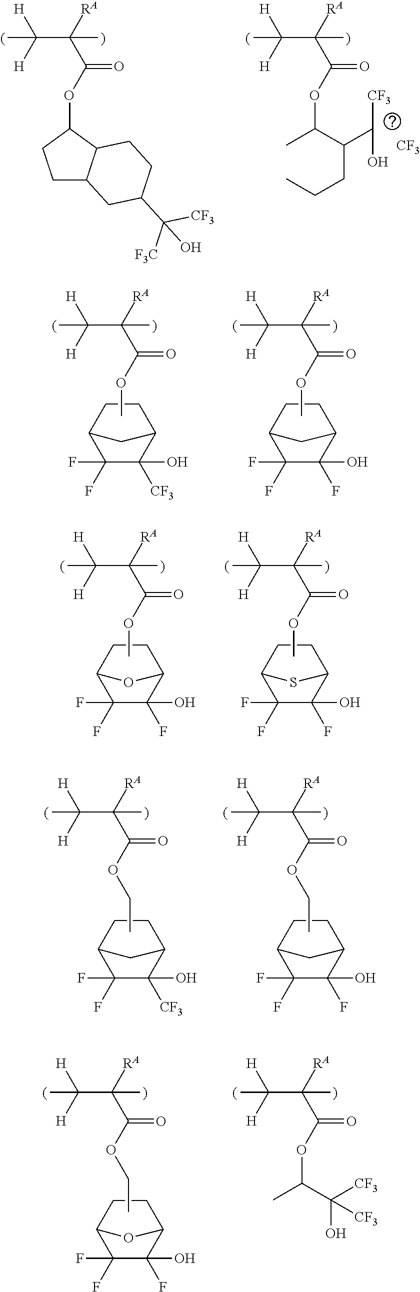

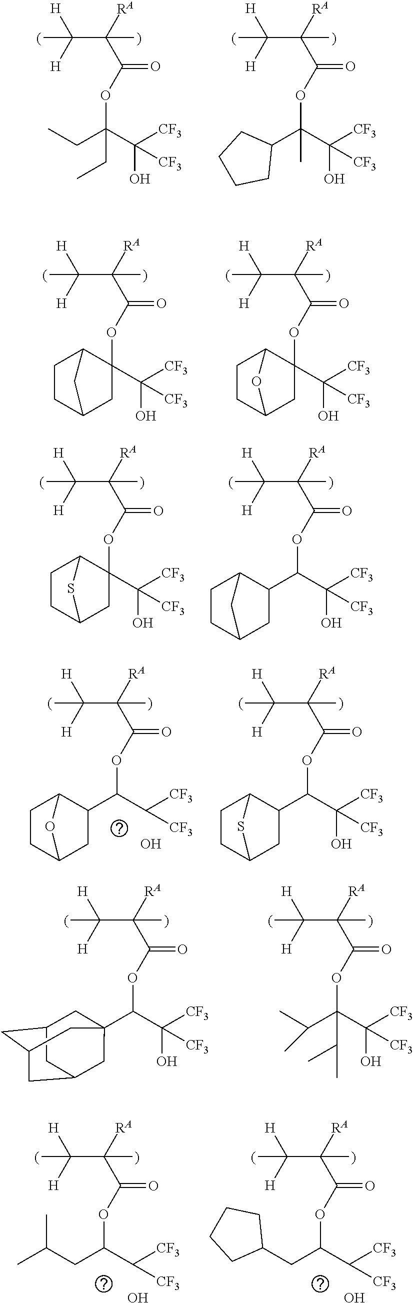

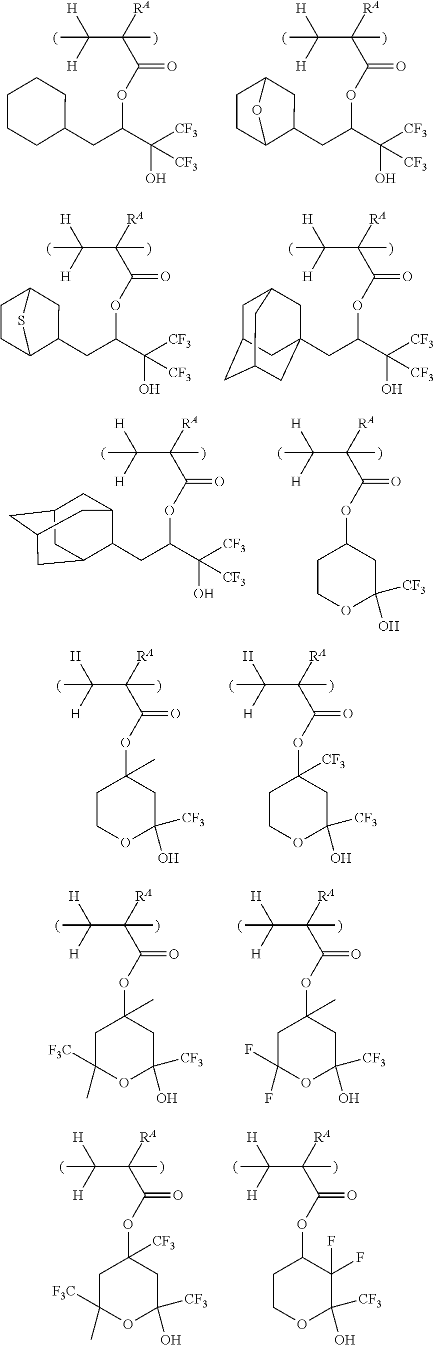

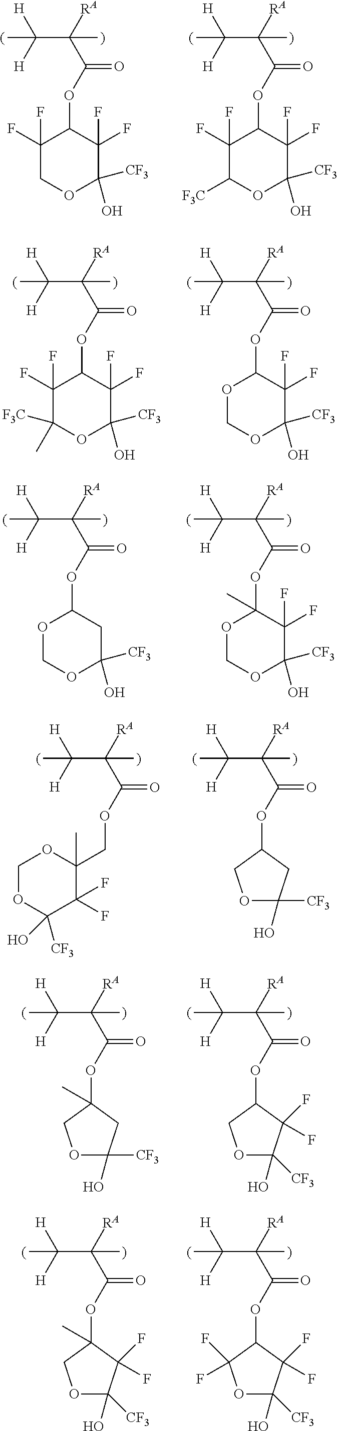

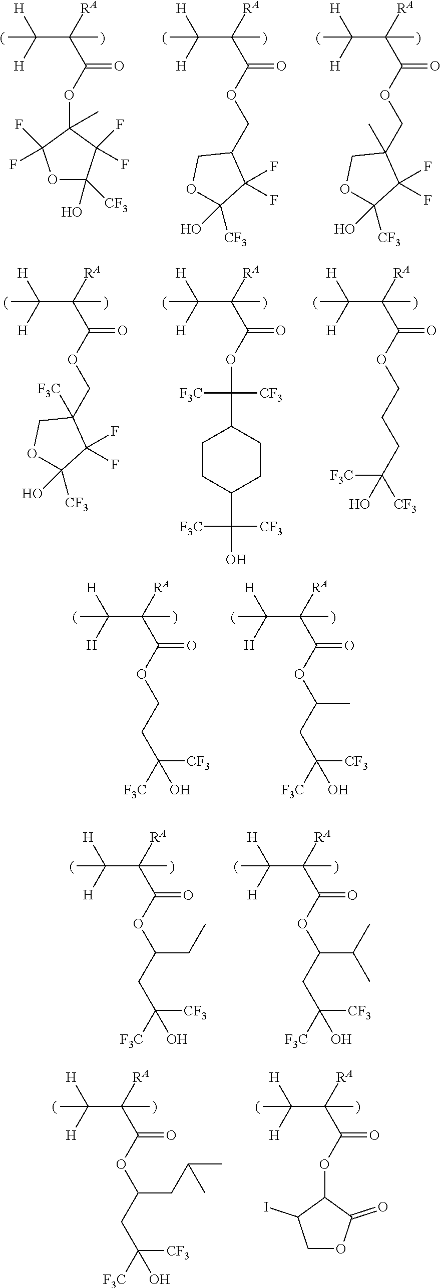

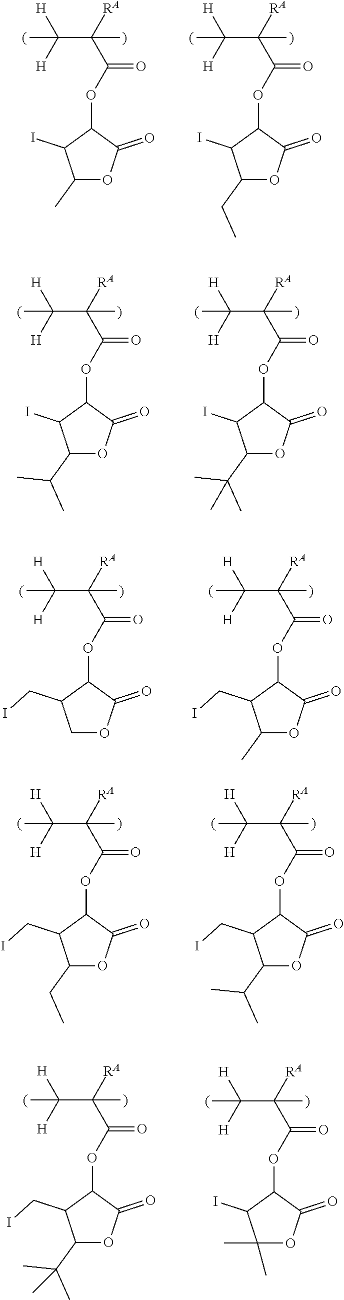

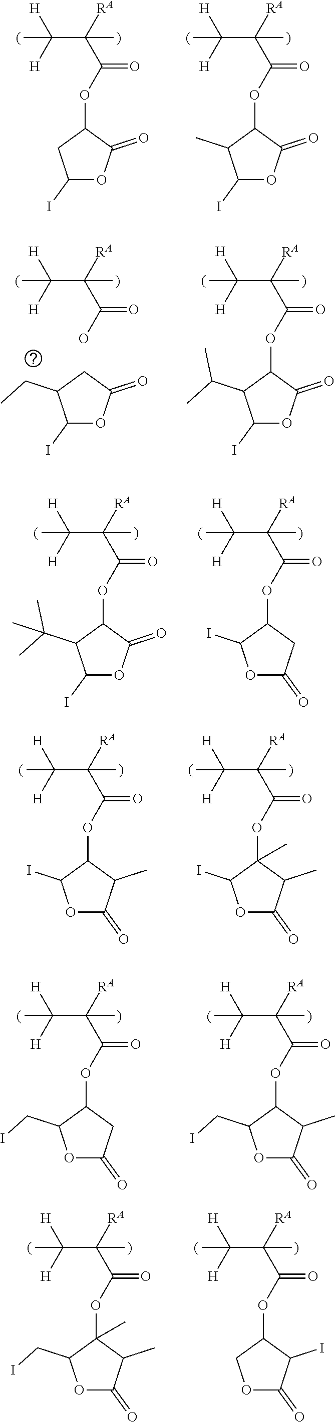

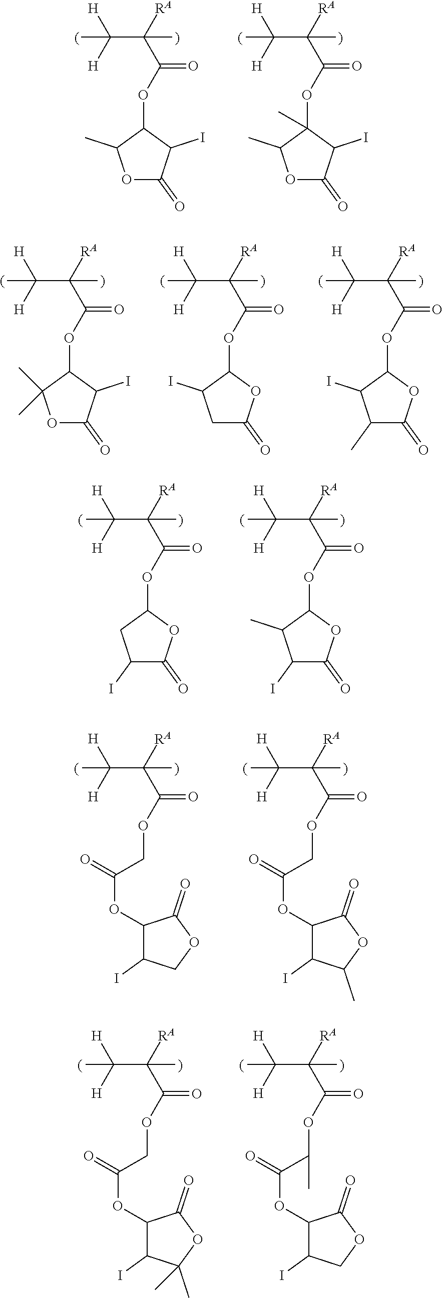

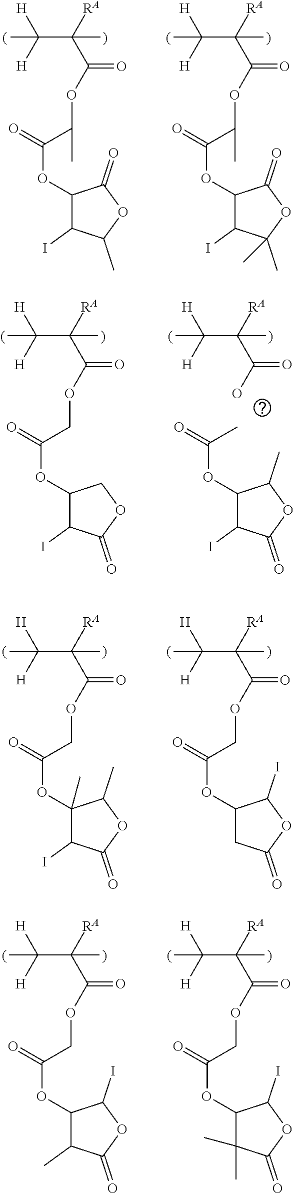

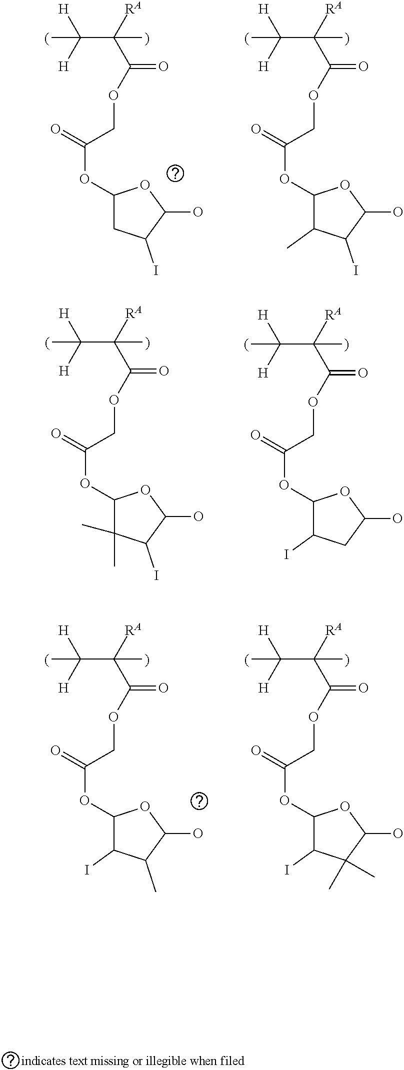

### [Repeating Unit E]

The inventive polymer optionally further comprises a repeating unit E derived from indene, benzofuran, benzothiophene, acenaphthylene, chromone, coumarin, norbornadiene, or a derivative thereof. Examples of monomers yielding the repeating unit E include the following monomers, but the monomer is not limited thereto.

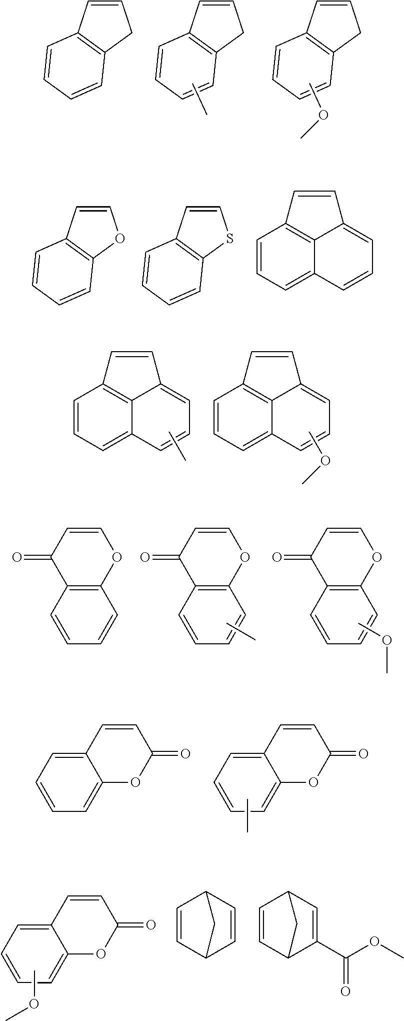

### [Repeating Unit F]

The inventive polymer optionally further comprises a repeating unit F derived from indane, vinylpyridine, or vinylcarbazole.

In the inventive polymer, a content ratio between the repeating units A, a1, a2, B, C, D, E, and F is preferably 0<A<1.0, 0≤a1≤0.8, 0≤a2≤0.8, 0<B<1.0, 0≤C<1.0, 0≤D≤0.8, 0≤E≤0.8, and 0≤F≤0.4, more preferably 0.05≤A≤0.9, 0≤a1≤0.7, 0≤a2≤0.7, 0≤a1+a2≤0.7, 0.01≤B≤0.4, 0.09≤C≤0.55, 0≤D≤0.7, 0≤E≤0.7, and 0≤F≤0.3, and further preferably 0.1≤A≤0.8, 0≤a1≤0.6, 0≤a2≤0.6, 0≤a1+a2≤0.4, 0.1≤B≤0.45, 0.1≤C≤0.45, 0≤D≤0.6, 0≤E≤0.6, and 0≤F≤0.2.

When the repeating unit B is at least one selected from the repeating units B1 to B4, B=B1+B2+B3+B4. A+a1+a2+B+C+D+E+F=1.

A weight-average molecular weight (Mw) of the polymer is preferably 1,000 to 500,000, and more preferably 3,000 to 100,000. Mw within this range yields sufficient etching resistance and has no risk of deterioration of resolution due to failure to achieve difference in the dissolution rete before and after the light exposure. Mw in the present invention is a polystyrene-converted measurement value by gel permeation chromatography (GPC) using tetrahydrofuran (THF) or N,N-dimethylformamide (DMF) as a solvent.

As a finer pattern rule, the molecular weight distribution (Mw/Mn) of the polymer has greater effect. Thus, the polymer preferably has narrow dispersion of Mn/Mn of 1.0 to 2.0 to obtain a resist composition suitably used for a fine pattern size. Within the above range, there are few polymers having a low molecular weight and a high molecular weight, and there is no risk of foreign matter observed on the pattern and deterioration of the pattern shape after the light exposure.

To synthesize the polymer, monomers to yield the aforementioned repeating units can be polymerized in an organic solvent by adding a radical polymerization initiator and heating, for example.

Examples of the organic solvent used in the polymerization include toluene, benzene, THF, diethyl ether, dioxane, cyclohexane, cyclopentane, methyl ethyl ketone (MEK), propylene glycol monomethyl ether acetate (PGMEA), and γ-butyrolactone (GBL). Examples of the polymerization initiator include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. An addition amount of these initiators is preferably 0.01 to 25 mol % relative to a total of the monomers to be polymerized. The reaction temperature is preferably 50 to 150° C., and more preferably 60 to 100° C. The reaction time is preferably 2 to 24 hours, and from the viewpoint of production efficiency, more preferably 2 to 12 hours.

The polymerization initiator may be added into a solution of the monomers to be fed into a reaction vessel, or an initiator solution is prepared separately from the monomer solution and each of the solutions may be independently fed into a reaction vessel. Since a radical generated from the initiator may proceed the polymerization reaction during the waiting time to generate a polymer having an ultra-high molecular weight, the monomer solution and the initiator solution are preferably each independently prepared to be added dropwise from the viewpoint of quality control. The acid-labile group may be introduced into the monomer to be used as it is, or may be protected or partially protected after the polymerization. To regulate the molecular weight, known chain transfer agents, such as dodecyl mercaptan and 2-mercaptoethanol may be used in combination. In this case, an addition amount of these chain transfer agents is preferably 0.01 to 20 mol % relative to the total of the monomers to be polymerized.

When the monomer has a hydroxy group, the hydroxy group may be substituted with an acetal group, such as an ethoxyethoxy group, which is easily deprotected by an acid, during the polymerization, and the protected hydroxy group may be deprotected by a weak acid and water after the polymerization. Alternatively, the hydroxy group may be substituted with an acetyl group, a formyl group, a pivaloyl group, etc. to be hydrolyzed with an alkali after the polymerization.

When hydroxystyrene or hydroxyvinylnaphthalene is copolymerized, hydroxystyrene or hydroxyvinylnaphthalene and other monomers may be heat-polymerized in the organic solvent with adding the radical polymerization initiator. Alternatively, acetoxystyrene or acetoxyvinylnaphthalene may be used, and the acetoxy group is deprotected with alkaline hydrolysis after the polymerization to be converted into polyhydroxystyrene or hydroxypolyvinylnaphthalene.

As a base in the alkaline hydrolysis, aqueous ammonia, triethylamine, etc. can be used. The reaction temperature is preferably −20 to 100° C., and more preferably 0 to 60° C. The reaction time is preferably 0.2 to 100 hours, and more preferably 0.5 to 20 hours.

An amount of each monomer in the monomer solution is appropriately set so as to be a preferable content ratio of the above repeating units, for example.

As for the polymer obtained in the producing method, a reaction solution obtained by the polymerization reaction may be a final product. Alternatively, a powder obtained via a purification step, such as reprecipitation method in which the polymerization solution is added into a poor solvent to obtain a powder, may be treated as a final product. From the viewpoints of operation efficiency and quality stabilization, the powder obtained in the purification step is preferably dissolved in a solvent to form a polymer solution to be operated as a final product.

Specific examples of the solvent used in this case include solvents described in paragraphs [0144] to [0145] in JP 2008-111103 A, and specifically include: ketones, such as cyclohexanone and methyl-2-n-pentylketone; alcohols, such as 3-methoxybutanol, 3-methyl-3-methoxybutanol, 1-methoxy-2-propanol, and 1-ethoxy-2-propanol; ethers, such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters, such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as GBL; alcohols, such as diacetone alcohol (DAA); alcoholic solvents having a high boiling point, such as diethylene glycol, propylene glycol, glycerin, 1,4-butanediol, and 1,3-butanediol; and a mixed solvent thereof.

In the polymer solution, a concentration of the polymer is preferably 0.01 to 30 mass %, and more preferably 0.1 to 20 mass %.

The reaction solution and the polymer solution are preferably filtered with a filter. The filtration can remove a foreign matter and gel, which may cause a defect, and is effective in terms of quality stabilization.

Examples of a material of the filter used for the filtration include a fluorocarbon, cellulose, nylon, a polyester, and a hydrocarbon. In the step of filtering the resist composition, the filter is preferably formed with a fluorocarbon, so-called Teflon®, a hydrocarbon such as polyethylene and polypropylene, or nylon. A pore size of the filter can be appropriately selected depending on target cleanliness, and is preferably 100 nm or smaller, and more preferably 20 nm or smaller. These filter may be used alone, or may be used in combination of a plurality of these filters. As for the filtration method, the solution may be passed through the filter once, but the solution is preferably circulated to be filtered a plurality of times. In the step for producing the polymer, the filtration step may be performed in any order and times, but the reaction solution after the polymerization reaction, the polymer solution, or both thereof are preferably filtered.

The polymer may contain two or more polymers having different composition ratios, Mw, and molecular weight distributions.

The present invention can provide a resist composition comprising the polymer. Specifically, the present invention can provide a chemically amplified resist composition described below.

### [Chemically Amplified Resist Composition]

The inventive chemically amplified resist composition comprises:

(P) a base polymer;

(G) a quencher; and

(H) an organic solvent.

The inventive chemically amplified resist composition may comprise, as necessary, at least one selected from:

(I) a photoacid generator other than the photoacid generator bonded to a chain of the base polymer;

(J) a nitrogen-containing quencher; and

(K) a surfactant insoluble or hardly soluble in water and soluble in an alkaline developing liquid; and/or a surfactant insoluble or hardly soluble in water and an alkaline developing liquid.

The inventive chemically amplified resist composition can further comprise, as necessary,

(L) another component.

### [(G) Quencher]

Examples of (G) the quencher include an onium salt represented by the following formula (1) or (2).

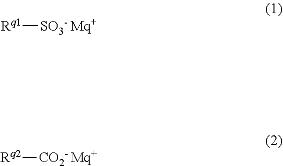

In the formula (1), R^{q}1 represents a hydrogen atom or a hydrocarbyl group having 1 to 40 carbon atoms and optionally having a heteroatom, except for a group in which a hydrogen atom bonded to a carbon atom at the α-position of the sulfo group is substituted with a fluorine atom or a fluoroalkyl group. In the formula (2), R^{q2} represents a hydrogen atom or a hydrocarbyl group having 1 to 40 carbon atoms and optionally having a heteroatom.

Specific examples of the hydrocarbyl group represented by R^{q1} include: alkyl groups, such as a methyl group, an ethyl group, a propyl group, an isopropyl group, an n-butyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; and aryl groups, such as a phenyl group, a naphthyl group, and an anthracenyl group. A part or all of hydrogen atoms in these groups are optionally substituted with a group having a heteroatom, such as an oxygen atom, a sulfur atom, a nitrogen atom, and a halogen atom. A part of carbon atoms in these groups is optionally substituted with a group having a heteroatom, such as an oxygen atom, a sulfur atom, and a nitrogen atom. As a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, etc. are optionally contained.

Specific examples of the hydrocarbyl group represented by R^{q2} include: the substituents exemplified as the specific examples of R^{q1}; fluorinated alkyl groups, such as a trifluoromethyl group and a trifluoroethyl group; and fluorinated aryl groups, such as a pentafluorophenyl group and 4-trifluoromethylphenyl group.

Examples of the anion of the onium salt represented by the formula (1) include the following anions, but the anion is not limited thereto.

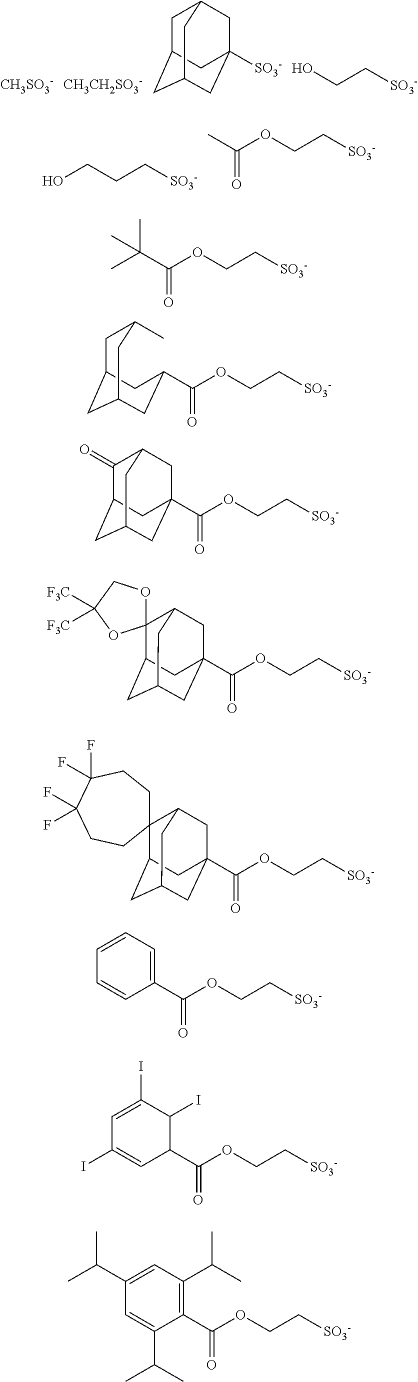

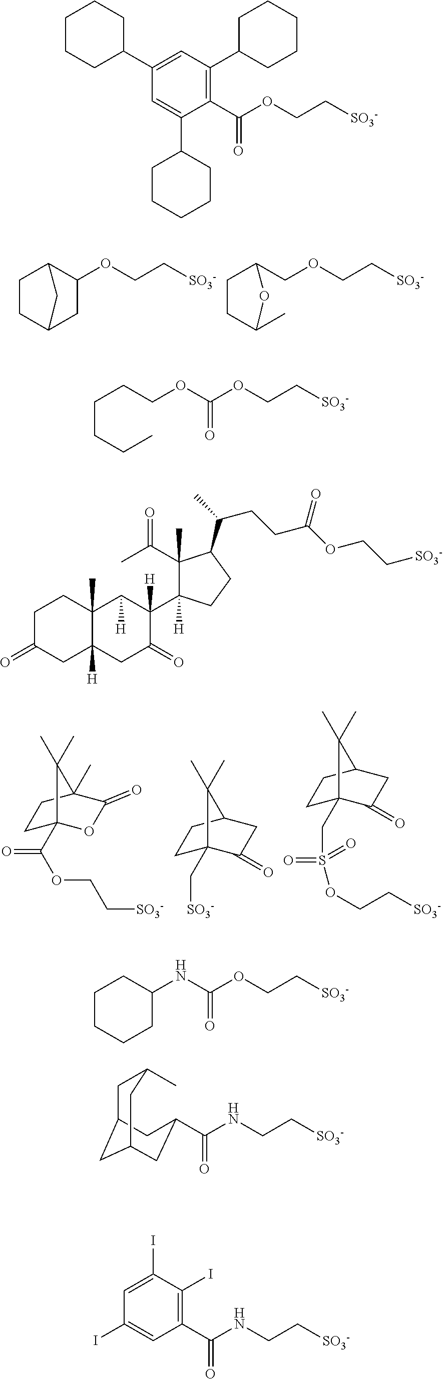

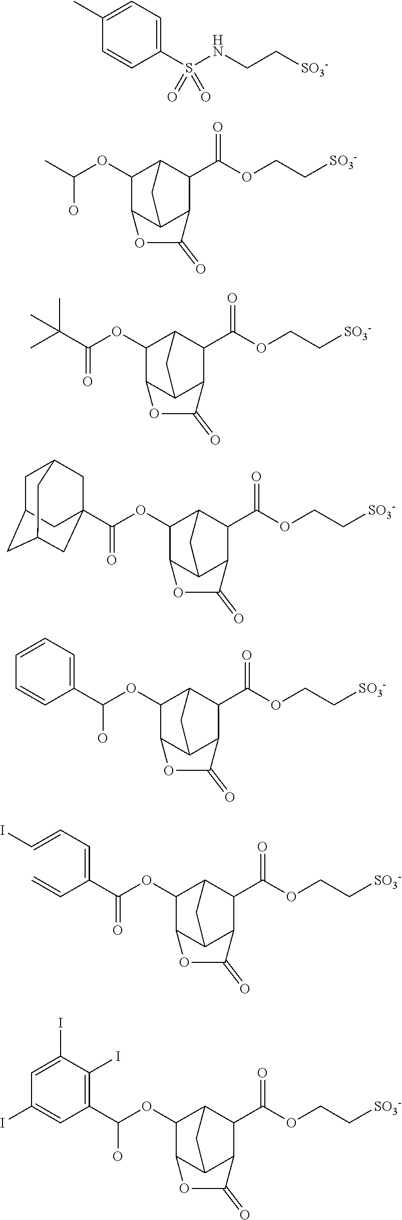

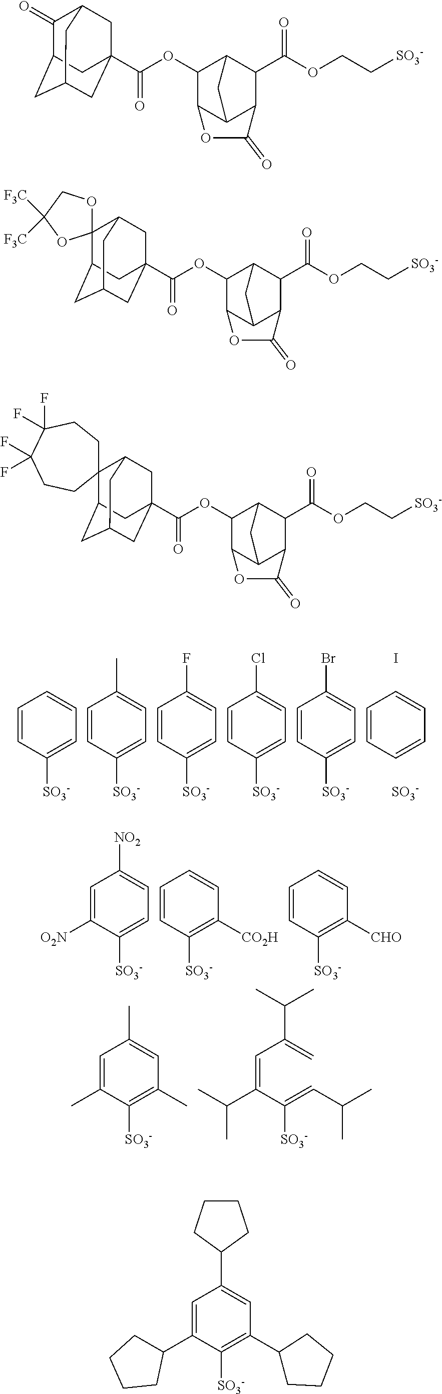

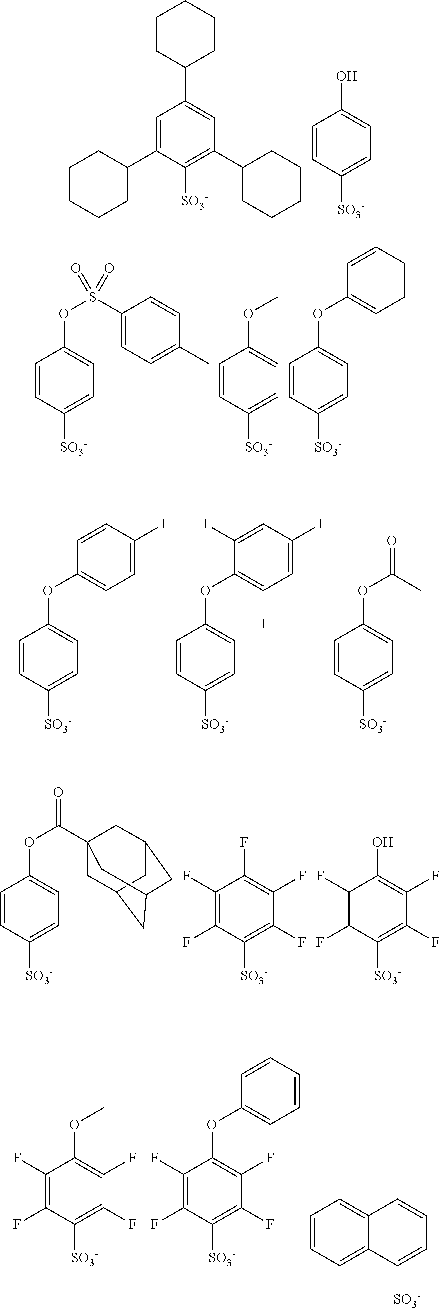

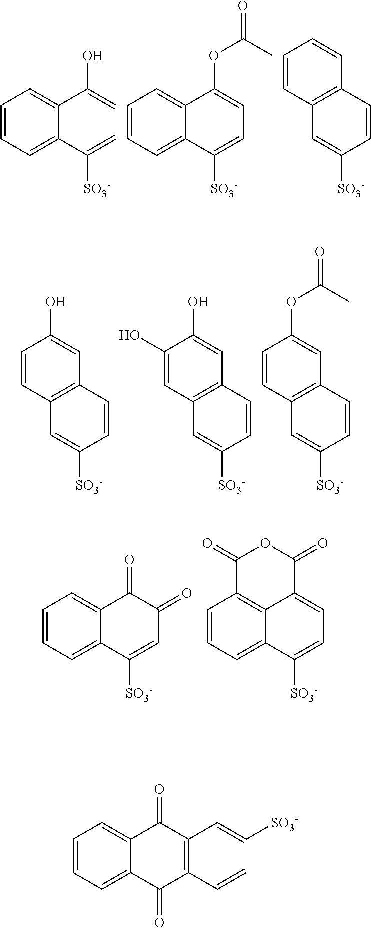

Examples of the anion of the onium salt represented by the formula (2) include the following anions, but the anion is not limited thereto.

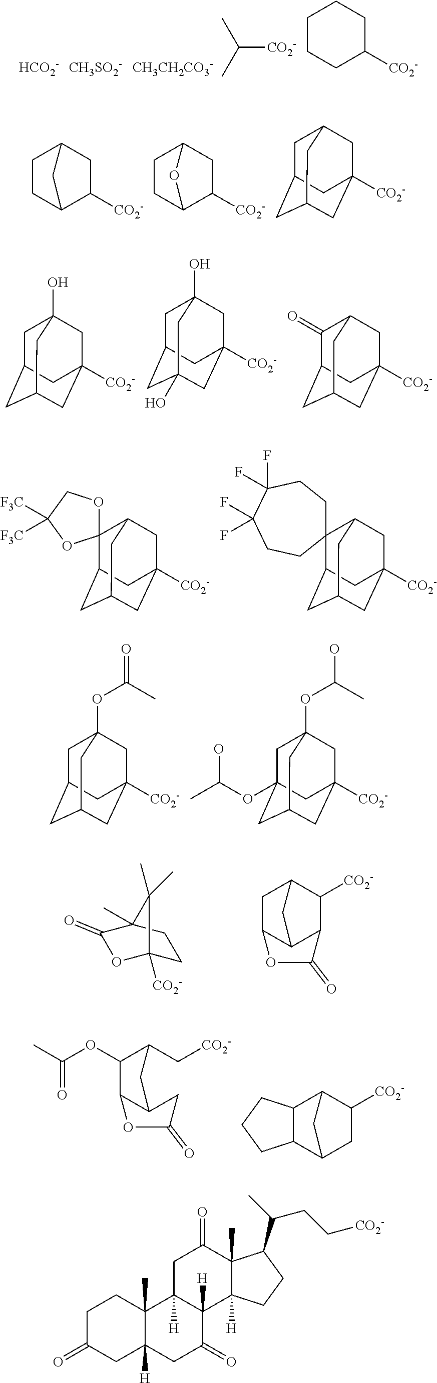

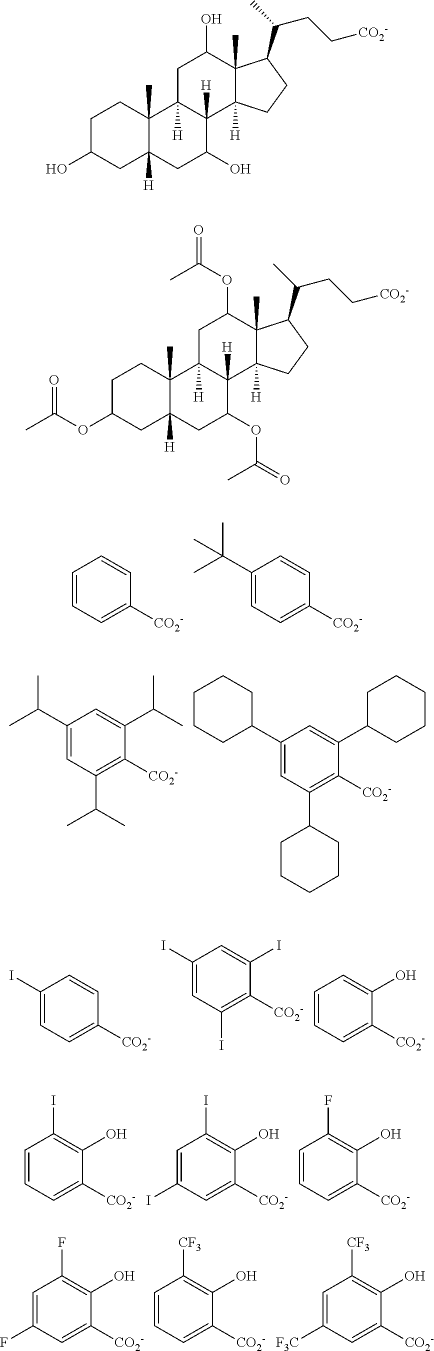

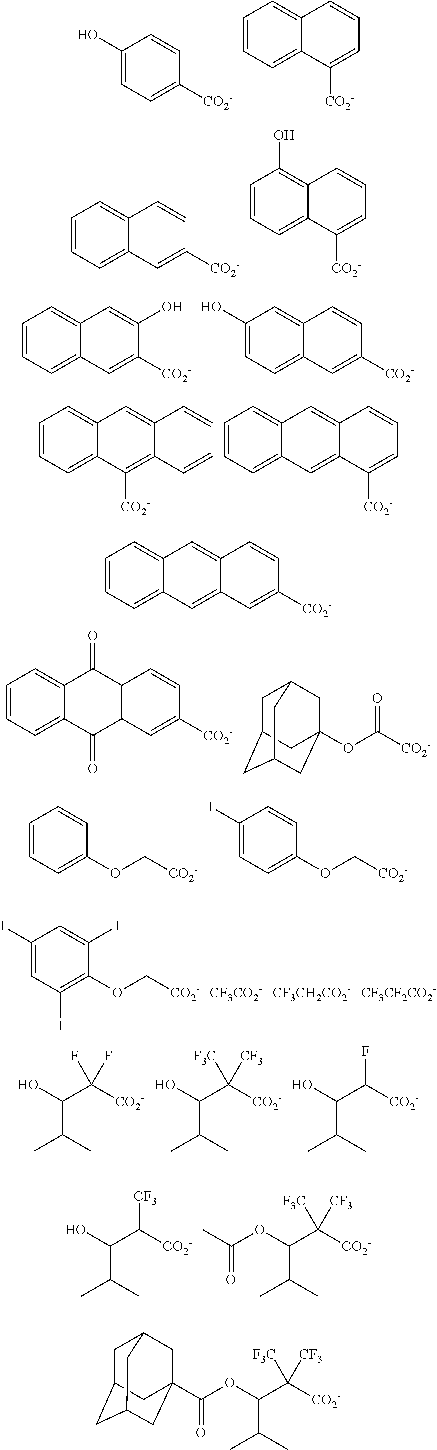

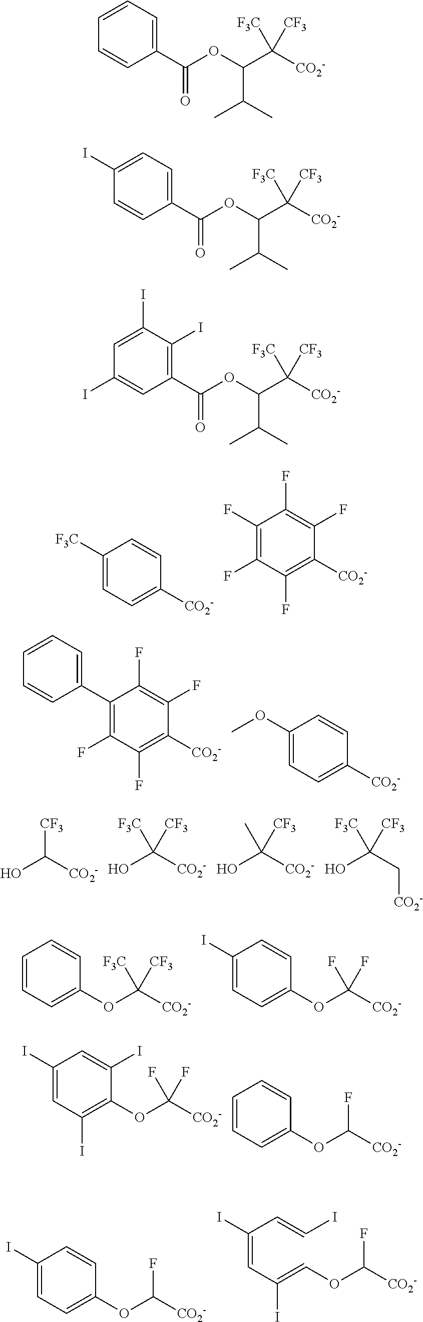

In the formulae (1) and (2), Mq⁺ represents an onium cation. The onium cation is preferably represented by the following formula (cation-1), (cation-2), or (cation-3).

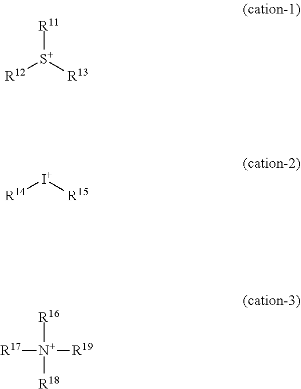

Examples of the cation represented by the formulae (cation-1) and (cation-2) include cations same as A⁺ in the formulae (B-2) to (B-4). In (cation-3), R¹⁶ to R¹⁹ each independently represent a hydrocarbyl group having 1 to 40 carbon atoms and optionally having a heteroatom. R¹⁶ and R¹⁷ are optionally bonded each other to form a ring together with the nitrogen atom to which R¹⁶ and R¹⁷ are bonded. Examples of the hydrocarbyl group include groups same as the group exemplified in the description of R¹¹ to R¹⁵ in the formulae (cation-1) and (cation-2).

In the onium cation represented by Mq⁺, examples of the ammonium cation represented by (cation-3) include the following cations, but the cation is not limited thereto.

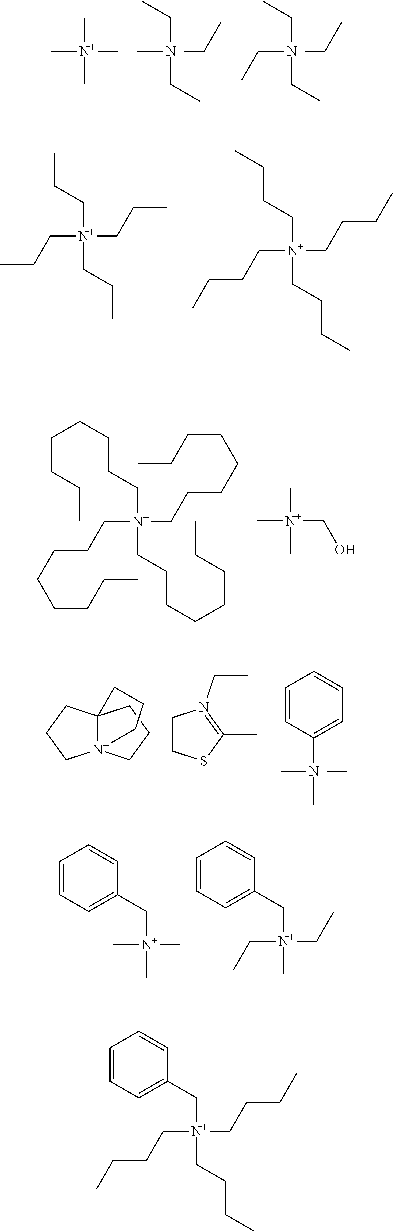

Specific examples of the onium salt represented by the formula (1) or (2) include any combination of the aforementioned anions and cations. These onium salts are easily prepared by an ion-exchange reaction using a known organic chemical method. About the ion-exchange reaction, JP 2007-145797 A can be referred, for example.

The onium salt represented by the formula (1) or (2) acts as a quencher in the inventive chemically amplified resist composition. This is because each counter anion of the onium salt is a conjugated base of a weak acid. The weak acid herein means an acid exhibit acidity that cannot deprotect the acid-labile group in the acid-labile group-containing unit used for the base polymer.

The onium salt represented by the formula (1) or (2) functions as a quencher when used in combination with an onium-salt type photoacid generator having a conjugated base of a strong acid, such as an α-fluorinated sulfonic acid, as a counter anion. That is, when an onium salt to generate a strong acid, such as an α-fluorinated sulfonic acid, and an onium salt to generate a weak acid, such as non-fluorinated sulfonic acid and a carboxylic acid, are mixed to be used, the strong acid generated from the photoacid generator by high-energy ray irradiation collides the unreacted onium salt having the weak acid anion to release the weak acid with salt exchange, resulting in generation of an onium salt having the strong acid anion. This process exchanges the strong acid into the weak acid having low catalytic ability, and the acid is apparently deactivated to enable to control the acid diffusion.

When the photoacid generator to generate the strong acid is an onium salt, the strong acid generated by high-energy ray irradiation can be exchanged into the weak acid, as described above. Meanwhile, it is considered that the weak acid generated by high-energy ray irradiation hardly collides the unreacted onium salt to generate the strong acid to cause salt exchange. This is because of a phenomenon that an onium cation is more likely to form an ion pair with an anion of a stronger acid.

When the onium salt represented by the formula (1) or (2) is contained as (G) the onium-salt type quencher, the content thereof is preferably 0.1 to 20 parts by mass, and more preferably 0.1 to 10 parts by mass, relative to 80 parts by mass of (P) the base polymer. The onium-salt type quencher of the component (G) within the above range is preferable in terms of the good resolution without considerable deterioration of the sensitivity. The onium salt represented by the formula (1) or (2) can be used alone, or used in combination of two or more kinds thereof.

### [(H) Organic Solvent]

The organic solvent of the component (H) is not particularly limited as long as it can dissolve each component described above and each component described later. Examples of such an organic solvent include: ketones, such as cyclopentanone, cyclohexanone, and methyl-2-n-pentyl ketone; alcohols, such as 3-methoxybutanol, 3-methyl-3-methoxybutanol, 1-methoxy-2-propanol, and 1-ethoxy-2-propanol; keto alcohols, such as DAA; ethers, such as PGME, ethylene glycol monomethyl ether, propylene glycol monoethyl ether, ethylene glycol monoethyl ether, propylene glycol dimethyl ether, and diethylene glycol dimethyl ether; esters, such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as GBL; and a mixed solvent thereof.

When the polymer having an acetal-based acid-labile group is used, an alcoholic solvent having a high boiling point can be added to accelerate the deprotection reaction of the acetal. Specific examples of such an alcoholic solvent having a high boiling point include diethylene glycol, propylene glycol, glycerin, 1,4-butanediol, and 1,3-butanediol.

Among these organic solvents, 1-ethoxy-2-propanol, PGMEA, cyclohexanone, GBL, DAA, ethyl lactate, and a mixed solvent thereof, which have particularly excellent solubility to the base polymer of the component (P), are preferable.

A used amount of the organic solvent is preferably 200 to 5,000 parts by mass, and more preferably 400 to 3,000 parts by mass, relative to 80 parts by mass of (P) the base polymer. (H) the organic solvent can be used alone, or two or more kinds thereof can be mixed to use.

[(I) Photoacid Generator other than Photoacid Generator Bonded to Base Polymer Chain]

The inventive chemically amplified resist composition may comprise a photoacid generator, as a component (I), other than the photoacid generator bonded to the base polymer chain. The photoacid generator is not particularly limited as long as it is a compound to generate an acid by high-energy ray irradiation. Examples of preferable photoacid generators include compounds represented by the following formula (3).

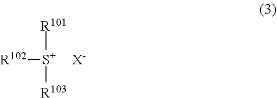

In the formula (3), R¹⁰¹, R¹⁰², and R¹⁰³ each independently represent a hydrocarbyl group having 1 to 20 carbon atoms and optionally having a heteroatom. Any two of R¹⁰¹, R¹⁰², and R¹⁰³ are optionally bonded each other to form a ring together with the sulfur atom to which R¹⁰¹, R¹⁰², and R¹⁰³ are bonded. The hydrocarbyl group may be a saturated or unsaturated group, and may be any of linear, branched, and cyclic groups. Specific examples thereof include groups same as the groups exemplified in the description of R¹¹ to R¹⁵ in the formulae (cation-1) and (cation-2). Specific examples of the cation of the sulfonium salt represented by the formula (3) include cations same as the cations exemplified as the specific examples of the sulfonium cation represented by the formula (cation-1).

In the formula (3), X⁻ represents an anion selected from the following formulae (3A) to (3D).

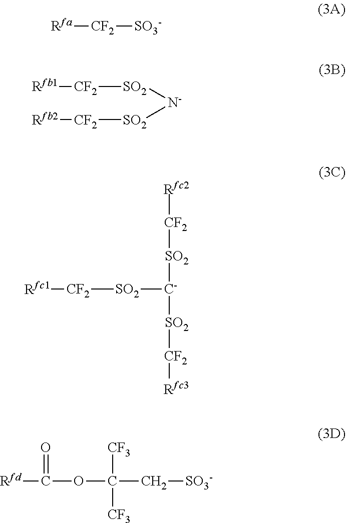

In the formula (3A), R^{fa} represents a fluorine atom or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as groups described in the description of R¹⁰⁵ in the formula (3A′), described later.

The anion represented by the formula (3A) is preferably represented by the formula (3A′).

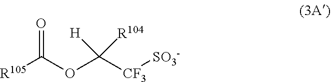

In the formula (3A′), R¹⁰⁴ represents a hydrogen atom or a trifluoromethyl group, and preferably a trifluoromethyl group. R¹⁰⁵ represents a hydrocarbyl group having 1 to 38 carbon atoms and optionally having a heteroatom. The heteroatom is preferably an oxygen atom, a nitrogen atom, a sulfur atom, a halogen atom, etc., and more preferably an oxygen atom. The hydrocarbyl group particularly preferably has 6 to 30 carbon atoms in terms of obtaining high resolution in the fine pattern formation.

The hydrocarbyl group represented by R¹⁰⁵ may be a saturated or unsaturated group, and may be any of linear, branched, and cyclic groups. Specific examples thereof include: alkyl groups, such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups, such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclodecanyl group, a tetracyclododecanylmethyl group, and a dicyclohexylmethyl group; unsaturated aliphatic hydrocarbyl groups, such as an allyl group and a 3-cyclohexenyl group; aryl groups, such as a phenyl group, a 1-naphthyl group, and a 2-naphthyl group; and aralkyl groups, such as a benzyl group and a diphenylmethyl group. Among these, aliphatic groups are preferable as R¹⁰⁵. A part or all of hydrogen atoms in these groups are optionally substituted with a group having a heteroatom, such as an oxygen atom, a sulfur atom, a nitrogen atom, and a halogen atom. A part of carbon atoms in these groups is optionally substituted with a group having a heteroatom, such as an oxygen atom, a sulfur atom, and a nitrogen atom. As a result, a hydroxy group, a cyano group, a carbonyl group, an ether bond, an ester bond, a sulfonic acid ester bond, a carbonate group, a lactone ring, a sultone ring, a carboxylic anhydride, a haloalkyl group, etc. are optionally contained. Examples of the hydrocarbyl groups having a heteroatom include a tetrahydrofuryl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and 3-oxocyclohexyl group.

Synthesis of the sulfonium salt having the anion represented by the formula (3A′) is described in detail in JP 2007-145797 A, JP 2008-106045 A, JP 2009-7327 A, and JP 2009-258695 A. Sulfonium salts described in JP 2010-215608 A, JP 2012-41320 A, JP 2012-106986 A, and JP 2012-153644 A are also preferably used.

Examples of the anion represented by the formula (3A) include anions same as the anions described in M⁻ in the formula (B-1), but the anion is not limited thereto.

In the formula (3B), R^{fb1} and R^{fb2} each independently represent a fluorine atom or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as the groups exemplified in the description of R¹⁰⁵ in the formula (3A′). R^{fb1} and R^{fb2} are preferably a fluorine atom or a linear fluorinated alkyl group having 1 to 4 carbon atoms. R^{fb1} and R^{fb2} are optionally bonded each other to form a ring together with the group to which R^{fb1} and R^{fb2} are bonded (—CF₂—SO₂—N⁻—SO₂—CF₂—), and the group obtained by bonding R^{fb1} and R^{fb2} each other is preferably a fluorinated ethylene group or a fluorinated propylene group.

In the formula (3C), R^{fc1}, R^{fc2}, and R^{fc3} each independently represent a fluorine atom or a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as the groups exemplified in the description of R¹⁰⁵ in the formula (3A′). R^{fc1}, R^{fc2}, and R^{fc3} are preferably a fluorine atom or a linear fluorinated alkyl group having 1 to 4 carbon atoms. R^{fc1} and R^{fc2} are optionally bonded each other to form a ring together with the group to which R^{fc1} and R^{fc2} are bonded (—CF₂—SO₂—C⁻—SO₂—CF₂—), and the group obtained by bonding R^{fc1} and R^{fc2} each other is preferably a fluorinated ethylene group or a fluorinated propylene group.

In the formula (3D), R^{fd} represents a hydrocarbyl group having 1 to 40 carbon atoms and optionally having a heteroatom. The hydrocarbyl group may be a saturated or unsaturated group, and may be any of linear, branched, and cyclic groups. Specific examples thereof include groups same as the groups exemplified in the description of R¹⁰⁵ in the formula (3A′).

Synthesis of the sulfonium salt having the anion represented by the formula (3D) is described in detail in JP 2010-215608 A and JP 2014-133723 A.

Examples of the anion represented by the formula (3D) include the following anions, but the anion is not limited thereto.

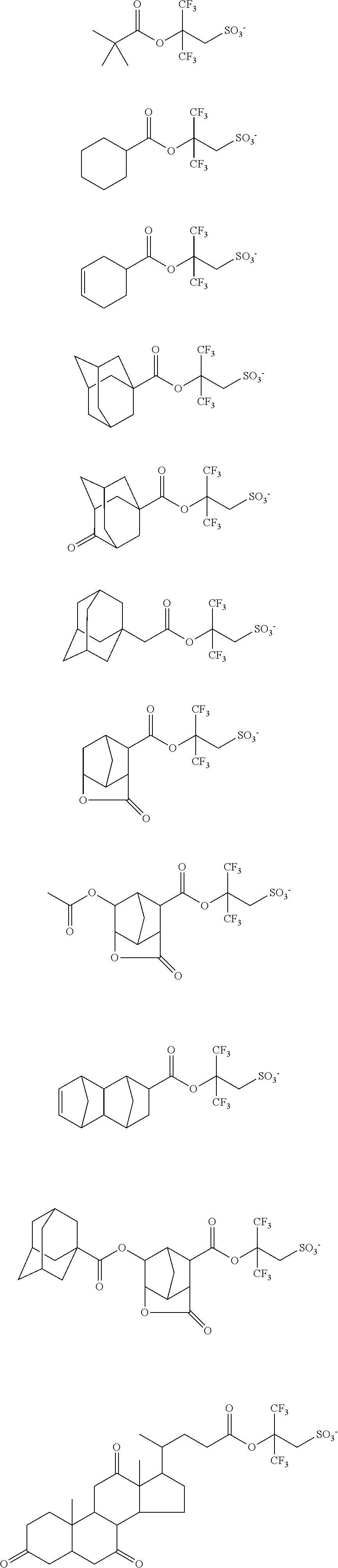

Although having no fluorine atom at the α-position of the sulfo group, the photoacid generator having the anion represented by the formula (3D) has sufficient acidity for cleaving the acid-labile group in the base polymer because the anion has two trifluoromethyl groups at the β-position. Thus, it can be used as a photoacid generator.

The photoacid generator other than the photoacid generator bonded to the base polymer chain of the component (I) is also preferably photoacid generators represented by the following formula (4).

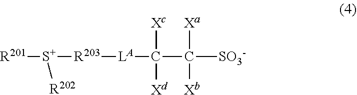

In the formula (4), R²⁰¹ and R²⁰² each independently represent a hydrocarbyl group having 1 to 30 carbon atoms and optionally having a heteroatom. R²⁰³ represents a hydrocarbylene group having 1 to 30 carbon atoms and optionally having a heteroatom. Any two of R²⁰¹, R²⁰², and R²⁰³ are optionally bonded each other to form a ring together with the sulfur atom to which R²⁰¹, R²⁰², and R²⁰³ are bonded. Examples of the ring include rings same as the rings exemplified as the ring that can be formed by bonding R²¹ and R²² each other together with the sulfur atom to which R²¹ and R²² are bonded in the description of the formula (B-1).

The hydrocarbyl group represented by R²⁰¹ and R²⁰² may be a saturated or unsaturated group, and may be any of linear, branched, and cyclic groups. Specific examples thereof include: alkyl groups, such as a methyl group, an ethyl group, a propyl group, an isopropyl group, an n-butyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; and aryl groups, such as a phenyl group, a naphthyl group, and an anthracenyl group. A part of hydrogen atoms in these groups is optionally substituted with a group having a heteroatom, such as an oxygen atom, a sulfur atom, a nitrogen atom, and a halogen atom. A part of carbon atoms in these groups is optionally substituted with a group having a heteroatom, such as an oxygen atom, a sulfur atom, and a nitrogen atom. As a result, a hydroxy group, a cyano group, a carbonyl group, an ether bond, an ester bond, a sulfonic acid ester bond, a carbonate group, a lactone ring, a sultone ring, a carboxylic anhydride, a haloalkyl group, etc. are optionally contained.

The hydrocarbylene group represented by R²⁰³ may be a saturated or unsaturated group, and may be any of linear, branched, and cyclic groups. Specific examples thereof include: alkanediyl groups, such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; cyclic saturated hydrocarbylene groups, such as a cyclopentanediyl group, a cyclohexanediyl group, a norbornanediyl group, and an adamantanediyl group; and arylene groups, such as a phenylene group, a methylphenylene group, an ethylphenylene group, an n-propylphenylene group, an isopropylphenylene group, an n-butylphenylene group, an isobutylphenylene group, a sec-butylphenylene group, a tert-butylphenylene group, a naphthylene group, a methylnaphthylene group, an ethylnaphthylene group, an n-propylnaphthylene group, an isopropylnaphthylene group, an n-butylnaphthylene group, an isobutylnaphthylene group, a sec-butylnaphthylene group, and a tert-butylnaphthylene group. A part of hydrogen atoms in these groups is optionally substituted with a group having a heteroatom, such as an oxygen atom, a sulfur atom, a nitrogen atom, and a halogen atom. A part of carbon atoms in these groups is optionally substituted with a group having a heteroatom, such as an oxygen atom, a sulfur atom, and a nitrogen atom. As a result, a hydroxy group, a cyano group, a carbonyl group, an ether bond, an ester bond, a sulfonic acid ester bond, a carbonate group, a lactone ring, a sultone ring, a carboxylic anhydride, a haloalkyl group, etc. are optionally contained. The heteroatom is preferably an oxygen atom.

In the formula (4), L^{A} represents a single bond, an ether bond, or a hydrocarbylene group having 1 to 20 carbon atoms and optionally having a heteroatom. The hydrocarbylene group may be a saturated or unsaturated group, and may be any of linear, branched, and cyclic groups. Specific examples thereof include groups same as the groups exemplified as the hydrocarbylene group represented by R²⁰³.

In the formula (4), X^{a}, X^{b}, X^{c}, and X^{d} each independently represent a hydrogen atom, a fluorine atom, or a trifluoromethyl group. At least one of X^{a}, X^{b}, X^{c}, and X^{d} represents a fluorine atom or a trifluoromethyl group.

The photoacid generator represented by the formula (4) is preferably photoacid generators represented by the following formula (4′).

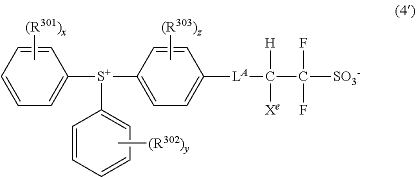

In the formula (4′), L^{A} is same as above. X^{e} represents a hydrogen atom or a trifluoromethyl group, and preferably represents a trifluoromethyl group. R³⁰¹, R³⁰², and R³⁰³ each independently represent a hydrogen atom or a hydrocarbyl group having 1 to 20 carbon atoms and optionally having a heteroatom. The hydrocarbyl group may be a saturated or unsaturated group, and may be any of linear, branched, and cyclic groups. Specific examples thereof include groups same as the groups exemplified in the description of R¹⁰⁵ in the formula (3A′). “x” and “y” each independently represent an integer of 0 to 5. “z” represents an integer of 0 to 4.

Examples of the photoacid generator represented by the formula (4) include photoacid generators same as the photoacid generators exemplified as the photoacid generators represented by the formula (4) in JP 2017-026980 A.

Among the above other photoacid generators, the photoacid generators having the anion represented by the formula (3A′) or (3D) are particularly preferable since having small acid diffusion and excellent solubility in the resist solvent. The photoacid generators having the anion represented by the formula (4′) is particularly preferable since having extremely small acid diffusion.

As the other acid generators, onium salts represented by the following formula (5-1) or (5-2) can also be used.

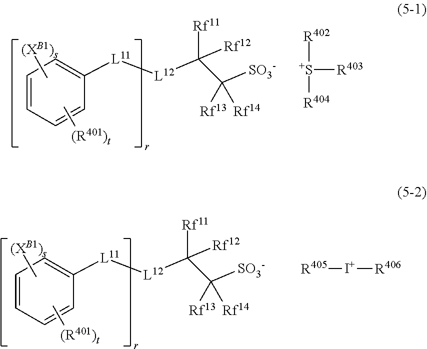

In the formulae (5-1) and (5-2), “r” represents an integer satisfying 1≤r≤3. “s” and “t” represent integers satisfying 1≤s≤5, 0≤t≤3, and 1≤s+t≤5. “s” preferably represents an integer satisfying 1≤s≤3, and more preferably represents 2 or 3. “t” preferably represents an integer satisfying 0≤t≤2.

In the formulae (5-1) and (5-2), X^{BI} represents an iodine atom or a bromine atom. When “s” represents 2 or more, X^{BI} may be same as or different from each other.

In the formulae (5-1) and (5-2), L¹¹ represents a single bond, an ether bond, an ester bond, or a saturated hydrocarbylene group having 1 to 6 carbon atoms and optionally having an ether bond or an ester bond. The saturated hydrocarbylene group may be any of linear, branched, and cyclic groups.

In the formulae (5-1) and (5-2), L¹² represents a single bond or a divalent linkage group having 1 to 20 carbon atoms when “r” represents 1, and L¹² represents a trivalent or tetravalent linkage group having 1 to 20 carbon atoms when “r” represents 2 or 3. The linkage group optionally has an oxygen atom, a sulfur atom, or a nitrogen atom.

In the formulae (5-1) and (5-2), R⁴⁰¹ represents a hydroxy group, a carboxy group, a fluorine atom, a chlorine atom, a bromine atom, an amino group, a saturated hydrocarbyl group having 1 to 20 carbon atoms, a saturated hydrocarbyloxy group having 1 to 20 carbon atoms, a saturated hydrocarbyloxycarbonyl group having 2 to 10 carbon atoms, a saturated hydrocarbylcarbonyloxy group having 2 to 20 carbon atoms, a saturated hydrocarbylsulfonyloxy group having 1 to 20 carbon atoms, —NR^{401A}—C(═O)—R^{401B}, or —NR^{401A}—C(═O)—O—R^{401B}. The saturated hydrocarbyl group, the saturated hydrocarbyloxy group, the saturated hydrocarbyloxycarbonyl group, the saturated hydrocarbylcarbonyloxy group, and the saturated hydrocarbylsulfonyloxy group optionally have a fluorine atom, a chlorine atom, a bromine atom, a hydroxy group, an amino group, or an ether bond.

R^{401A} represents a hydrogen atom or a saturated hydrocarbyl group having 1 to 6 carbon atoms. R^{401A} optionally has a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms.

R^{401B} represents an aliphatic hydrocarbyl group having 1 to 16 carbon atoms or an aryl group having 6 to 12 carbon atoms. R^{401B} optionally has a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms.

The aliphatic hydrocarbyl group may be a saturated or unsaturated group, and may be any of linear, branched, and cyclic groups. The saturated hydrocarbyl group, the saturated hydrocarbyloxy group, the saturated hydrocarbyloxycarbonyl group, the saturated hydrocarbylcarbonyl group, and the saturated hydrocarbylcarbonyloxy group may be any of linear, branched, and cyclic groups.

When “t” represents 2 or more, each R⁴⁰¹ may be same as or different from each other.

Among these, R⁴⁰¹ preferably represents a hydroxy group, —NR^{401A}—C(═O)—R^{401B}, —NR^{401A}—C(═O)—O—^{R401B}, a fluorine atom, a chlorine atom, a bromine atom, a methyl group, a methoxy group, etc.

In the formulae (5-1) and (5-2), R^{f11} to R^{f14} each independently represent a hydrogen atom, a fluorine atom, or a trifluoromethyl group, and at least one of them represents a fluorine atom or a trifluoromethyl group. R^{f11} and R^{f12} are optionally combined to form a carbonyl group. Both R^{f13} and R^{f14} particularly preferably represent fluorine atoms.

In the formulae (5-1) and (5-2), R⁴⁰², R⁴⁰³, R⁴⁰⁴, R⁴⁰⁵, and R⁴⁰⁶ each independently represent a hydrocarbyl group having 1 to 20 carbon atoms and optionally having a heteroatom. The hydrocarbyl group may be a saturated or unsaturated group, and may be any of linear, branched, and cyclic groups. Specific examples thereof include alkyl groups having 1 to 20 carbon atoms, cycloalkyl groups having 3 to 20 carbon atoms, alkenyl groups having 2 to 12 carbon atoms, alkynyl groups having 2 to 12 carbon atoms, aryl groups having 6 to 20 carbon atoms, and aralkyl groups having 7 to 12 carbon atoms.

A part or all of hydrogen atoms in these groups are optionally substituted with a hydroxy group, a carboxy group, a halogen atom, a cyano group, a nitro group, a mercapto group, a sultone group, a sulfone group, or a sulfonium salt-containing group. A part of carbon atoms in these groups is optionally substituted with an ether bond, an ester bond, a carbonyl group, an amide bond, a carbonate group, or a sulfonic acid ester bond.

Any two of R⁴⁰², R⁴⁰³, and R⁴⁰⁴ are optionally bonded each other to form a ring together with the sulfur atom to which R⁴⁰², R⁴⁰³, and R⁴⁰⁴ are bonded. Examples of the ring include rings same as the rings exemplified as the ring that can be formed by bonding R¹⁰¹ and R¹⁰² each other together with the sulfur atom to which R²¹ and R²² are bonded in the description of the formula (3).

Examples of the cation of the sulfonium salt represented by the formula (5-1) include cations same as the cations exemplified as the sulfonium cation represented by the formula (cation-1). Examples of the cation of the iodonium salt represented by the formula (5-2) include cations same as the cations exemplified as the iodonium cation represented by the formula (cation-2).

Examples of the anion of the onium salt represented by the formulae (5-1) and (5-2) include anions exemplified as the anion of the onium salt represented by the formulae (5-1) and (5-2) in JP 2018-197853 A, and in addition, anions in which the iodine atom in the anion is substituted with a bromine atom.

When the photoacid generator other than the photoacid generator bonded to the base polymer chain of the component (I) is contained, the content thereof is preferably 0.1 to 40 parts by mass, and more preferably 0.5 to 20 parts by mass, relative to 80 parts by mass of (P) the base polymer. The addition amount of the photoacid generator other than the photoacid generator bonded to the base polymer chain of the component (I) within the above range is preferable because of good resolution and no risk of generation of a foreign matter problem after the development or during the removal of the resist film. The photoacid generator other than the photoacid generator bonded to the base polymer chain of the component (I) may be used alone, or may be used in combination of two or more kinds thereof.

### [(J) Nitrogen-Containing Quencher]

The inventive chemically amplified resist composition may further comprise a nitrogen-containing quencher. In the present invention, the nitrogen-containing quencher is referred to a material that traps the acid generated from the photoacid generator in the chemically amplified resist composition for inhibiting the diffusion toward an unexposed portion to form a desired pattern.

Examples of the nitrogen-containing quencher of the component (J) include primary, secondary, or tertiary amine compounds described in paragraphs [0146] to [0164] of JP 2008-111103 A, in particular, amine compounds having a hydroxy group, an ether bond, an ester bond, a lactone ring, a cyano group, or a sulfonic acid ester bond. Examples thereof also include compounds in which a primary or secondary amine is protected with a carbamate group, as compounds described in JP 3790649 B.

As the nitrogen-containing quencher, a sulfonium sulfonate salt having a nitrogen-containing group may also be used. Such a compound functions as a so-called photodegradable base, which functions as a quencher in an unexposed portion, and losses the quenching ability by neutralization with a generated acid of the photodegradable base itself in an exposed portion. Using the photodegradable base can further enhance the contrast between the exposed portion and the unexposed portion. As the photodegradable base, JP 2009-109595 A and JP 2012-46501 A can be referred, for example.

When the nitrogen-containing quencher of the component (J) is contained, the content thereof is preferably 0.001 to 12 parts by mass, and more preferably 0.01 to 8 parts by mass, relative to 80 parts by mass of (P) the base polymer. The nitrogen-containing compound may be used alone, or may be used in combination of two or more kinds thereof.

[(K) Surfactant Insoluble or Hardly Soluble in Water and Soluble in Alkaline Developing Liquid; and/or Surfactant Insoluble or Hardly Soluble in Water and Alkaline Developing Liquid]

The inventive chemically amplified resist composition may further comprise (K) a surfactant insoluble or hardly soluble in water and soluble in an alkaline developing liquid; and/or a surfactant insoluble or hardly soluble in water and an alkaline developing liquid. As such a surfactant, surfactants described in JP 2010-215608 A and JP 2011-16746 A can be referred.

Among the surfactants described in the above patent documents, the surfactant insoluble or hardly soluble in water and an alkaline developing liquid is preferably FC-4430 (manufactured by 3M Company), SURFLON®S-381 (manufactured by AGC Seimi Chemical Co., Ltd.), OLFIN® E1004 (manufactured by Nissin Chemical Industry Co., Ltd.), KH-20 and KH-30 (manufactured by AGC Seimi Chemical Co., Ltd.), and oxetane ring-opening polymerized product represented by the following formula (surf-1).

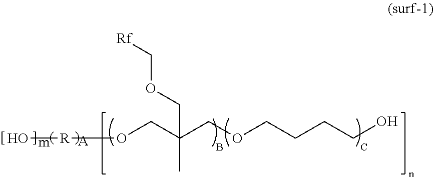

Here, R, Rf, A, B, C, “m”, and “n” in the formula (surf-1) are applied only in the formula (surf-1) regardless of the above description. R represents a divalent to tetravalent aliphatic group having 2 to 6 carbon atoms. Examples of the divalent aliphatic group include an ethylene group, a 1,4-butylene group, a 1,2-propylene group, a 2,2-dimethyl-1,3-propylene group, and a 1,5-pentylene group. Examples of the trivalent or tetravalent aliphatic group include the following groups.

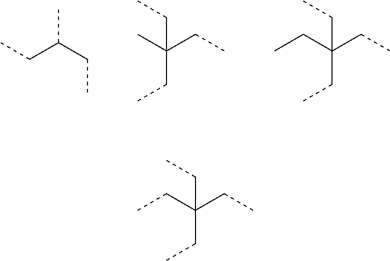

In the formula, a broken line represents a bond. The groups are partial structures derived from glycerol, trimethylolethane, trimethylolpropane, and pentaerythritol, respectively.

Among these, a 1,4-butylene group and a 2,2-dimethyl-1,3-propylene group are preferable.

Rf represents a trifluoromethyl group or a pentafluoroethyl group, and preferably represents a trifluoromethyl group. “m” represents an integer of 0 to 3. “n” represents an integer of 1 to 4. The sum of “n” and “m”, which represents a valency of R, represents an integer of 2 to 4. “A” represents 1. “B” represents an integer of 2 to 25, and preferably represents an integer of 4 to 20. “C” represents an integer of 0 to 10, and preferably represents 0 or 1. As for each constituting unit in the formula (surf-1), the order is not stipulated, and may be block-bonded or random-bonded. Production of the surfactant of the partially fluorinated oxetane ring-opening polymerized product is described in detail in U.S. Pat. No. 5,650,483 B.

In the ArF immersion exposure without a resist protective film, the surfactant insoluble or hardly soluble in water and soluble in an alkaline developing liquid has a function of reducing penetration of water or leaching by segregating at the surface of the resist film. Thus, such a surfactant is useful for inhibiting elution of a water-soluble component from the resist film to reduce damage of an exposure apparatus. Such a surfactant is also useful because such a surfactant becomes soluble during development with an alkaline aqueous solution after the exposure or after the PEB, and hardly forms a foreign matter causing a defect. Such a surfactant, which has a property of being insoluble or hardly soluble in water and soluble in an alkaline developing liquid, is preferably a polymer surfactant, which is also referred to as a hydrophobic resin. In particular, such a surfactant preferably has high water repellency and improves water-slipping property.

Examples of such a polymer surfactant include a polymer having at least one selected from repeating units represented by the following formulae (6A) to (6E).

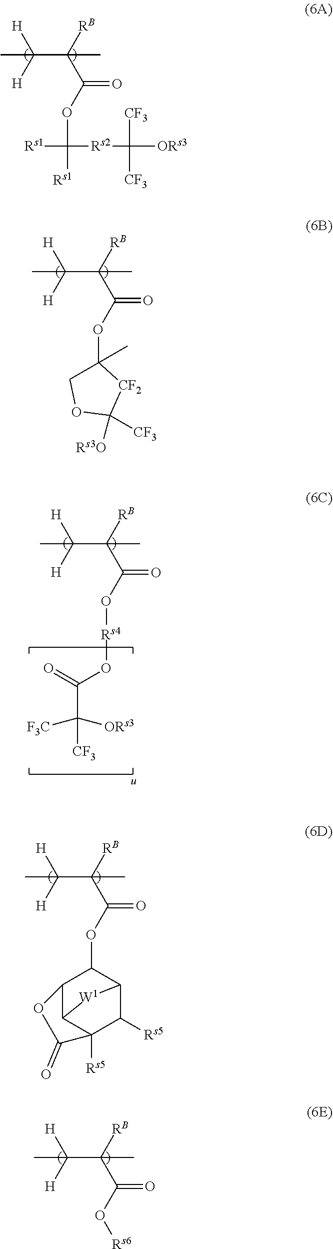

In the formulae (6A) to (6E), R^{B} represents a hydrogen atom, a fluorine atom, a methyl group, or a trifluoromethyl group. W¹ represents —CH₂—, —CH₂CH₂—, —O—, or two “—H”s which are separated to each other. R^{s1} each independently represents a hydrogen atom or a hydrocarbyl group having 1 to 10 carbon atoms. R^{s2} represents a single bond or a linear or branched hydrocarbylene group having 1 to 5 carbon atoms. R^{s3} each independently represents a hydrogen atom, a hydrocarbyl group or fluorinated hydrocarbyl group having 1 to 15 carbon atoms, or an acid-labile group. When R^{s3} represents a hydrocarbyl group or a fluorinated hydrocarbyl group, an ether bond (—O—) or a carbonyl group (—C(═O)—) is optionally interposed between a carbon-carbon bond. R^{s4} represents a (u+1)-valent hydrocarbon group or fluorinated hydrocarbon group having 1 to 20 carbon atoms. “u” represents an integer of 1 to 3. R^{s5} each independently represents a hydrogen atom or a group represented by —C(═O)—O—R^{sa}. R^{sa} represents a fluorinated hydrocarbyl group having 1 to 20 carbon atoms. R^{s6} represents a hydrocarbyl group or fluorinated hydrocarbyl group having 1 to 15 carbon atoms, and an ether bond (—O—) or a carbonyl group (—C(═O)—) is optionally interposed between a carbon-carbon bond.

The hydrocarbyl group represented by R^{s1} is preferably a saturated hydrocarbyl group, and may be any of linear, branched, and cyclic groups. Specific examples thereof include: alkyl groups, such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, and an n-decyl group; and cyclic saturated hydrocarbyl groups, such as a cyclopropyl group, a cyclobutyl group, a cyclopentyl group, a cyclohexyl group, an adamantyl group, and a norbornyl group. Among these, groups having 1 to 6 carbon atoms are preferable.

The hydrocarbylene group represented by R^{s2} is preferably a saturated hydrocarbylene group, and may be any of linear, branched, and cyclic groups. Specific examples thereof include a methylene group, an ethylene group, a propylene group, a butylene group, and a pentylene group.

The hydrocarbyl group represented by R^{s3} or R^{s6} may be a saturated or unsaturated group, and may be any of linear, branched, and cyclic groups. Specific examples thereof include: saturated hydrocarbyl groups; and aliphatic unsaturated hydrocarbyl groups, such as alkenyl groups and alkynyl groups, and saturated hydrocarbyl groups are preferable. Examples of the saturated hydrocarbyl group include the groups exemplified as the hydrocarbyl group represented by R^{s1}, and in addition, an n-undecyl group, an n-dodecyl group, a tridecyl group, a tetradecyl group, and a pentadecyl group. Examples of the fluorinated hydrocarbyl group represented by R^{s3} or R^{s6} include groups in which a part or all of hydrogen atoms bonded to a carbon atom in the above hydrocarbyl group is substituted with a fluorine atom. As described above, an ether bond (—O—) or a carbonyl group (—C(═O)—) is optionally interposed between a carbon-carbon bond thereof.

Examples of the acid-labile group represented by R^{s3} include: the groups represented by the aforementioned formulae (AL-1) to (AL-3); trialkylsilyl groups in which each alkyl group has 1 to 6 carbon atoms; and an oxo-group-containing alkyl groups having 4 to 20 carbon atoms.

The (u+1)-valent hydrocarbon group or fluorinated hydrocarbon group represented by R^{s4} may be any of linear, branched, and cyclic groups. Specific examples thereof include groups in which u hydrogen atoms are further removed from the above hydrocarbyl group, fluorinated hydrocarbyl group, etc.

The fluorinated hydrocarbyl group represented by R^{sa} is preferably a saturated group, and may be any of linear, branched, and cyclic groups. Specific examples thereof include groups in which a part or all of hydrogen atoms in the above hydrocarbyl group are substituted with a fluorine atom. Specific examples thereof include a trifluoromethyl group, a 2,2,2-trifluoroethyl group, a 3,3,3-trifluoro-1-propyl group, a 3,3,3-trifluoro-2-propyl group, a 2,2,3,3-tetrafluoropropyl group, a 1,1,1,3,3,3-hexafluoroisopropyl group, a 2,2,3,3,4,4,4-heptafluorobutyl group, a 2,2,3,3,4,4,5,5-octafluoropentyl group, a 2,2,3,3,4,4,5,5,6,6,7,7-dodecafluoroheptyl group, a 2-(perfluorobutyl)ethyl group, a 2-(perfluorohexyl)ethyl group, a 2-(perfluorooctyl)ethyl group, and a 2-(perfluorodecyl)ethyl group.

Examples of the repeating units represented by the formulae (6A) to (6E) include the following repeating units, but the repeating unit is not limited thereto. In the following formulae, R^{B} is same as above.

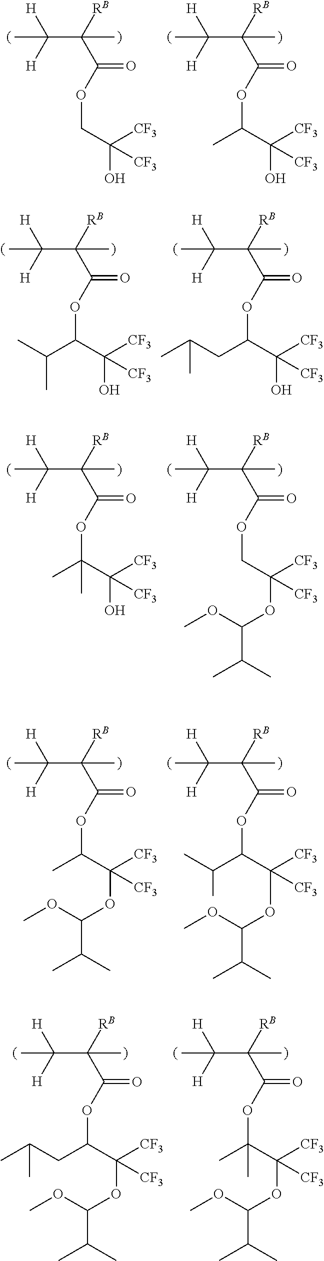

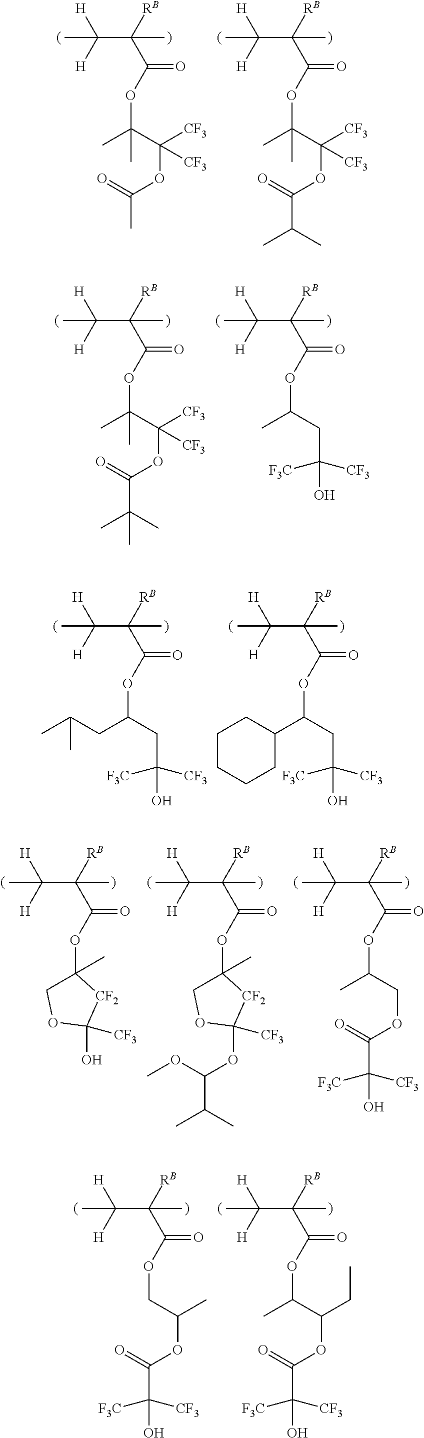

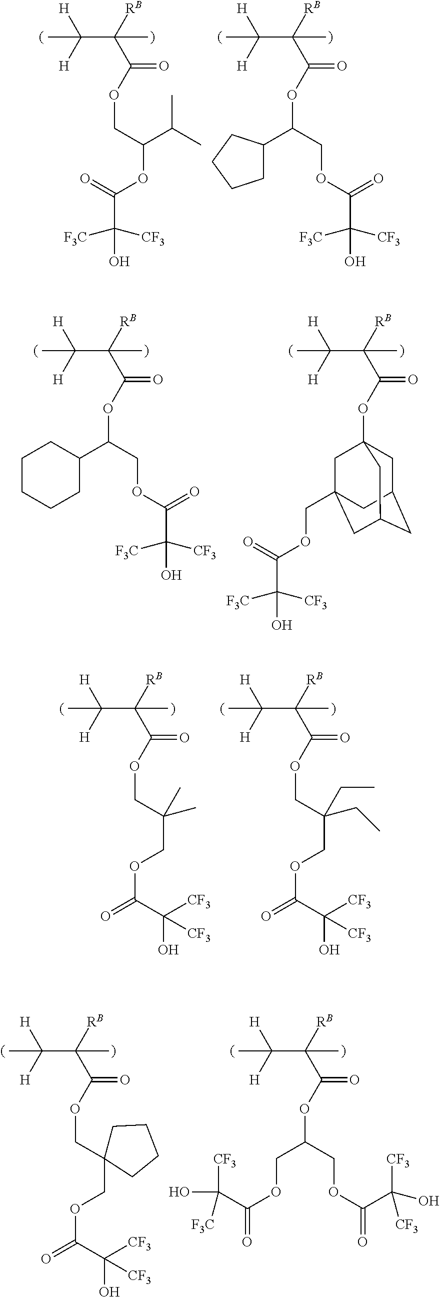

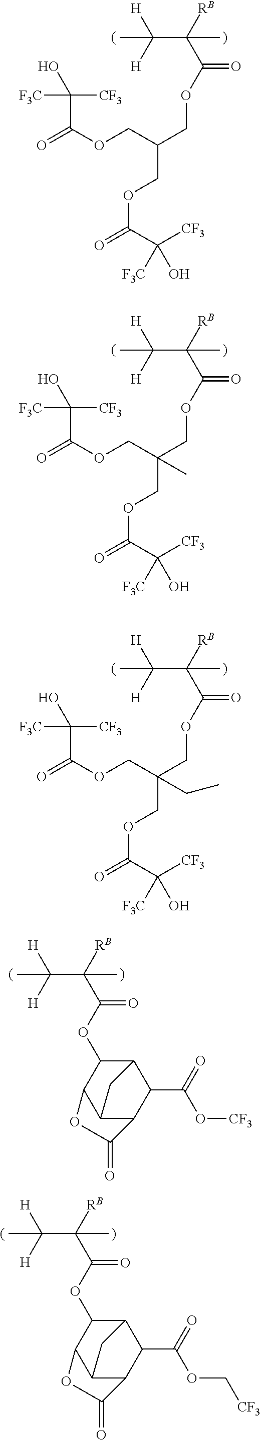

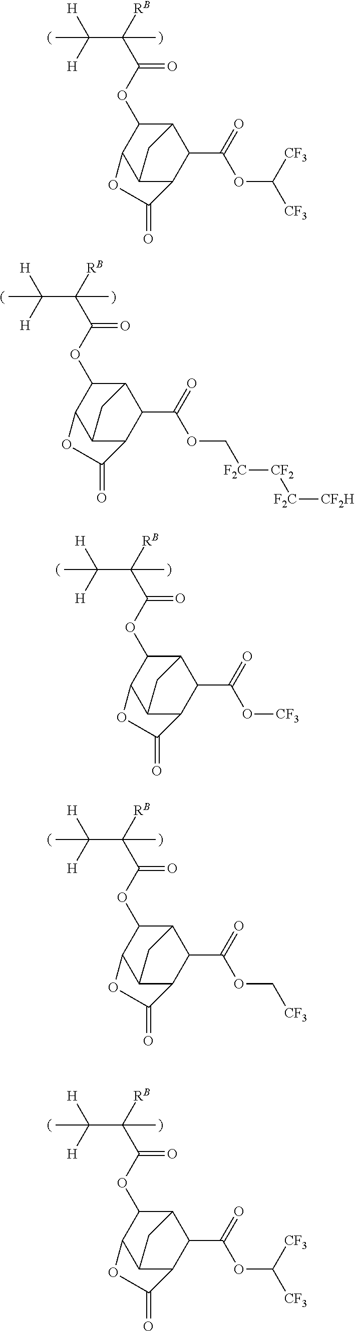

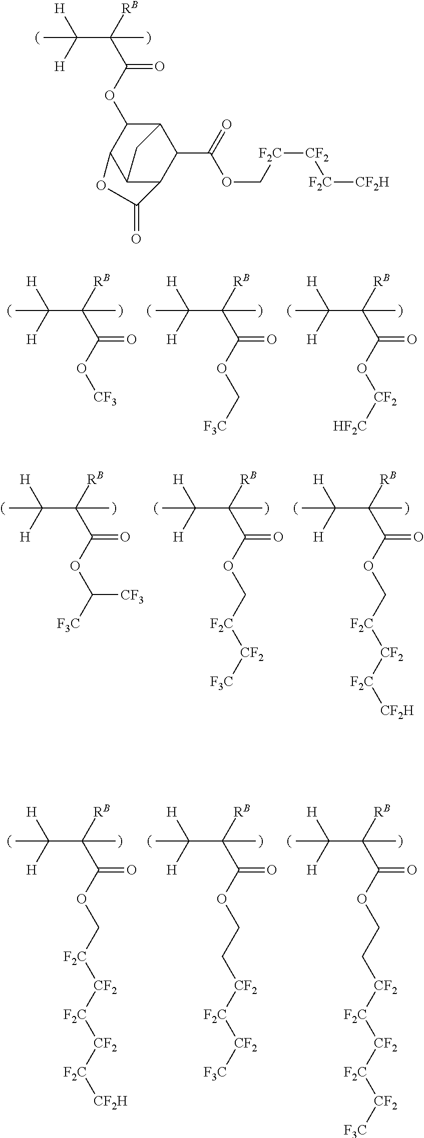

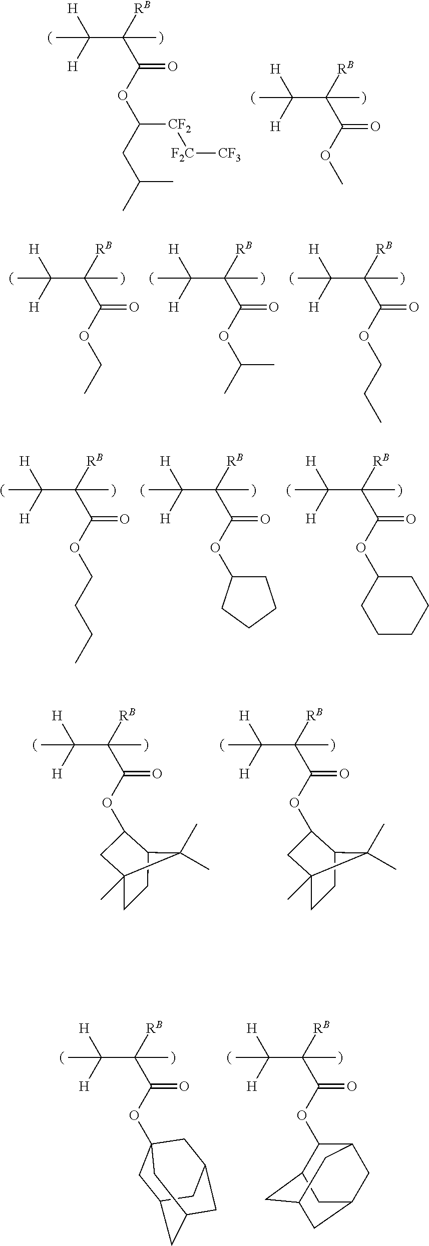

The polymer surfactant may further have a repeating unit other than the repeating unit represented by the formulae (6A) to (6E). Examples of the other repeating unit include repeating units obtained from methacrylic acid, an α-trifluoromethylacrylic acid derivative, etc. In the polymer surfactant, the content of the repeating units represented by the formulae (6A) to (6E) is preferably 20 mol % or more, more preferably 60 mol % or more, and further preferably 100 mol % in all the repeating units.

Mw of the polymer surfactant is preferably 1,000 to 500,000, and more preferably 3,000 to 100,000. Mw/Mn is preferably 1.0 to 2.0, and more preferably 1.0 to 1.6.

Examples of a method for synthesizing the polymer surfactant include a method in which, in an organic solvent, monomers having an unsaturated bond to yield the repeating unit represented by the formulae (6A) to (6E) and, as necessary, other repeating units are added with a radical initiator and heated to be polymerized. Examples of the organic solvent used in the polymerization include toluene, benzene, THF, diethyl ether, and dioxane. Examples of the polymerization initiator include AIBN, 2,2′-azobis(2,4-dimethylvaleronitrile), dimethyl 2,2-azobis(2-methylpropionate), benzoyl peroxide, and lauroyl peroxide. The reaction temperature is preferably 50 to 100° C. The reaction time is preferably 4 to 24 hours. The acid-labile group may be introduced into the monomer to be used as it is, or may be protected or partially protected after the polymerization.

When the polymer surfactant is synthesized, known chain transfer agents, such as dodecyl mercaptan and 2-mercaptoethanol may be used to regulate the molecular weight. In this case, the addition amount of these chain transfer agents is preferably 0.01 to 10 mol % relative to the total number of moles of the monomers to be polymerized.

When the surfactant of the component (K) is contained, the content thereof is preferably 0.1 to 50 parts by mass, and more preferably 0.5 to 10 parts by mass, relative to 80 parts by mass of (P) the base polymer. When the addition amount is 0.1 part by mass or more, a sweepback contact angle between the resist film surface and water is sufficiently improved. When the addition amount is 50 parts by mass or less, the resist film surface has a low dissolution rate in the developing liquid to sufficiently maintain the height of the formed fine pattern.

### [(L) Other Components]

The inventive chemically amplified resist composition may comprise: compounds to be decomposed by an acid to generate an acid (acid amplifying compounds); organic acid derivatives; fluorine-substituted alcohols; compounds to change in solubility in a developing liquid by an action of an acid, the compound having Mw of 3,000 or less (dissolution inhibitors); etc. as another component (L). As the acid amplifying compound, compounds described in JP 2009-269953 A or JP 2010-215608 A can be referred. When the acid amplifying compound is contained, the content thereof is preferably 0 to 5 parts by mass, and more preferably 0 to 3 parts by mass, relative to 80 parts by mass of (P) the base polymer. Within the above range, the diffusion is easily controlled, and there is no deterioration of resolution nor deterioration of the pattern shape. As the organic acid derivative, the fluorine-substituted alcohol, and the dissolution inhibitor, compounds described in JP 2009-269953 A or JP 2010-215608 A can be referred.

### [Pattern Forming Method]

The inventive pattern forming method comprises:

(i) a step of forming a resist film on a substrate using the resist composition comprising the above polymer;

(ii) a step of exposing the resist film with a high-energy ray; and

(iii) a step of developing the exposed resist film with a developing liquid.

As the substrate in the step (i), a substrate for producing an integrated circuit (such as Si, SiO₂, SiN, SiON, TiN, WSi, BPSG, SOG, and an organic anti-reflection film) or a substrate for producing a mask circuit (such as Cr, CrO, CrON, MoSi₂, and SiO₂) can be used, for example.

In the step (i), the resist film can be formed by, for example, applying the resist composition so as to have a film thickness of 0.05 to 2 μm by a method such as spin-coating, and prebaking this composition on a hot plate preferably at 60 to 150° C. for 1 to 10 minutes, more preferably at 80 to 140° C. for 1 to 5 minutes.

In the step (ii), examples of the high energy ray used for exposing the resist film include i-line, KrF excimer laser light, ArF excimer laser light, electron beam (EB), and extreme ultraviolet ray (EUV). Extreme ultraviolet ray having a wavelength of 3 to 15 nm may be used. When the KrF excimer laser light, the ArF excimer laser light, or EUV is used for the exposure, the light-exposure can be performed by using a mask for forming a target pattern, and irradiating such ray at an exposure dose of preferably 1 to 200 mJ/cm², more preferably 10 to 100 mJ/cm². When the EB is used, the light-exposure can be performed by irradiating the EB at an exposure dose of preferably 1 to 300 μC/cm², more preferably 10 to 200 μC/cm², directly or using a mask for forming a target pattern.

The light-exposure can be performed by a common light-exposure method, or can be performed by using an immersion method in which a liquid having an refractive index of 1.0 or more is interposed between a resist film and a projection lens. In this case, a protective film insoluble in water can be used.

The protective film insoluble in water, which is used for preventing an eluted material from the resist film and for improving water-slipping property on the film surface, roughly includes two types. One type is an organic-solvent removal type, and the other type is alkaline aqueous solution-soluble type. In the former type, the protective film is required to be removed by an organic solvent not dissolving the resist film before development with an alkaline aqueous solution. In the latter type, the protective film is soluble in an alkaline developing liquid and removed together with a soluble portion in the resist film. The latter protective film is particularly preferably a material containing a base polymer having a 1,1,1,3,3,3-hexafluoro-2-propanol residue group, which is insoluble in water and soluble in the alkaline developing liquid, and dissolved in a solvent. Examples of such a solvent include an alcoholic solvent having 4 or more carbon atoms, an ether solvent having 8 to 12 carbon atoms, and a mixed solvent thereof. The aforementioned surfactant insoluble in water and soluble in an alkaline developing liquid can be dissolved in the alcoholic solvent having 4 or more carbon atoms, the ether solvent having 8 to 12 carbon atoms, or the mixed solvent thereof to form the above material.

PEB may be performed after the light exposure. PEB can be performed by heating, for example, on a hot plate preferably at 60 to 150° C. for 1 to 5 minutes, more preferably 80 to 140° C. for 1 to 3 minutes.

In the step (iii), a positive-tone development method can be used. This method uses an alkaline aqueous solution as the developing liquid, and the exposed portion is dissolved and the unexposed portion is not dissolved to achieve the development. This method can yield a positive pattern.

In the step (iii), a developing liquid of an alkaline aqueous solution, such as tetramethylammonium hydroxide (TMAH) at preferably 0.1 to 5 mass %, more preferably 2 to 3 mass %, can be used as the developing liquid, for example. The development can be performed for preferably 0.1 to 3 minutes, more preferably 0.5 to 2 minutes, by a common method, such as a dip method, a puddle method, and a spray method, to form a target pattern on the substrate.

As a means for forming a pattern, after the resist film formation, the acid generator, etc. may be extracted from the film surface by performing a rinse with pure water (post soak), particles may be washed away, and rinsing (post soak) may be performed to remove water remained on the film after the exposure.

Furthermore, a pattern may be formed by a double-patterning method. Examples of the double-patterning method include: a trench method in which a first exposure and etching processes a foundation of 1:3 trenched pattern, and a position-shifted second exposure forms a 1:3 trenched pattern to form a 1:1 pattern; and a line method in which a first exposure and etching processes a first foundation of 1:3 isolated left pattern, and a position-shifted second exposure processes a second foundation in which a 1:3 isolated left pattern is formed under the first foundation to form a 1:1 pattern with a half pitch.

Alternatively, in the step (iii) of the inventive pattern forming method, a negative-tone development method can be used. This method uses an organic solvent as a developing liquid instead of the developing liquid of the alkaline aqueous solution, and the unexposed portion is dissolved to achieve the development. This method can yield a negative pattern.

As the developing liquid for this organic solvent development, 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, 2-phenylethyl acetate, etc. can be used. These organic solvents can be used alone, or two or more kinds thereof can be mixed to use.

### EXAMPLE

Hereinafter, the present invention will be specifically described with showing Synthesis Examples, Examples, and Comparative Examples, but the present invention is not limited to the following Examples. Used apparatuses were as follows.

IR: NICOLET 6700, manufactured by Thermo Fisher Scientific K.K.

¹H-NMR: ECA-500, manufactured by JEOL Ltd.

¹⁹F-NMR: ECA-500, manufactured by JEOL Ltd.

### [1] Synthesis of Monomer

### [Synthesis of Monomer A1]

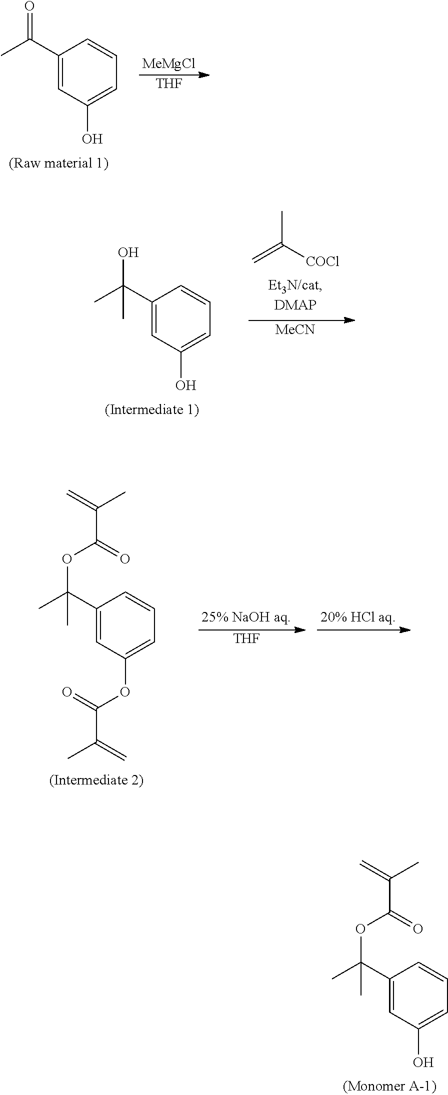

### (1) Synthesis of Intermediate 1

Under a nitrogen atmosphere, into a solution in which methylmagnesium chloride (800 ml, 3.0 M THF solution) was diluted with THF (800 ml), a solution composed of a raw material 1 (136.1 g) and THF (150 ml) was added dropwise with maintaining an internal temperature at 45° C. or lower. The mixture was stirred at an internal temperature of 50° C. for 2 hours. Then the reaction solution was cooled with ice, and a mixed aqueous solution of ammonium chloride (240 g) and 3.0 mass % aqueous hydrochloric acid (1200 g) was added dropwise to terminate the reaction. Ethyl acetate (1000 mL) was added, and a common aqueous work-up was performed. After the solvent was removed, a product was recrystallized with hexane to obtain 146.1 g of an intermediate 1 as a white crystal (96% yield).

### (2) Synthesis of Intermediate 2

Under a nitrogen atmosphere, into a solution of the intermediate 1 (146.1 g), triethylamine (272 g), dimethylaminopyridine (11.7 g), and acetonitrile (450 mL), methacrylyol chloride (240.8 g) was added dropwise with ice-bath cooling. After the dropwise addition, the internal temperature was raised to 50° C., and the reaction liquid was aged for 20 hours. The reaction liquid was cooled with ice, and a saturated aqueous sodium bicarbonate solution (300 mL) was added dropwise to terminate the reaction. A product was extracted with toluene (500 mL), a common aqueous work-up was performed, and after solvent removal, a product was purified by silica-gel column chromatography to obtain 257.4 g of an intermediate 2 as a colorless oil (93% yield).

### (3) Synthesis of Monomer A1

Under a nitrogen atmosphere, the intermediate 2 (257.4 g) was dissolved in THF (400 ml), and a 25 mass % aqueous sodium hydroxide solution (171.4 g) was added dropwise with ice-bath cooling. After the dropwise addition, the internal temperature was raised to 25° C., and the reaction liquid was aged for 15 hours. The reaction liquid was cooled with ice, and 20 mass % aqueous hydrochloric acid (244.1 g) was added dropwise to terminate the reaction. A product was extracted with toluene (500 mL), a common aqueous work-up was performed, and after solvent removal, a product was purified by silica-gel column chromatography to obtain 177 g of a monomer A1 as a colorless oil (90% yield).

IR spectrum data and results of 1H-NMR of the monomer A1 are described as follows.

IR (D-ATR): ν=3392, 2982, 2930, 1717, 1698, 1634, 1620, 1590, 1490, 1451, 1402, 1382, 1367, 1329, 1313, 1292, 1196, 1135, 1105, 1078, 1009, 941, 896, 867, 815, 784, 701, 652, 575, 475 cm⁻¹.

¹H-NMR (600 MHz in DMSO-d6): δ=9.34 (1H, s), 7.10 (1H, t), 6.74 (2H, m), 6.62 (1H, d), 6.02 (1H, d), 5.64 (1H, d), 1.85 (3H, s), 1.69 (6H, s) ppm.

### [Synthesis of Monomer A2]

A monomer A2 was obtained as a clear colorless oil (82% total yield) in the same synthesis manner as in (1) to (3) in Synthesis Example 1-1 except that a raw material 2 was used instead of the raw material 1.

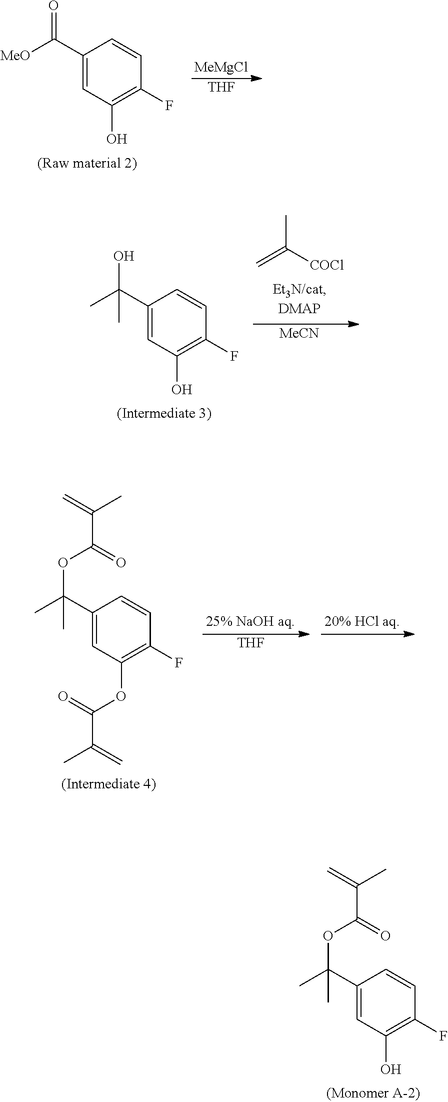

IR spectrum data and results of ¹H-NMR and ¹⁹F-NMR of the monomer A2 are described as follows.

IR (D-ATR): ν=3402, 2988, 2927, 1705, 1635, 1608, 1507, 1470, 1450, 1437, 1403, 1384, 1379, 1369, 1340, 1327, 1313, 1277, 1213, 1190, 1136, 1119, 1087, 1013, 970, 949, 920, 866, 835, 812, 772, 715, 661, 551 cm⁻¹.

¹H-NMR (600 MHz in DMSO-d6): δ=9.78 (1H, s), 7.05 (1H, dd), 6.93 (1H, dd), 6.74 (1H, m), 6.02 (1H, d), 5.65 (1H, d), 1.85 (3H, s), 1.68 (6H, s) ppm.

¹⁹F-NMR (600 MHz in DMSO-d6): δ=−140.41 (1F, m) ppm.

### [Syntheses of Monomers A3 to A10]

Monomers A3 to A10 were synthesized by using raw materials corresponding to the monomers A3 to A10.

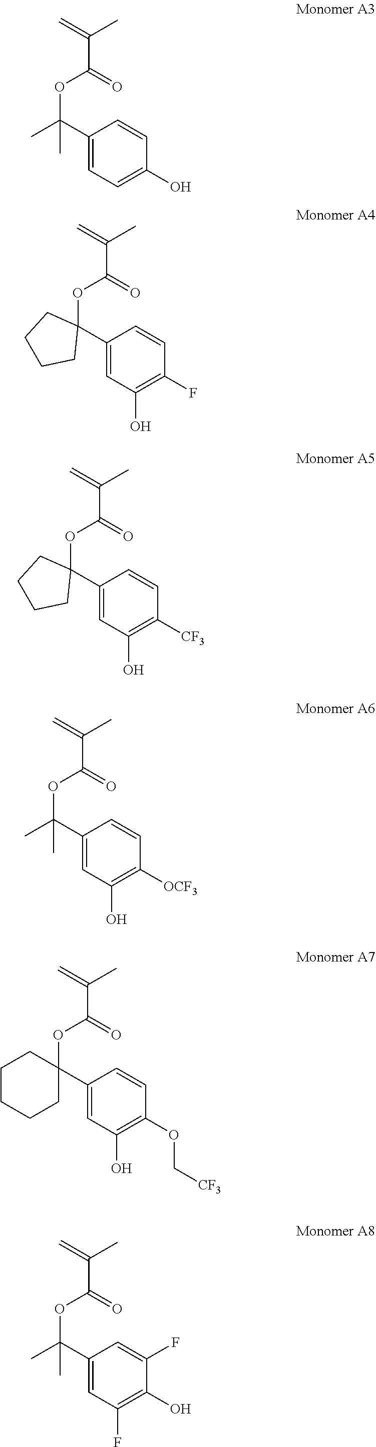

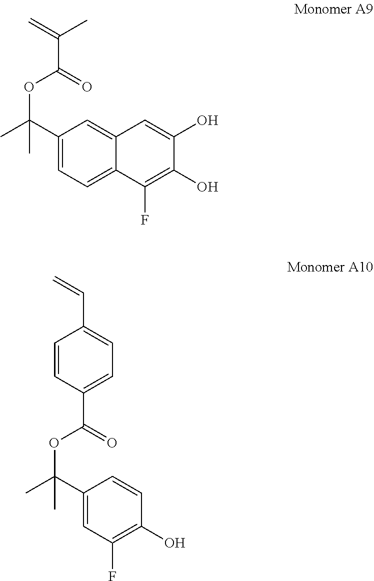 [SMILES: C=C(C)C(=O)OC(C)(C)c1ccc2c(F)c(O)c(O)cc2c1 ; C=Cc1ccc(C(=O)OC(C)(C)c2ccc(O)c(F)c2)cc1]

### [Syntheses of Comparative Monomers AX1 to AX8]

Comparative monomers AX1 to AX8 were synthesized as comparative monomers of the unit A by using raw materials corresponding to the monomers AX1 to AX8.

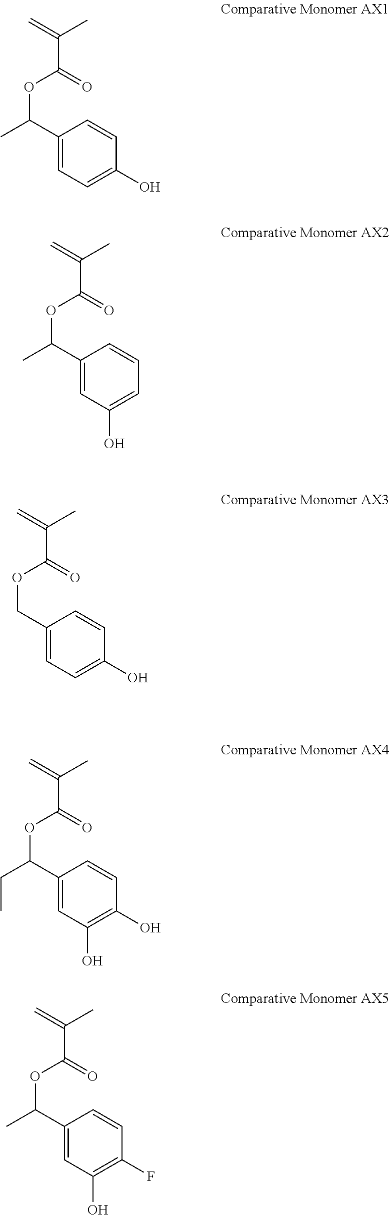 [SMILES: C=C(C)C(=O)OC(C)c1ccc(O)cc1 ; C=C(C)C(=O)OC(C)c1cccc(O)c1 ; C=C(C)C(=O)OCc1ccc(O)cc1 ; C=C(C)C(=O)OC(CC)c1ccc(O)c(O)c1 ; C=C(C)C(=O)OC(C)c1ccc(F)c(O)c1]

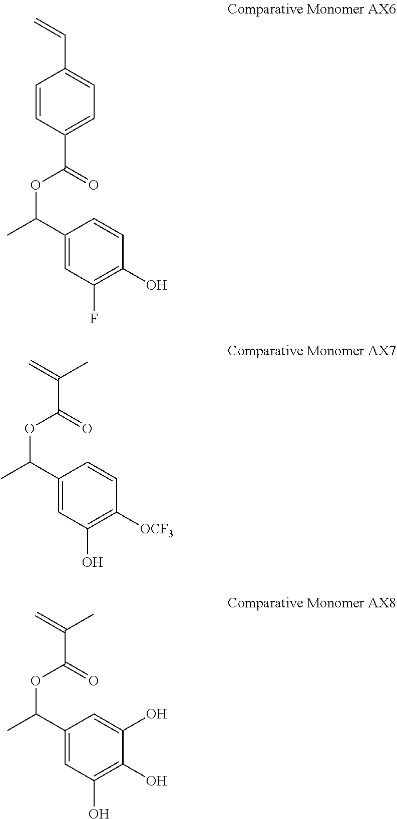

[2] Synthesis of Polymer Among monomers used for synthesizing a polymer, the following monomers were used as monomers other than the monomers A1 to A10 and comparative monomers AX1 to AX8.

### Monomers a1 and a2

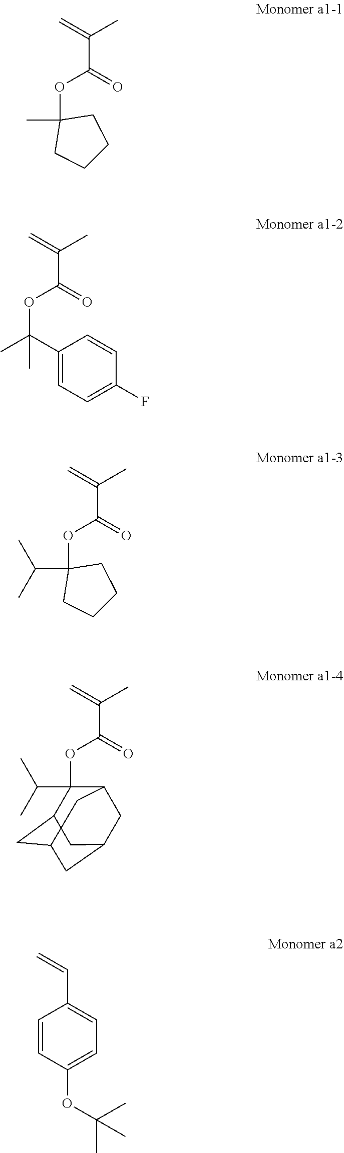 [SMILES: C=C(C)C(=O)OC1(C)CCCC1 ; C=C(C)C(=O)OC(C)(C)c1ccc(F)cc1 ; C=C(C)C(=O)OC1(C(C)C)CCCC1 ; C=C(C)C(=O)OC1(C(C)C)C2CC3CC(C2)CC1C3 ; C=Cc1ccc(OC(C)(C)C)cc1]

### Monomer B

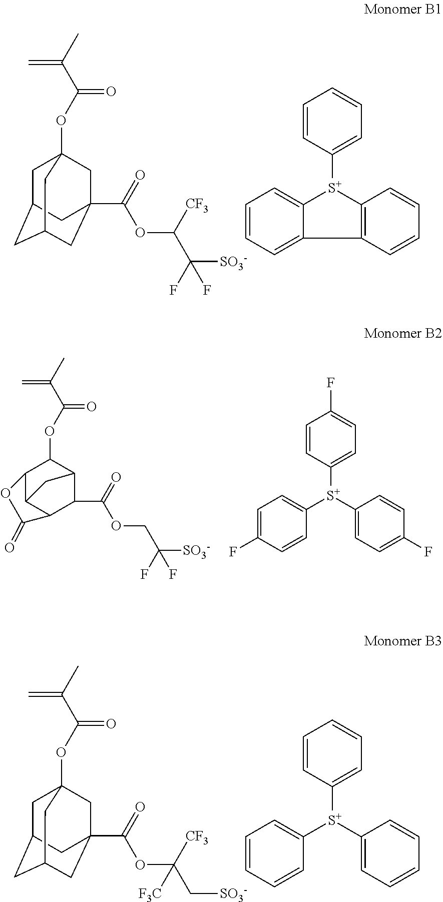

### Monomer C

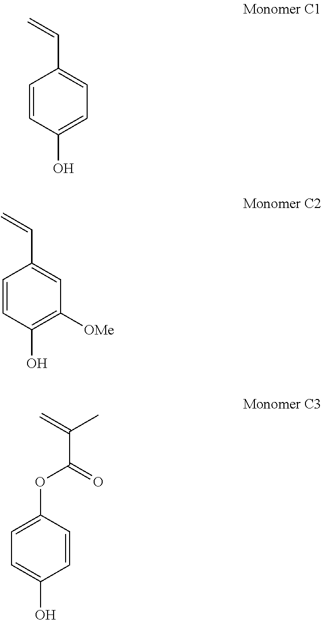

### Monomer D

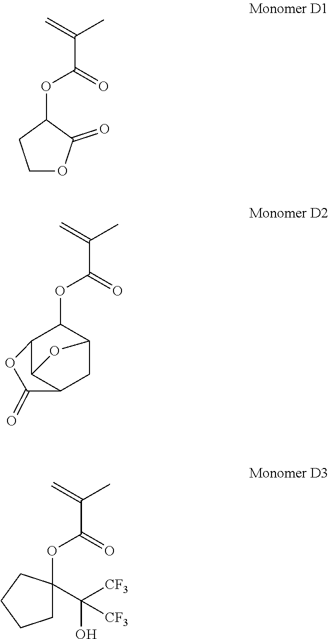 [SMILES: C=C(C)C(=O)OC1CCOC1=O ; C=C(C)C(=O)OC1C2CC3C(=O)OC1C3O2 ; C=C(C)C(=O)OC1(C(O)(C(F)(F)F)C(F)(F)F)CCCC1]

### [Synthesis of Polymer P-1]

Under a nitrogen atmosphere, the monomer A1 (50.1 g), the monomer a1-1 (22.3 g), the monomer B1 (48.7 g), 3.80 g of V-601 (manufactured by Wako Pure Chemical Industries, Ltd.) as the polymerization initiator, and 225 g of MEK were added into a flask to prepare a monomer-polymerization initiator solution. Into another flask with a nitrogen atmosphere, 75 g of MEK was added to heated to 80° C. with stirring, and then the monomer-polymerization initiator solution was added dropwise over 4 hours. After the dropwise addition, the polymerization liquid was further stirred for 2 hours with maintaining the temperature at 80° C., and then cooled to a room temperature. The obtained polymerization liquid was added dropwise to 2,000 g of vigorously stirred hexane, and a precipitated polymer was filtered. Thereafter, the obtained polymer was washed twice with 600 g of hexane, and then dried in vacuo at 50° C. for 20 hours to obtain a white powder polymer P-1 (98.1 g, 98% yield). The polymer P-1 had Mw of 10,000 and Mw/Mn of 2.03. The Mw is a polystyrene-converted measurement value by GPC using DMF as a solvent.

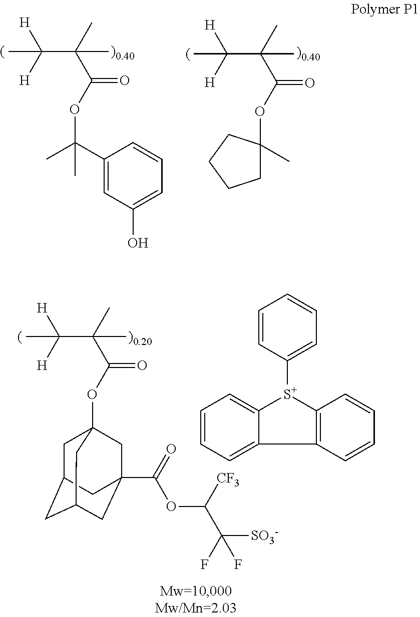

### [Syntheses of Polymers P-2 to P-20 and Comparative Polymers CP-1 to CP-20]

Polymers shown in Tables 1 and 2 were produced in the same manner as the polymer P-1 except that a kind and blending ratio of each monomer were changed.

TABLE 1

| | Unit | Introduction | Unit | Introduction | Unit | Introduction | Unit | Introduction | Unit | Introduction | | |
|---|---|---|---|---|---|---|---|---|---|---|---|---|
| Polymer | A | rate (mol %) | a | rate (mol %) | B | rate (mol %) | C | rate (mol %) | D | rate (mol %) | Mw | Mw/Mn |
| P-1 | A1 | 40 | a1-1 | 40 | B1 | 20 | — | — | — | — | 10000 | 2.03 |
| P-2 | A1 | 40 | a1-1 | 50 | B1 | 10 | — | — | — | — | 10400 | 1.98 |
| P-3 | A2 | 40 | a1-1 | 40 | B1 | 20 | — | — | — | — | 10800 | 1.99 |
| P-4 | A3 | 40 | a1-1 | 40 | B1 | 20 | — | — | — | — | 10600 | 2.00 |
| P-5 | A4 | 40 | a1-1 | 40 | B1 | 20 | — | — | — | — | 10900 | 2.01 |
| P-6 | A5 | 40 | a1-1 | 40 | B1 | 20 | — | — | — | — | 10100 | 1.98 |
| P-7 | A6 | 40 | a1-1 | 40 | B1 | 20 | — | — | — | — | 10300 | 1.97 |
| P-8 | A7 | 40 | a1-1 | 40 | B1 | 20 | — | — | — | — | 10700 | 2.01 |
| P-9 | A8 | 40 | a1-1 | 40 | B1 | 20 | — | — | — | — | 10300 | 2.03 |
| P-10 | A9 | 40 | a1-1 | 40 | B1 | 20 | — | — | — | — | 11000 | 1.96 |
| P-11 | A10 | 40 | a1-1 | 40 | B1 | 20 | — | — | — | — | 11100 | 2.01 |
| P-12 | A1 | 20 | a1-1 | 40 | B1 | 20 | C1 | 20 | — | — | 10900 | 1.95 |
| P-13 | A1 | 25 | a1-2 | 40 | B1 | 15 | C1 | 20 | — | — | 10800 | 1.99 |
| P-14 | A1 | 25 | a1-3 | 40 | B1 | 15 | C1 | 20 | — | — | 10500 | 1.96 |
| P-15 | A2 | 20 | a1-2 | 40 | B2 | 20 | C3 | 20 | — | — | 10800 | 2.00 |
| P-16 | A4 | 20 | a1-2 | 40 | B3 | 20 | C1 | 20 | — | — | 10700 | 1.97 |
| P-17 | A6 | 25 | a1-2 | 45 | B1 | 10 | C2 | 20 | — | — | 10200 | 2.01 |
| P-18 | A10 | 20 | a1-1 | 10 | B1 | 20 | C3 | 20 | — | — | 10600 | 2.04 |
| | | | a2 | 30 | | | | | | | | |
| P-19 | A6 | 25 | a1-2 | 25 | B1 | 15 | C3 | 15 | D2 | 20 | 10800 | 1.98 |
| P-20 | A9 | 15 | a1-2 | 45 | B1 | 15 | C3 | 15 | D3 | 10 | 10300 | 1.96 |

TABLE 2

| | Unit | Introduction | Unit | Introduction | Unit | Introduction | Unit | Introduction | Unit | Introduction | | |
|---|---|---|---|---|---|---|---|---|---|---|---|---|
| Polymer | A | rate (mol %) | a | rate (mol %) | B | rate (mol %) | C | rate (mol %) | D | rate (mol %) | Mw | Mw/Mn |
| CP-1 | AX1 | 40 | a1-1 | 40 | B1 | 20 | — | — | — | — | 10500 | 1.97 |
| CP-2 | AX2 | 40 | a1-1 | 40 | B1 | 20 | — | — | — | — | 9900 | 1.96 |
| CP-3 | AX3 | 40 | a1-1 | 40 | B1 | 20 | — | — | — | — | 10200 | 2.01 |
| CP-4 | AX4 | 40 | a1-1 | 40 | B1 | 20 | — | — | — | — | 10100 | 1.99 |
| CP-5 | AX5 | 40 | a1-1 | 40 | B1 | 20 | — | — | — | — | 10400 | 1.98 |
| CP-6 | AX6 | 40 | a1-1 | 40 | B1 | 20 | — | — | — | — | 10800 | 2.02 |
| CP-7 | AX7 | 40 | a1-1 | 40 | B1 | 20 | — | — | — | — | 10100 | 2.04 |
| CP-8 | AX8 | 40 | a1-1 | 40 | B1 | 20 | — | — | — | — | 10200 | 1.99 |
| CP-9 | AX2 | 20 | a1-1 | 40 | B1 | 20 | C1 | 20 | — | — | 9800 | 1.98 |
| CP-10 | — | — | a1-1 | 55 | B1 | 15 | C1 | 30 | — | — | 10300 | 2.03 |
| CP-11 | — | — | a1-3 | 55 | B2 | 15 | C1 | 30 | — | — | 10400 | 2.01 |
| CP-12 | — | — | a1-3 | 55 | B3 | 15 | C3 | 30 | — | — | 10600 | 1.99 |
| CP-13 | AX1 | 66 | — | — | — | — | C1 | 34 | — | — | 6600 | 1.97 |
| CP-14 | AX1 | 22 | a1-3 | 22 | — | — | C1 | 34 | — | — | 8400 | 1.97 |
| | | | a1-4 | 22 | | | | | | | | |
| CP-15 | AX1 | 22 | a1-3 | 22 | — | — | C3 | 34 | — | — | 8800 | 1.99 |
| | | | a1-4 | 22 | | | | | | | | |
| CP-16 | AX1 | 56 | — | — | — | — | — | — | D1 | 44 | 19000 | 2.01 |
| CP-17 | AX4 | 16 | a1-3 | 32 | — | — | C1 | 24 | — | — | 8900 | 1.96 |
| | | | a1-4 | 28 | | | | | | | | |
| CP-18 | AX8 | 16 | a1-3 | 32 | — | — | C1 | 24 | — | — | 9200 | 2.01 |
| | | | a1-4 | 28 | | | | | | | | |
| CP-19 | AX3 | 35 | a1-3 | 24 | B1 | 3 | — | — | D1 | 3 | 10200 | 1.98 |
| | | | a1-4 | 35 | | | | | | | | |
| CP-20 | AX3 | 18 | a1-3 | 24 | — | — | C1 | 20 | D1 | 3 | 9300 | 1.99 |
| | | | a1-4 | 35 | | | | | | | | |

### [3] Preparation of Resist Composition

### Examples 1-1 to 1-20 and Comparative Examples 1-1 to 1-20

Prepared was a solution of each of the inventive polymers (P-1 to P-20), the comparative polymers (CP-1 to CP-20), photoacid generators (PAG-1 and PAG-2), and quenchers (SQ-1 to SQ-3 and AQ-1) at a composition shown in the following Tables 3 and 4, and dissolved FC-4430, manufactured 3M Company, as a surfactant at 100 ppm. The prepared solution was filtered with a filter made of Teflon® with 0.2 μm to prepare a resist composition.

In Tables 3 and 4, each component is as follows.

Organic solvent 1: PGMEA (propylene glycol monomethyl ether acetate)

Organic solvent 2: DAA (diacetone alcohol)

Photoacid generator: PAG-1 and PAG-2

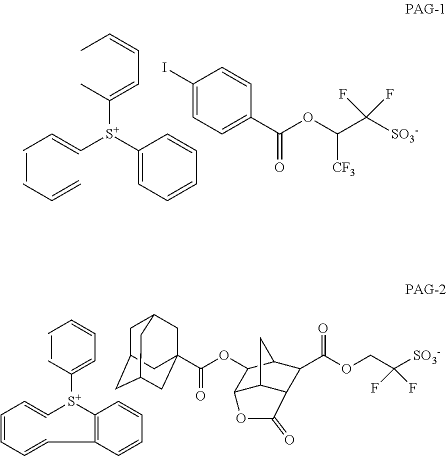

Quencher: SQ-1 to SQ-3 and AQ-1

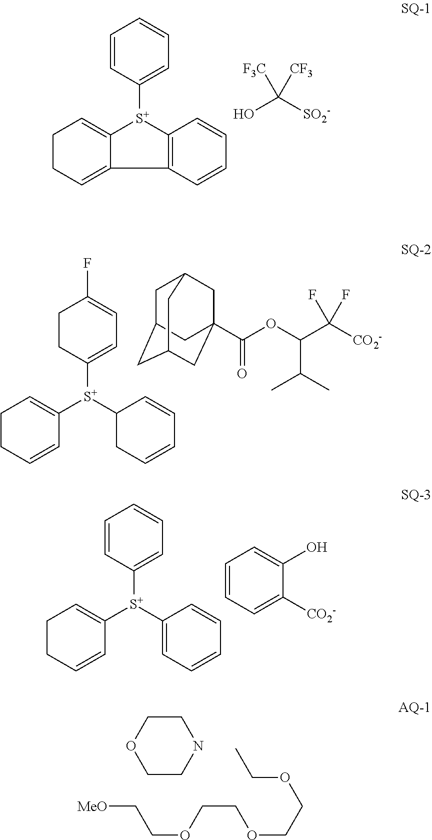

TABLE 3

| | | | Photoacid | | | |
|---|---|---|---|---|---|---|
| | Resist | Base resin | generator | Quencher | Solvent 1 | Solvent 2 |
| | composition | (parts by mass) | (parts by mass) | (parts by mass) | (parts by mass) | (parts by mass) |
| Example | R-1 | P-1 (80) | — | SQ-1 (7.8) | PGMEA | DAA (900) |
| 1-1 | | | | | (2,200) | |
| Example | R-2 | P-2 (80) | PAG-1 (14) | SQ-2 (7.8) | PGMEA | DAA (900) |
| 1-2 | | | | | (2,200) | |
| Example | R-3 | P-3 (80) | — | SQ-1 (7.8) | PGMEA | DAA (900) |
| 1-3 | | | | | (2,200) | |
| Example | R-4 | P-4 (80) | — | SQ-1 (7.8) | PGMEA | DAA (900) |
| 1-4 | | | | | (2,200) | |
| Example | R-5 | P-5 (80) | — | SQ-1 (7.8) | PGMEA | DAA (900) |
| 1-5 | | | | | (2,200) | |
| Example | R-6 | P-6 (80) | — | SQ-1 (7.8) | PGMEA | DAA (900) |
| 1-6 | | | | | (2,200) | |
| Example | R-7 | P-7 (80) | — | SQ-3 (8.0) | PGMEA | DAA (900) |
| 1-7 | | | | | (2,200) | |
| Example | R-8 | P-8 (80) | — | SQ-1 (7.8) | PGMEA | DAA (900) |
| 1-8 | | | | | (2,200) | |
| Example | R-9 | P-9 (80) | — | SQ-1 (7.8) | PGMEA | DAA (900) |
| 1-9 | | | | | (2,200) | |
| Example | R-10 | P-10 (80) | — | SQ-2 (8.2) | PGMEA | DAA (900) |
| 1-10 | | | | | (2,200) | |
| Example | R-11 | P-11 (80) | — | SQ-1 (7.8) | PGMEA | DAA (900) |
| 1-11 | | | | | (2,200) | |
| Example | R-12 | P-12 (80) | — | SQ-1 (7.8) | PGMEA | DAA (900) |
| 1-12 | | | | | (2,200) | |
| Example | R-13 | P-13 (80) | — | SQ-1 (7.8) | PGMEA | DAA (900) |
| 1-13 | | | | | (2,200) | |
| Example | R-14 | P-14 (80) | — | SQ-1 (7.8) | PGMEA | DAA (900) |
| 1-14 | | | | | (2,200) | |
| Example | R-15 | P-15 (80) | — | SQ-1 (4.8) | PGMEA | DAA (900) |
| 1-15 | | | | AQ-1 (3.0) | (2,200) | |
| Example | R-16 | P-16 (80) | — | SQ-2 (7.6) | PGMEA | DAA (900) |
| 1-16 | | | | | (2,200) | |
| Example | R-17 | P-17 (80) | PAG-2 (16) | SQ-1 (7.8) | PGMEA | DAA (900) |
| 1-17 | | | | | (2,200) | |
| Example | R-18 | P-18 (80) | — | SQ-3 (8.1) | PGMEA | DAA (900) |
| 1-18 | | | | | (2,200) | |
| Example | R-19 | P-19 (80) | — | SQ-1 (7.8) | PGMEA | DAA (900) |
| 1-19 | | | | | (2,200) | |
| Example | R-20 | P-20 (80) | — | SQ-3 (7.8) | PGMEA | DAA (900) |
| 1-20 | | | | | (2,200) | |

TABLE 4

| | | | Photoacid | | | |
|---|---|---|---|---|---|---|
| | Resist | Base resin | generator | Quencher | Solvent 1 | Solvent 2 |
| | composition | (parts by mass) | (parts by mass) | (parts by mass) | (parts by mass) | (parts by mass) |
| Comparative | CR-1 | CP-1 | — | SQ-1 | PGMEA | DAA (900) |
| Example | | (80) | | (7.8) | (1,400) | |
| 1-1 | | | | | | |
| Comparative | CR-2 | CP-2 | — | SQ-2 | PGMEA | DAA (900) |
| Example | | (80) | | (7.8) | (1,400) | |
| 1-2 | | | | | | |
| Comparative | CR-3 | CP-3 | — | SQ-1 | PGMEA | DAA (900) |
| Example | | (80) | | (7.8) | (1,400) | |
| 1-3 | | | | | | |
| Comparative | CR-4 | CP-4 | — | SQ-1 | PGMEA | DAA (900) |
| Example | | (80) | | (7.8) | (1,400) | |
| 1-4 | | | | | | |
| Comparative | CR-5 | CP-5 | — | SQ-2 | PGMEA | DAA (900) |
| Example | | (80) | | (8.2) | (1,400) | |
| 1-5 | | | | | | |
| Comparative | CR-6 | CP-6 | — | SQ-1 | PGMEA | DAA (900) |
| Example | | (80) | | (7.8) | (1,400) | |
| 1-6 | | | | | | |
| Comparative | CR-7 | CP-7 | — | SQ-3 | PGMEA | DAA (900) |
| Example | | (80) | | (8.2) | (1,400) | |
| 1-7 | | | | | | |
| Comparative | CR-8 | CP-8 | — | SQ-1 | PGMEA | DAA (900) |
| Example | | (80) | | (7.8) | (1,400) | |
| 1-8 | | | | | | |
| Comparative | CR-9 | CP-9 | — | SQ-1 | PGMEA | DAA (900) |
| Example | | (80) | | (7.8) | (1,400) | |
| 1-9 | | | | | | |
| Comparative | CR-10 | CP-10 | — | SQ-1 | PGMEA | DAA (900) |
| Example | | (80) | | (7.8) | (1,400) | |
| 1-10 | | | | | | |
| Comparative | CR-11 | CP-11 | — | SQ-3 | PGMEA | DAA (900) |
| Example | | (80) | | (7.6) | (1,400) | |
| 1-11 | | | | | | |
| Comparative | CR-12 | CP-12 | — | SQ-1 | PGMEA | DAA (900) |
| Example | | (80) | | (7.8) | (1,400) | |
| 1-12 | | | | | | |
| Comparative | CR-13 | CP-13 | PAG-1 | AQ-1 | PGMEA | DAA (900) |
| Example | | (80) | (20) | (7.6) | (1,400) | |
| 1-13 | | | | | | |
| Comparative | CR-14 | CP-14 | PAG-2 | SQ-2 | PGMEA | DAA (900) |
| Example | | (80) | (24) | (8.4) | (1,400) | |
| 1-14 | | | | | | |
| Comparative | CR-15 | CP-15 | PAG-1 | SQ-1 | PGMEA | DAA (900) |
| Example | | (80) | (20) | (7.8) | (1,400) | |
| 1-15 | | | | | | |
| Comparative | CR-16 | CP-16 | PAG-1 | AQ-1 | PGMEA | DAA (900) |
| Example | | (80) | (20) | (8.0) | (1,400) | |
| 1-16 | | | | | | |
| Comparative | CR-17 | CP-17 | PAG-2 | SQ-2 | PGMEA | DAA (900) |
| Example | | (80) | (22) | (7.6) | (1,400) | |
| 1-17 | | | | | | |
| Comparative | CR-18 | CP-18 | PAG-1 | AQ-1 | PGMEA | DAA (900) |
| Example | | (80) | (20) | (7.8) | (1,400) | |
| 1-18 | | | | | | |
| Comparative | CR-19 | CP-19 | — | SQ-2 | PGMEA | DAA (900) |
| Example | | (80) | | (8.2) | (1,400) | |
| 1-19 | | | | | | |
| Comparative | CR-20 | CP-20 | PAG-1 | SQ-1 | PGMEA | DAA (900) |
| Example | | (80) | (24) | (7.8) | (1,400) | |
| 1-20 | | | | | | |

### [4] EUV Lithography Evaluation (1)

### Examples 2-1 to 2-20 and Comparative Examples 2-1 to 2-20

Each of the chemically amplified resist compositions (R-1 to R-20 and CR-1 to CR-20) shown in Tables 3 and 4 was spin-applied on a Si substrate on which a silicon-containing spin-on hard mask SHB-A940, manufactured by Shin-Etsu Chemical Co., Ltd. (silicon content of 43 mass %), was formed with 20 nm in film thickness. Then, the substrate was prebaked at 100° C. for 60 seconds using a hot plate to produce a resist film with 50 nm in film thickness. This resist film was exposed using an EUV scanner NXE3300 (NA 0.33, σ 0.9/0.6, dipole illumination), manufactured by ASML Holding N.V. The exposure was performed with a LS pattern with 18 nm on wafer size and 36 nm in pitch, and with changing an exposure dose and focus of extreme ultraviolet ray with 13.5 nm in wavelength (exposure dose pitch: 1 mJ/cm², focus pitch: 0.020 μm). After the exposure, PEB was performed at a temperature shown in Tables 5 and 6 for 60 seconds. Thereafter, puddle development with a 2.38 mass % aqueous TMAH solution for 30 seconds, rinse with a surfactant-containing rinse material, and spin-drying were performed to obtain a positive pattern. The LS pattern after the development was observed with a length-measurement SEM (CG6300), manufactured by Hitachi High-Technologies Corporation, to evaluate sensitivity, EL, LWR, and DOF in accordance with the following methods. Tables 5 and 6 show the results.

### [Sensitivity Evaluation]

An optimum exposure dose Eₒₚ(mJ/cm²) to yield the LS pattern with 18 nm in line width and 36 nm in pitch was determined to specify this value as a sensitivity.

### [EL Evaluation]

From exposure doses to form the LS pattern within a range of ±10% of 18 nm space width (16.2 to 19.8 nm), EL (unit: %) was determined by the following equation. The larger the EL value, the better the performance.

EL (%)=(|E₁−E₂|/Eₒₚ)×100
E₁: An optimum exposure dose to yield a LS pattern with 16.2 nm in line width and 36 nm in pitch.
E₂: An optimum exposure dose to yield a LS pattern with 19.8 nm in line width and 36 nm in pitch.
Eₒₚ: An optimum exposure dose to yield the LS pattern with 18 nm in line width and 36 nm in pitch.

### [LWR Evaluation]

In the LS pattern obtained by irradiation at Eₒₚ, sizes at 10 positions in the longitudinal direction of the line were measured. From the results, a tripled value (3σ) of a standard variation (σ) was determined as LWR. A smaller LWR value can yield a pattern with smaller roughness and uniform line width.

### [DOF Evaluation]

As evaluation of depth of focus, determined was a focus range to form the LS pattern within a range of i 10% of 18 nm size (16.2 to 19.8 nm). A larger DOF value indicates wider depth of focus, and has wider process margin of the resist pattern.

TABLE 5

| | | | Optimum | | | |
|---|---|---|---|---|---|---|
| | | PEB | exposure | | | |
| | Resist | temperature | dose | EL | LWR | DOF |
| | composition | (° C.) | (mJ/cm2) | (%) | (nm) | (nm) |
| Example | R-1 | 95 | 40 | 19 | 2.6 | 120 |
| 2-1 | | | | | | |
| Example | R-2 | 95 | 40 | 18 | 2.7 | 110 |
| 2-2 | | | | | | |
| Example | R-3 | 95 | 41 | 18 | 2.9 | 120 |
| 2-3 | | | | | | |
| Example | R-4 | 95 | 42 | 17 | 2.9 | 110 |
| 2-4 | | | | | | |
| Example | R-5 | 95 | 41 | 19 | 2.7 | 110 |
| 2-5 | | | | | | |
| Example | R-6 | 90 | 40 | 18 | 2.8 | 110 |
| 2-6 | | | | | | |
| Example | R-7 | 90 | 42 | 18 | 2.8 | 120 |
| 2-7 | | | | | | |
| Example | R-8 | 95 | 40 | 19 | 3.0 | 110 |
| 2-8 | | | | | | |
| Example | R-9 | 90 | 41 | 17 | 3.1 | 120 |
| 2-9 | | | | | | |
| Example | R-10 | 90 | 41 | 17 | 2.8 | 110 |
| 2-10 | | | | | | |
| Example | R-11 | 95 | 41 | 18 | 2.6 | 100 |
| 2-11 | | | | | | |
| Example | R-12 | 90 | 42 | 17 | 2.9 | 110 |
| 2-12 | | | | | | |
| Example | R-13 | 90 | 41 | 19 | 3.1 | 120 |
| 2-13 | | | | | | |
| Example | R-14 | 95 | 40 | 19 | 2.8 | 120 |
| 2-14 | | | | | | |
| Example | R-15 | 90 | 42 | 18 | 3.0 | 110 |
| 2-15 | | | | | | |
| Example | R-16 | 95 | 44 | 17 | 2.9 | 100 |
| 2-16 | | | | | | |
| Example | R-17 | 90 | 42 | 18 | 3.1 | 120 |
| 2-17 | | | | | | |
| Example | R-18 | 95 | 41 | 19 | 2.8 | 110 |
| 2-18 | | | | | | |
| Example | R-19 | 95 | 42 | 18 | 3.0 | 110 |
| 2-19 | | | | | | |
| Example | R-20 | 90 | 42 | 17 | 2.8 | 100 |
| 2-20 | | | | | | |

TABLE 6

| | | | Optimum | | | |
|---|---|---|---|---|---|---|
| | | PEB | exposure | | | |
| | Resist | temperature | dose | EL | LWR | DOF |
| | composition | (° C.) | (mJ/cm2) | (%) | (nm) | (nm) |
| Comparative | CR-1 | 100 | 48 | 17 | 3.5 | 80 |
| Example 2-1 | | | | | | |
| Comparative | CR-2 | 105 | 47 | 18 | 3.6 | 90 |
| Example 2-2 | | | | | | |
| Comparative | CR-3 | 110 | 49 | 16 | 3.9 | 70 |
| Example 2-3 | | | | | | |
| Comparative | CR-4 | 100 | 48 | 17 | 3.5 | 90 |
| Example 2-4 | | | | | | |
| Comparative | CR-5 | 100 | 49 | 16 | 3.3 | 90 |
| Example 2-5 | | | | | | |
| Comparative | CR-6 | 105 | 50 | 17 | 3.4 | 90 |
| Example 2-6 | | | | | | |
| Comparative | CR-7 | 100 | 49 | 18 | 3.2 | 80 |
| Example 2-7 | | | | | | |
| Comparative | CR-8 | 105 | 48 | 16 | 3.5 | 70 |
| Example 2-8 | | | | | | |
| Comparative | CR-9 | 100 | 49 | 17 | 3.6 | 90 |
| Example 2-9 | | | | | | |
| Comparative | CR-10 | 90 | 43 | 17 | 3.1 | 80 |
| Example 2-10 | | | | | | |
| Comparative | CR-11 | 95 | 42 | 16 | 3.2 | 80 |
| Example 2-11 | | | | | | |
| Comparative | CR-12 | 90 | 43 | 18 | 3.1 | 90 |
| Example 2-12 | | | | | | |
| Comparative | CR-13 | 100 | 49 | 17 | 3.4 | 80 |
| Example 2-13 | | | | | | |
| Comparative | CR-14 | 105 | 48 | 16 | 3.5 | 70 |
| Example 2-14 | | | | | | |
| Comparative | CR-15 | 100 | 49 | 17 | 3.9 | 70 |
| Example 2-15 | | | | | | |
| Comparative | CR-16 | 105 | 48 | 15 | 3.4 | 70 |
| Example 2-16 | | | | | | |
| Comparative | CR-17 | 100 | 49 | 18 | 3.4 | 60 |
| Example 2-17 | | | | | | |
| Comparative | CR-18 | 105 | 50 | 17 | 3.3 | 80 |
| Example 2-18 | | | | | | |
| Comparative | CR-19 | 100 | 51 | 18 | 3.7 | 90 |
| Example 2-19 | | | | | | |
| Comparative | CR-20 | 100 | 49 | 16 | 3.9 | 80 |
| Example 2-20 | | | | | | |

From the results shown in Tables 5 and 6, the resist compositions of Examples entirely have higher EL values and DOF values than Comparative Examples, and tend to have smaller optimum exposure doses and LWR values. Therefore, it has been confirmed that the resist composition using the inventive polymer has good sensitivity and performance, small roughness on the formed pattern, and wide depth of focus, and thereby has excellent lithography performances.

### [5] EUV Lithography Evaluation (2)

### Examples 3-1 to 3-20 and Comparative Examples 3-1 to 3-20

Each of the chemically amplified resist compositions (R-1 to R-20 and CR-1 to CR-20) shown in Tables 3 and 4 was spin-applied on a Si substrate on which a silicon-containing spin-on hard mask SHB-A940, manufactured by Shin-Etsu Chemical Co., Ltd. (silicon content of 43 mass %), was formed with 20 nm in film thickness. Then, the substrate was prebaked at 105° C. for 60 seconds using a hot plate to produce a resist film with 50 nm in film thickness. This resist film was exposed with extreme ultraviolet ray with 13.5 nm in wavelength using an EUV scanner NXE3400 (NA 0.33, σ 0.9/0.6, quadrupole illumination, 46 nm in pitch on wafer size, hole pattern mask with +20% bias), manufactured by ASML Holding N.V. Then, PEB was performed at a temperature shown in Tables 7 and 8 for 60 seconds using a hot plate. Thereafter, development was performed with a 2.38 mass % TMAH aqueous solution for 30 seconds to form a hole pattern with 23 nm in size.

Using a length-measurement SEM (CG6300), manufactured by Hitachi High-Technologies Corporation, an exposure dose when the hole size was formed with 23 nm was measured to specify this exposure dose as a sensitivity (optimum exposure dose). Sizes of 50 holes were measured in this time, and a tripled value (3σ) of a standard variation (σ) calculated from the results was determined as size variation (CDU). Tables 7 and 8 show the results.

TABLE 7

| | | PEB | Optimum | |
|---|---|---|---|---|
| | Resist | temperature | exposure dose | CDU |
| | composition | (° C.) | (mJ/cm2) | (nm) |
| Example 3-1 | R-1 | 90 | 25 | 2.3 |
| Example 3-2 | R-2 | 90 | 25 | 2.2 |
| Example 3-3 | R-3 | 90 | 26 | 2.4 |
| Example 3-4 | R-4 | 90 | 27 | 2.5 |
| Example 3-5 | R-5 | 90 | 26 | 2.6 |
| Example 3-6 | R-6 | 85 | 25 | 2.4 |
| Example 3-7 | R-7 | 85 | 26 | 2.3 |
| Example 3-8 | R-8 | 90 | 27 | 2.6 |
| Example 3-9 | R-9 | 90 | 25 | 2.5 |
| Example 3-10 | R-10 | 85 | 26 | 2.4 |
| Example 3-11 | R-11 | 90 | 27 | 2.6 |
| Example 3-12 | R-12 | 85 | 25 | 2.5 |
| Example 3-13 | R-13 | 90 | 26 | 2.6 |
| Example 3-14 | R-14 | 90 | 25 | 2.6 |
| Example 3-15 | R-15 | 90 | 26 | 2.6 |
| Example 3-16 | R-16 | 85 | 26 | 2.4 |
| Example 3-17 | R-17 | 90 | 27 | 2.7 |
| Example 3-18 | R-18 | 85 | 26 | 2.5 |
| Example 3-19 | R-19 | 90 | 26 | 2.6 |
| Example 3-20 | R-20 | 90 | 26 | 2.6 |

TABLE 8

| | | PEB | Optimum | |
|---|---|---|---|---|
| | Resist | temperature | exposure dose | CDU |
| | composition | (° C.) | (mJ/cm2) | (nm) |
| Comparative | CR-1 | 95 | 28 | 3.2 |
| Example 3-1 | | | | |
| Comparative | CR-2 | 95 | 27 | 3.1 |
| Example 3-2 | | | | |
| Comparative | CR-3 | 105 | 28 | 3.9 |
| Example 3-3 | | | | |
| Comparative | CR-4 | 90 | 26 | 3.3 |
| Example 3-4 | | | | |
| Comparative | CR-5 | 90 | 28 | 3.4 |
| Example 3-5 | | | | |
| Comparative | CR-6 | 95 | 29 | 3.1 |
| Example 3-6 | | | | |
| Comparative | CR-7 | 95 | 27 | 3.2 |
| Example 3-7 | | | | |
| Comparative | CR-8 | 95 | 45 | 3.5 |
| Example 3-8 | | | | |
| Comparative | CR-9 | 90 | 25 | 3.3 |
| Example 3-9 | | | | |
| Comparative | CR-10 | 90 | 26 | 3.1 |
| Example 3-10 | | | | |
| Comparative | CR-11 | 90 | 34 | 3.1 |
| Example 3-11 | | | | |
| Comparative | CR-12 | 100 | 33 | 3.5 |
| Example 3-12 | | | | |
| Comparative | CR-13 | 100 | 33 | 3.4 |
| Example 3-13 | | | | |
| Comparative | CR-14 | 100 | 34 | 3.6 |
| Example 3-14 | | | | |
| Comparative | CR-15 | 100 | 35 | 3.7 |
| Example 3-15 | | | | |
| Comparative | CR-16 | 100 | 35 | 3.6 |
| Example 3-16 | | | | |
| Comparative | CR-17 | 100 | 35 | 3.6 |
| Example 3-17 | | | | |
| Comparative | CR-18 | 95 | 35 | 3.5 |
| Example 3-18 | | | | |
| Comparative | CR-19 | 100 | 35 | 3.4 |
| Example 3-19 | | | | |
| Comparative | CR-20 | 100 | 35 | 3.5 |
| Example 3-20 | | | | |

From the results shown in Tables 7 and 8, the resist compositions of Examples entirely tend to have smaller optimum exposure doses and CDU values than Comparative Examples. Therefore, it has been confirmed that the resist composition using the inventive polymer has good sensitivity and excellent in-plane uniformity of the pattern.

From the above, it has been shown that the present invention provides the polymer, the resist material, and the pattern forming method with high sensitivity, high resolution, and high contrast, and that can form a resist pattern having small variation in pattern width (LWR), small in-plane uniformity of the pattern (CDU), and wide process margin in the lithography being ultrafine processing technology using high energy ray.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A polymer to generate an acid by light exposure and to change in solubility in a developing liquid with an action of the acid, the polymer comprising:
a repeating unit represented by the following formula (A-1); and
a repeating unit represented by any one or more of the following formulae (B-1) to (B-4), 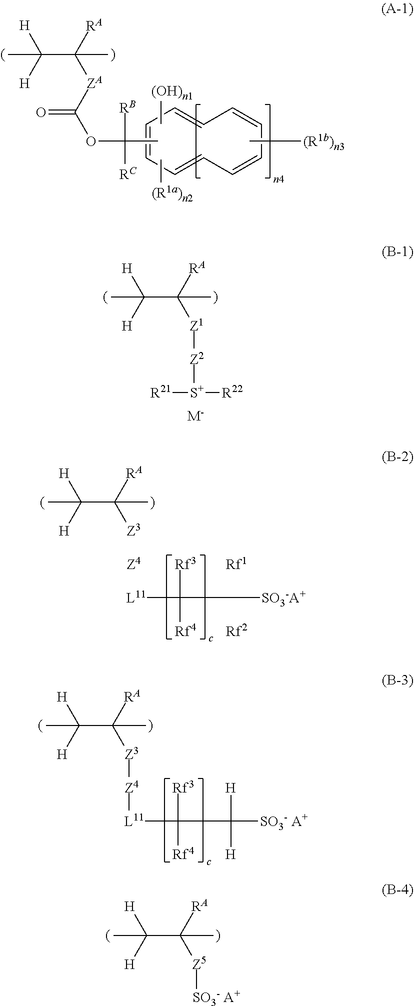
wherein R^{A} represents a hydrogen atom, a fluorine atom, a methyl group, or a trifluoromethyl group; Z^{A} represents a single bond, (main chain)-C(═O)—O—Z^{A1}—, or a phenylene group or a naphthylene group each of which may have an alkoxy group having 1 to 10 carbon atoms and optionally having a fluorine atom, or a halogen atom; Z^{A1} represents a linear, branched, or cyclic alkanediyl group having 1 to 20 carbon atoms, phenylene group, or naphthylene group optionally having a heteroatom, an alkoxy group having 1 to 10 carbon atoms and optionally having a fluorine atom, a hydroxy group, an ether bond, an ester bond, or a lactone ring; R^{B} and R^{C} each independently represents a linear, branched, or cyclic hydrocarbyl group having 1 to 10 carbon atoms and optionally having a heteroatom, R^{B} and R^{C} are optionally bonded to each other to form a cyclic structure; R^{1a} each independently represents any one of a halogen atom, a cyano group, an acyl group having 1 to 5 carbon atoms, an alkoxy group having 1 to 5 carbon atoms, a fluorine-containing alkyl group having 1 to 5 carbon atoms, or a fluorine-containing alkoxy group having 1 to 5 carbon atoms; R^{1b} each independently represents a linear, branched, or cyclic hydrocarbyl group having 1 to 10 carbon atoms and optionally having a heteroatom; n1 represents an integer of 1 or 2; n2 represents an integer of 0 to 2; n3 represents an integer of 0 to 5; and n4 represents an integer of 0 to 2;
Z¹ represents a single bond or a phenylene group;
Z² represents a single bond, —C(═O)—O—Z²¹—, —C(═O)—NH—Z²¹—, or —O—Z²¹—; Z²¹ represents an aliphatic hydrocarbylene group having 1 to 6 carbon atoms, a phenylene group, or a divalent group obtained by combining these groups, and Z²¹ optionally has a carbonyl group, an ester bond, an ether bond, or a hydroxy group;
Z³ represents a single bond, a phenylene group, a naphthylene group, or (main chain)-C(═O)—O—Z³¹—; Z³¹ represents an aliphatic hydrocarbylene group having 1 to 10 carbon atoms, or a phenylene group or a naphthylene group optionally having a hydroxy group, an ether bond, an ester bond, or a lactone ring;
Z⁴ represents a single bond, a methylene group, or —Z⁴¹—C(═O)—O—; Z⁴¹ represents a hydrocarbylene group having 1 to 20 carbon atoms and optionally having a heteroatom, an ether bond, or an ester bond;
Z⁵ represents a single bond, a methylene group, an ethylene group, a phenylene group, a fluorinated phenylene group, a phenylene group substituted with a trifluoromethyl group, —C(═O)—O—Z⁵¹—, —C(═O)—NH—Z⁵¹—, or —O—Z⁵¹—; Z⁵¹ represents an aliphatic hydrocarbylene group having 1 to 6 carbon atoms, a phenylene group, a fluorinated phenylene group, or a phenylene group substituted with a trifluoromethyl group, and Z⁵¹ optionally has a carbonyl group, an ester bond, an ether bond, or a hydroxy group;
R²¹ and R²² each independently represents a hydrocarbyl group having 1 to 20 carbon atoms and optionally having a heteroatom, and R²¹ and R²² are optionally bonded to each other to form a ring together with a sulfur atom to which R²¹ and R²² are bonded;
L¹¹ represents a single bond, an ether bond, an ester bond, a carbonyl group, a sulfonic acid ester bond, a carbonate bond, or a carbamate bond;
Rf¹ and Rf² each independently represents a fluorine atom or a fluorinated alkyl group having 1 to 6 carbon atoms;
Rf³ and Rf⁴ each independently represents a hydrogen atom, a fluorine atom, or a fluorinated alkyl group having 1 to 6 carbon atoms;
M⁻ represents a non-nucleophilic counterion;
A⁺ represents an onium cation; and
“c” represents an integer of 0 to 3.

2. The polymer according to claim 1, wherein the repeating unit represented by the formula (A-1) is a repeating unit represented by the following formula (A-2), 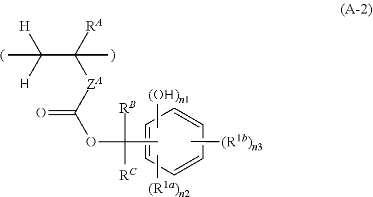
wherein R^{A}, Z^{A}, R^{B}, R^{C}, R^{1a}, R^{1b}, n1, n2, and n3 are same as the above.

3. The polymer according to claim 1, wherein R^{1a} in the formula (A-1) represents any one of a fluorine atom, a trifluoromethyl group, and a trifluoromethoxy group.

4. The polymer according to claim 2, wherein R^{1a} in the formula (A-1) represents any one of a fluorine atom, a trifluoromethyl group, and a trifluoromethoxy group.

5. The polymer according to claim 1, wherein A⁺ in the formulae (B-2) to (B-4) represents a cation represented by the following formula (cation-1) or (cation-2), 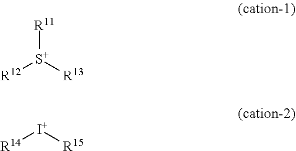
wherein R¹¹, R¹², and R¹³ each independently represents a linear, branched, or cyclic monovalent hydrocarbon group having 1 to 30 carbon atoms and optionally having a heteroatom, and any two of R¹¹, R¹², and R¹³ are optionally bonded to each other to form a ring together with a sulfur atom in the formula; and R¹⁴ and R¹⁵ each independently represents a linear, branched, or cyclic monovalent hydrocarbon group having 1 to 30 carbon atoms and optionally having a heteroatom.

6. The polymer according to claim 2, wherein A⁺ in the formulae (B-2) to (B-4) represents a cation represented by the following formula (cation-1) or (cation-2), 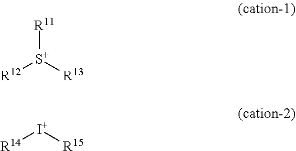
wherein R¹¹, R¹², and R¹³ each independently represents a linear, branched, or cyclic monovalent hydrocarbon group having 1 to 30 carbon atoms and optionally having a heteroatom, and any two of R¹¹, R¹², and R¹³ are optionally bonded to each other to form a ring together with a sulfur atom in the formula; and R¹⁴ and R¹⁵ each independently represents a linear, branched, or cyclic monovalent hydrocarbon group having 1 to 30 carbon atoms and optionally having a heteroatom.

7. The polymer according to claim 3, wherein A⁺ in the formulae (B-2) to (B-4) represents a cation represented by the following formula (cation-1) or (cation-2), 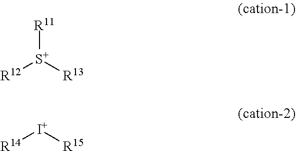
wherein R¹¹, R¹², and R¹³ each independently represents a linear, branched, or cyclic monovalent hydrocarbon group having 1 to 30 carbon atoms and optionally having a heteroatom, and any two of R¹¹, R¹², and R¹³ are optionally bonded to each other to form a ring together with a sulfur atom in the formula; and R¹⁴ and R¹⁵ each independently represents a linear, branched, or cyclic monovalent hydrocarbon group having 1 to 30 carbon atoms and optionally having a heteroatom.

8. The polymer according to claim 4, wherein A⁺ in the formulae (B-2) to (B-4) represents a cation represented by the following formula (cation-1) or (cation-2), 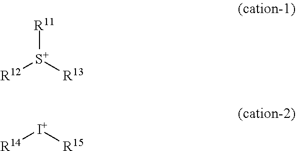
wherein R¹¹, R¹², and R¹³ each independently represents a linear, branched, or cyclic monovalent hydrocarbon group having 1 to 30 carbon atoms and optionally having a heteroatom, and any two of R¹¹, R¹², and R¹³ are optionally bonded to each other to form a ring together with a sulfur atom in the formula; and R¹⁴ and R¹⁵ each independently represents a linear, branched, or cyclic monovalent hydrocarbon group having 1 to 30 carbon atoms and optionally having a heteroatom.

9. The polymer according to claim 1, further comprising a repeating unit represented by the following formula (a-1) or (a-2), 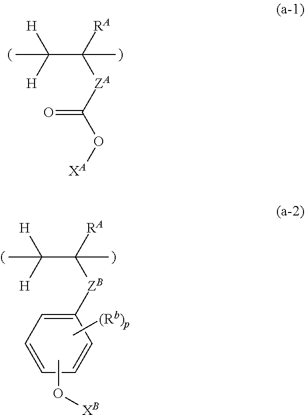
wherein R^{A} and Z^{A} are same as above; Z^{B} represents a single bond, (main chain)-C(═O)—O—, or an alkanediyl group having 1 to 10 carbon atoms and optionally having an ester group, an ether group, or a carbonyl group; R^{b} represents a linear, branched, or cyclic hydrocarbyl group having 1 to 20 carbon atoms and optionally having a heteroatom, a halogen atom, an alkoxy group optionally having a fluorine, or a cyano group; “p” represents an integer of 0 to 4; and X^{A} and X^{B} each independently represents an acid-labile group having no fluorine-containing aromatic ring.

10. The polymer according to claim 1, further comprising a repeating unit represented by the following formula (C-1), 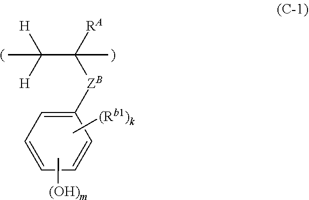
wherein R^{A} is same as above; Z^{B} represents a single bond, (main chain)-C(═O)—O—, or an alkanediyl group having 1 to 10 carbon atoms and optionally having an ester group, an ether group, or a carbonyl group; R^{b1} represents a halogen atom, a cyano group, a hydrocarbyl group having 1 to 20 carbon atoms and optionally having a heteroatom, a hydrocarbyloxy group having 1 to 20 carbon atoms and optionally having a heteroatom, a hydrocarbylcarbonyl group having 2 to 20 carbon atoms and optionally having a heteroatom, a hydrocarbylcarbonyloxy group having 2 to 20 carbon atoms and optionally having a heteroatom, or a hydrocarbyloxycarbonyl group having 2 to 20 carbon atoms and optionally having a heteroatom; “m” represents an integer of 1 to 4; “k” represents an integer of 0 to 3; and “m+k” represents an integer of 4 or less.

11. The polymer according to claim 1, further comprising a repeating unit represented by the following formula (D-1), 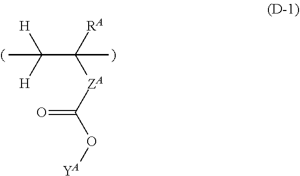
wherein R^{A} and Z^{A} are same as above; and Y^{A} represents a hydrogen atom or a polar group having at least one or more structures selected from a hydroxy group, a cyano group, a carbonyl group, a carboxy group, an ether bond, an ester bond, a sulfonic acid ester bond, a sulfonic acid amide bond, a carbonate bond, a lactone ring, a sultone ring, a sulfur atom, and a carboxylic anhydride.

12. A resist composition, comprising the polymer according to claim 1.

13. The resist composition according to claim 12, further comprising an organic solvent.

14. The resist composition according to claim 12, further comprising a photoacid generator other than a photoacid generator bonded to the polymer chain.

15. The resist composition according to claim 12, further comprising a quencher.

16. The resist composition according to claim 12, further comprising:
a surfactant insoluble or hardly soluble in water and soluble in an alkaline developing liquid; and/or
a surfactant insoluble or hardly soluble in water and an alkaline developing liquid.

17. A pattern forming method, comprising:
(i) a step of forming a resist film on a substrate using the resist composition according to claim 12;
(ii) a step of exposing the resist film with a high-energy ray; and
(iii) a step of developing the exposed resist film with a developing liquid.

18. The pattern forming method according to claim 17, wherein the high-energy ray in the step (ii) is i-line, KrF excimer laser light, ArF excimer laser light, electron beam, or extreme ultraviolet having a wavelength of 3 to 15 nm.

19. The pattern forming method according to claim 17, wherein the developing liquid in the step (iii) is an alkaline aqueous solution, and an exposed part is dissolved to obtain a positive pattern with undissolved not-exposure part.

20. The pattern forming method according to claim 17, wherein the developing liquid in the step (iii) is an organic solvent, and a non-exposed part is dissolved to obtain a negative pattern with undissolved exposure part.
